(19) United States
(12) Patent Application Publication
(10) Pub. No.: US 2016/0005979 A1
(43) Pub. Date: Jan. 7, 2016

(54) ORGANIC LIGHT-EMITTING DEVICE

(71) Applicant: SAMSUNG DISPLAY CO., LTD., Yongin-City (KR)

(72) Inventors: Seul-Ong KIM, Yongin-City (KR); Youn-Sun KIM, Yongin-City (KR); Dong-Woo SHIN, Yongin-City (KR); Jung-Sub LEE, Yongin-City (KR); Naoyuki ITO, Yongin-City (KR)

(21) Appl. No.: 14/530,342

(22) Filed: Oct. 31, 2014

(30) Foreign Application Priority Data
Jul. 2, 2014 (KR) 10-2014-0082525

(51) Int. Cl. H01L 51/00

(52) U.S. Cl. CPC H01L 51/0072; H01L 51/0067; H01L 51/0073; H01L 51/0052; H01L 51/0071; H01L 51/0074; H01L 51/508

(57) ABSTRACT

An organic light-emitting device including a first electrode; a second electrode; and an organic layer between the first electrode and the second electrode, wherein the organic layer includes at least one first material and at least one second material, the first material being represented by one of Formulae 1-1 and 1-2, below, and the second material being represented by Formula 2, below:

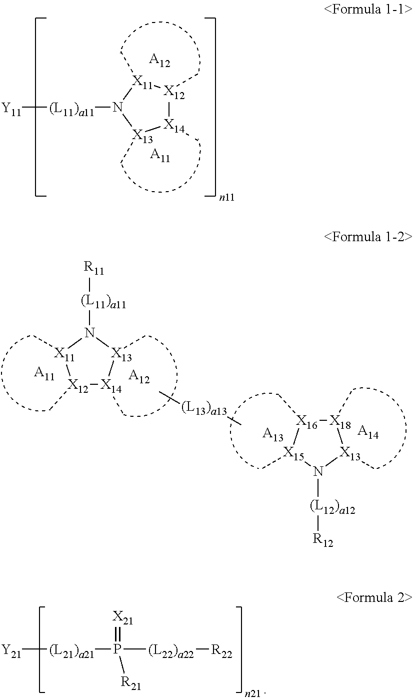

### CROSS-REFERENCE TO RELATED APPLICATION

Korean Patent Application No. 10-2014-0082525, filed on Jul. 2, 2014, in the Korean Intellectual Property Office, and entitled: “Organic Light-Emitting Device,” is incorporated by reference herein in its entirety.

### BACKGROUND

1. Field

Embodiments relate to an organic light-emitting device.

2. Description of the Related Art

Organic light emitting devices are self-emission devices that have wide viewing angles, high contrast ratios, short response times, and excellent brightness, driving voltage, and response speed characteristics, and produce full-color images.

The organic light-emitting device may include a first electrode on a substrate, and a hole transport region, an emission layer, an electron transport region, and a second electrode, which are sequentially on the first electrode. Holes provided from the first electrode may move toward the emission layer through the hole transport region, and electrons provided from the second electrode may move toward the emission layer through the electron transport region. Carriers, such as holes and electrons, may be recombined in the emission layer to produce excitons. The excitons may change from an excited state to a ground state, thereby generating light.

### SUMMARY

Embodiments are directed to an organic light-emitting device.

One or more embodiments include an organic light-emitting device including: a first electrode; a second electrode; and an organic layer that is disposed between the first electrode and the second electrode, wherein the organic layer includes at least one selected from first materials represented by any one of Formulae 1-1 and 1-2 and at least one selected from second materials represented by Formula 2 below:

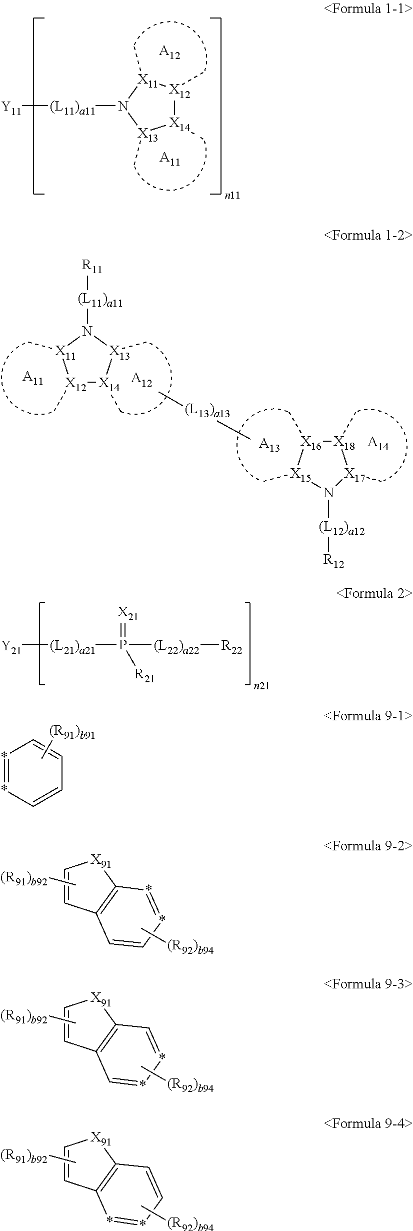

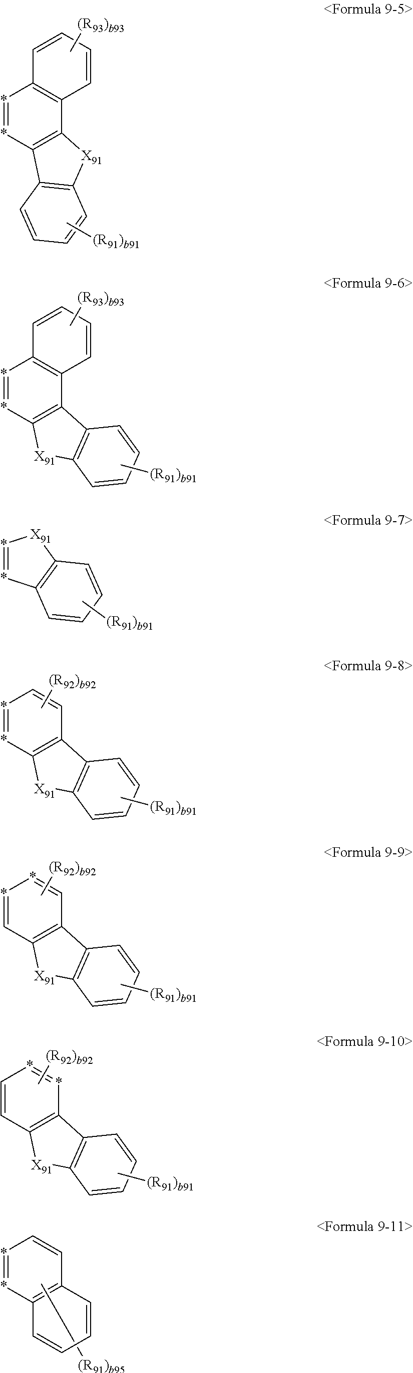

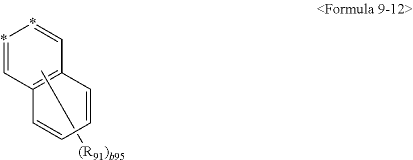

in Formulae 1-1, 1-2, 2, and 9-1 to 9-12,

A₁₁ and A₁₄ are each independently selected from groups represented by Formulae 9-1 to 9-12;

two adjacent groups among X₁₁ to X₁₈ are each independently a carbon atom corresponding to * in Formulae 9-1 to 9-12;

L₁₁ to L₁₃ are each independently selected from a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed hetero-polycyclic group;

L₂₁ and L₂₂ are each independently selected from a substituted or unsubstituted C₁—C alkylene group, a substituted or unsubstituted silylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed hetero-polycyclic group;

a11 to a13, a21, and a22 are each independently selected from 0 and 1;

R₁₁, R₁₂, R₂₁, and R₂₂ are each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;

X₂₁ is selected from an oxygen atom, a sulfur atom, and a selenium atom;

Y₁₁ and Y₂₁ are each independently selected from a substituted or unsubstituted C₆-C₆₀ aryl ring and a substituted or unsubstituted C₁-C₆₀ heteroaryl ring;

n11 and n21 are each independently selected from 1, 2, and 3;

X₉₁ is selected from an oxygen atom, a sulfur atom, C(Q₁)(Q₂), and N(Q₁);

R₉₁ to R₉₃ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arythio group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;

b91 and b93 are each independently selected from 1, 2, 3, and 4;

b92 and b94 are each independently selected from 1 and 2;

b95 may be selected from 1, 2, 3, 4, 5, and 6;

at least one substituent of the substituted C₁-C₁₀ alkylene group, the substituted silylene group, the substituted C₆-C₆₀ arylene group, the substituted C₁-C₆₀ heteroarylene group, the substituted divalent non-aromatic condensed polycyclic group, the substituted divalent non-aromatic condensed hetero-polycyclic group, the substituted C₆-C₆₀ aryl group, the substituted C₁-C₆₀ heteroaryl group, the substituted monovalent non-aromatic condensed polycyclic group, the substituted monovalent non-aromatic condensed hetero-polycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryloxy group, the substituted C₆-C₆₀ arylthio group, the substituted C₆-C₆₀ aryl group, and the substituted C₁-C₆₀ heteroaryl group is selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

wherein Q₁, Q₂, Q₁₁ to Q₁₃, Q₂₁ to Q₂₃ and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

### BRIEF DESCRIPTION OF THE DRAWING

Features will be apparent to those of skill in the art by describing in detail exemplary embodiments with reference to the attached drawing in which:

FIG. 1 illustrates a schematic cross-sectional view of an organic light-emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

As used herein, the term “and/or” includes any and a11 combinations of one or more of the associated listed items. Expressions such as “at least one of,” when preceding a list of elements, modify the entire list of elements and do not modify the individual elements of the list.

As used herein, the singular forms “a,” “an” and “the” are intended to include the plural forms as well, unless the context clearly indicates otherwise.

It will be further understood that the terms “includes”, “including”, “comprises” and/or “comprising” used herein specify the presence of stated features or components, but do not preclude the presence or addition of one or more other features or components.

It will be understood that when a layer, region, or component is referred to as being “on” or “onto” another layer, region, or component, it may be directly or indirectly formed on the other layer, region, or component. For example, intervening layers, regions, or components may be present.

The expression “(an organic layer) includes at least one selected from first materials” used herein may be interpreted as a case in which “(an organic layer) includes identical first materials represented by Formula 1 or two or more different first materials represented by Formula 1.”

The term “organic layer” used herein refers to a single layer and/or a plurality of layers disposed between the first electrode and the second electrode of the organic light-emitting device. A material included in the “organic layer” is not limited to an organic material.

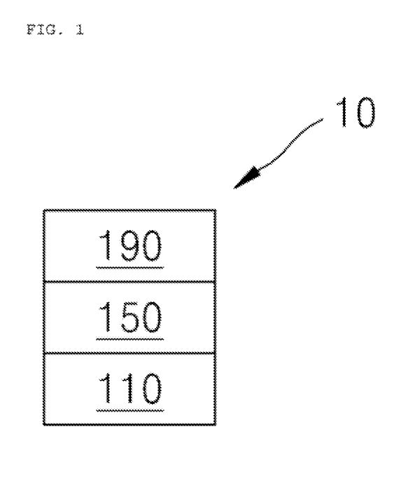

FIG. 1 illustrates a schematic cross-sectional view of an organic light-emitting device 10 according to an embodiment. For example, the organic light-emitting device 10 may include a first electrode 110, a second electrode 190, and an organic layer 150 between the first electrode 110 and the second electrode 190. In FIG. 1, a substrate may be provided under the first electrode 110 or above the second electrode 190. The substrate may be a glass substrate or transparent plastic substrate, each with excellent mechanical strength, thermal stability, transparency, surface smoothness, ease of handling, and water repellency.

The first electrode 110 may be formed by depositing or sputtering a material for forming the first electrode on the substrate. When the first electrode 110 is an anode, the material for the first electrode 110 may be selected from materials with a high work function to facilitate hole injection. The first electrode 110 may be a reflective electrode or a transmissive electrode. The material for the first electrode 110 may be a transparent and highly conductive material, and examples of such a material may include indium tin oxide (ITO), indium zinc oxide (IZO), tin oxide (SnO₂), and zinc oxide (ZnO). When the first electrode 110 is a semi-transmissive electrode or a reflective electrode, as a material for forming the first electrode, at least one of magnesium (Mg), aluminum (Al), aluminum-lithium (Al—Li), calcium (Ca), magnesium-indium (Mg—In), magnesium-silver (Mg—Ag) may be used.

The first electrode 110 may have a single-layer structure, or a multi-layer structure including two or more layers. For example, the first electrode 110 may have a three-layered structure of ITO/Ag/ITO, but the structure of the first electrode 110 is not limited thereto.

An organic layer 150 may be on the first electrode 110. The organic layer 150 may include an emission layer.

The organic layer 150 may include at least one first material and at least one second material. The first material may be represented by one of Formulae 1-1 and 1-2 below. The second material may be represented by Formula 2 below.

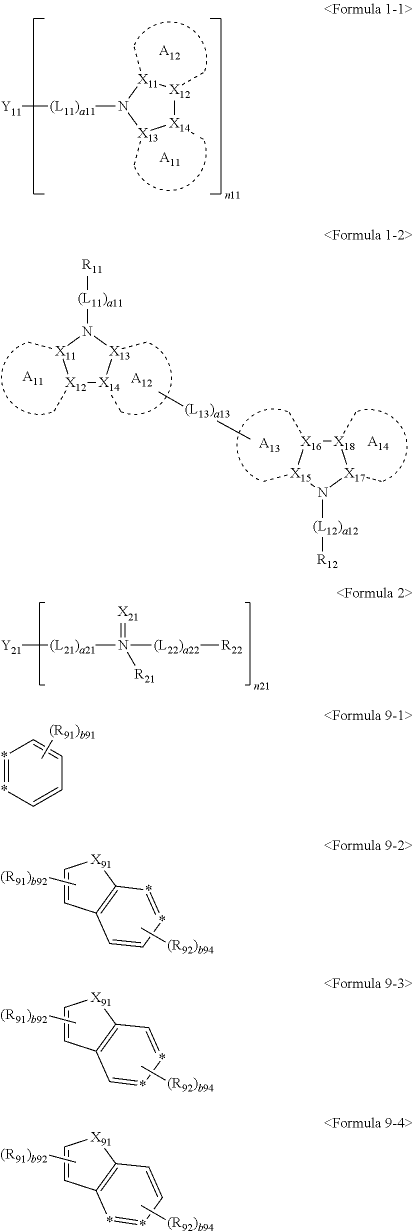

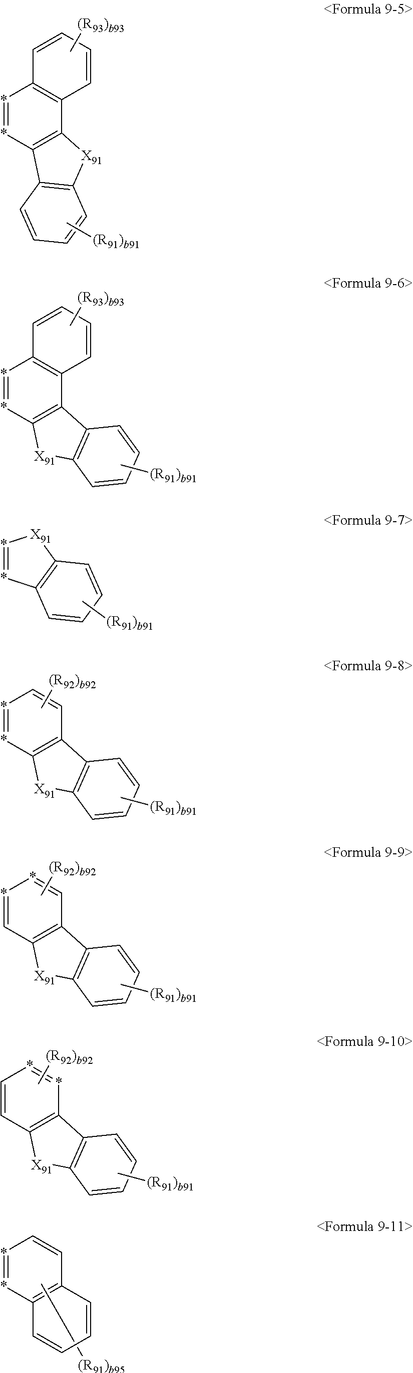

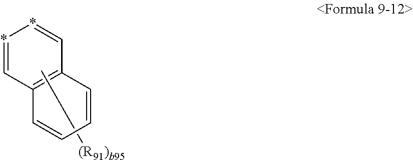

A₁₁ to A₁₄ in Formulae 1-1 and 1-2 may be each independently groups or moieties represented by or selected from Formulae 9-1 to 9-12.

In some embodiments, A₁₁ to A₁₄ in Formulae 1-1 and 1-2 may be each independently selected from Formulae 9-1, 9-3, and 9-6, but are not limited thereto.

Two adjacent groups among X₁₁ to X₁₈ in Formulae 1-1 and 1-2 may be each independently a carbon atom corresponding to * in Formulae 9-1 to 9-12.

In some embodiments, in Formulae 1-1 and 1-2, X₁₁ and X₁₂ may be each a carbon atom corresponding to * in Formula 9-1, and X₁₃ and X₁₄ may be each a carbon atom corresponding to * in Formula 9-1, but they are not limited thereto.

In other embodiments, in Formula 1-2, X₁₅ and X₁₆ may be each a carbon atom corresponding to * in Formula 9-1, and X₁₇ and X₁₈ may be each a carbon atom corresponding to * in Formula 9-1, but they are not limited thereto.

L₁₁ to L₁₃ in Formulae 1-1 and 1-2 may be each independently selected from a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed hetero-polycyclic group;

at least one substituent selected from the substituted C₆-C₆₀ arylene group, the substituted C₁-C₆₀ heteroarylene group, the substituted divalent non-aromatic condensed polycyclic group, and the substituted divalent non-aromatic condensed hetero-polycyclic group may be selected from:

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

Q₁₁ to Q₁₃, Q₂₁ to Q₂₃, and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, L₁₁ to L₁₃ in Formulae 1-1 and 1-2 may be each independently selected from a phenylenegroup, a naphthylene group, a phenanthrenylene group, an anthracenylene group, a triphenylenylene group, a pyrenylene group, a chrysenylene group, a pyrrolylene group, a thiophenylene group, a furanylene group, an imidazolylene group, a pyridinylene group, a pyrazinylene group, a pyrimidinylene group, an indolylene indolylene group, a quinolinylene group, an isoquinolinylene group, a benzoquinolinylene group, a phenanthridinylene group, an acridinylene group, a phenanthrolinylene group, a benzofuranylene group, a benzothiophenylene group, a triazolylene group, a tetrazolylene group, a triazinylene triazinylene group, a carbazolylene group, a dibenzofuranylene group, and a dibenzothiophenylene group; and

a phenylene group, a naphthylene group, a phenanthrenylene group, an anthracenylene group, a triphenylenylene group, a pyrenylene group, a chrysenylene group, a pyrrolylene group, a thiophenylene group, a furanylene group, an imidazolylene group, a pyridinylene group, a pyrazinylene group, a pyrimidinylene group, an indolylene group, a quinolinylene group, an isoquinolinylene group, a benzoquinolinylene group, a phenanthridinylene group, an acridinylene group, a phenanthrolinylene group, a benzofuranylene group, a benzothiophenylene group, a triazolylene group, tetrazolylene group, a triazinylene group, a carbazolylene group, a dibenzofuranylene group, and a dibenzothiophenylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, and an imidazopyridinyl group, but they are not limited thereto.

In some embodiments, L₁₁ to L₁₃ in Formulae 1-1 and 1-2 may be each independently selected from a phenylene group, a naphthylene group, a phenanthrenylene group, an anthracenylene group, a triphenylenylene group, a pyrenylene group, a chrysenylene group, a pyrrolylene group, a thiophenylene group, a furanylene group, an imidazolylene group, a pyridinylene group, a pyrazinylene group, a pyrimidinylene group, an indolylene group, a quinolinylene group, an isoquinolinylene group, a benzoquinolinylene group, a phenanthridinylene group, an acridinylene group, a phenanthrolinylene group, a benzofuranylene group, a benzothiophenylene group, a triazolylene group, a tetrazolylene group, a triazinylene group, a carbazolylene group, a dibenzofuranylene group, and a dibenzothiophenylene group; and

a phenylene group, a naphthylene group, a phenanthrenylene group, an anthracenylene group, a triphenylenylene group, a pyrenylene group, a chrysenylene group, a pyrrolylene group, a thiophenylene group, a furanylene group, an imidazolylene group, a pyridinylene group, a pyrazinylene group, a pyrimidinylene group, an indolylene group, a quinolinylene group, an isoquinolinylene group, a benzoquinolinylene group, a phenanthridinylene group, an acridinylene group, a phenanthrolinylene group, a benzofuranylene group, a benzothiophenylene group, a triazolylene group, a tetrazolylene group, a triazinylene group, a carbazolylene group, a dibenzofuranylene group and a dibenzothiophenylene group, each substituted with at least one selected from a deuterium, —F, —Cl, —Br, —I, a cyano group, a nitro group, a C₁-C₂₀ alkyl group, a phenyl group and a naphthyl group, but they are not limited thereto.

In some embodiments, L₁₁ to L₁₃ in Formulae 1-1 and 1-2 may be each independently selected from a phenylene group, a naphthylene group, a pyridinylene group, a pyrazinylene group, a pyrimidinylene group, a quinolinylene group, an isoquinolinylene group, a triazinylene group a carbazolylene group, a dibenzofuranylene group, and a dibenzothiophenylene group; and

a phenylene group, a naphthylene group, a pyridinylene group, a pyrazinylene group, a pyrimidinylene group, a quinolinylene group, an isoquinolinylene group, a triazinylene group a carbazolylene group, a dibenzofuranylene group, and a dibenzothiophenylene group, each substituted with at least one selected from a deuterium, —F, —Cl, —Br, —I, a cyano group, a nitro group, a C₁-C₂₀ alkyl group, a phenyl group, and a naphthyl group, but they are not limited thereto.

In some embodiments, L₁₁ to L₁₃ in Formulae 1-1 and 1-2 may be each independently selected from a phenylene group, a naphthylene group, a pyridinylene group, a pyrazinylene group, a pyrimidinylene group, a quinolinylene group, an isoquinolinylene group, a triazinylene group a carbazolylene group, a dibenzofuranylene group, and a dibenzothiophenylene group, but they are not limited thereto.

a11 in Formulae 1-1 and 1-2 indicates the number of L₁₁, and a11 may be selected from 0 and 1. When a11 is 0, -(L₁₁)ₐ₁₁- is a single bond. For example, a11 in Formulae 1-1 and 1-2 may be 0, but is not limited thereto.

a12 in Formulae 1-1 and 1-2 indicates the number of L₁₂, and a12 may be selected from 0 and 1. When a12 is 0, -(L₁₂)ₐ₁₂- is a single bond. For example, a12 in Formulae 1-1 and 1-2 may be 0, but is not limited thereto.

a12 in Formula 1-2 indicates the number of L₁₂, and a12 may be selected from 0 and 1. When a12 is 0, -(L₁₂)ₐ₁₂- is a single bond. For example, a12 in Formulae 1-1 and 1-2 may be 0, but is not limited thereto.

a13 in Formula 1-2 indicates the number of L₁₃, and a13 may be selected from 0 and 1. When a13 is 0, -(L₁₃)ₐ₁₃- is a single bond. For example, a13 in Formula 1-2 may be 0, but is not limited thereto.

R₁₁ and R₁₂ in Formulae 1-1 and 1-2 may be each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;

at least one substituent selected from the substituted C₆-C₆₀ aryl group, the substituted C₁-C₆₀ heteroaryl group, the substituted monovalent non-aromatic condensed polycyclic group, and the substituted monovalent non-aromatic condensed hetero-polycyclic group may be selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

Q₁₁ to Q₁₃, Q₂₁ to Q₂₃, and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, R₁₁ and R₁₂ in Formulae 1-1 and 1-2 may be each independently selected from a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, a ovalenyl group, a pyrrolyl group, a thiophenyl group, a furanyl group, an imidazolyl group, a pyrazolyl group, a thiazolyl group, an isoothiazolyl group, a oxazolyl group, an isooxazolyl group, a pyridinyl group, a pyrazinyl group, a pyrimidinyl group, a pyridazinyl group, an isooindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, an isoobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, and a dibenzocarbazolyl group; and

a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, but they are not limited thereto.

In some embodiments, R₁₁ and R₁₂ in Formulae 1-1 and 1-2 may be each independently selected from a phenyl group, a naphthyl group, a fluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a pyridinyl group, a pyrazinyl group, a pyrimidinyl group, a quinolinyl group, an isoquinolinyl group, a quinazolinyl group, and a triazinyl group; and

a phenyl group, a naphthyl group, a fluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a pyridinyl group, a pyrazinyl group, a pyrimidinyl group, a quinolinyl group, an isoquinolinyl group, a quinazolinyl group, and a triazinyl group, each substituted with at least one selected from a deuterium, —F, —Cl, —Br, —I, a C₁-C₂₀ alkyl group, a phenyl group, and a naphthyl group, but they are not limited thereto.

In some embodiments, R₁₁ and R₁₂ in Formulae 1-1 and 1-2 may be each independently selected from a phenyl group, a naphthyl group, a pyridinyl group, a pyrimidinyl group, a quinolinyl group, an isoquinolinyl group, a quinazolinyl group, and a triazinyl group; and

a phenyl group, a naphthyl group, a pyridinyl group, a pyrimidinyl group, a quinolinyl group, an isoquinolinyl group, a quinazolinyl group, and a triazinyl group, each substituted with at least one selected from a deuterium, —F, —Cl, —Br, —I, a methyl group, a phenyl group, and a naphthyl group, but they are not limited thereto.

In other embodiments, R₁₁ and R₁₂ in Formulae 1-1 and 1-2 may be each independently a group represented by one of Formulae 4-31 to 4-38 below, but they are not limited thereto:

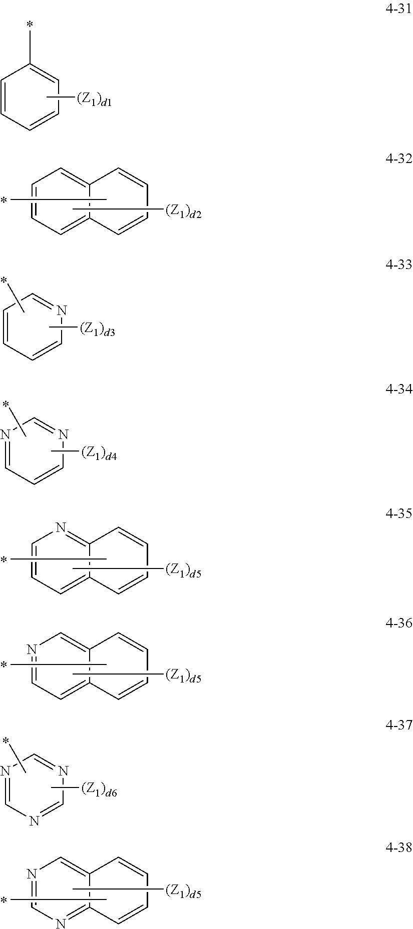

wherein in Formulae 4-31 to 4-38,

Z₁ may be selected from a hydrogen, a deuterium, —F, —Cl, —Br, —I, a methyl group, a phenyl group, and a naphthyl group;

d1 may be selected from 1, 2, 3, 4, and 5;

d2 is selected from 1, 2, 3, 4, 5, 6, and 7;

d3 may be selected from 1, 2, 3, and 4;

d4 may be selected from 1, 2, and 3;

d5 may be selected from 1, 2, 3, 4, 5, and 6;

d6 may be 1 or 2; and

* indicates a binding site to a neighboring atom.

In other embodiments, R₁₁ and R₁₂ in Formulae 1-1 and 1-2 may be each independently a group represented by one of Formulae 5-31 to 5-37 below, but they are not limited thereto:

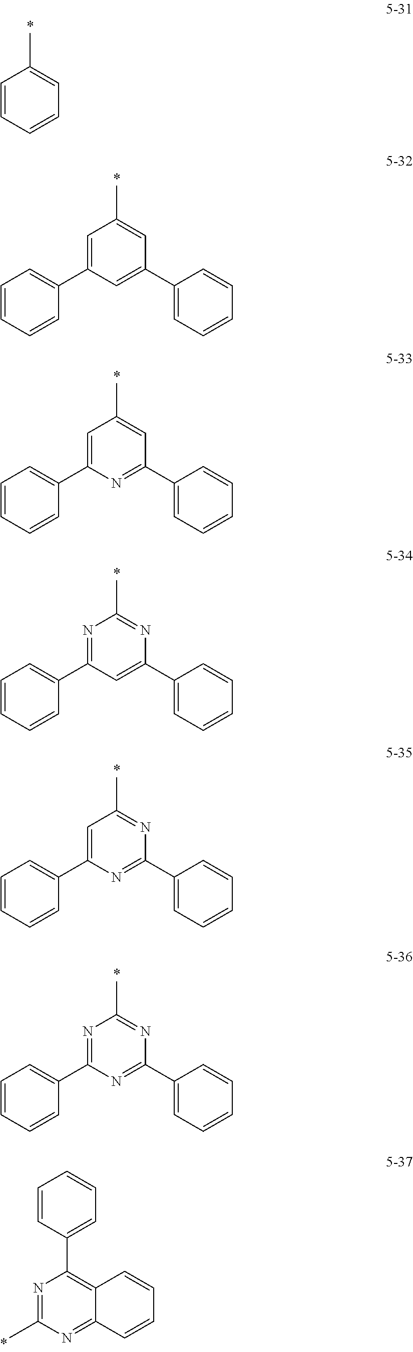

wherein in Formulae 5-31 to 5-37, * indicates a binding site to a neighboring atom.

Y₁₁ in Formulae 1-1 and 1-2 may be each independently selected from or include a substituted or unsubstituted C₆-C₆₀ aryl ring and a substituted or unsubstituted C₁-C₆₀ heteroaryl ring;

at least one substituent selected from the substituted C₆-C₆₀ aryl ring and the substituted C₁-C₆₀ heteroaryl ring may be selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

Q₁₁ to Q₁₃, Q₂₁ to Q₂₃, and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, Y₁₁ in Formula 1-1 may be selected from or may include a benzene, a naphthalene, a pyridine, a pyrimidine, a quinoline, an isoquinoline, a quinazoline, and a triazine; and

a benzene, a naphthalene, a pyridine, a pyrimidine, a quinoline, an isoquinoline, a quinazoline, and a triazine, each substituted with at least one selected from a phenyl group and a naphthyl group, but is not limited thereto.

In some embodiments, Y₁₁ in Formula 1-1 may be or may include a triazine substituted with a benzene and a phenyl group, but is not limited thereto.

n11 In Formula 1-1 indicates the number of moieties that are represented by

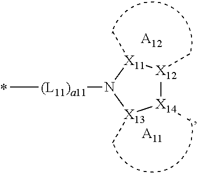

and n11 may be selected from 1, 2, and 3. When n11 is 2 or more, a plurality of the moiety represented by

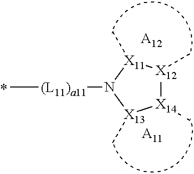

may be identical or different. For example, n11 in Formula 1-1 may be selected from 1 and 3, but not limited thereto.

In Formulae 9-1 to 9-12, * indicates a carbon atom, and corresponds to any one selected from X₁₁ to X₁₈ in Formulae 1-1 and 1-2.

X₉₁ in Formulae 9-1 to 9-12 may be selected from an oxygen atom, a sulfur atom, C(Q₁)(Q₂), and N(Q₁), and Q₁ and Q₂ are each independently the same as described below in this specification.

For example, X₉₁ in Formulae 9-1 to 9-12 may be N(Q₁), but is not limited thereto.

R₉₁ to R₉₃ in Formulae 9-1 to 9-12 may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arythio group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;

at least one substituent of the substituted C₆-C₆₀ aryl group, the substituted C₁-C₆₀ heteroaryl group, the substituted monovalent non-aromatic condensed polycyclic group, the substituted monovalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryloxy group, and the substituted C₆-C₆₀ arylthio group may be selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

Q₁₁ to Q₁₃, Q₂₁ to Q₂₃, and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, R₉₁ to R₉₃ in Formulae 9-1 to 9-12 may be each independently selected from a hydrogen, a deuterium, —F, —Cl, —Br, —I, a cyano group, a nitro group, a C₁-C₆₀ alkyl group, and a C₆-C₆₀ aryl group, but are not limited thereto.

b91 and b93 In Formulae 9-1 to 9-12 may be each independently selected from 1, 2, 3, and 4; b92 and b94 may be each independently selected from 1 and 2; b95 may be selected from 1, 2, 3, 4, 5, and 6.

Q₁ and Q₂ in Formulae 9-1 to 9-12 may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

In some embodiments, Q₁ and Q₂ in Formulae 9-1 to 9-12 may be each independently a C₆-C₆₀ aryl group, but are not limited thereto.

L₂₁ and L₂₂ in Formula 2 may be each independently selected from a substituted or unsubstituted C₁-C₁₀ alkylene group, a substituted or unsubstituted silylene group, a substituted or unsubstituted C₆-C₆₀ arylene group, a substituted or unsubstituted heteroarylene group, a substituted or unsubstituted divalent non-aromatic condensed polycyclic group, and a substituted or unsubstituted divalent non-aromatic condensed hetero-polycyclic group;

at least one substituent selected from the substituted C₁-C₁₀ alkylene group, the substituted silylene group, the substituted C₁-C₆₀ arylene group, the substituted C₁-C₆₀ heteroarylene group, the substituted divalent non-aromatic condensed polycyclic group, and the substituted divalent non-aromatic condensed hetero-polycyclic group may be selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

wherein Q₁ to Q₃, Q₁₁ to Q₁₃, Q₂₁ to Q₂₃ and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, L₂₁ and L₂₂ in Formula 2 may be each independently selected from a methylene group, an ethylene group, a propylene group, a butylene group, a phenylene group, a naphthylene group, a phenanthrenylene group, an anthracenylene group, a triphenylenylene group, a pyrenylene group, a chrysenylene group, a pyrrolylene group, a thiophenylene group, a furanylene group, an imidazolylene group, a pyridinylene group, a pyrazinylene group, a pyrimidinylene group, an indolylene group, a quinolinylene group, an isoquinolinylene group, a benzoquinolinylene group, a phenanthridinylene group, an acridinylene group, a phenanthrolinylene group, a benzofuranylene group, a benzothiophenylene group, a triazolylene group, a tetrazolylene group, a triazinylene group, a dibenzofuranylene group, and a dibenzothiophenylene group; and

a methylene group, an ethylene group, a propylene group, a butylene group, a phenylene group, a naphthylene group, a phenanthrenylene group, an anthracenylene group, a triphenylenylene group, a pyrenylene group, a chrysenylene group, a pyrrolylene group, a thiophenylene group, a furanylene group, an imidazolylene group, a pyridinylene group, a pyrazinylene group, a pyrimidinylene group, a pyridazinylene group, an indolylene group, a quinolinylene group, an isoquinolinylene group, a benzoquinolinylene group, a phenanthridinylene group, an acridinylene group, a phenanthrolinylene group, a benzofuranylene group, a benzothiophenylene group, a triazolylene group, tetrazolylene group, a triazinylene group, a dibenzofuranylene group, and a dibenzothiophenylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, and an imidazopyridinyl group, but they are not limited thereto.

In some embodiments, L₂₁ and L₂₂ in Formula 2 may be each independently selected from a phenylene group, a naphthylene group, a pyridinylene group, a quinolinylene group and an isoquinolinylene group; and

a phenylene group, a naphthylene group, a pyridinylene group, a quinolinylene group, and an isoquinolinylene group, each substituted with at least one selected from a deuterium, —F, —Cl, —Br, —I, a cyano group, a nitro group, a C₁-C₂₀ alkyl group, a phenyl group, and a naphthyl group, but they are not limited thereto.

In other embodiments, L₂₁ and L₂₂ in Formula 2 may be each independently a group selected from a phenylene group and a naphthylene group, but they are not limited thereto:

In other embodiments, L₂₁ and L₂₂ in Formula 2 may be each independently a group represented by one of Formulae 3-1 to 3-9 below, but they are not limited thereto:

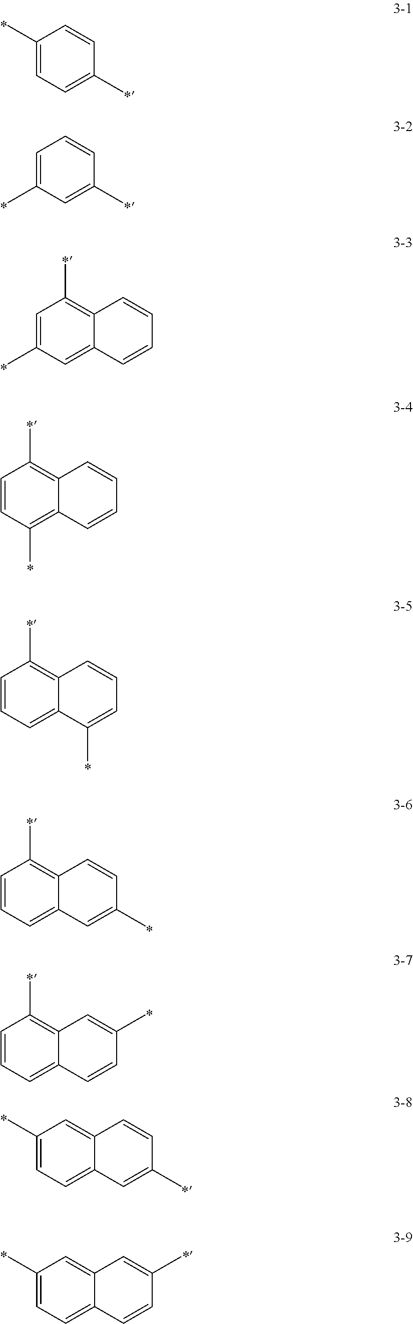

wherein in Formulae 3-1 to 3-9, * and *′ indicate binding sites to a neighboring atom.

a21 in Formula 2 indicates the number of L₂₁, and a21 may be selected from 0 and 1. When a21 is 0, -(L₂₁)ₐ₂₁- is a single bond.

a22 in Formula 2 indicates the number of L₂₂, and a22 may be selected from 0 and 1. When a22 is 0, -(L₂₂)ₐ₂₂- is a single bond.

R₂₁ and R₂₂ in Formula 2 may be each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;

at least one substituent selected from the substituted C₆-C₆₀ aryl group, the substituted C₁-C₆₀ heteroaryl group, the substituted monovalent non-aromatic condensed polycyclic group, and the substituted monovalent non-aromatic condensed hetero-polycyclic group may be selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

wherein Q₁ to Q₃, Q₁₁ to Q₁₃, Q₂₁ to Q₂₃ and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, R₂₁ and R₂₂ in Formula 2 may be each independently selected from a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, a ovalenyl group, a pyrrolyl group, a thiophenyl group, a furanyl group, an imidazolyl group, a pyrazolyl group, a thiazolyl group, an isoothiazolyl group, a oxazolyl group, an isoooxazolyl group, a pyridinyl group, a pyrazinyl group, a pyrimidinyl group, a pyridazinyl group, an isooindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, an isoobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, and a dibenzocarbazolyl group; and

a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, but they are not limited thereto.

In some embodiments, R₂₁ and R₂₂ in Formula 2 may be each independently selected from a phenyl group, a naphthyl group, a fluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a pyridinyl group, a pyrazinyl group, a pyrimidinyl group, an indolyl group, a quinolinyl group, an isoquinolinyl group, a carbazolyl group, a benzoquinolinyl group, a phthalazinyl group, a phenanthridinyl group, an acridinyl group, a phenanthrolinyl group, a phenazinyl group, a benzoimidazolyl group, a benzofuranyl group, a benzothiophenyl group, a triazolyl group, a tetrazolyl group, a triazinyl group, a dibenzofuranyl group, and a dibenzothiophenyl group; and

a phenyl group, a naphthyl group, a fluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a pyridinyl group, a pyrazinyl group, a pyrimidinyl group, an indolyl group, a quinolinyl group, an isoquinolinyl group, a carbazolyl group, a benzoquinolinyl group, a phthalazinyl group, a phenanthridinyl group, an acridinyl group, a phenanthrolinyl group, a phenazinyl group, a benzoimidazolyl group, a benzofuranyl group, a benzothiophenyl group, a triazolyl group, a tetrazolyl group, a triazinyl group, a dibenzofuranyl group, and a dibenzothiophenyl group, each substituted with at least one selected from a deuterium, —F, —Cl, —Br, —I, a C₁-C₂₀ alkyl group, a phenyl group, and a naphthyl group, but they are not limited there to.

In other embodiments, R₂₁ and R₂₂ in Formula 2 may be each independently selected from a phenyl group, a naphthyl group, a fluorenyl group, a pyridinyl group, a phenanthridinyl group, an acridinyl group, a phenanthrolinyl group, and a benzoimidazolyl group; and

a phenyl group, a naphthyl group, a fluorenyl group, a pyridinyl group, a phenanthridinyl group, an acridinyl group, a phenanthrolinyl group and a benzoimidazolyl group, each substituted with at least one selected from a deuterium, —F, —Cl, —Br, —I, a methyl group, a phenyl group, and a naphthyl group, but they are not limited thereto.

In other embodiments, R₂₁ and R₂₂ in Formula 2 may be each independently a group represented by one of Formulae 4-1 to 4-14 below, but they are not limited thereto:

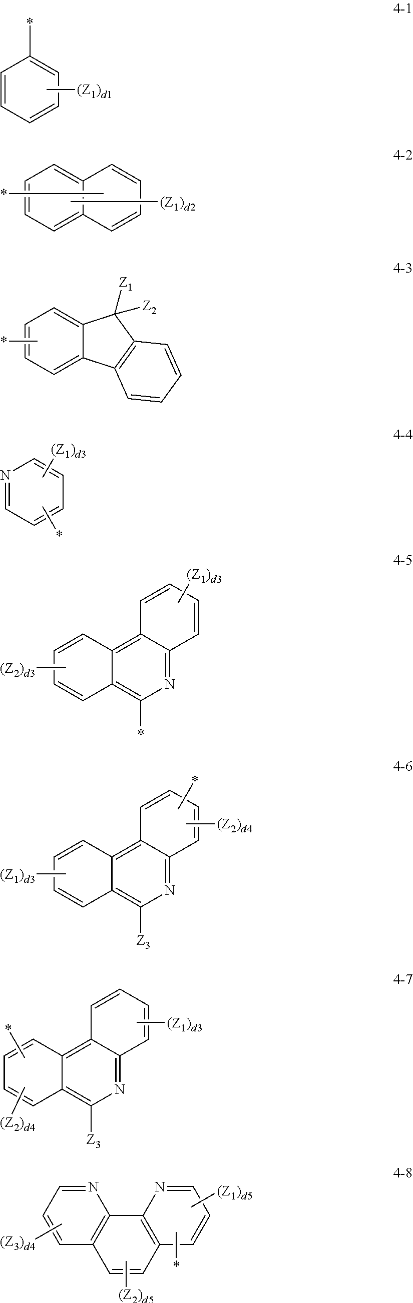

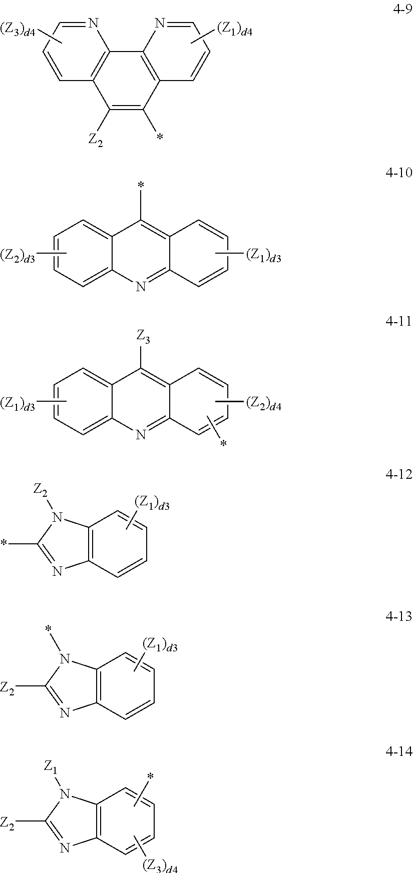

wherein in Formulae 4-1 to 4-14,

Z₁, Z₂, and Z₃ are each independently selected from a hydrogen, a deuterium, —F, —Cl, —Br, —I, a methyl group, a phenyl group, and a naphthyl group;

d1 may be selected from 1, 2, 3, 4, and 5;

d2 is selected from 1, 2, 3, 4, 5, 6, and 7;

d3 may be selected from 1, 2, 3, and 4;

d4 may be selected from 1, 2, and 3;

d5 may be 1 or 2; and

* indicates a binding site to a neighboring atom.

In other embodiments, R₂₁ and R₂₂ in Formula 2 may be each independently a group represented by one of Formulae 5-1 to 5-27 below, but they are not limited thereto:

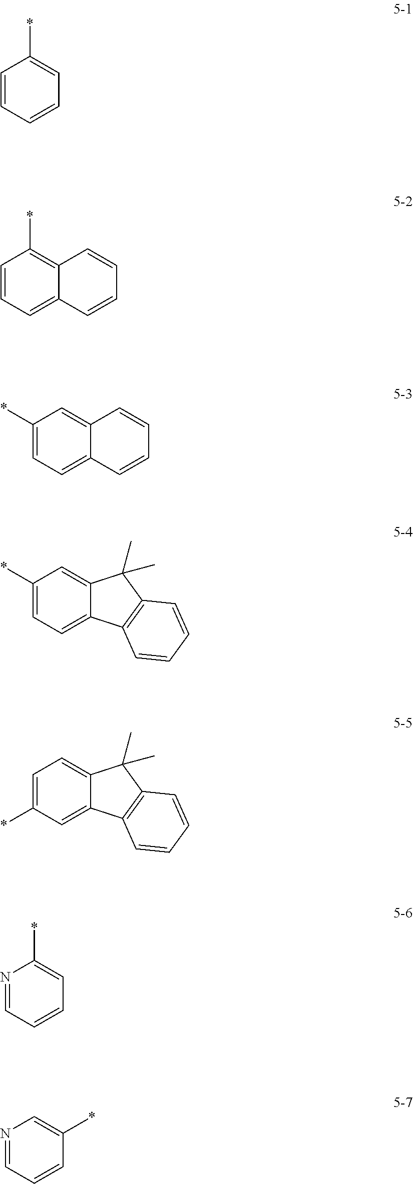

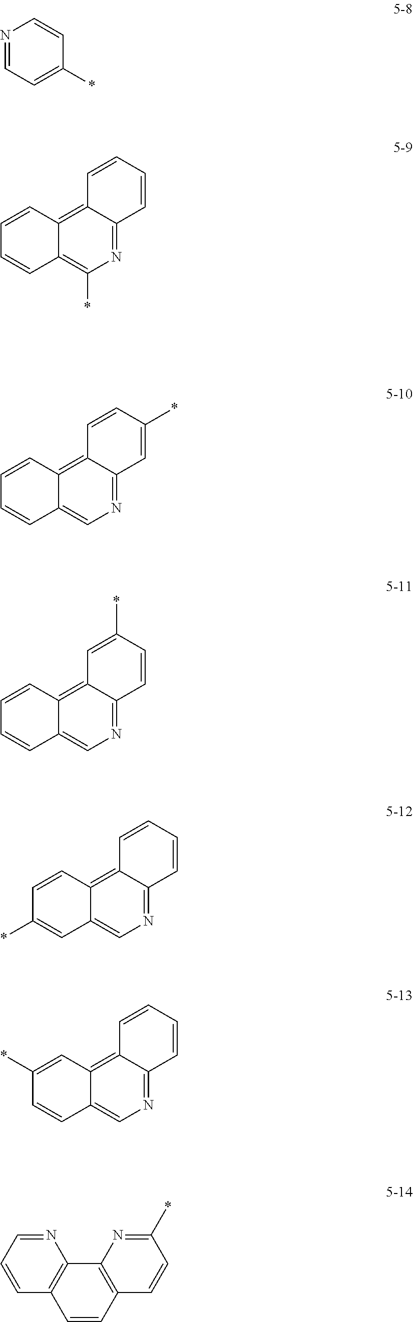

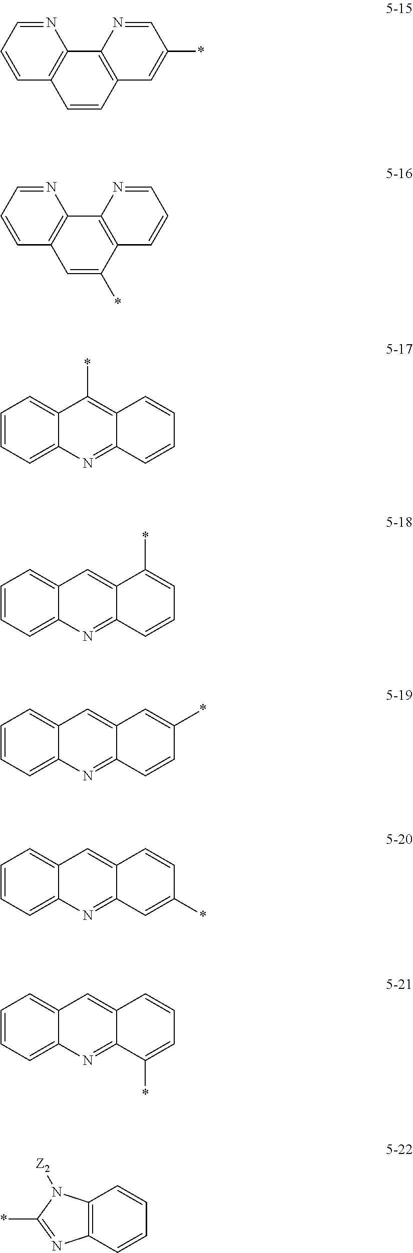

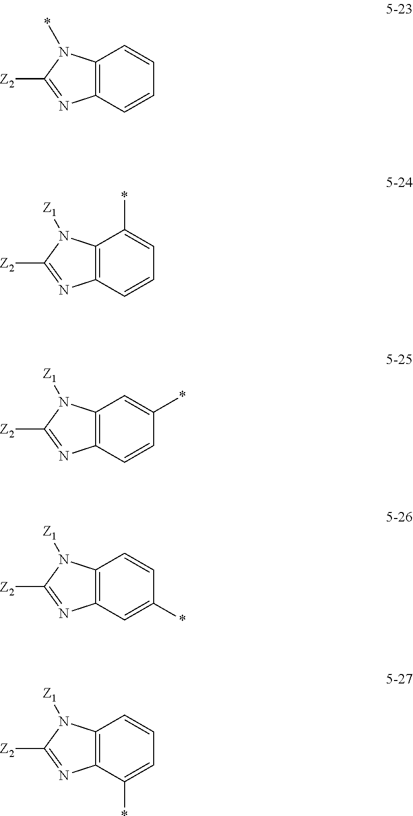

wherein in Formulae 5-1 to 5-27,

Z₁ and Z₂ may be each independently selected from a hydrogen and a phenyl group;

and

* indicates a binding site to a neighboring atom.

X₂₁ in Formula 2 may be selected from an oxygen atom, a sulfur atom, and a selenium atom.

For example, X₂₁ in Formula 2 may be an oxygen atom, but is not limited thereto.

Y₂₁ in Formula 2 may be selected from or may include a substituted or unsubstituted C₆-C₆₀ aryl ring and a substituted or unsubstituted C₁-C₆₀ heteroaryl ring;

at least one substituent of the substituted C₆-C₆₀ aryl ring and the substituted C₁-C₆₀ heteroaryl ring may be selected from:

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and

—Si(Q₃₁)(Q₃₂)(Q₃₃),

wherein Q₁ to Q₃, Q₁₁ to Q₁₃, Q₂₁ to Q₂₃ and Q₃₁ to Q₃₃ may be each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

For example, Y₂₁ in Formula 2 may be selected from or may include a C₁-C₃₀ heteroaryl group containing at least one nitrogen atom, but is not limited thereto.

According to other embodiments, Y₂₁ in Formula 2 may be selected from or may include a moiety represented by Formulae 7-1 to 7-7 below, but is not limited thereto:

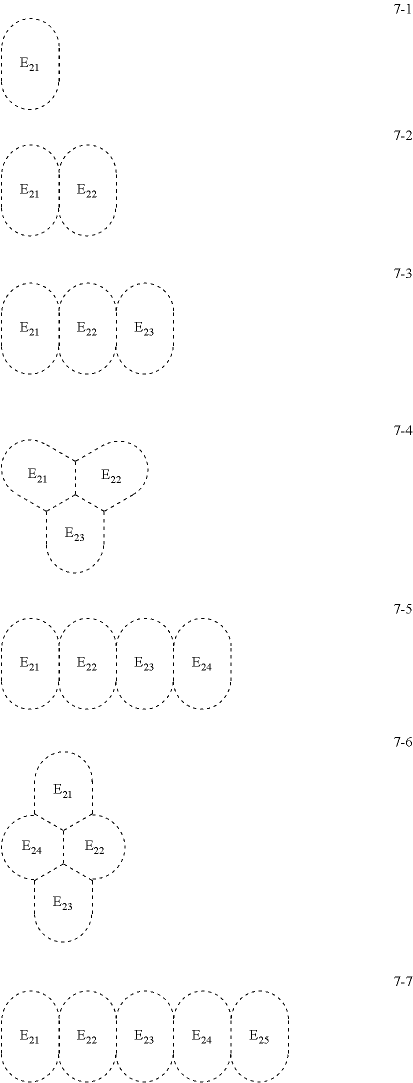

E₂₁ to E₂₅ may be each independently selected from or may include a benzene, a naphthalene, a phenanthrene, an anthracene, a triphenylene, a pyrrole, a thiophene, a furan, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a benzofuran, a benzothiophene, a triazole, a tetrazole, a triazine, a dibenzofuran, and a dibenzothiophene; and

a benzene, a naphthalene, a phenanthrene, an anthracene, a triphenylene, a pyrrole, a thiophene, a furan, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a benzofuran, a benzothiophene, a triazole, a tetrazole, a triazine, a dibenzofuran, and a dibenzothiophene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, and an imidazopyridinyl group.

According to other embodiments, Y₂₁ in Formula 2 may be selected from or may include a moiety represented by Formulae 7-1 to 7-7 below, but is not limited thereto:

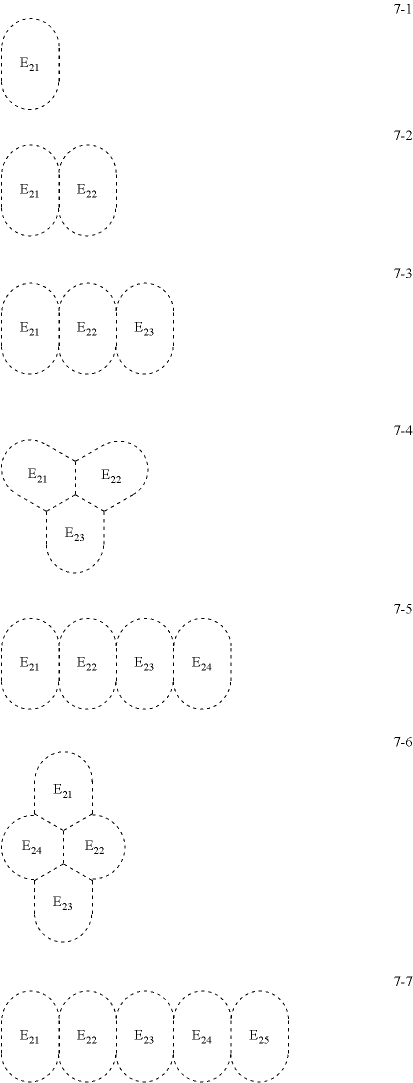

wherein in Formulae 7-1 to 7-7,

E₂₁ to E₂₅ are each independently selected from a benzene, a naphthalene, a phenanthrene, an anthracene, a triphenylene, a pyrrole, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine; and

a benzene, a naphthalene, a phenanthrene, an anthracene, a triphenylene, a pyrrole, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine, each substituted with at least one selected from a methyl group, a phenyl group, and a naphthyl group;

wherein E₂₁ in Formula 7-1, one selected from E₂₁ and E₂₂ in Formula 7-2, one selected from E₂₁, E₂₂, and E₂₃ in Formula 7-3, one selected from E₂₁, E₂₂, and E₂₃ in Formula 7-4, one selected from E₂₁, E₂₂, E₂₃, and E₂₄ in Formula 7-5, one selected from E₂₁, E₂₂, E₂₃, and E₂₄ in Formula 7-6, and one selected from E₂₁, E₂₂, E₂₃, and E₂₄ in Formula 7-7 are each independently selected from a pyrrole, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine.

According to other embodiments, Y₂₁ in Formula 2 may be selected from or may include a moiety represented by Formulae 8-1 to 8-38 below, but is not limited thereto:

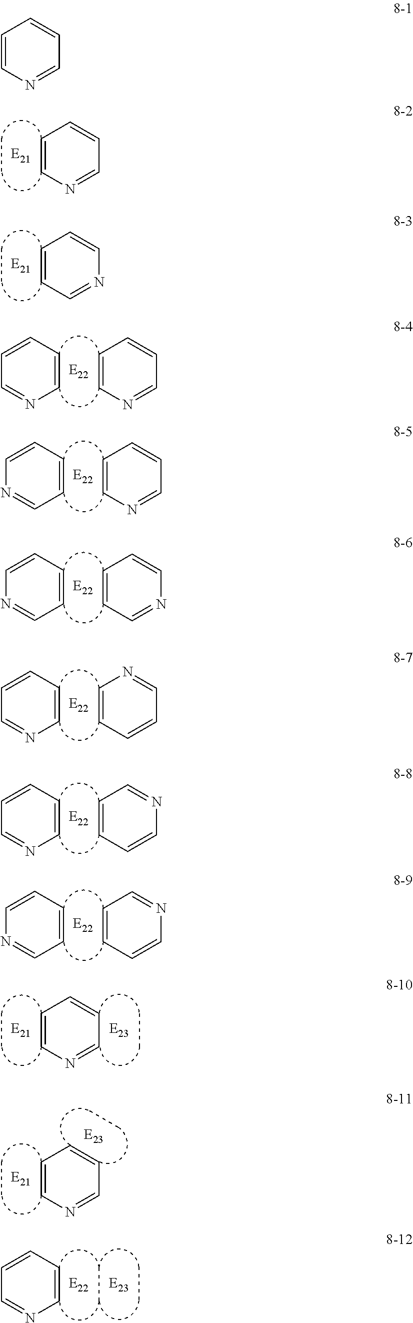

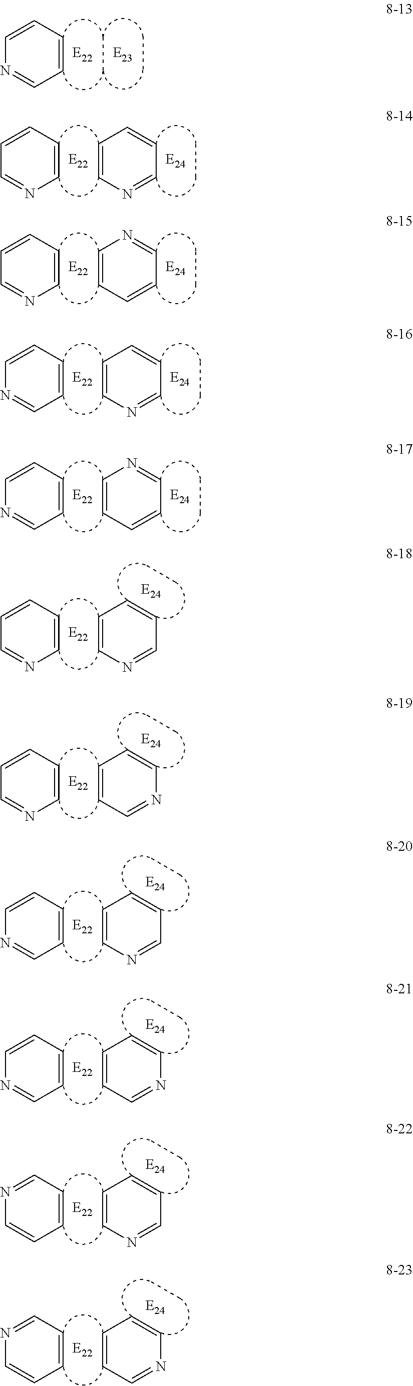

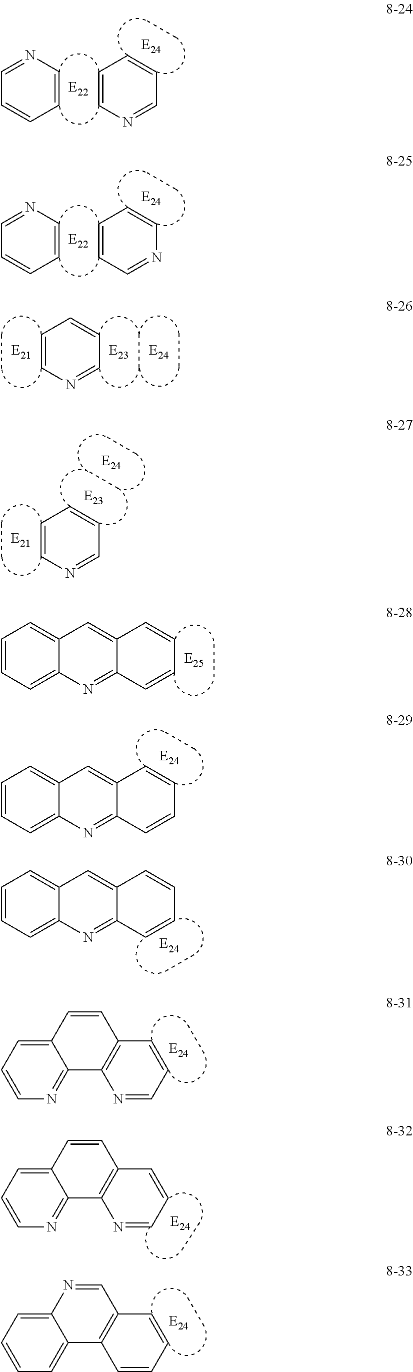

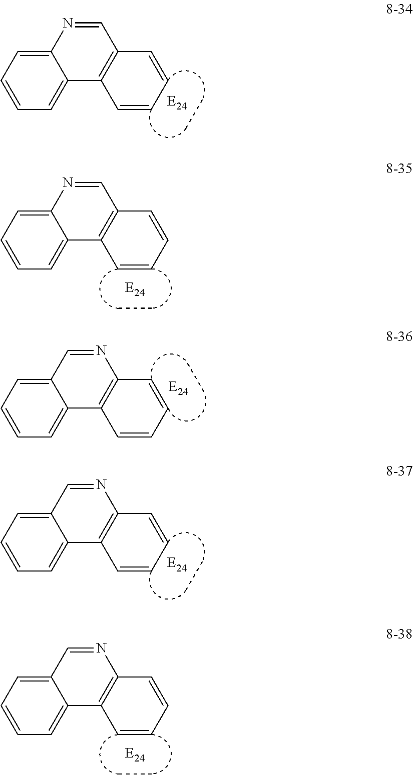

wherein in Formulae 8-1 to 8-38,

E₂₁ to E₂₄ are each independently selected from or may include a benzene, a naphthalene, a phenanthrene, an anthracene, a triphenylene, a pyrrole, an imidazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine.

According to other embodiments, Y₂₁ in Formula 2 may be selected from or may include a moiety represented by Formulae 8-1 to 8-38 below, but is not limited thereto:

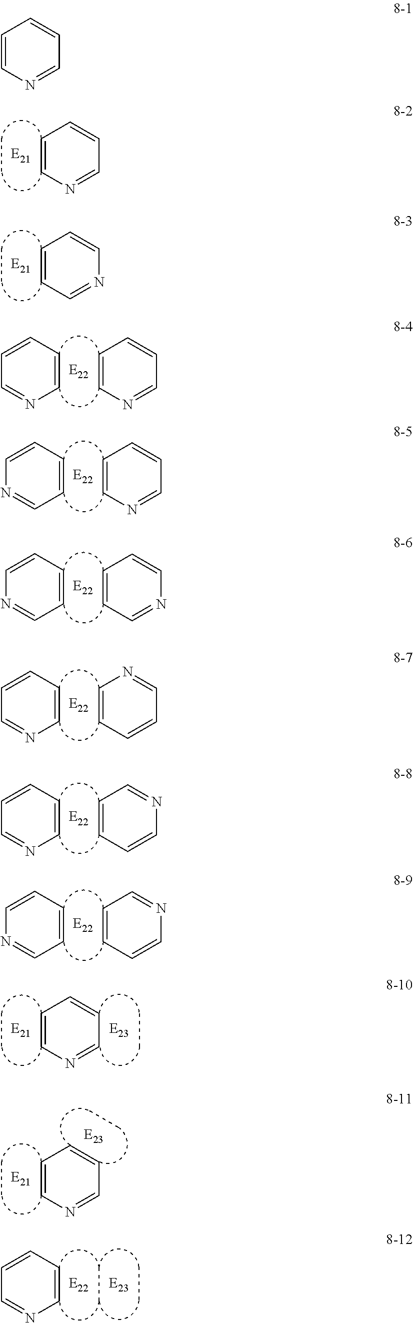

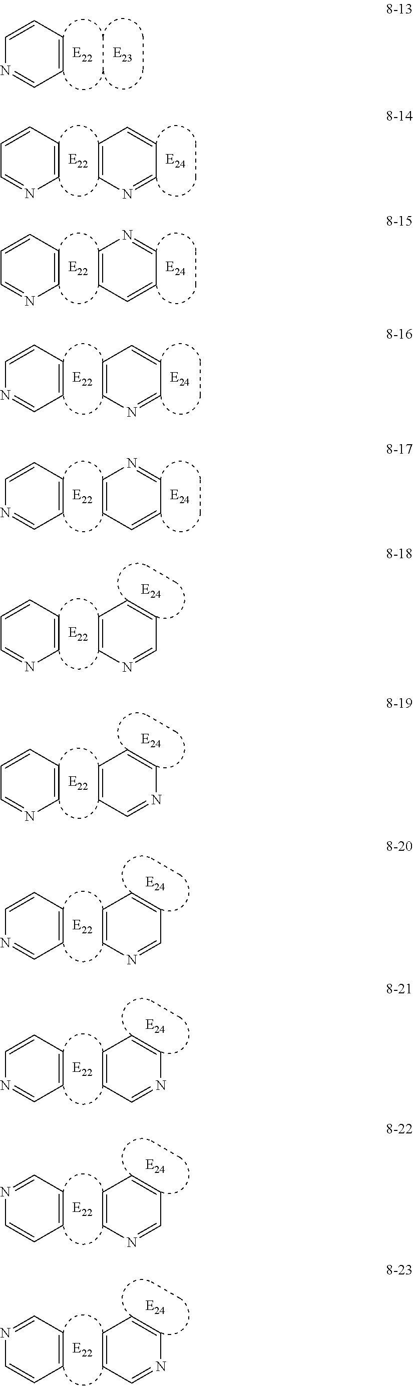

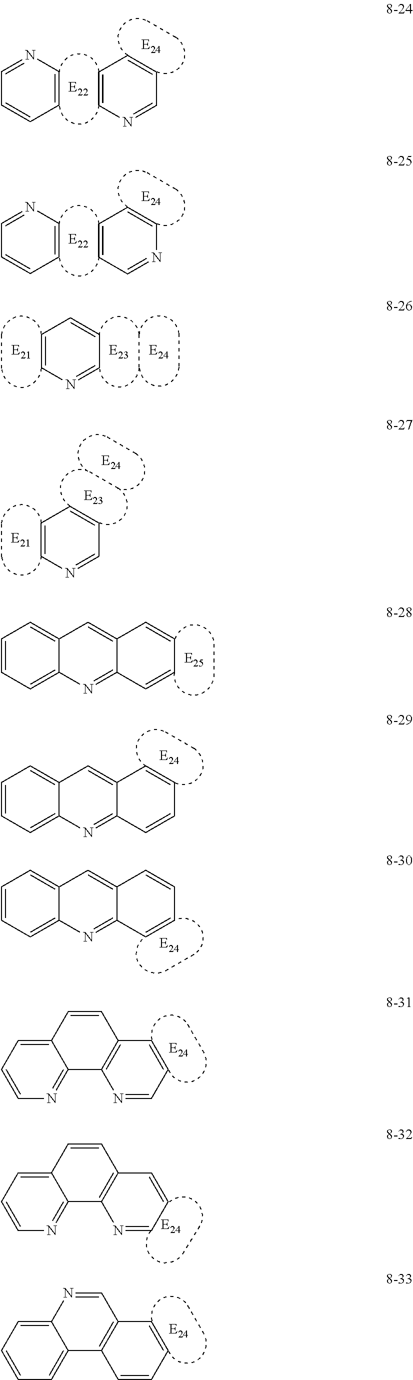

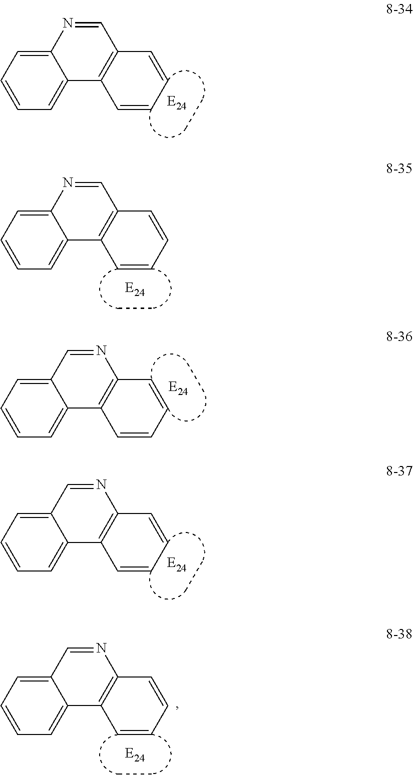

wherein, in Formulae 8-1 to 8-38,

E₂₁ to E₂₄ may be each independently selected from or may include a benzene, a naphthalene, a pyridine, a pyrazine, a pyrimidine, a quinoline, an isoquinoline, a phenanthridine, an acridine, and a phenanthroline.

n21 in Formula 2 indicates the number of moieties represented by

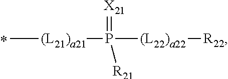

and n21 may be selected from 1, 2, and 3. For example, n21 in Formula 2 may be 1, but is not limited thereto. In some embodiments, n21 in Formula 2 may be 2, but is not limited thereto. When n21 is 1, Y₂₁ is a monovalent group. When n21 is 2, Y₂₁ is a divalent group. When n21 is 3, Y₂₁ is a trivalent group.

In some embodiments, the first material may be represented by one of Formulae 1-1A, 1-1B, 1-1C, and 1-2A below, and the second material may be represented by one of Formulae 2A and 2B below, but they are not limited thereto:

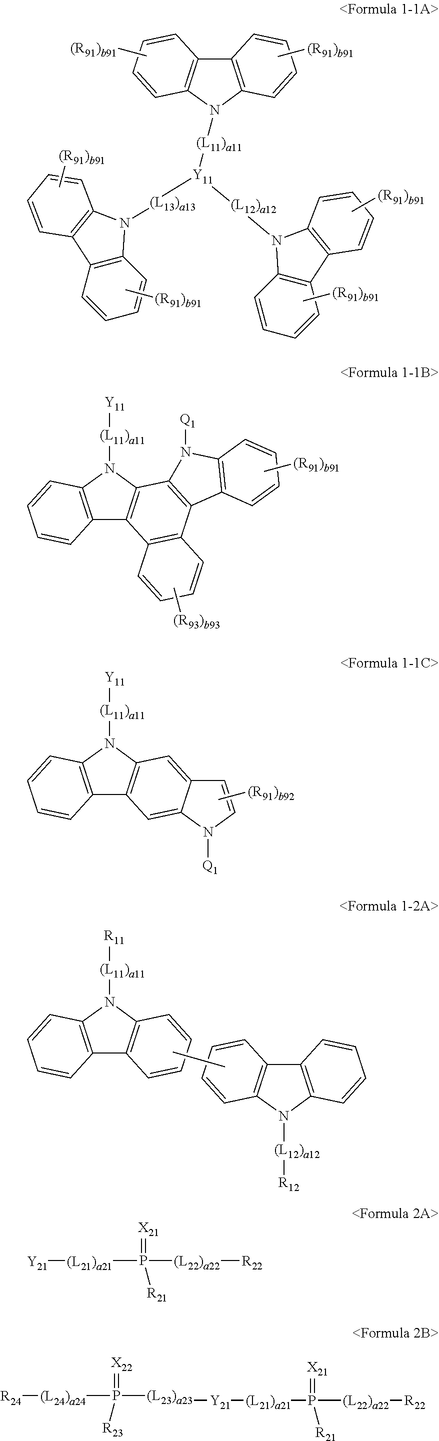

In Formulae 1A, 1-1B, 1-1C, 1-2A, 2A, and 2B,

Y₁₁, L₁₁, L₁₂, a11, a12, R₁₁, and R₁₂ may be defined the same as in Formulae 1-1 and 1-2;

X₂₁, L₂₁, L₂₂, a21, a22, R₂₁, R₂₂, and Y₂₁ may be each independently defined the same as in Formula 2;

Q₁, R₉₁, R₉₃, b91, b92, and b93 may be each independently defined the same as in Formulae 9-1 to 9-12;

L₁₃ may be defined the same as L₁₁ in Formula 1-1;

a13 may be defined the same as a13 in Formula 1-1;

X₂₂ may be defined the same as X₂₁ in Formula 2;

L₂₃ and L₂₄ may be each independently defined the same as L₂₁ in Formula 2;

a23 and a24 may be each independently defined the same as a21 in Formula 2; and

R₂₃ and R₂₄ may be each independently defined the same as R₂₁ in Formula 2;

In some embodiments, the first material may be represented by any one of Formulae 1-2A below, and the second material may be represented by one of Formulae 2A-1 and 2B-1 below, but they are not limited thereto:

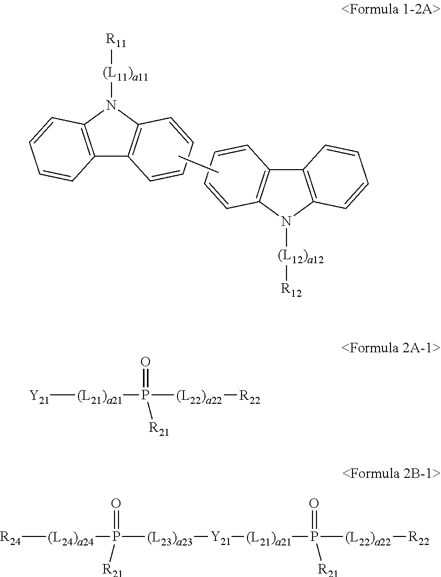

wherein in Formulae 1-2A, 2A-1, and 2B-1,

L₁₁, L₁₂, a11, a12, R₁₁, and R₁₂ may be each independently defined the same as in Formula 1-2;

L₂₁, L₂₂, a21, a22, R₂₁, R₂₂, and Y₂₁ may be each independently defined the same as in Formula 2;

L₂₃ and L₂₄ may be each independently defined the same as L₂₁ in Formula 2;

a23 and a24 may be each independently defined the same as a21 in Formula 2; and

R₂₃ and R₂₄ may be each independently defined the same as R₂₁ in Formula 2;

In some embodiments, the first material may be selected from Compounds 1 to 173 below, and the second material may be selected from Compounds 201 to 276, but they are not limited thereto:

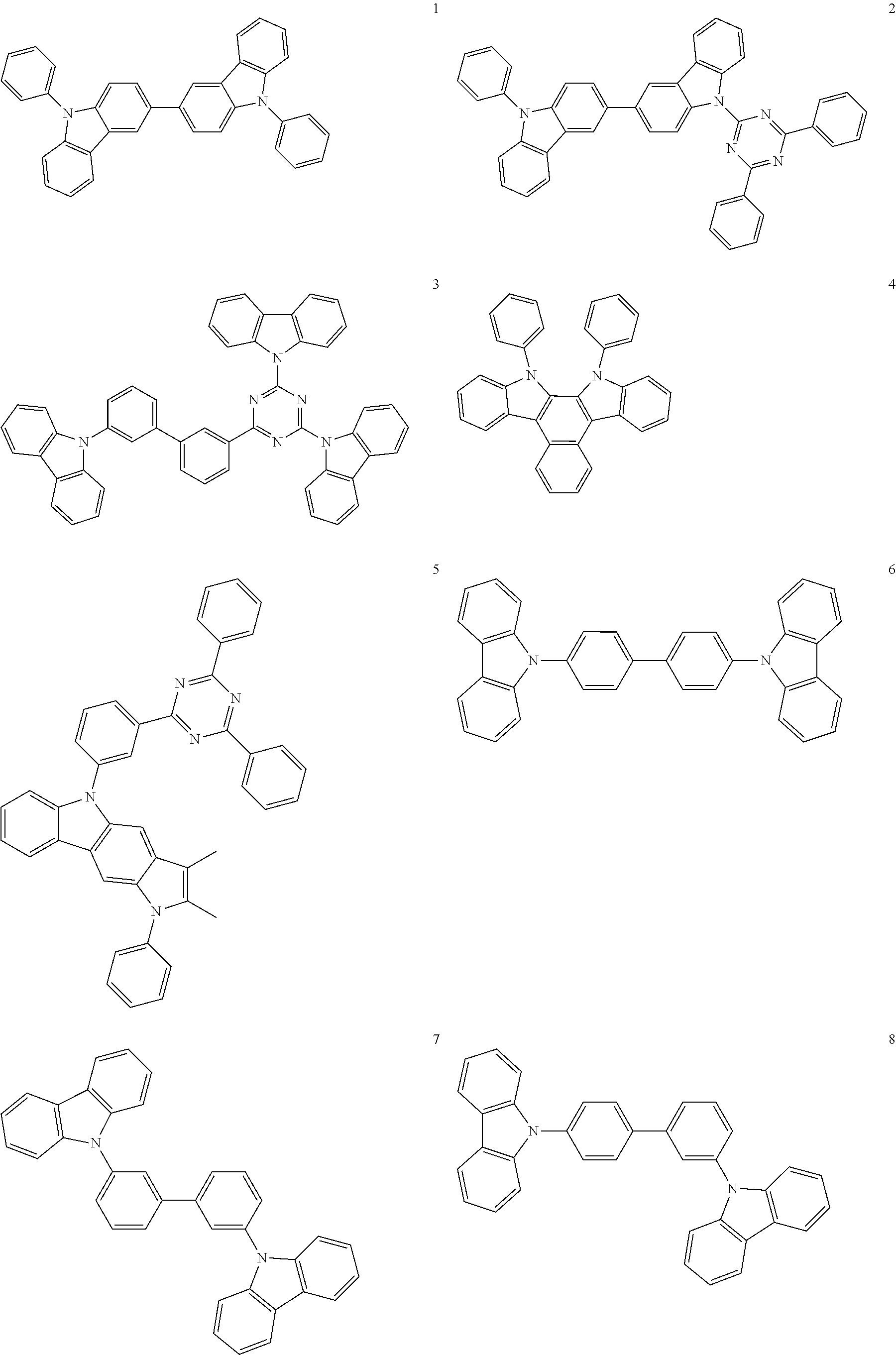

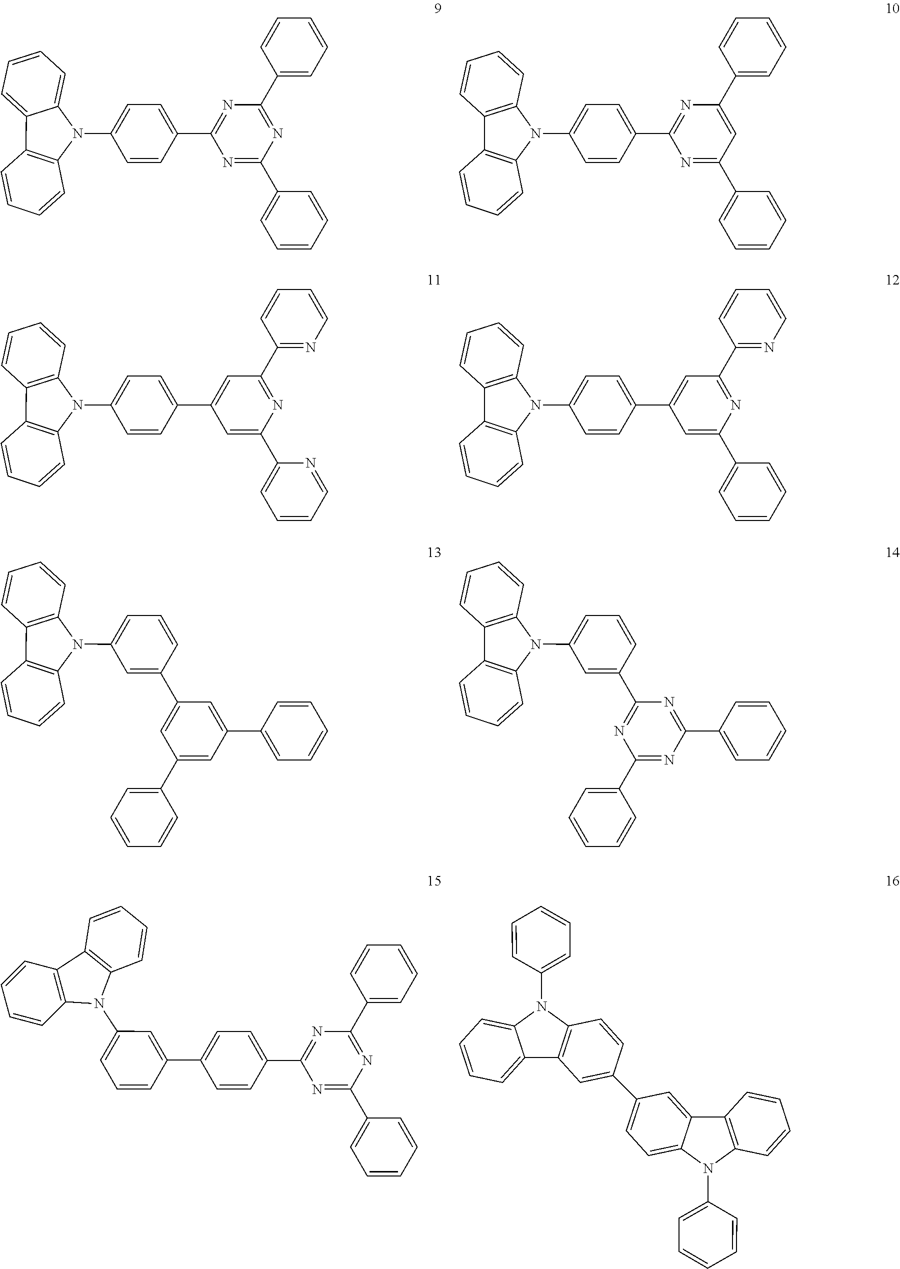

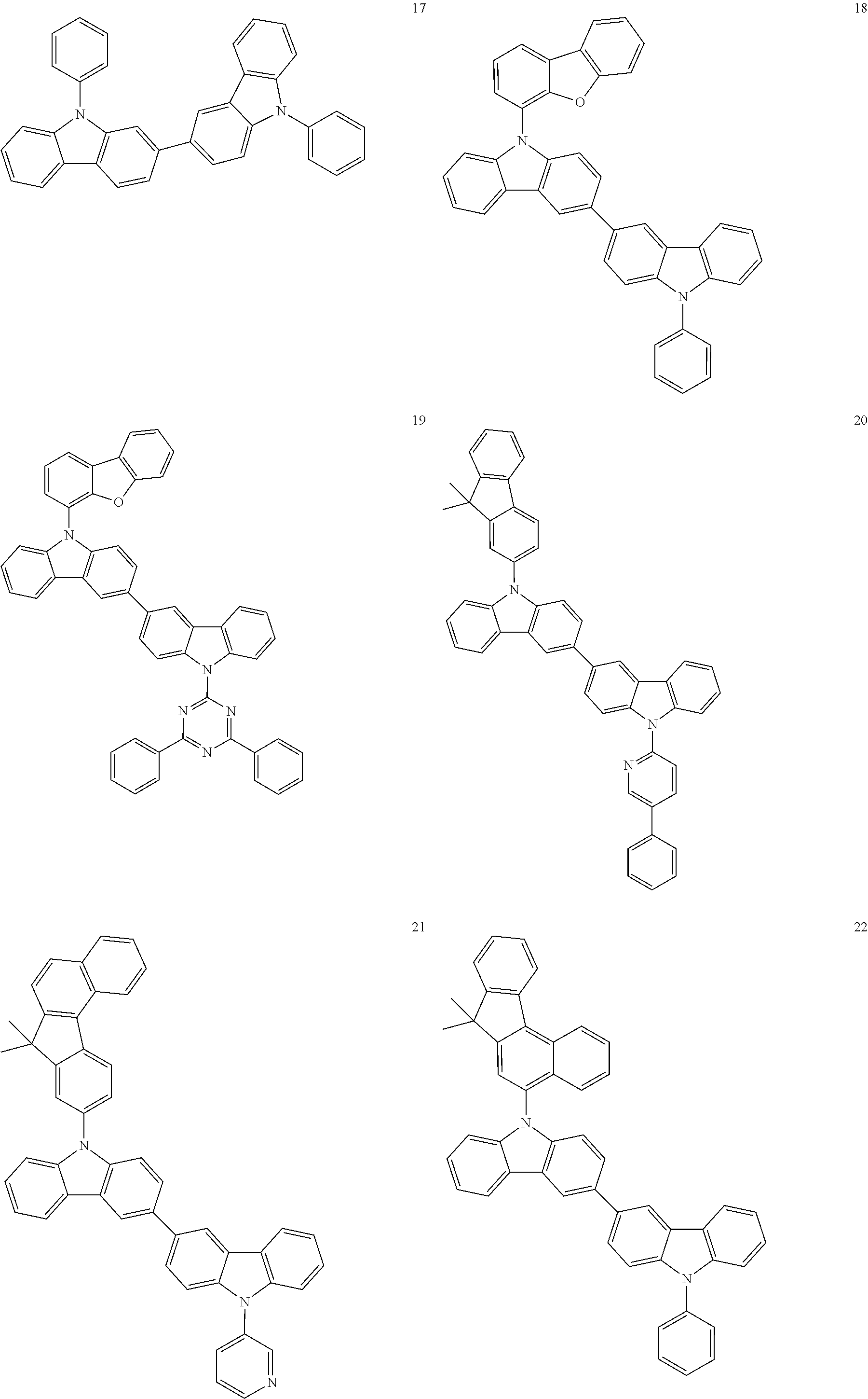

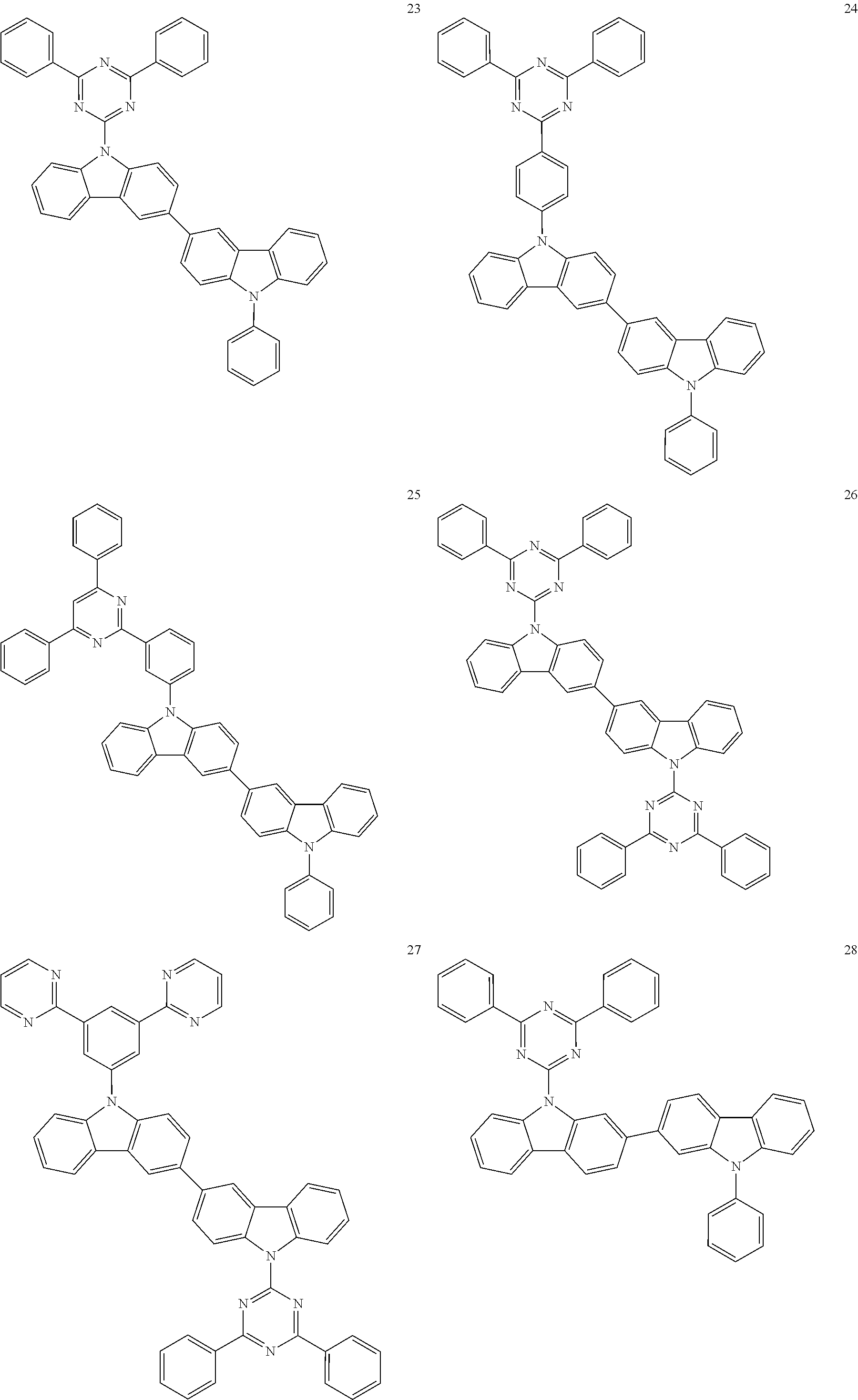

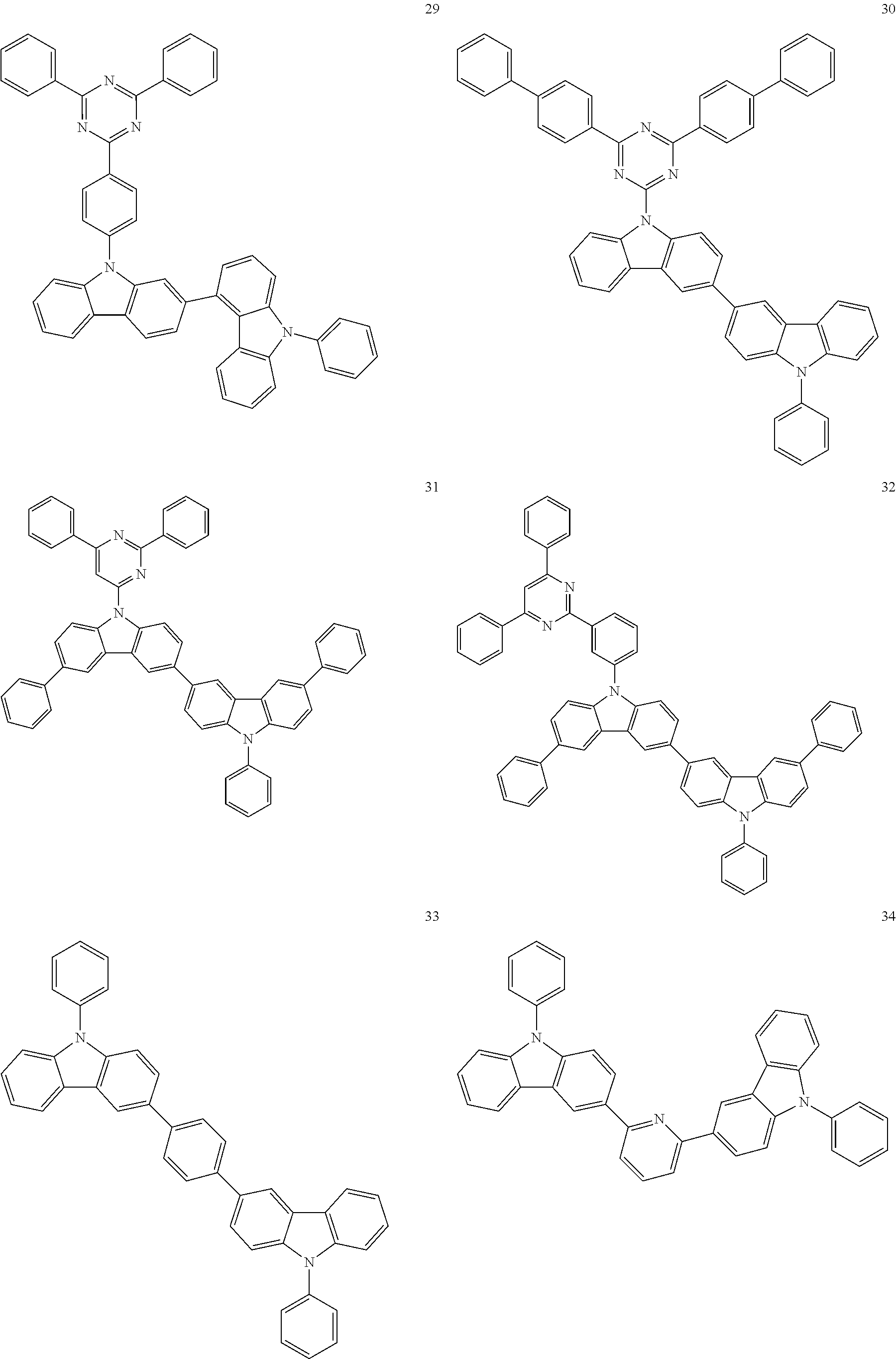

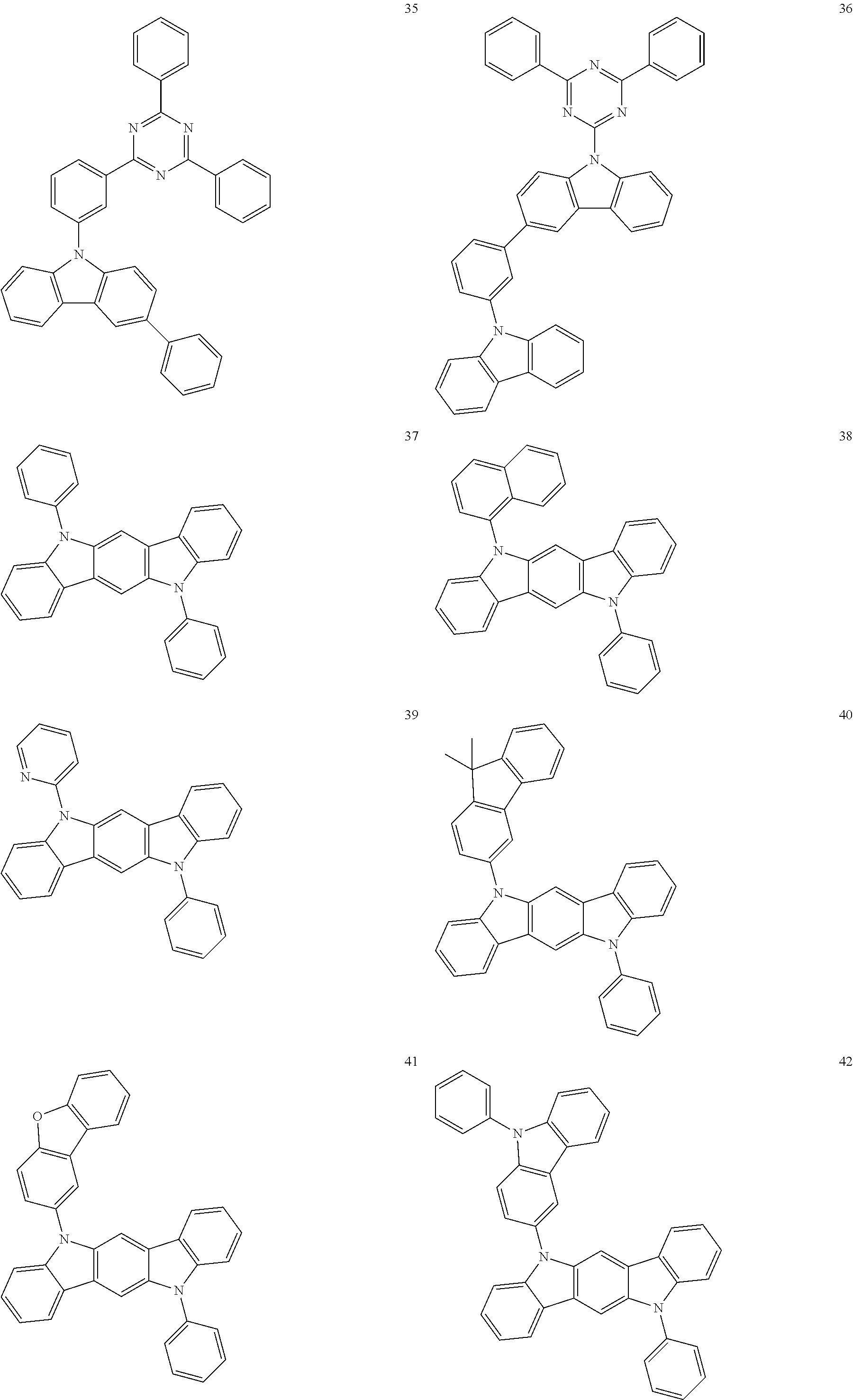

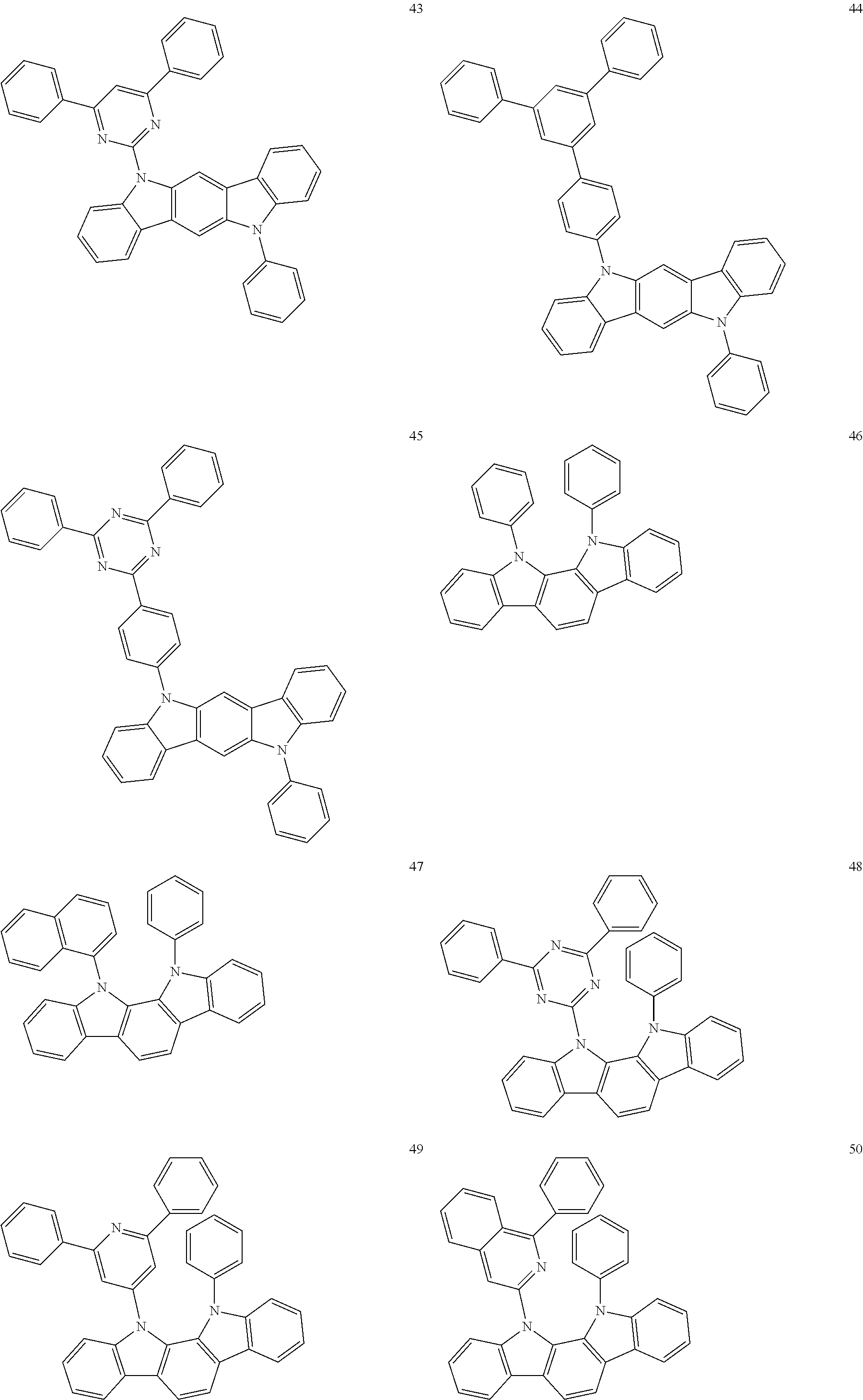

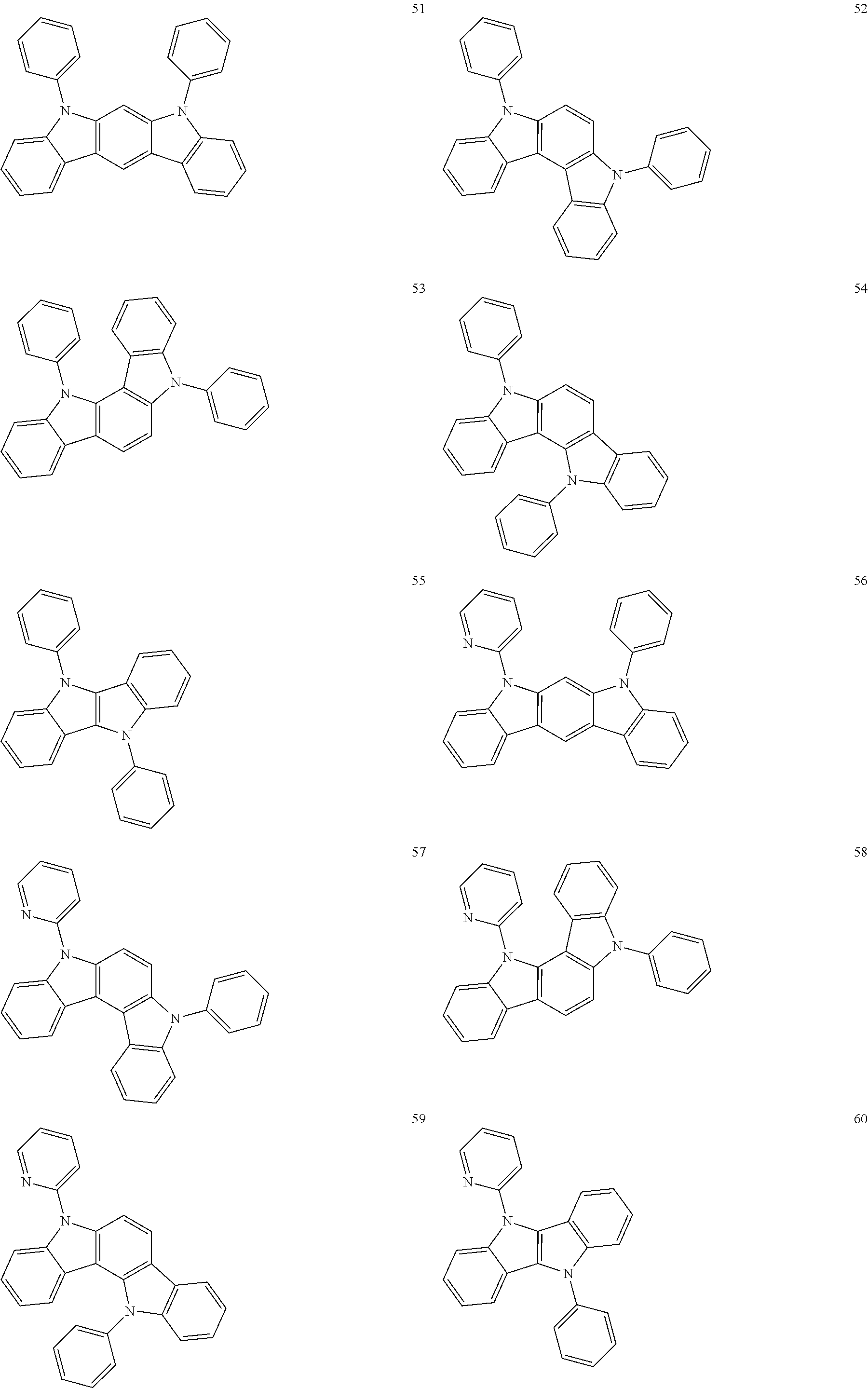

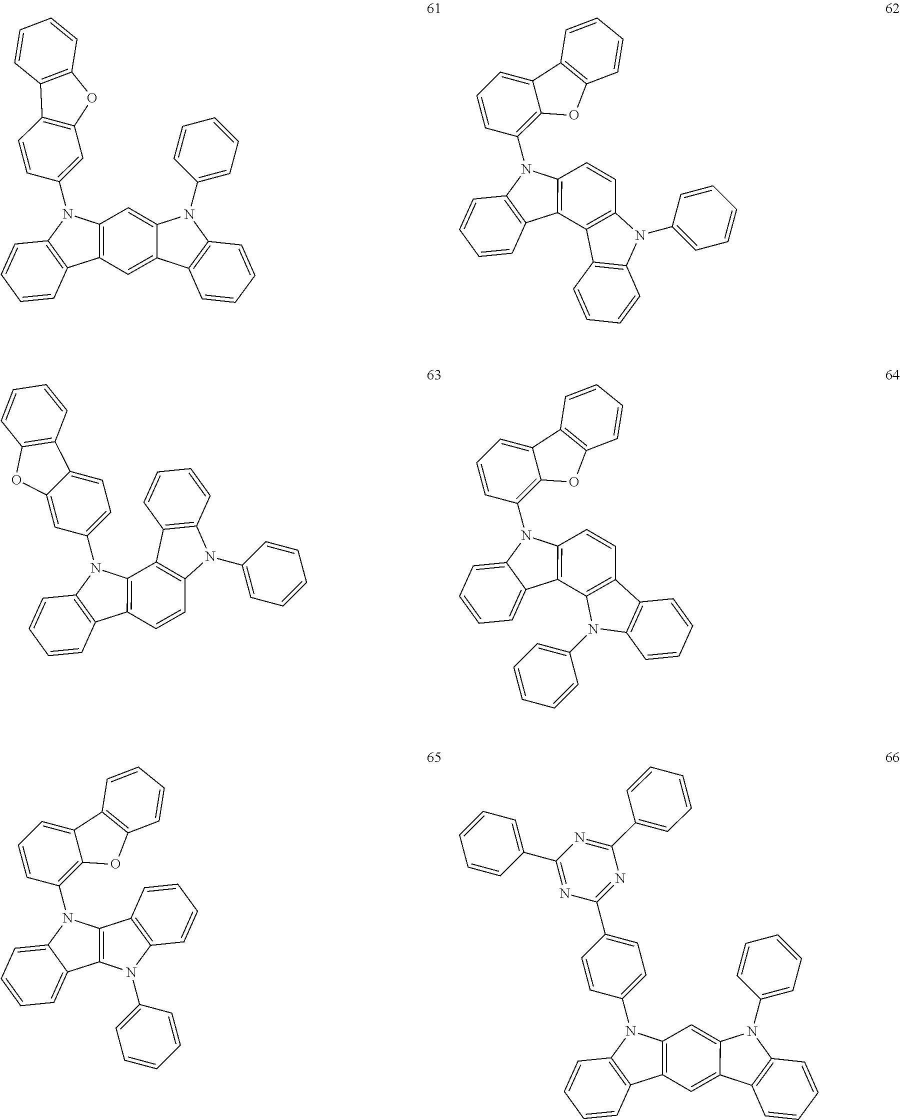 [SMILES: c1ccc(-n2c3ccccc3c3cc4c5ccccc5n(-c5ccc6c(c5)oc5ccccc56)c4cc32)cc1 ; c1ccc(-n2c3ccccc3c3c4c5ccccc5n(-c5cccc6c5oc5ccccc56)c4ccc32)cc1 ; c1ccc(-n2c3ccccc3c3c2ccc2c4ccccc4n(-c4ccc5c(c4)oc4ccccc45)c23)cc1 ; c1ccc(-n2c3ccccc3c3ccc4c(c5ccccc5n4-c4cccc5c4oc4ccccc45)c32)cc1 ; c1ccc(-n2c3ccccc3c3c2c2ccccc2n3-c2cccc3c2oc2ccccc23)cc1 ; c1ccc(-c2nc(-c3ccccc3)nc(-c3ccc(-n4c5ccccc5c5cc6c7ccccc7n(-c7ccccc7)c6cc54)cc3)n2)cc1]

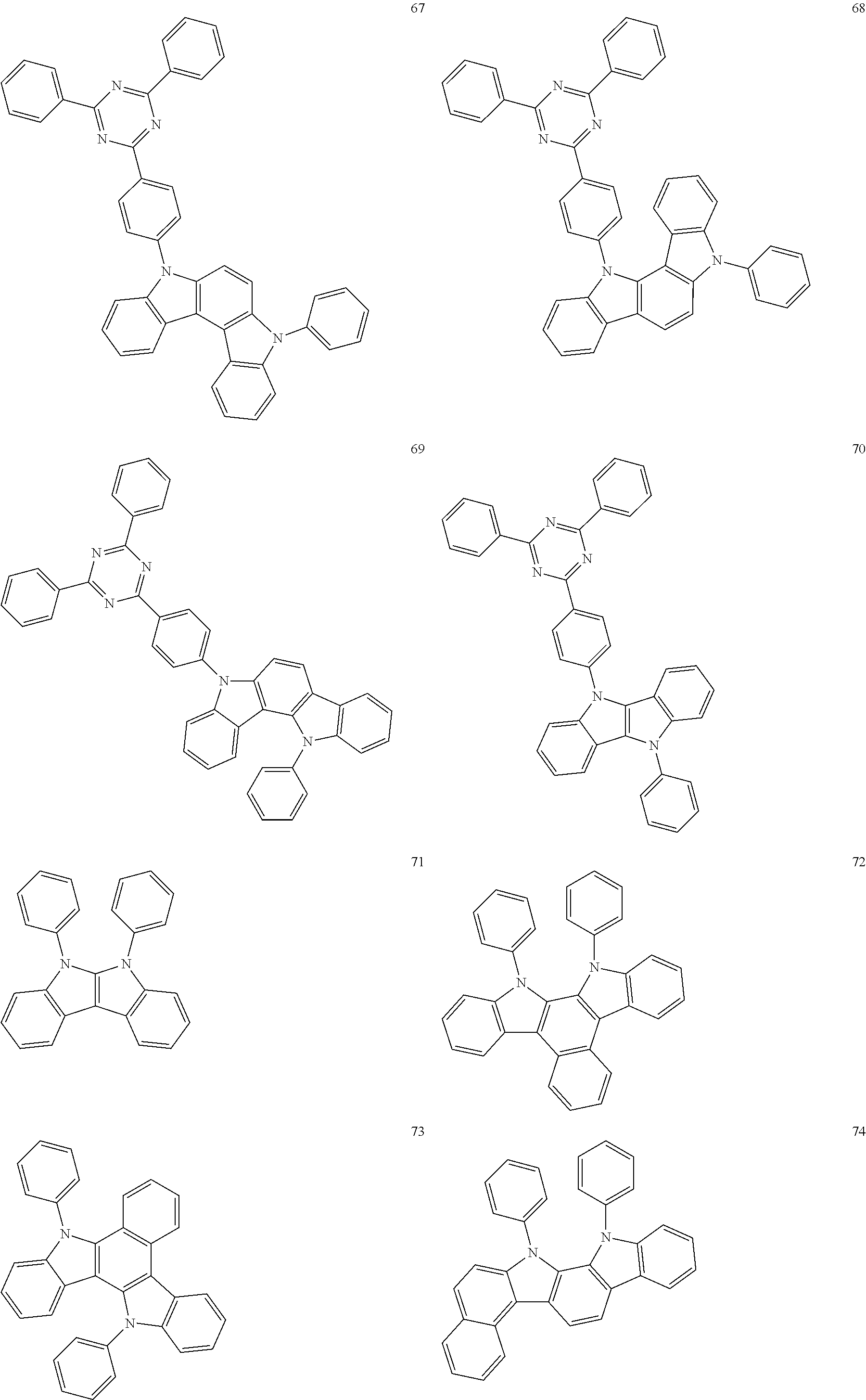

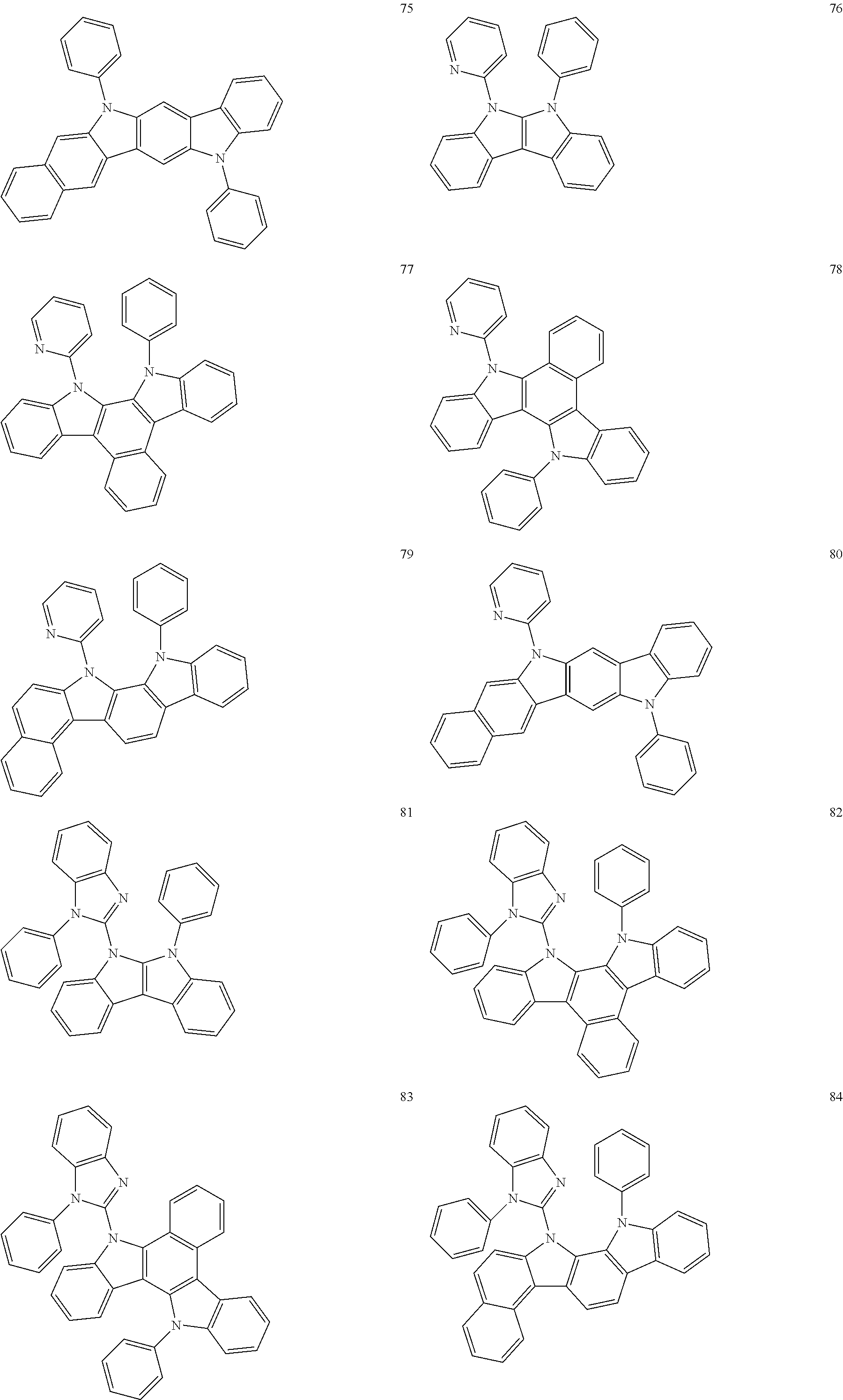

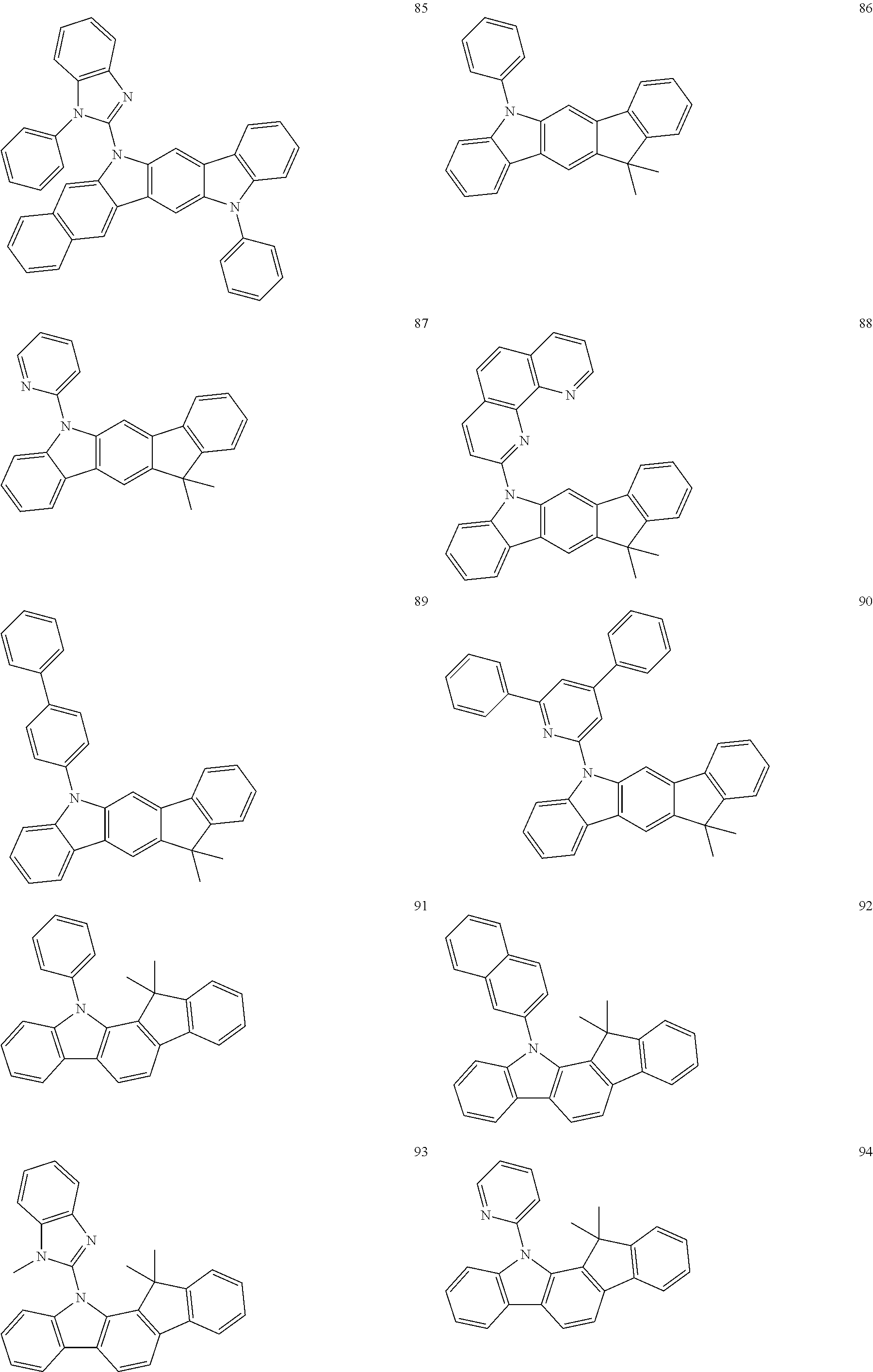

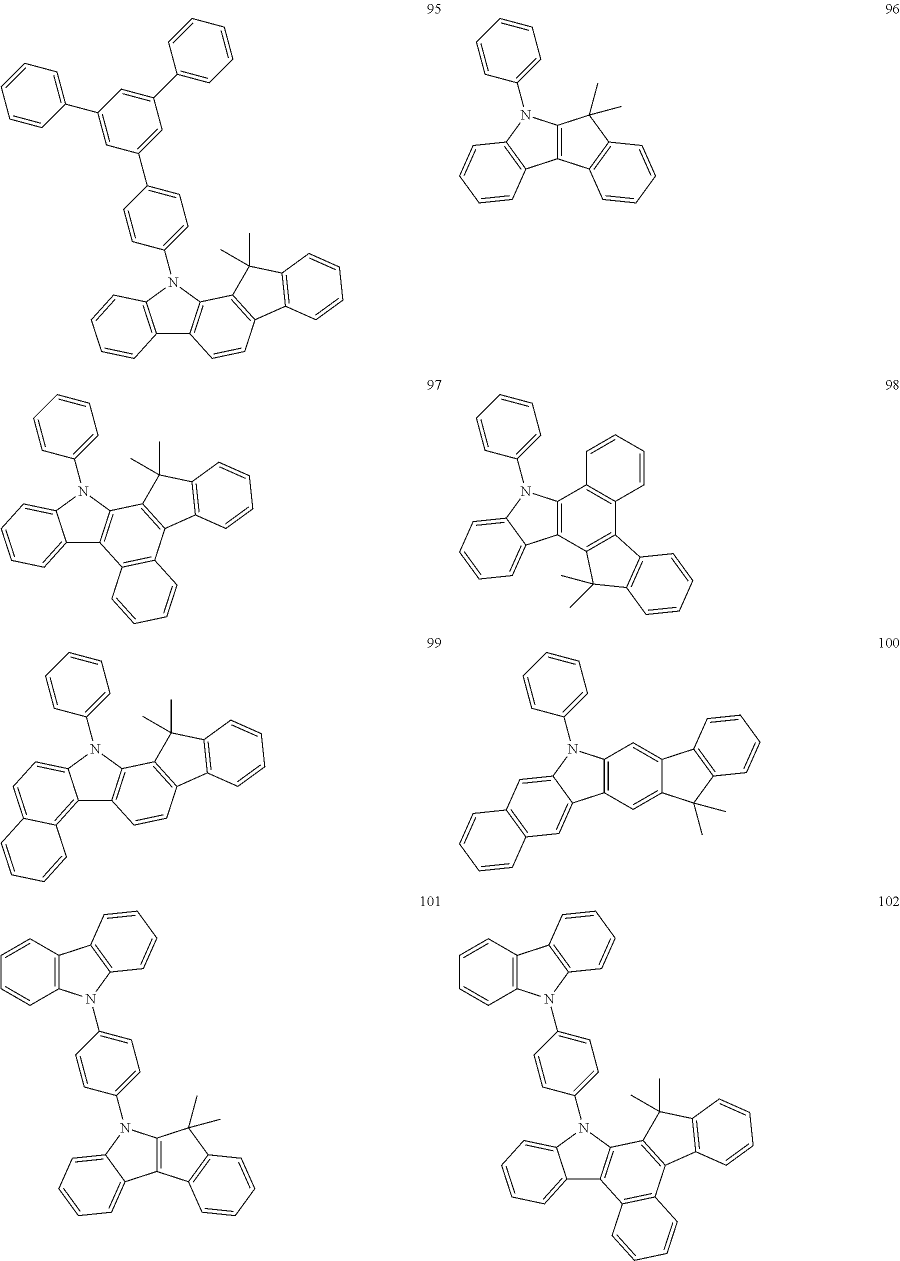

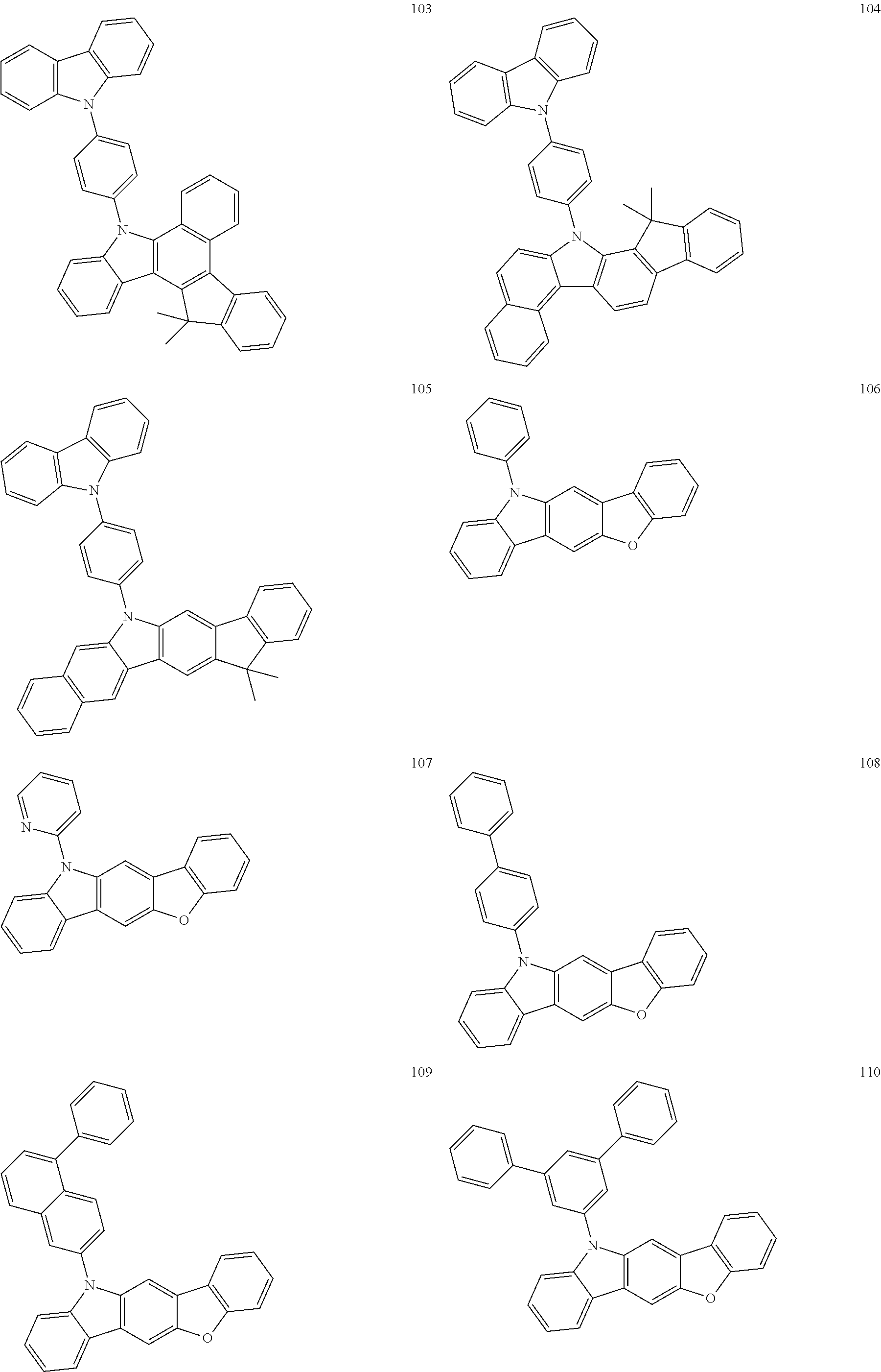

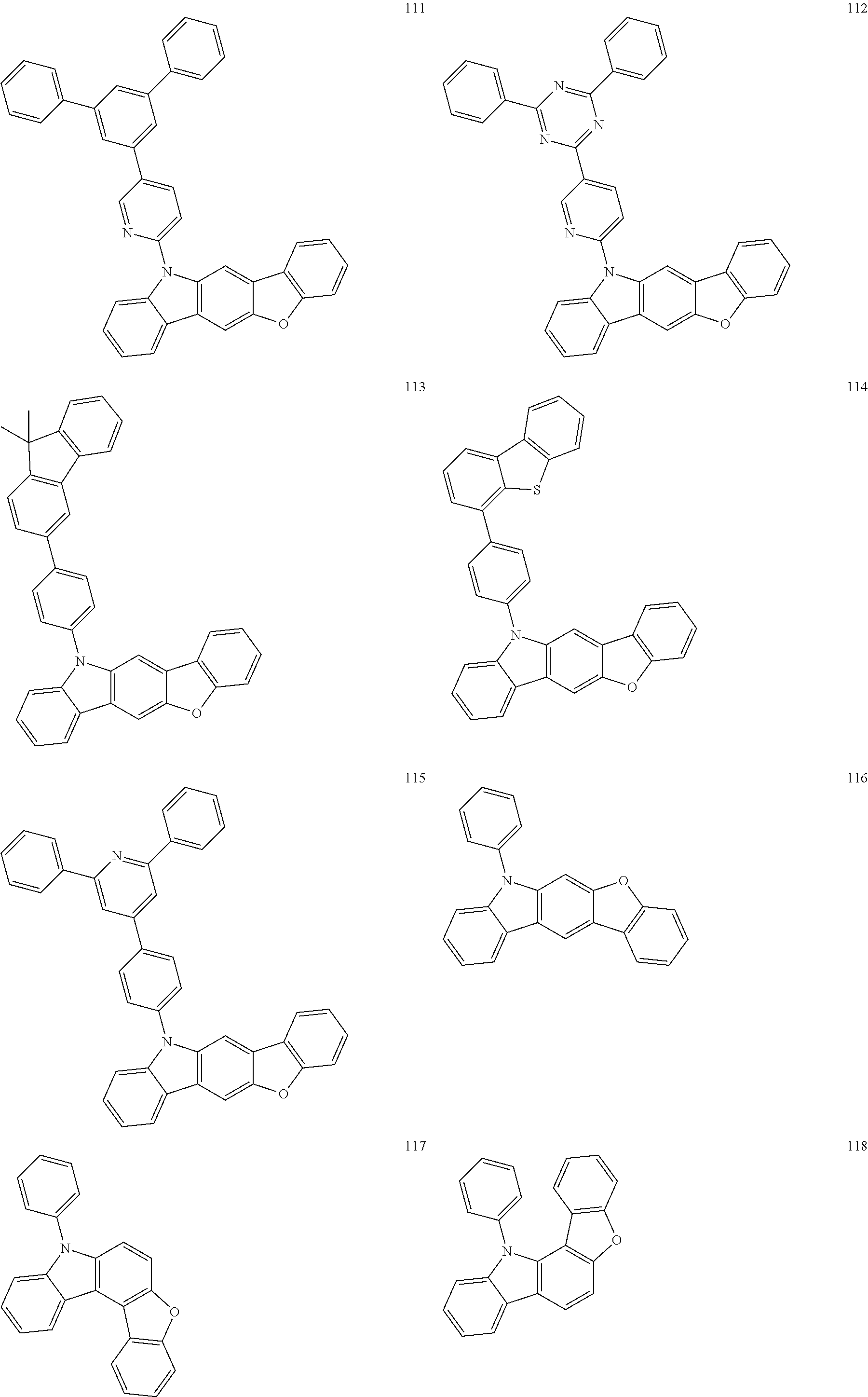

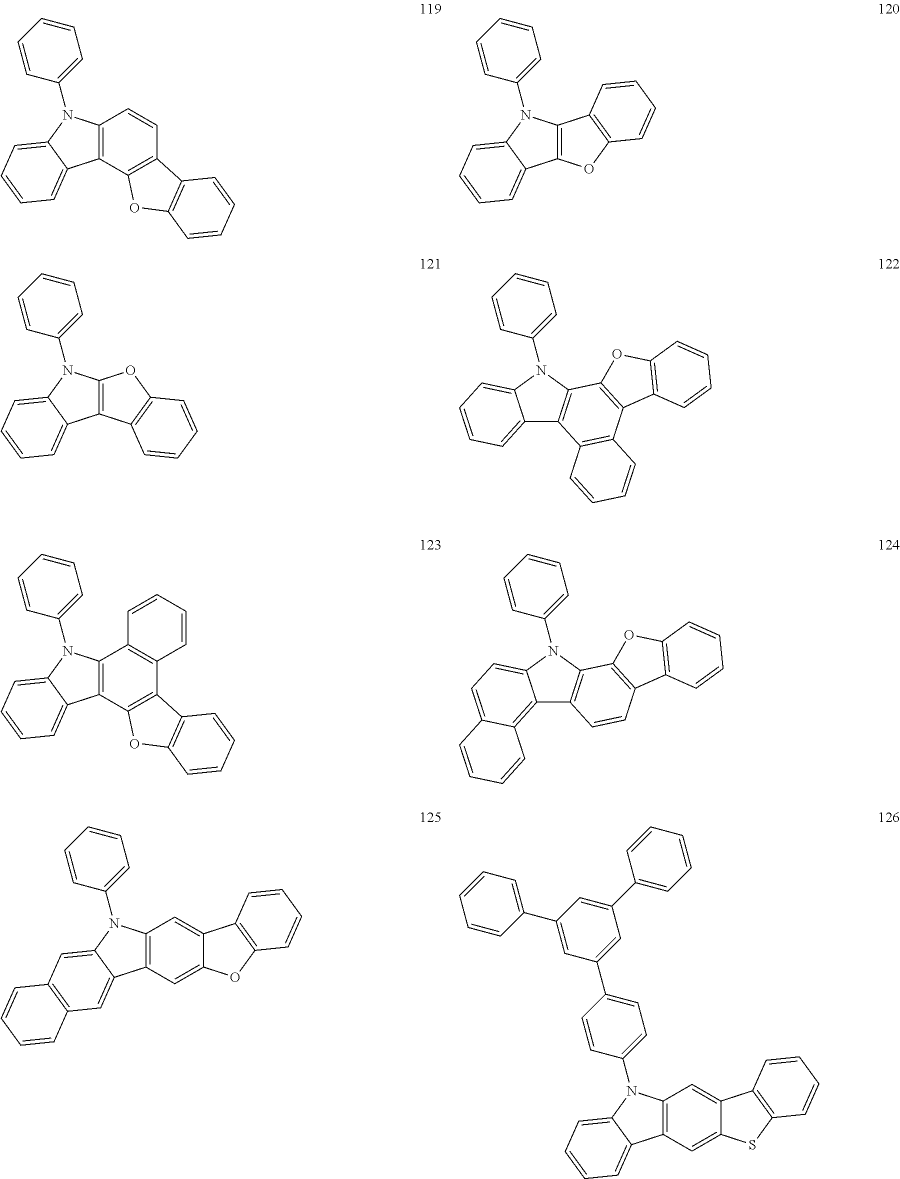

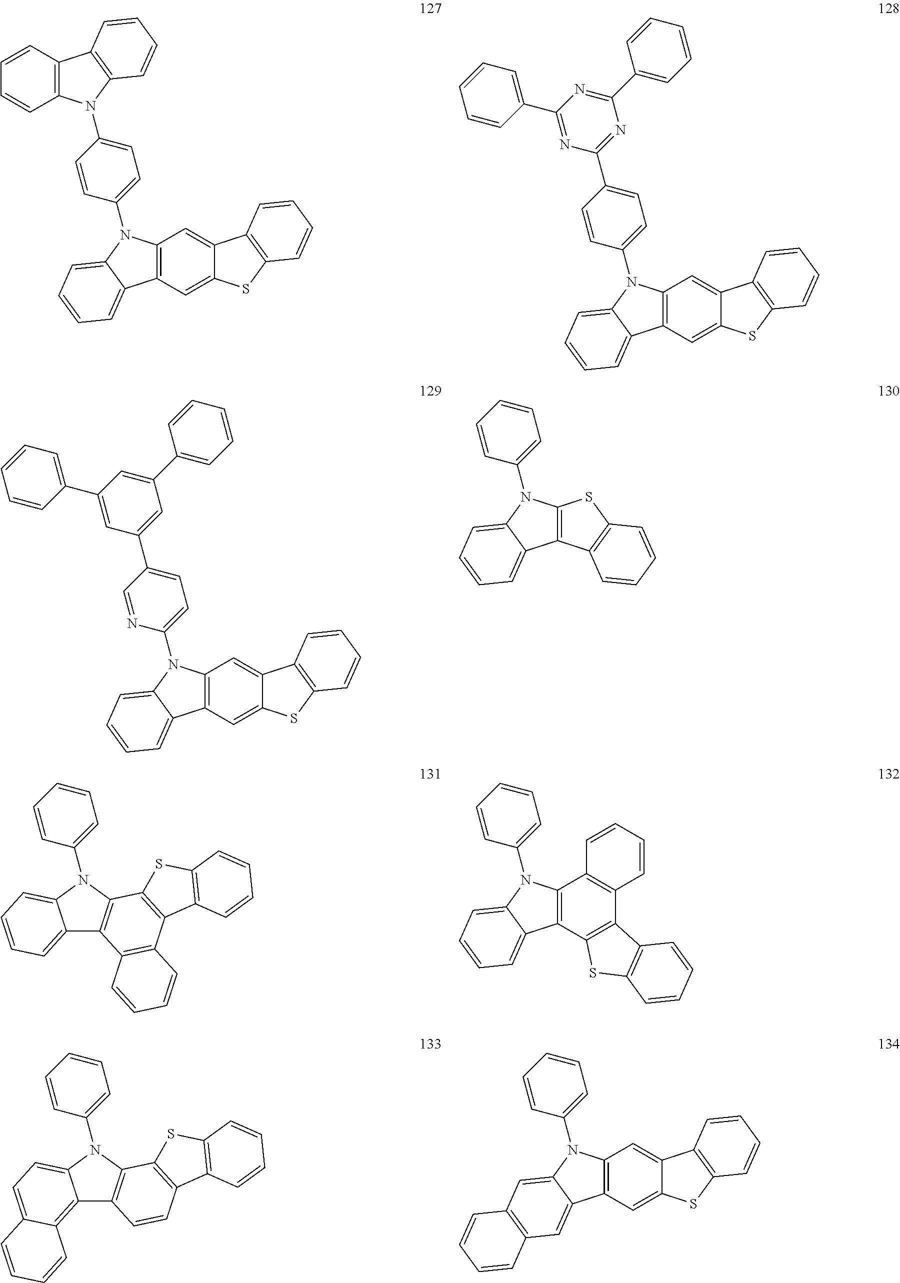

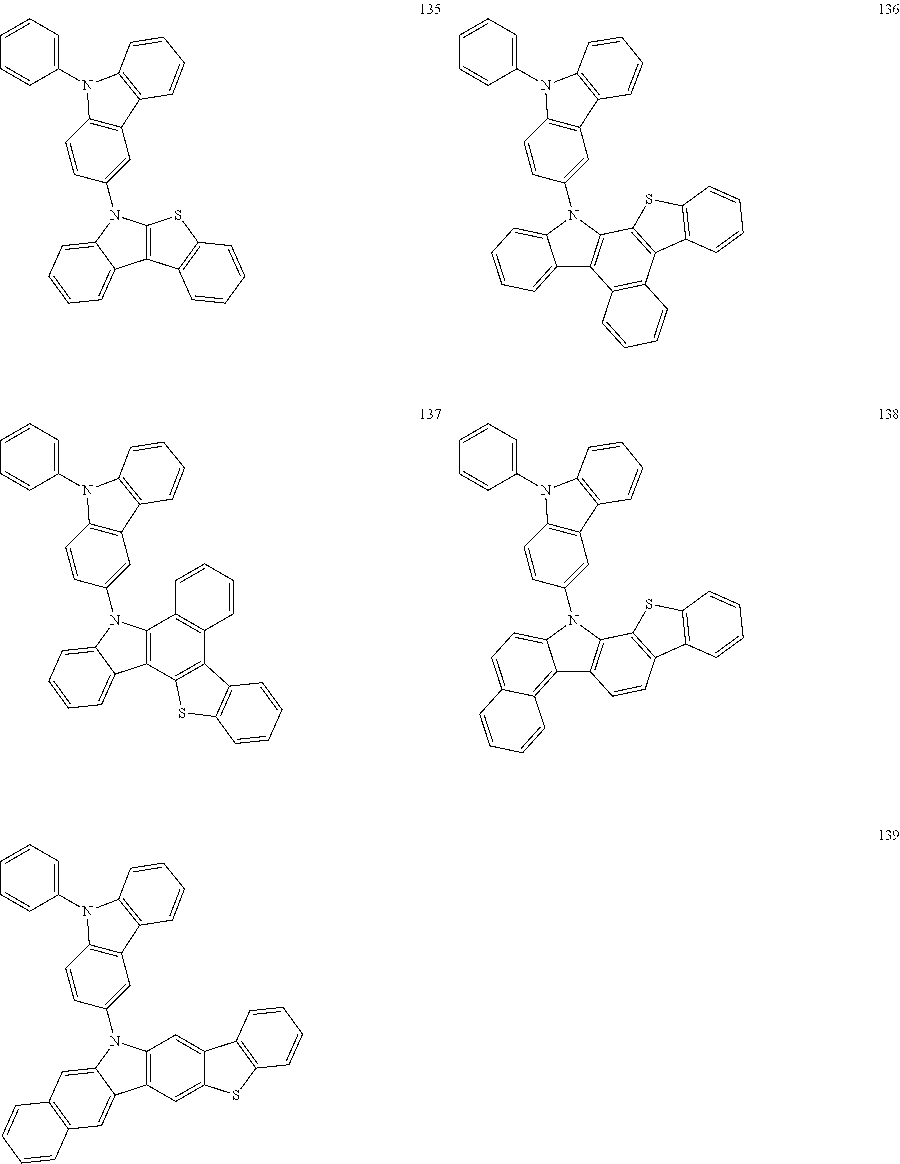 [SMILES: c1ccc(-n2c3ccccc3c3cc(-n4c5ccccc5c5c6ccccc6sc54)ccc32)cc1 ; c1ccc(-n2c3ccccc3c3cc(-n4c5ccccc5c5c6ccccc6c6c7ccccc7sc6c54)ccc32)cc1 ; c1ccc(-n2c3ccccc3c3cc(-n4c5ccccc5c5c6sc7ccccc7c6c6ccccc6c54)ccc32)cc1 ; c1ccc(-n2c3ccccc3c3cc(-n4c5ccc6ccccc6c5c5ccc6c7ccccc7sc6c54)ccc32)cc1 ; c1ccc(-n2c3ccccc3c3cc(-n4c5cc6ccccc6cc5c5cc6sc7ccccc7c6cc54)ccc32)cc1]

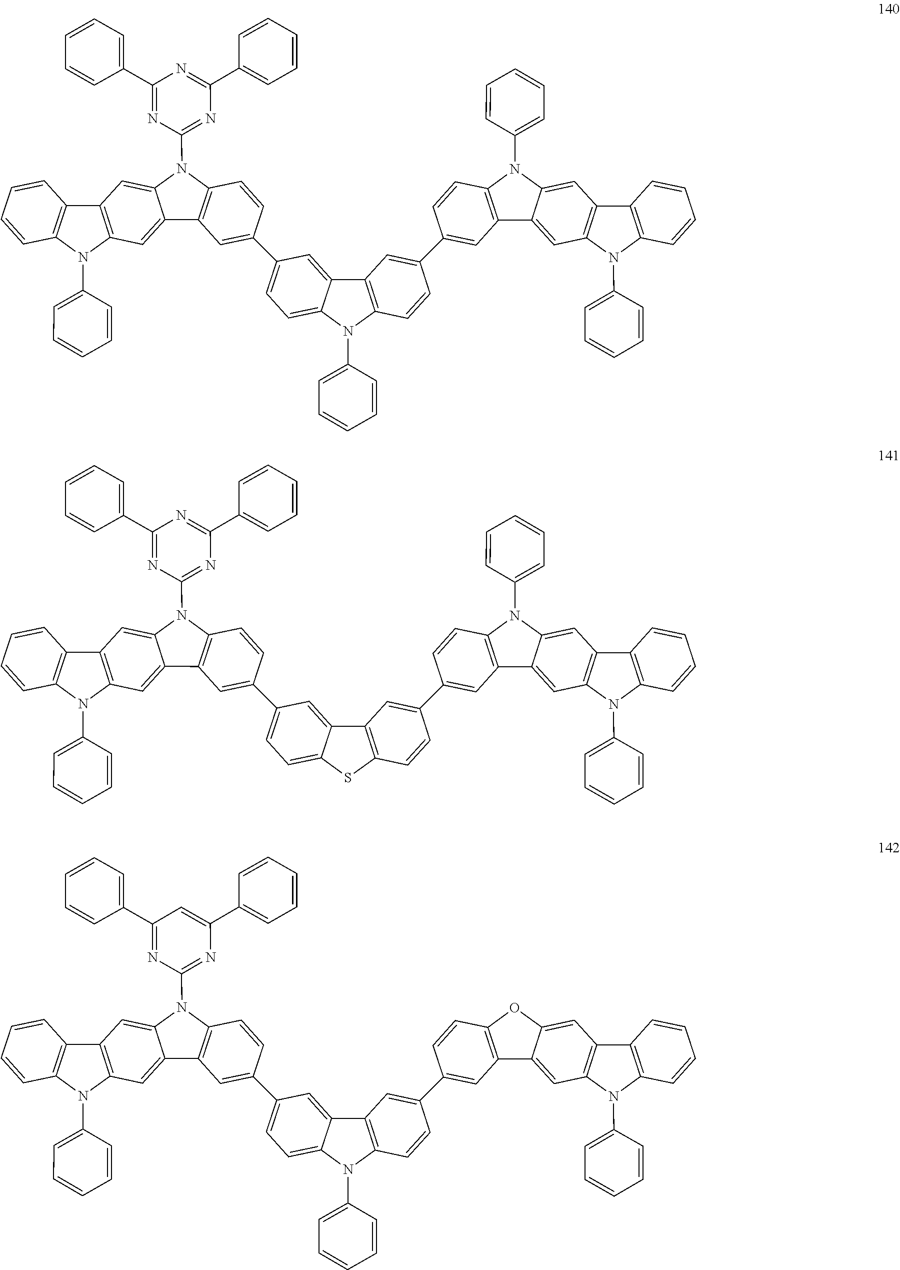 [SMILES: c1ccc(-c2nc(-c3ccccc3)nc(-n3c4ccc(-c5ccc6c(c5)c5cc(-c7ccc8c(c7)c7cc9c(cc7n8-c7ccccc7)c7ccccc7n9-c7ccccc7)ccc5n6-c5ccccc5)cc4c4cc5c(cc43)c3ccccc3n5-c3ccccc3)n2)cc1 ; c1ccc(-c2nc(-c3ccccc3)nc(-n3c4ccc(-c5ccc6sc7ccc(-c8ccc9c(c8)c8cc%10c(cc8n9-c8ccccc8)c8ccccc8n%10-c8ccccc8)cc7c6c5)cc4c4cc5c(cc43)c3ccccc3n5-c3ccccc3)n2)cc1 ; c1ccc(-c2cc(-c3ccccc3)nc(-n3c4ccc(-c5ccc6c(c5)c5cc(-c7ccc8oc9cc%10c%11ccccc%11n(-c%11ccccc%11)c%10cc9c8c7)ccc5n6-c5ccccc5)cc4c4cc5c(cc43)c3ccccc3n5-c3ccccc3)n2)cc1]

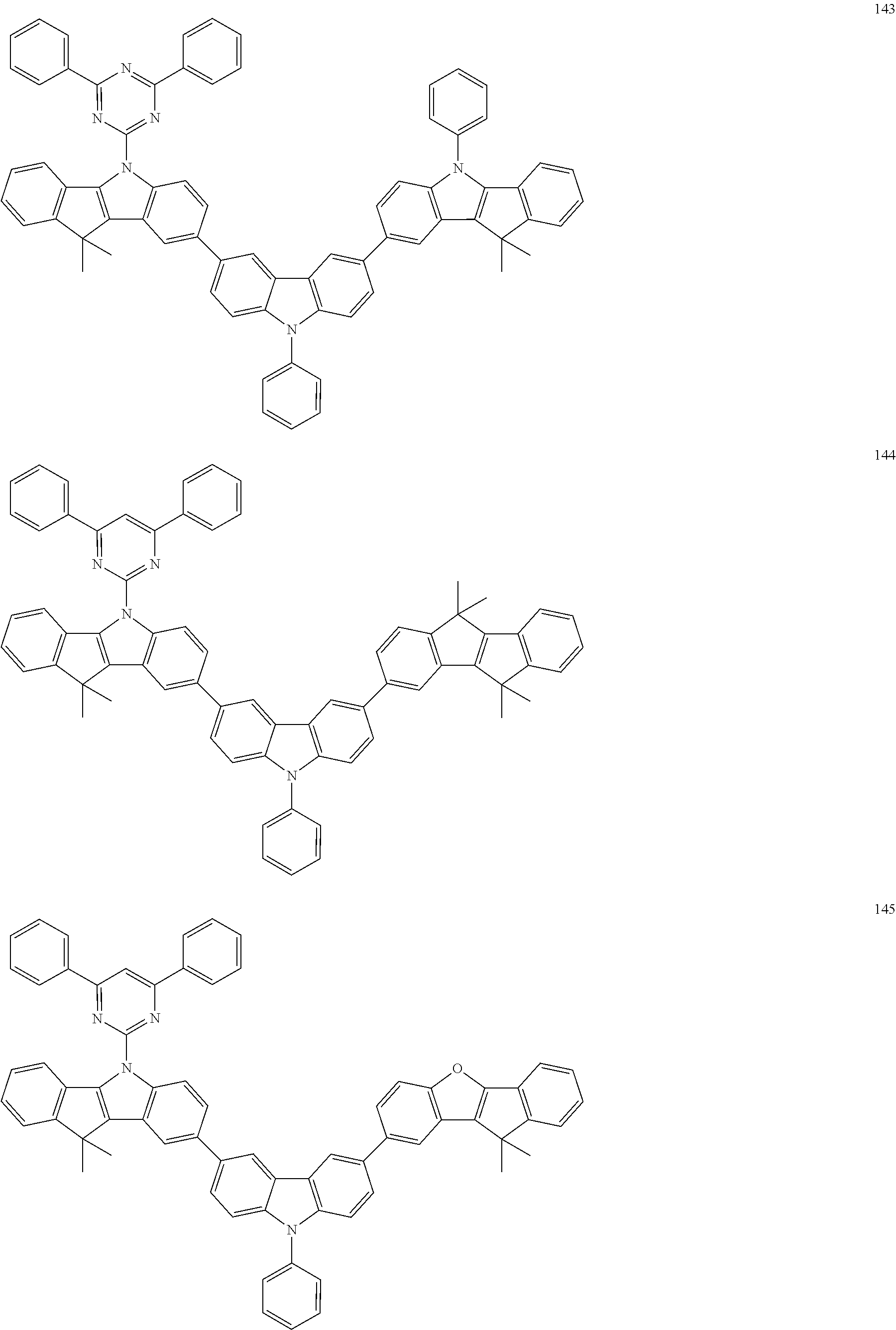 [SMILES: CC1(C)c2ccccc2-c2c1c1cc(-c3ccc4c(c3)c3cc(-c5ccc6c(c5)c5c(n6-c6nc(-c7ccccc7)nc(-c7ccccc7)n6)-c6ccccc6C5(C)C)ccc3n4-c3ccccc3)ccc1n2-c1ccccc1 ; CC1(C)C2=C(c3ccccc31)C(C)(C)c1ccc(-c3ccc4c(c3)c3cc(-c5ccc6c(c5)c5c(n6-c6nc(-c7ccccc7)cc(-c7ccccc7)n6)-c6ccccc6C5(C)C)ccc3n4-c3ccccc3)cc12 ; CC1(C)c2ccccc2-c2oc3ccc(-c4ccc5c(c4)c4cc(-c6ccc7c(c6)c6c(n7-c7nc(-c8ccccc8)cc(-c8ccccc8)n7)-c7ccccc7C6(C)C)ccc4n5-c4ccccc4)cc3c21]

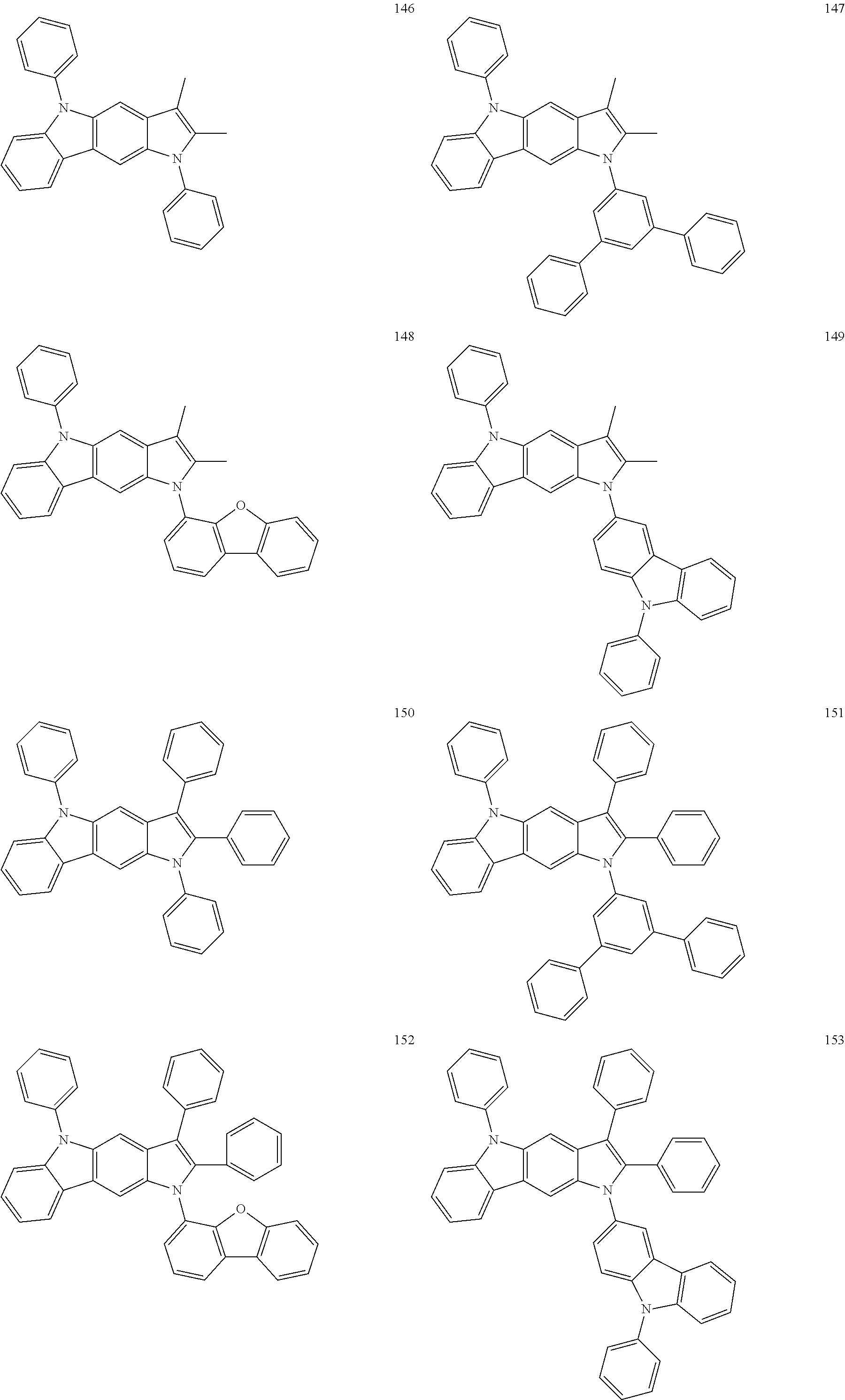

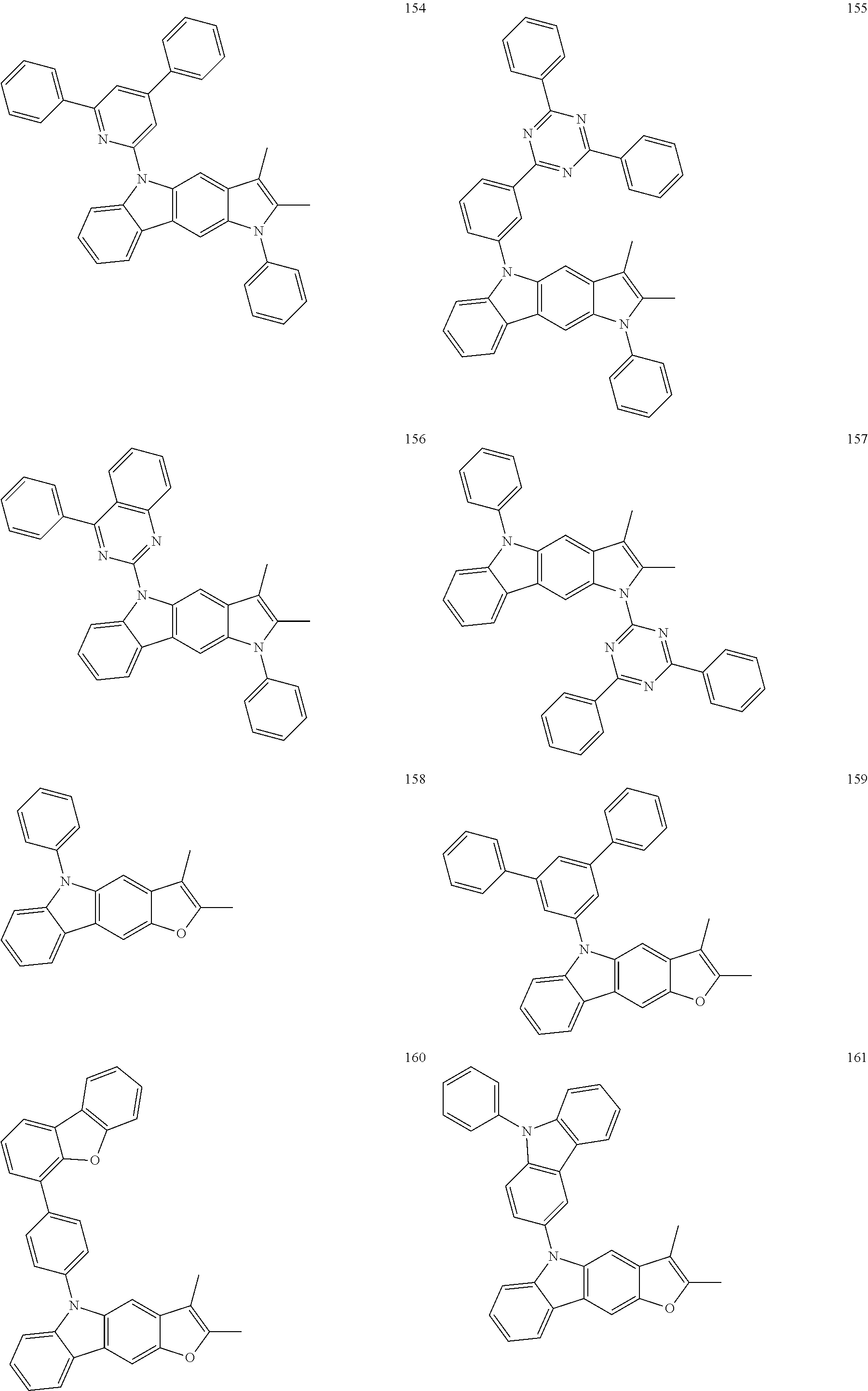

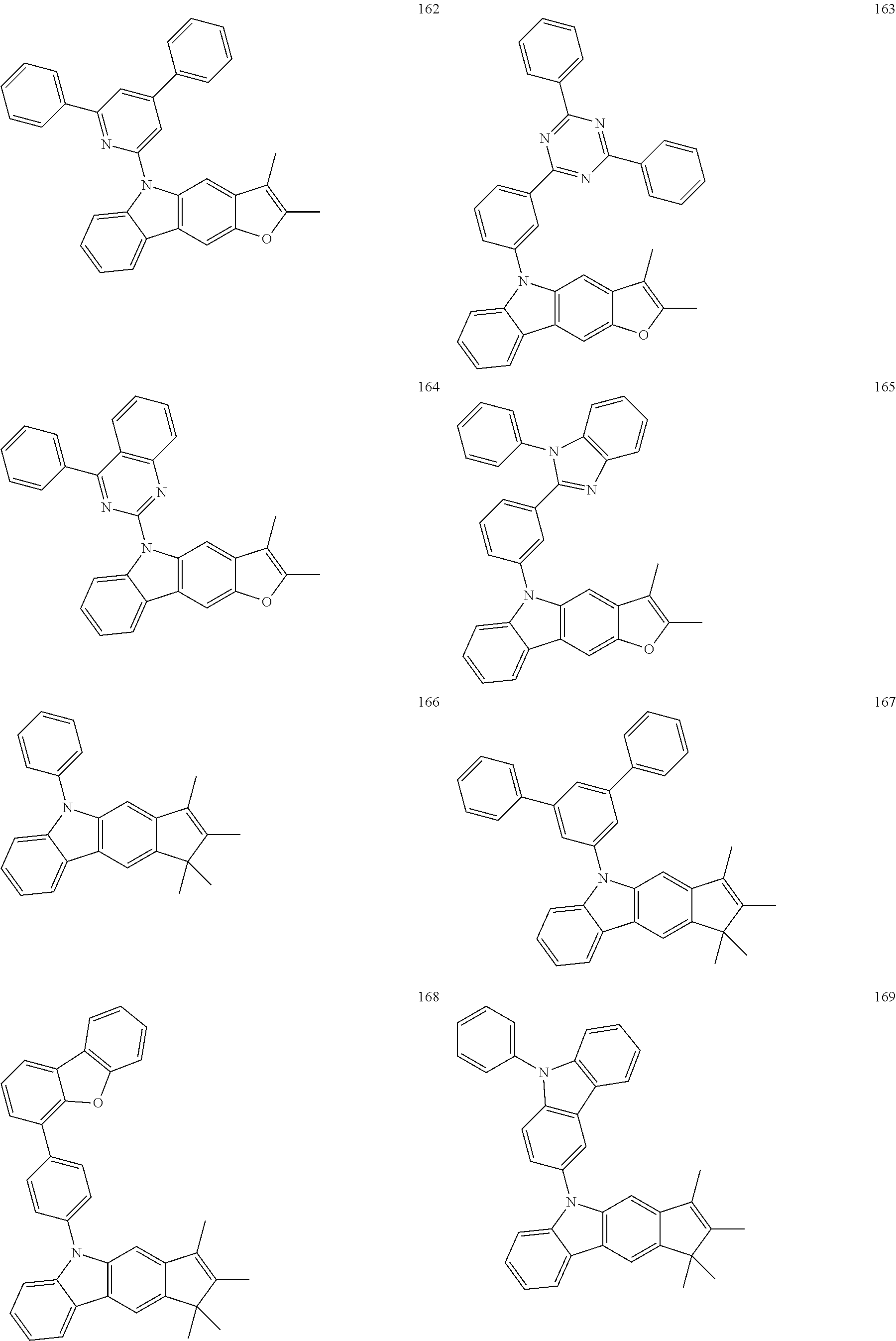

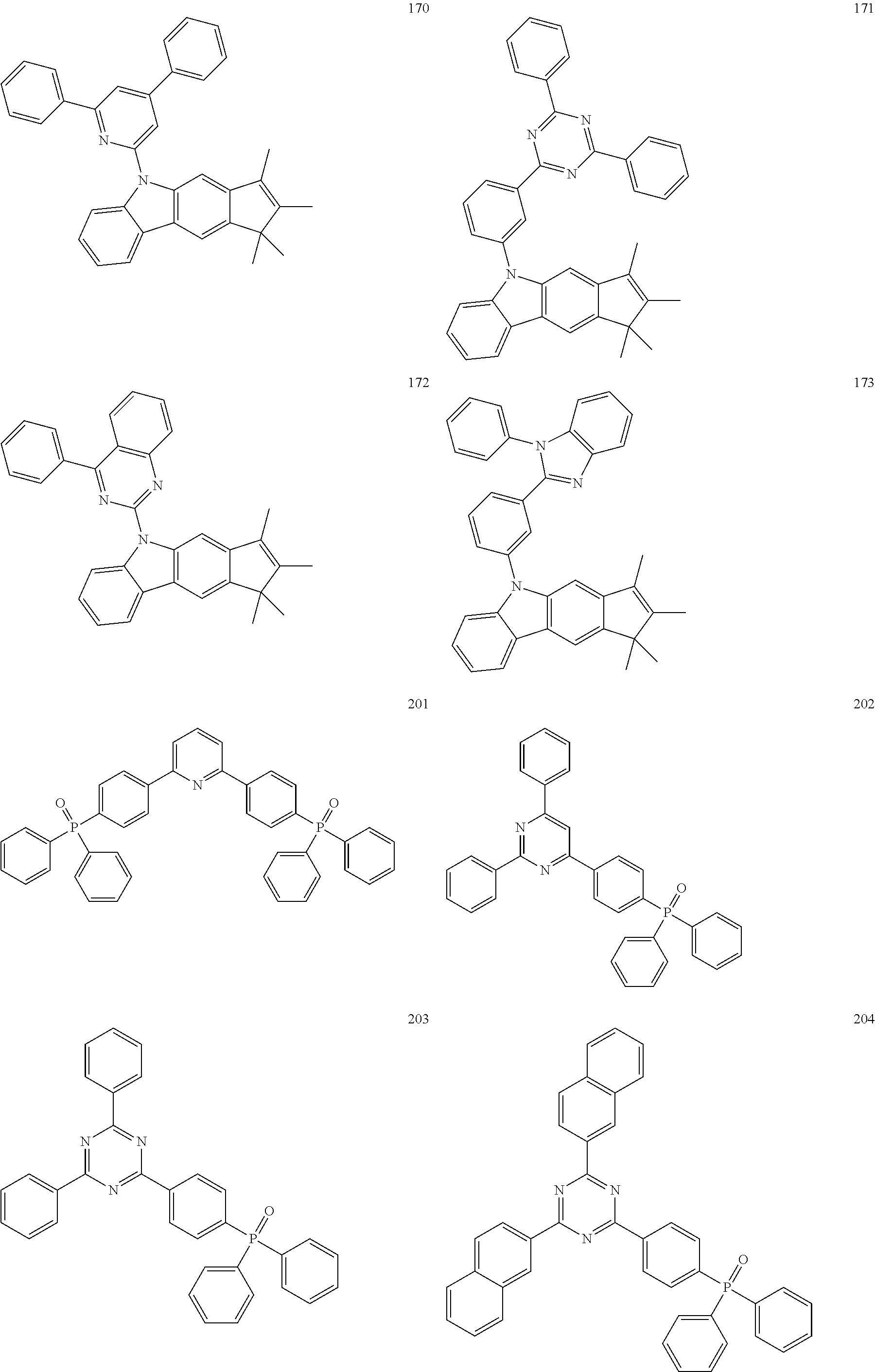

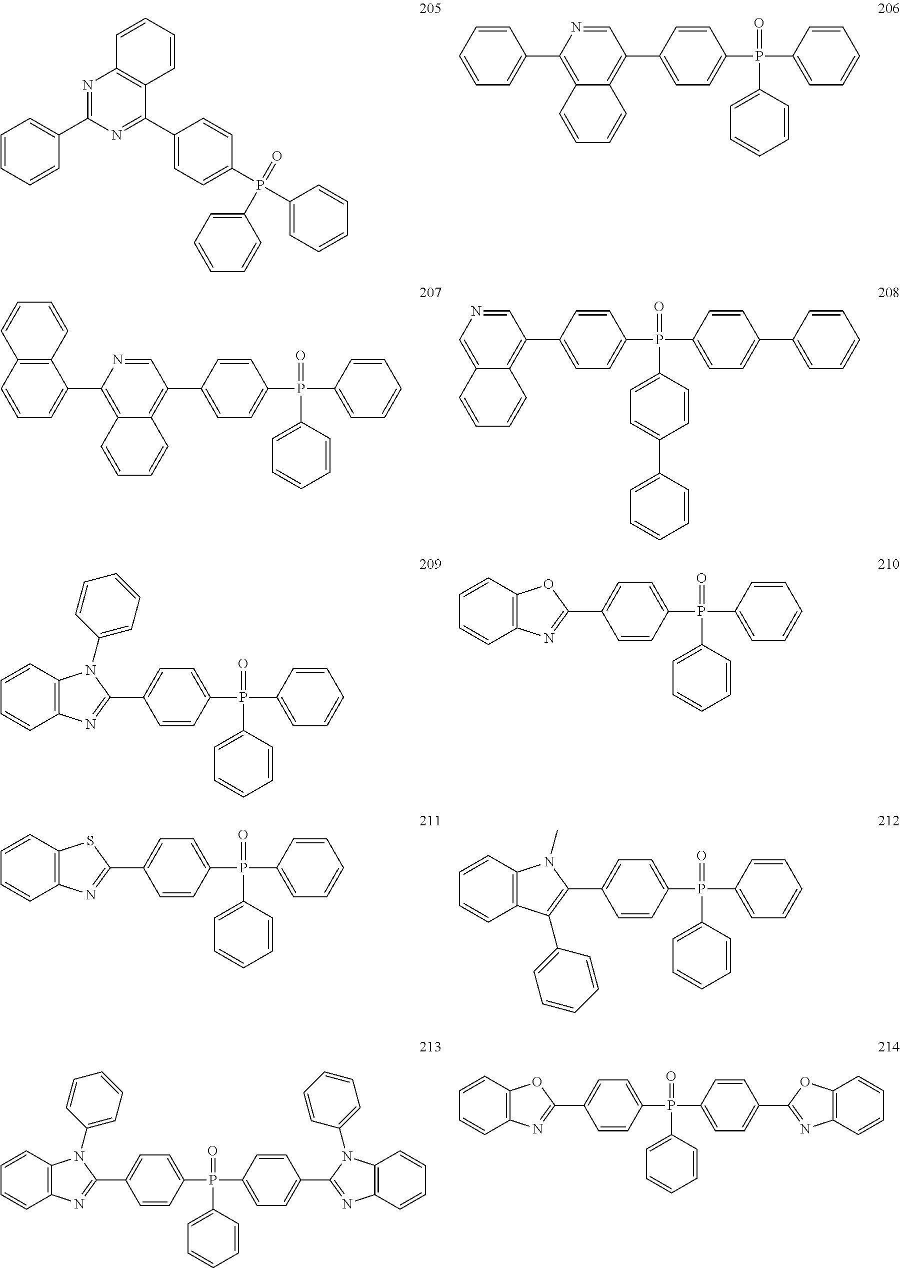

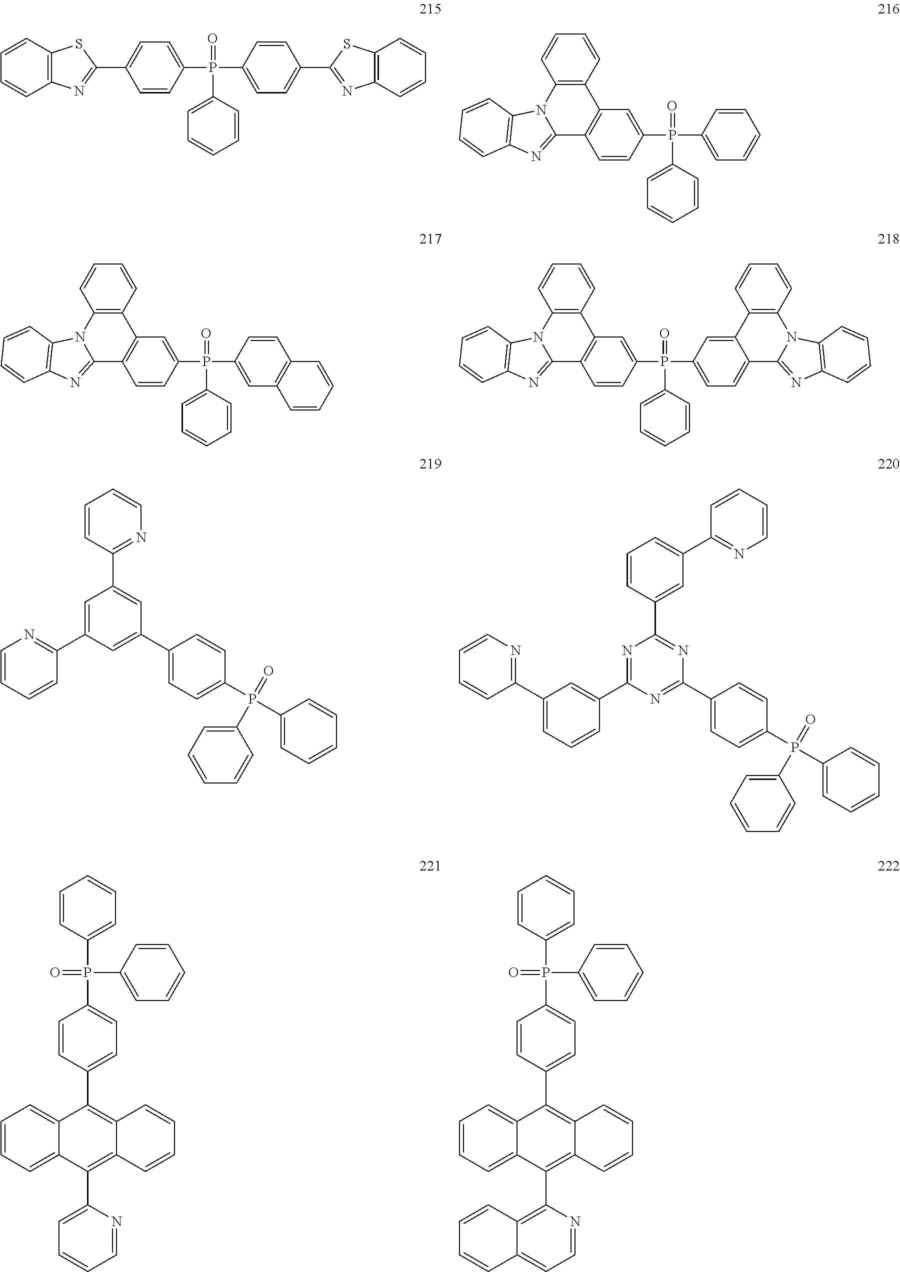

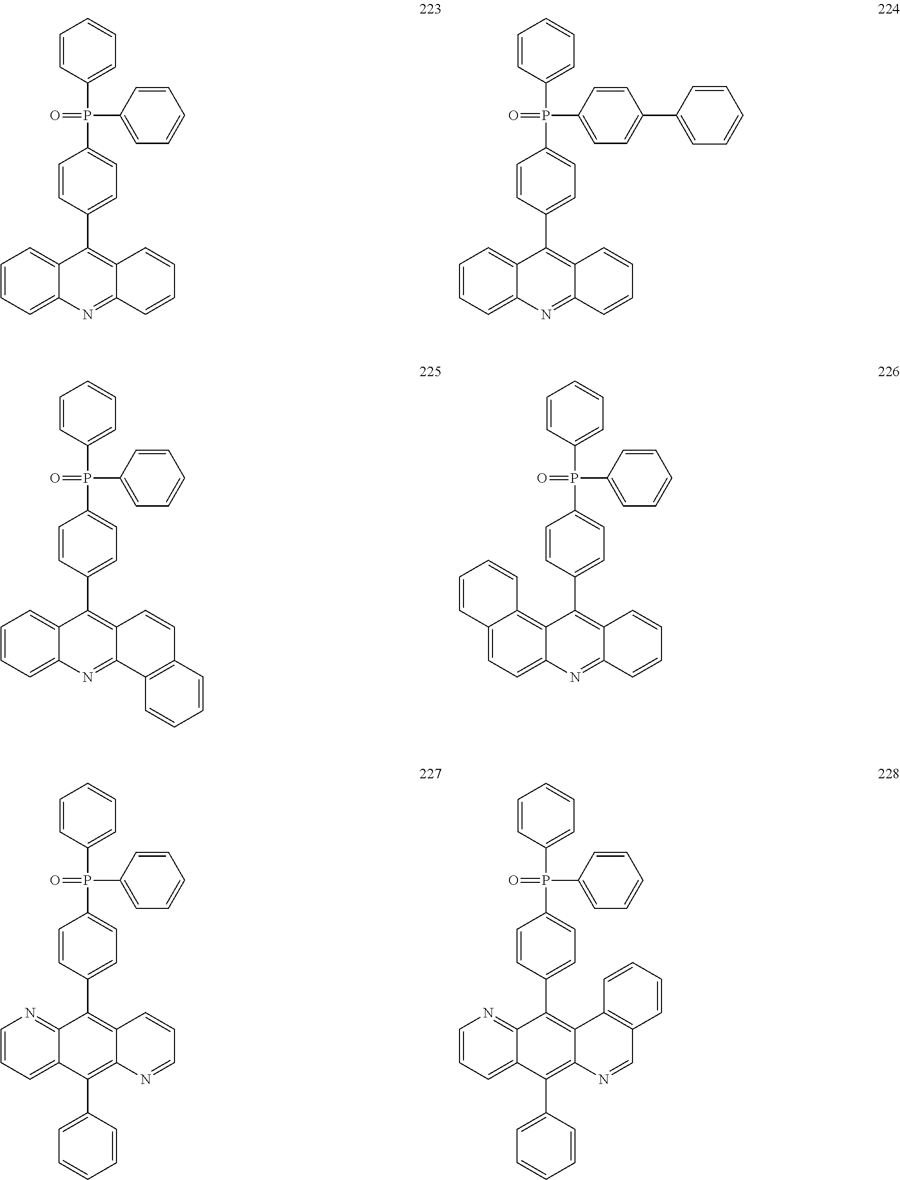 [SMILES: O=P(c1ccccc1)(c1ccccc1)c1ccc(-c2c3ccccc3nc3ccccc23)cc1 ; O=P(c1ccccc1)(c1ccc(-c2ccccc2)cc1)c1ccc(-c2c3ccccc3nc3ccccc23)cc1 ; O=P(c1ccccc1)(c1ccccc1)c1ccc(-c2c3ccccc3nc3c2ccc2ccccc23)cc1 ; O=P(c1ccccc1)(c1ccccc1)c1ccc(-c2c3ccccc3nc3ccc4ccccc4c23)cc1 ; O=P(c1ccccc1)(c1ccccc1)c1ccc(-c2c3cccnc3c(-c3ccccc3)c3cccnc23)cc1 ; O=P(c1ccccc1)(c1ccccc1)c1ccc(-c2c3ncccc3c(-c3ccccc3)c3ncc4ccccc4c23)cc1]

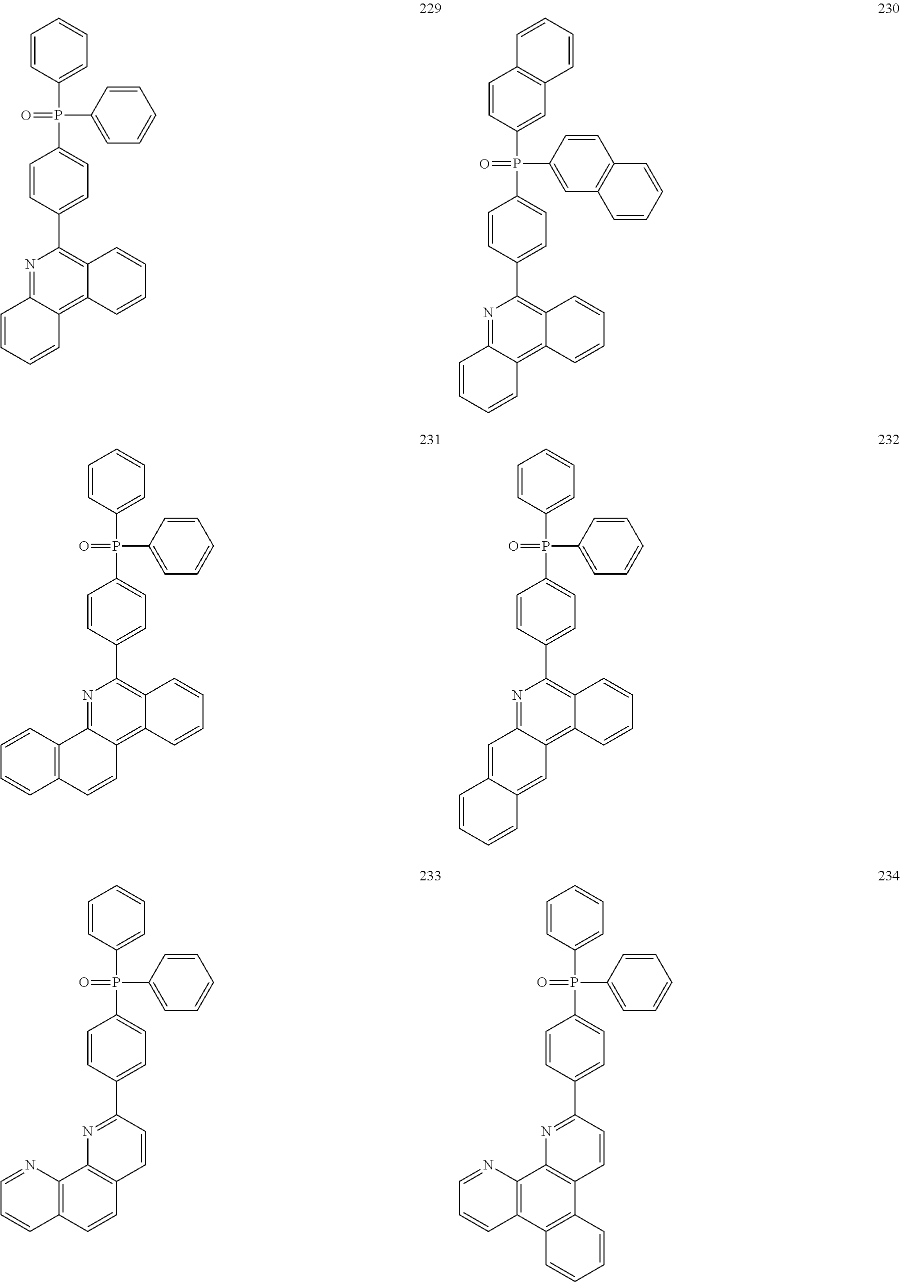 [SMILES: O=P(c1ccccc1)(c1ccccc1)c1ccc(-c2nc3ccccc3c3ccccc23)cc1 ; O=P(c1ccc(-c2nc3ccccc3c3ccccc23)cc1)(c1ccc2ccccc2c1)c1ccc2ccccc2c1 ; O=P(c1ccccc1)(c1ccccc1)c1ccc(-c2nc3c4ccccc4ccc3c3ccccc23)cc1 ; O=P(c1ccccc1)(c1ccccc1)c1ccc(-c2nc3cc4ccccc4cc3c3ccccc23)cc1 ; O=P(c1ccccc1)(c1ccccc1)c1ccc(-c2ccc3ccc4cccnc4c3n2)cc1 ; O=P(c1ccccc1)(c1ccccc1)c1ccc(-c2ccc3c4ccccc4c4cccnc4c3n2)cc1]

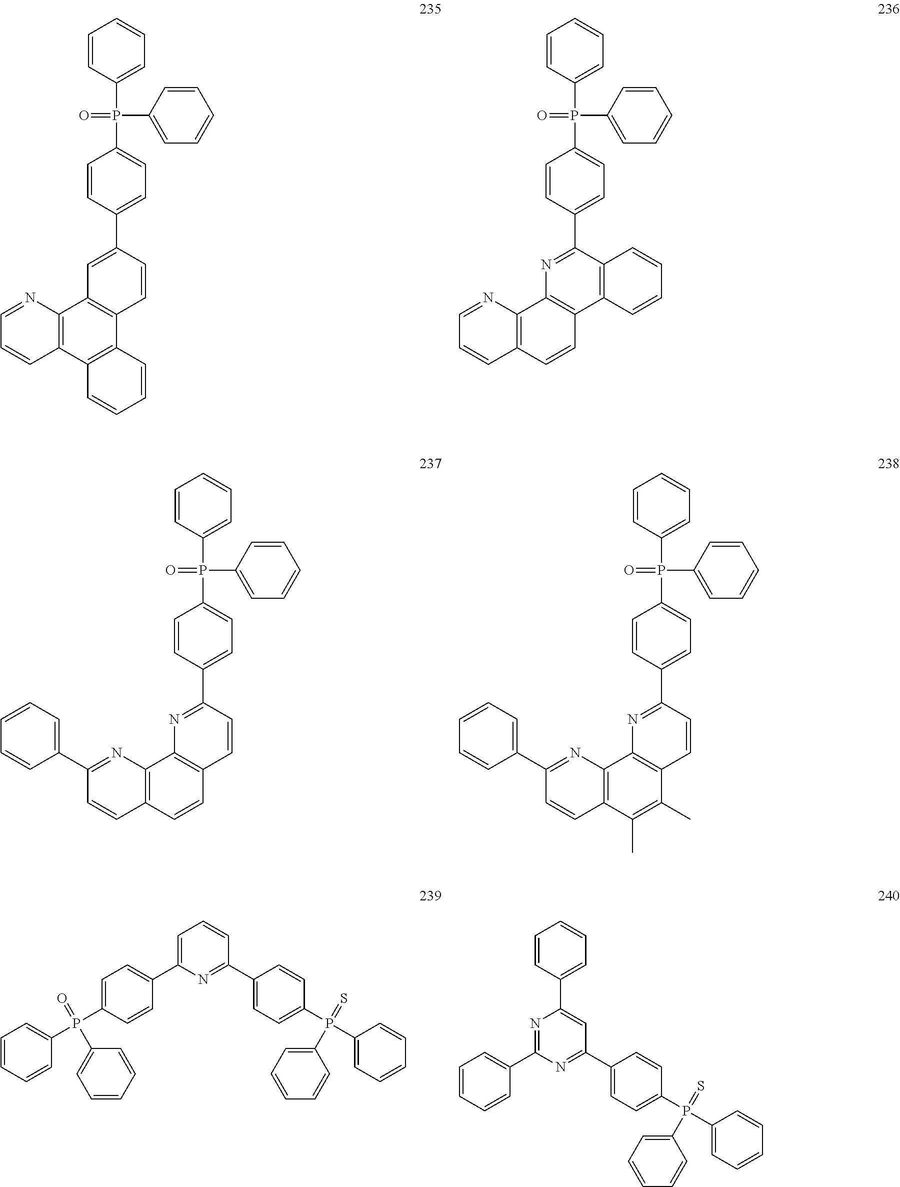 [SMILES: O=P(c1ccccc1)(c1ccccc1)c1ccc(-c2ccc3c4ccccc4c4cccnc4c3c2)cc1 ; O=P(c1ccccc1)(c1ccccc1)c1ccc(-c2nc3c(ccc4cccnc43)c3ccccc23)cc1 ; O=P(c1ccccc1)(c1ccccc1)c1ccc(-c2ccc3ccc4ccc(-c5ccccc5)nc4c3n2)cc1 ; Cc1c(C)c2ccc(-c3ccc(P(=O)(c4ccccc4)c4ccccc4)cc3)nc2c2nc(-c3ccccc3)ccc12 ; O=P(c1ccccc1)(c1ccccc1)c1ccc(-c2cccc(-c3ccc(P(=S)(c4ccccc4)c4ccccc4)cc3)n2)cc1 ; S=P(c1ccccc1)(c1ccccc1)c1ccc(-c2cc(-c3ccccc3)nc(-c3ccccc3)n2)cc1]

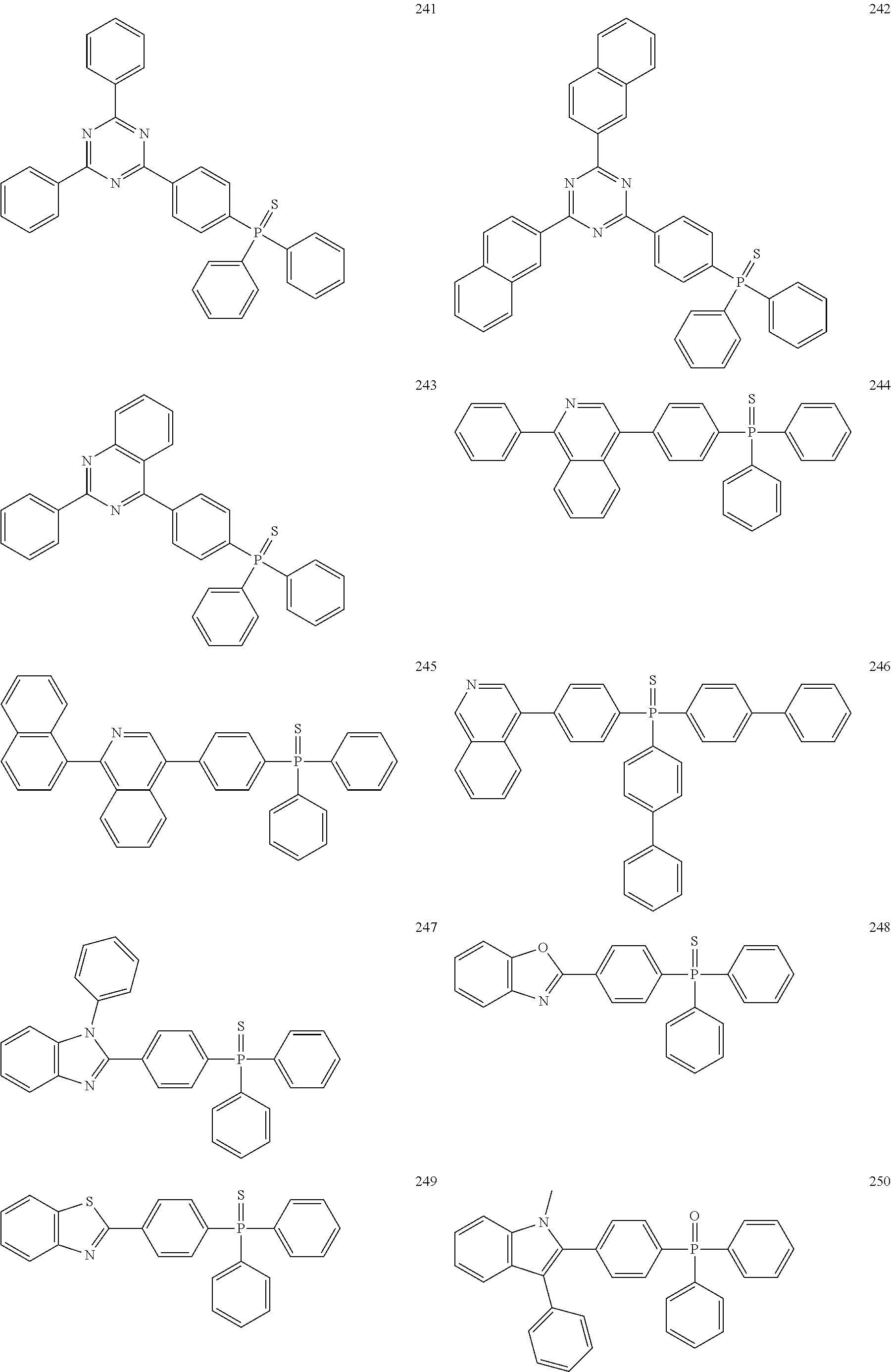

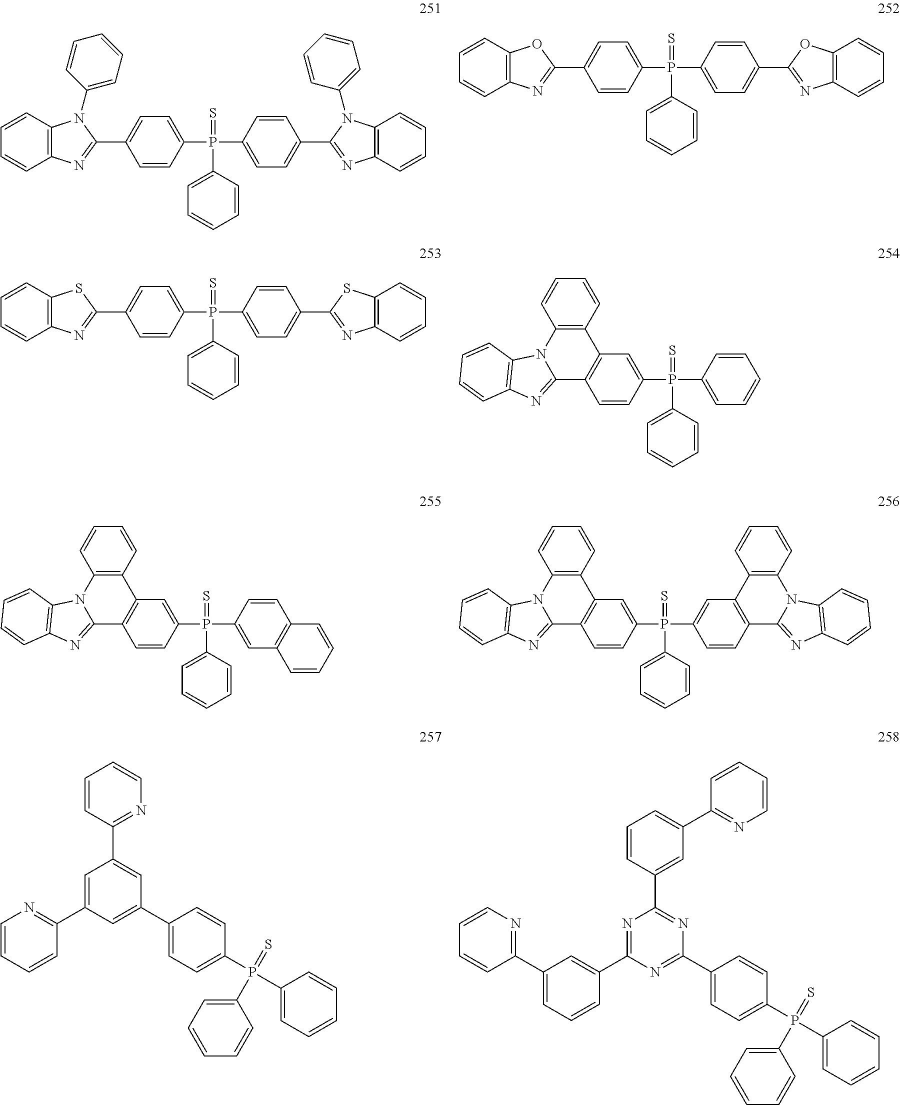

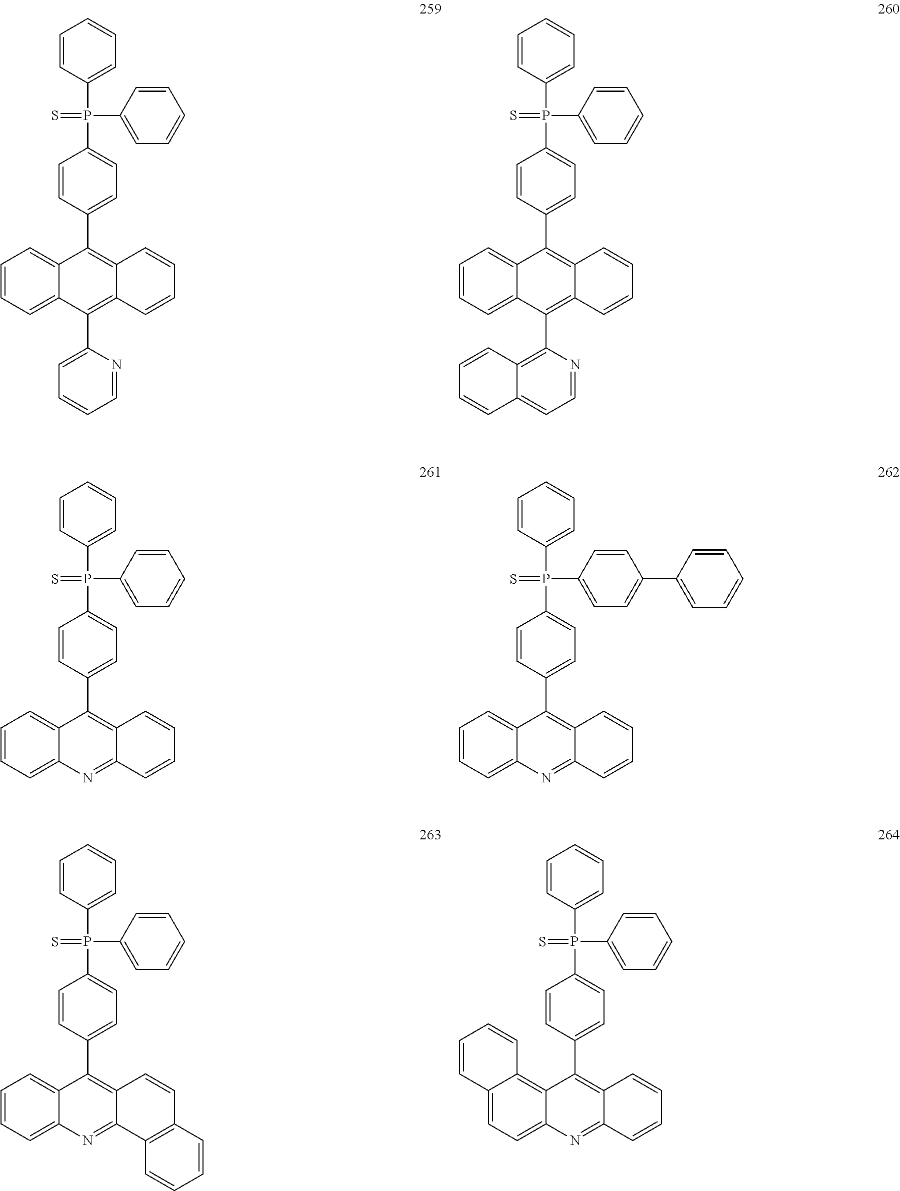 [SMILES: S=P(c1ccccc1)(c1ccccc1)c1ccc(-c2c3ccccc3c(-c3ccccn3)c3ccccc23)cc1 ; S=P(c1ccccc1)(c1ccccc1)c1ccc(-c2c3ccccc3c(-c3nccc4ccccc34)c3ccccc23)cc1 ; S=P(c1ccccc1)(c1ccccc1)c1ccc(-c2c3ccccc3nc3ccccc23)cc1 ; S=P(c1ccccc1)(c1ccc(-c2ccccc2)cc1)c1ccc(-c2c3ccccc3nc3ccccc23)cc1 ; S=P(c1ccccc1)(c1ccccc1)c1ccc(-c2c3ccccc3nc3c2ccc2ccccc23)cc1 ; S=P(c1ccccc1)(c1ccccc1)c1ccc(-c2c3ccccc3nc3ccc4ccccc4c23)cc1]

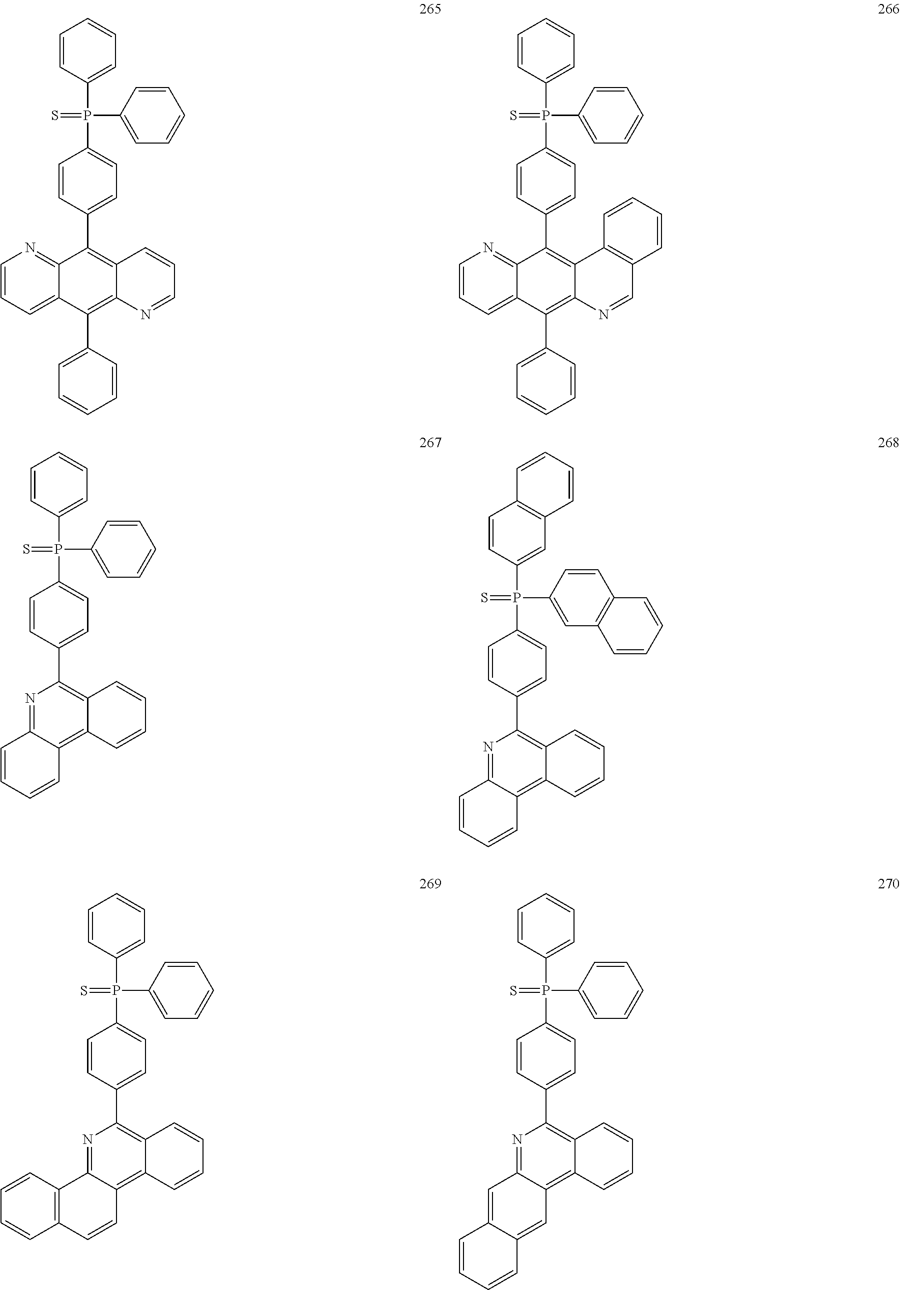

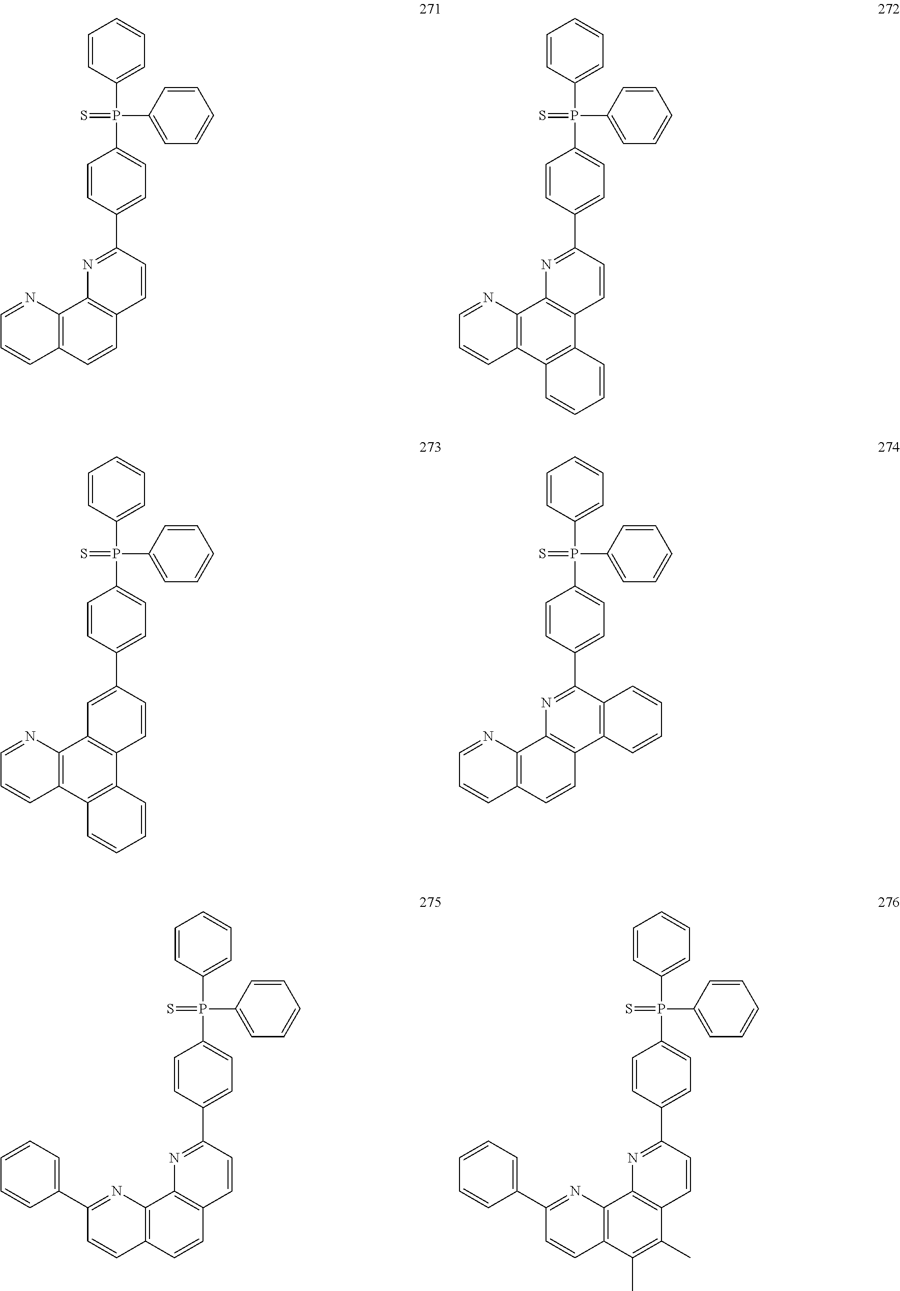

The first material may be an amphiprotic material that includes a moiety having a hole transporting property (e.g., a carbazole moiety) and a moiety having an electron transport property (e.g., an N-containing heteroaryl moiety). For example, when the first materials represented by Formula 1 are used in an emission layer or a buffer layer of an organic light-emitting device, charge balance of the organic light-emitting device may be appropriately maintained, and the efficiency of the organic light-emitting device may be improved.

A phosphine oxide group that is included in the second material may help improve an electron transport property of a compound, while having small influence on T1. For example, the introduction of a phosphine oxide group may lead to formation of various compound structures. For example, when a phosphine oxide group is introduced to a thermally and electrochemically stable core, the obtained compound may have high electron transport property and stability. An organic light-emitting device including such a compound may have improved lifespan.

In an organic light-emitting device including the first material and the second material, an emission layer may have high charge balance. For example, in an organic light-emitting device including the first material and the second material, holes provided from an anode may not be present at an interface of the emission layer and the hole transport region, and may move toward the electron transport region, and thus an emission region may be widely distributed.

The organic layer 150 may further include a hole transport region between the first electrode and the emission layer. The organic layer 150 may further include an electron transport region between the emission layer and the second electrode.

The hole transport region may include at least one selected from a hole injection layer (HIL), a hole transport layer (HTL), a buffer layer (BL), and an electron blocking layer (EBL). The electron transport region may include at least one selected from a buffer layer, an electron transport layer (ETL), and an electron injection layer (EIL), but is not limited thereto.

The hole transport region may have a single-layered structure formed of a single material, a single-layered structure formed of a plurality of different materials, or a multi-layered structure having a plurality of layers formed of a plurality of different materials.

For example, the hole transport region may have a single-layered structure formed of a plurality of different materials, or a structure of hole injection layer/hole transport layer, a structure of hole injection layer/hole transport layer/buffer layer, a structure of hole injection layer/buffer layer, a structure of hole transport layer/buffer layer, or a structure of hole injection layer/hole transport layer/electron blocking layer, wherein layers of each structure are sequentially stacked from the first electrode 110 in this stated order, but are not limited thereto.

When the hole transport region includes a hole injection layer, the hole injection layer may be formed on the first electrode 110 by using various methods, such as vacuum deposition, spin coating casting, a Langmuir-Blodgett (LB) method, ink-jet printing, laser-printing, or laser-induced thermal imaging.

When a hole injection layer is formed by vacuum deposition, for example, the vacuum deposition may be performed at a temperature of a deposition temperature of about 100 to about 500° C., at a vacuum degree of about 10⁻⁸ to about 10⁻³ torr, and at a deposition rate of about 0.01 to about 100 Åsec in consideration of a compound for a hole injection layer to be deposited, and the structure of a hole injection layer to be formed.

When a hole injection layer is formed by spin coating, the spin coating may be performed at a coating rate of about 2,000 rpm to about 5,000 rpm, and at a temperature of about 80° C. to 200° C. in consideration of a compound for a hole injection layer to be deposited, and the structure of a hole injection layer to be formed.

When the hole transport region includes a hole transport layer, the hole transport layer may be formed on the first electrode 110 or the hole injection layer by using various methods, such as vacuum deposition, spin coating, casting, a LB method, ink-jet printing, laser-printing, or laser-induced thermal imaging. When the hole transport layer is formed by vacuum deposition or spin coating, deposition and coating conditions for the hole transport layer may be determined by referring to the deposition and coating conditions for the hole injection layer.

The hole transport region may include at least one selected from m-MTDATA, TDATA, 2-TNATA, NPB, β-NPB, TPD, Spiro-TPD, Spiro-NPB, α-NPB, TAPC, HMTPD, 4,4′,4″-tris(N-carbazolyl)triphenylamine (TCTA), polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), (polyaniline)/poly(4-styrenesulfonate) (PANI/PSS), a compound represented by Formula 201 below, and a compound represented by Formula 202 below:

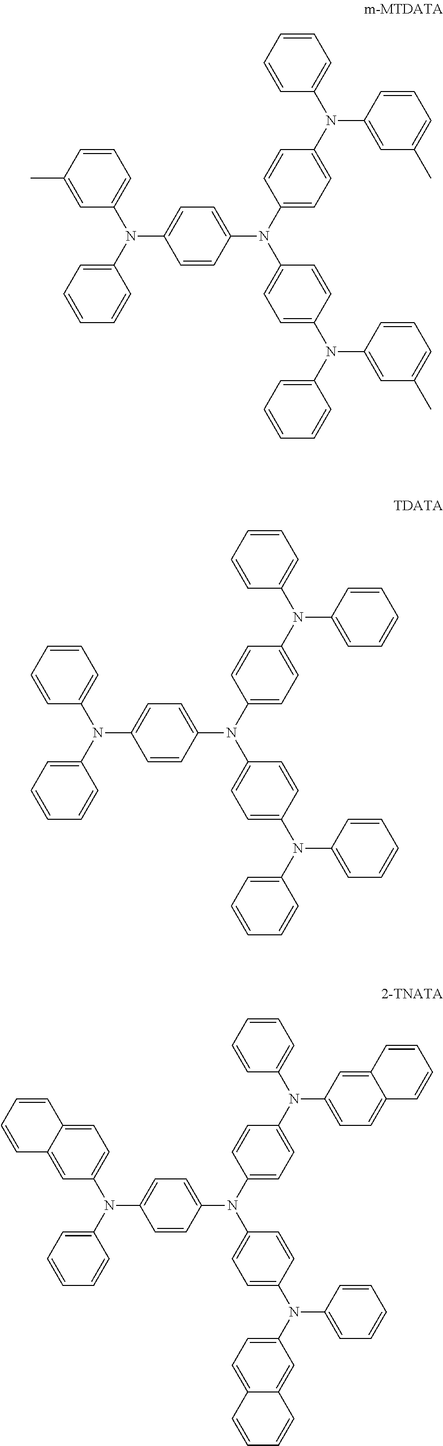

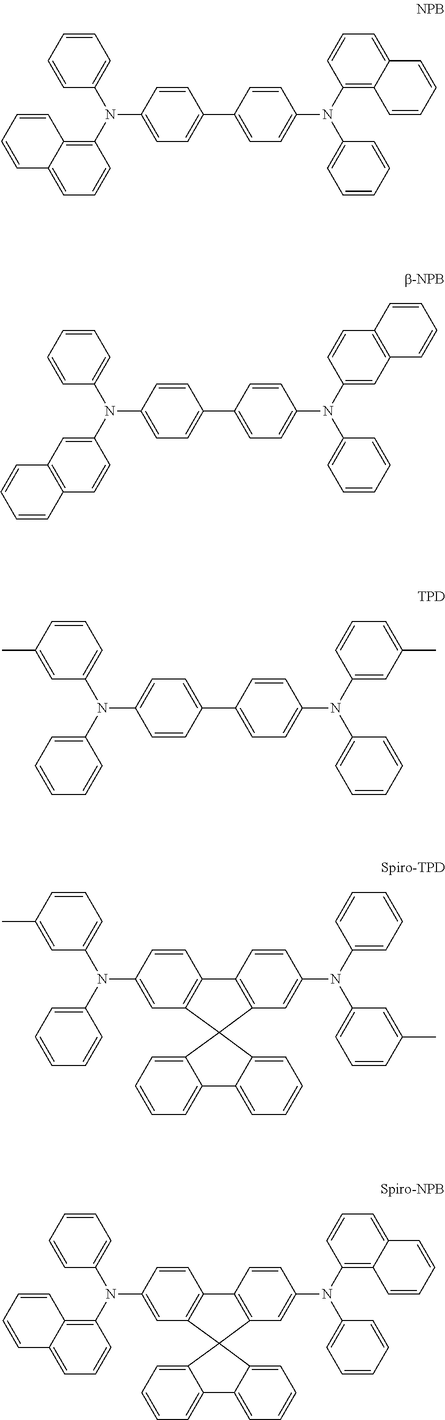

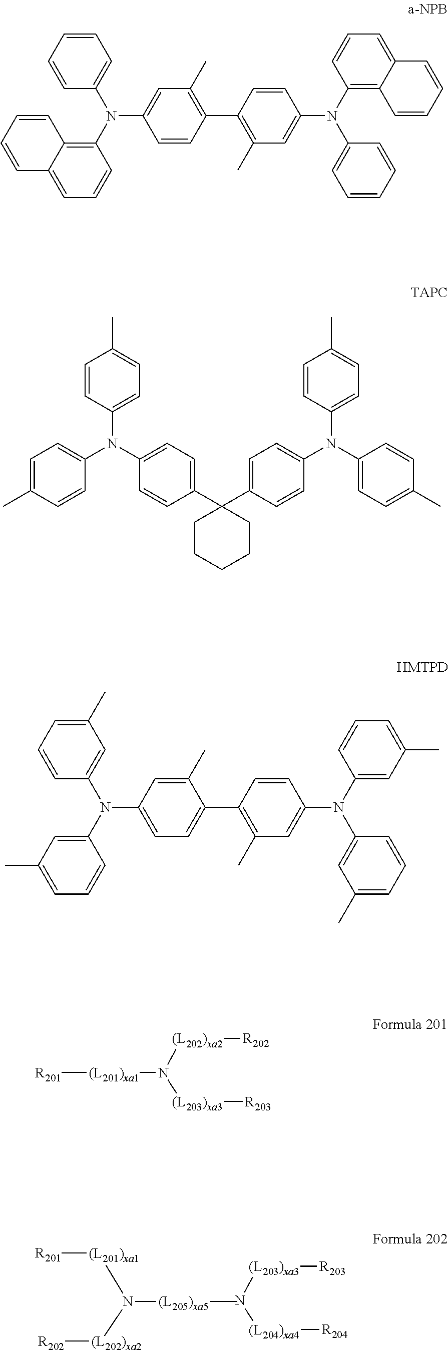

wherein in Formulae 201 and 202,

L₂₀₁ to L₂₀₅ may be each independently selected from a substituted or unsubstituted C₃-C₁₀ cycloalkylene, a substituted or unsubstituted C₁-C₁₀ heterocycloalkylene, a substituted or unsubstituted C₃-C₁₀ cycloalkenylene, a substituted or unsubstituted C₁-C₁₀ heterocycloalkenylene, a substituted or unsubstituted C₆-C₆₀ arylene, a substituted or unsubstituted C₁-C₆₀ heteroarylene, a substituted or unsubstituted divalent non-aromatic condensed polycyclic group, and a substituted or unsubstituted divalent non-aromatic condensed hetero-polycyclic group,

at least one substituent of the substituted C₃-C₁₀ cycloalkylene, the substituted C₁-C₁₀ heterocycloalkylene, the substituted C₃-C₁₀ cycloalkenylene, the substituted C₁-C₁₀ heterocycloalkenylene, the substituted C₆-C₆₀ arylene, the substituted C₁-C₆₀ heteroarylene, the substituted divalent non-aromatic condensed polycyclic group, and the substituted divalent non-aromatic hetero-condensed polycyclic group may be selected from

a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₁-C₆₀ alkyl, a C₂-C₆₀ alkenyl, a C₂-C₆₀ alkynyl, and a C₁-C₆₀ alkoxy;

a C₁-C₆₀ alkyl, a C₁-C₆₀ alkenyl, a C₂-C₆₀ alkynyl, and a C₁-C₆₀ alkoxy, each substituted with at least one selected from a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arylthio, a C₂-C₆₀ heteroaryl, a monovalent non-aromatic condensed polycyclic, a monovalent non-aromatic condensed heteropolycyclic, —N(Q₂₀₁)(Q₂₀₂), —Si(Q₂₀₃)(Q₂₀₄)(Q₂₀₅), and —B(Q₂₀₆)(Q₂₀₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed heteropolycyclic group;

a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arythio, a C₂-C₆₀ heteroaryl, a monovalent non-aromatic condensed polycyclic group, and a monovalent non-aromatic condensed heteropolycyclic group, each substituted with at least one selected from a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₁-C₆₀ alkyl, a C₂-C₆₀ alkenyl, a C₁-C₆₀ alkynyl, a C₁-C₆₀ alkoxy, a C₃-C₁₀ cycloalkyl, a C₁-C₁₀ heterocycloalkyl, a C₃-C₁₀ cycloalkenyl, a C₁-C₂₀ heterocycloalkenyl, a C₆-C₆₀ aryl, a C₆-C₆₀ aryloxy, a C₆-C₆₀ arythio, a C₁-C₆₀ heteroaryl, a monovalent non-aromatic condensed polycyclic group, a monovalent non-aromatic condensed heteropolycyclic group, —N(Q₂₁₁)(Q₂₁₂), —Si(Q₂₁₃)(Q₂₁₄)(Q₂₁₅), and —B(Q₂₁₆)(Q₂₁₇); and

—N(Q₂₂₁)(Q₂₂₂), —Si(Q₂₂₃)(Q₂₂₄)(Q₂₂₅) and —B(Q₂₂₆)(Q₂₂₇),

xa1 to xa4 may be each independently selected from 0, 1, 2, and 3;

xa5 may be selected from 1, 2, 3, 4, and 5; and

R₂₀₁ to R₂₀₄ may be each independently selected from a C₁-C₆₀ alkyl, a C₂-C₆₀ alkenyl, a C₂-C₆₀ alkynyl, and a C₁-C₆₀ alkoxy;

a C₁-C₆₀ alkyl, a C₁-C₆₀ alkenyl, a C₂-C₆₀ alkynyl, and a C₁-C₆₀ alkoxy, each substituted with at least one selected from a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arylthio, a C₂-C₆₀ heteroaryl, a monovalent non-aromatic condensed polycyclic, —N(Q₂₃₁)(Q₂₃₂), —Si(Q₂₃₃)(Q₂₃₄)(Q₂₃₅), and —B(Q₂₃₆)(Q₂₃₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed heteropolycyclic group; and

a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arythio, a C₂-C₆₀ heteroaryl, a monovalent non-aromatic condensed polycyclic group, and a monovalent non-aromatic condensed heteropolycyclic group, each substituted with at least one selected from a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₁-C₆₀ alkyl, a C₂-C₆₀ alkenyl, a C₁-C₆₀ alkynyl, a C₁-C₆₀ alkoxy, a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arythio, a C₁-C₆₀ heteroaryl, a monovalent non-aromatic condensed polycyclic group, a monovalent non-aromatic condensed heteropolycyclic group, —N(Q₂₄₁)(Q₂₄₂), —Si(Q₂₄₃)(Q₂₄₄)(Q₂₄₅), and —B(Q₂₄₆)(Q₂₄₇),

Q₂₀₁ to Q₂₀₇, Q₂₁₁ to Q₂₁₇, Q₂₂₁ to Q₂₂₇, Q₂₃₁ to Q₂₃₇, and Q₂₄₁ to Q₂₄₇ may be each independently selected from

a hydrogen, a deuterium, a halogen atom, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₁-C₆₀ alkenyl group, a C₂-C₆₀ alkynyl group, and a C₁-C₆₀ alkoxy group, each substituted with at least one selected from a deuterium, a halogen atom, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₂-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed heteropolycyclic group; and

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₂-C₆₀ heteroaryl group, a monovalent non-aromatic condensed polycyclic group, and a monovalent non-aromatic condensed heteropolycyclic group, each substituted with at least one selected from a deuterium, a halogen atom, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed heteropolycyclic group.

wherein in Formulae 201 and 202,

L₂₀₁ to L₂₀₅ may be each independently selected from

a phenylene, a naphthylenylene, a fluorenylene, a spiro-fluorenylene, a benzofluorenylene, a dibenzofluorenylene, a phenanthrenylene, an anthracenylene, a pyrenylene, a chrysenylene, a pyridinylene, a pyrazinylene, a pyrimidinylene, a pyridazinylene, a quinolinylene, an isoquinolinylene, a quinoxalinylene, a quinazolinylene, a carbazolylene, and a triazinylene; and

a phenylene group, a naphthylenylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, a halogen atom, a hydroxyl group, a cyano group, a nitro group, an amino group, an amidino group, a hydrazine group, a hydrazone group, a carboxyl group, and a salt thereof, a sulfonic acid, and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group, and a triazinyl group;

xa1 to xa4 may be each independently 0, 1, or 2;

xa5 may be 1, 2, or 3;

R₂₀₁ to R₂₀₅ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an azulenyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, but are not limited thereto.

The compound represented by Formula 201 may be represented by Formula 201A:

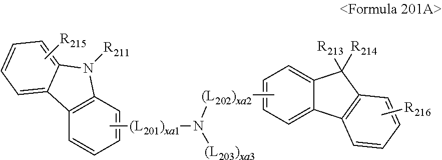

For example, the compound represented by Formula 201 may be represented by Formula 201A-1 below, but is not limited thereto:

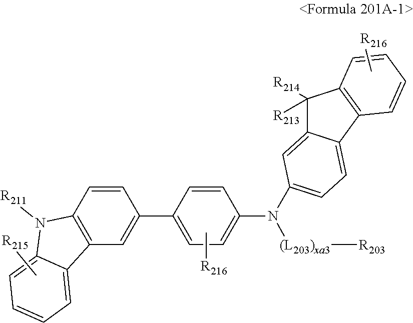

For example, the compound represented by Formula 202 may be represented by Formula 202A below, but is not limited thereto:

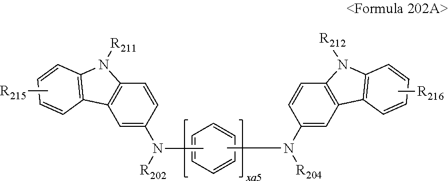

in Formulae 201A, 201A-1, and 202A, L₂₀₁ to L₂₀₃, xa1 to xa3, xa5 and R₂₀₂ to R₂₀₄ have already been described above, R₂₁₁ and R₂₁₂ may be understood by referring to the description provided in connection with R₂₀₃, and R₂₁₃ to R₂₁₆ may be each independently selected from a hydrogen, a deuterium, a halogen atom, a hydroxyl group, cyano, nitro, amino, amidino, hydrazine, a hydrazine group, a carboxylic acid and a salt thereof, a sulfonic acid and a salt thereof, a phosphoric acid and a salt thereof, a C₁-C₆₀ alkyl, a C₂-C₆₀ alkenyl, a C₂-C₆₀ alkynyl, a C₁-C₆₀ alkoxy, a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arylthio, a C₁-C₆₀ heteroaryl, and a non-aromatic condensed polycyclic group.

For example, in Formulae 201A, 201A-1, and 202A,

L₂₀₁ to L₂₀₃ may be each independently selected from

a phenylene, a naphthylenylene, a fluorenylene, a spiro-fluorenylene, a benzofluorenylene, a dibenzofluorenylene, a phenanthrenylene, an anthracenylene, a pyrenylene, a chrysenylene, a pyridinylene, a pyrazinylene, a pyrimidinylene, a pyridazinylene, a quinolinylene, an isoquinolinylene, a quinoxalinylene, a quinazolinylene, a carbazolylene, and a triazinylene; and

a phenylene group, a naphthylenylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, a halogen atom, a hydroxyl group, a cyano group, a nitro group, an amino group, an amidino group, a hydrazine group, a hydrazone group, a carboxyl group, and a salt thereof, a sulfonic acid, and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xa1 to xa3 may be each independently 0 or 1;

R₂₀₃, R₂₁₁, and R₂₁₂ may be each independently selected from

a phenyl group, a naphthyl group, a fluorenyl group, a Spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₃ and R₂₁₄ may be each independently selected from

a C₁-C₂₀ alkyl and a C₁-C₂₀ alkoxy;

a C₁-C₂₀ alkyl and a C₁-C₂₀ alkoxy, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl, a naphthyl, a fluorenyl, a spiro-fluorenyl, a benzofluorenyl, a dibenzofluorenyl, a phenanthrenyl, an anthracenyl, a pyrenyl, a chrysenyl, a pyridinyl, a pyrazinyl, a pyrimidinyl, a pyridazinyl, a quinolinyl, an isoquinolinyl, a quinoxalinyl, a quinazolinyl, a carbazolyl, and a triazinyl, each substituted with at least one selected from a deuterium, a halogen atom, a hydroxyl, a cyano, a nitro, an amino, an amidino, a hydrazine, a hydrazone, a carboxylic acid or a salt thereof, a sulfonic acid or a salt thereof, a phosphoric acid or a salt thereof, a C₁-C₂₀ alkyl, a C₁-C₂₀ alkoxy, a phenyl, a naphthyl, a fluorenyl, a spiro-fluorenyl, a benzofluorenyl, a dibenzofluorenyl, a phenanthrenyl, an anthracenyl, a pyrenyl, a chrysenyl, a pyridinyl, a pyrazinyl, a pyrimidinyl, a pyridazinyl, a quinolinyl, an isoquinolinyl, a quinoxalinyl, a quinazolinyl, a carbazolyl, and a triazinyl;

R₂₁₅ and R₂₁₆ may be each independently selected from

a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid or a salt thereof, a phosphoric acid or a salt thereof,

a C₁-C₂₀ alkyl and a C₁-C₂₀ alkoxy;

a C₁-C₂₀ alkyl and a C₁-C₂₀ alkoxy, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, and a triazinyl group; and

a phenyl, a naphthyl, a fluorenyl, a spiro-fluorenyl, a benzofluorenyl, a dibenzofluorenyl, a phenanthrenyl, an anthracenyl, a pyrenyl, a chrysenyl, a pyridinyl, a pyrazinyl, a pyrimidinyl, a pyridazinyl, a quinolinyl, an isoquinolinyl, a quinoxalinyl, a quinazolinyl, a carbazolyl, and a triazinyl, each substituted with at least one selected from a deuterium, a halogen atom, a hydroxyl, a cyano, a nitro, an amino, an amidino, a hydrazine, a hydrazone, a carboxylic acid or a salt thereof, a sulfonic acid or a salt thereof, a phosphoric acid or a salt thereof, a C₁-C₂₀ alkyl, a C₁-C₂₀ alkoxy, a phenyl, a naphthyl, a fluorenyl, a spiro-fluorenyl, a benzofluorenyl, a dibenzofluorenyl, a phenanthrenyl, an anthracenyl, a pyrenyl, a chrysenyl, a pyridinyl, a pyrazinyl, a pyrimidinyl, a pyridazinyl, a quinolinyl, an isoquinolinyl, a quinoxalinyl, a quinazolinyl, a carbazolyl, and a triazinyl;

xa5 is 1 or 2.

R₂₁₃ and R₂₁₄ in Formulae 201A, and 201A-1 may bind to each other to form a saturated or unsaturated ring.

The compound represented by Formula 201, and the compound represented by Formula 202 may each include compounds HT1 to HT20 illustrated below, but are not limited thereto.

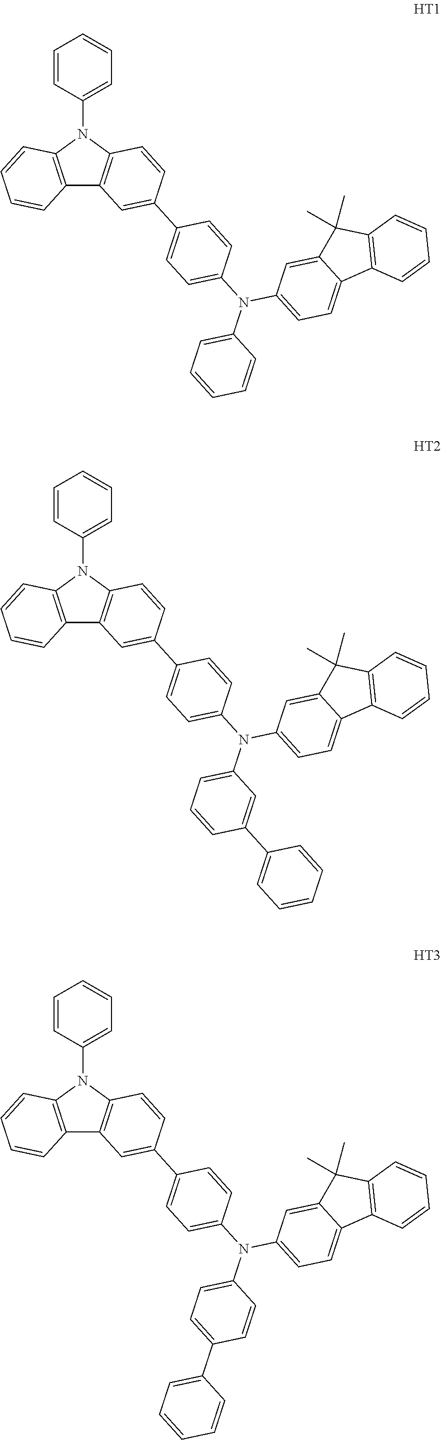 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

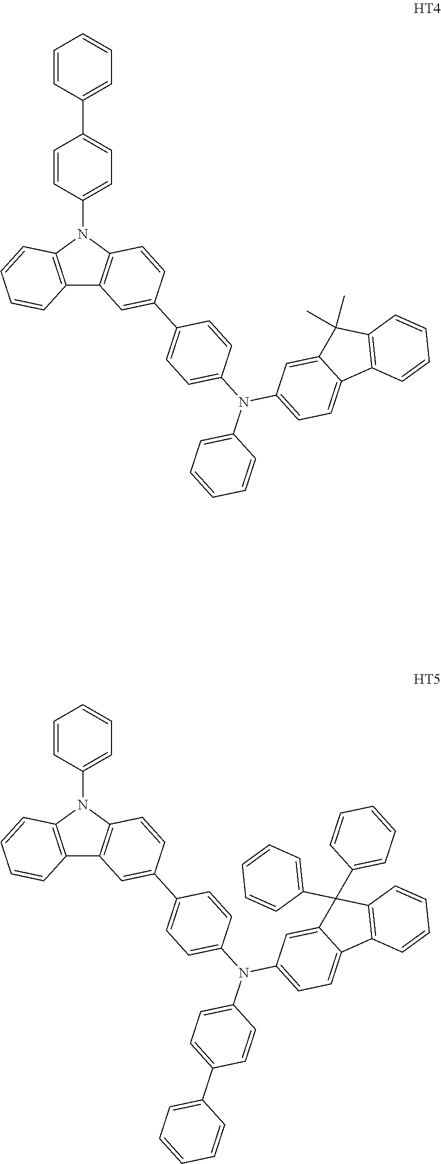 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

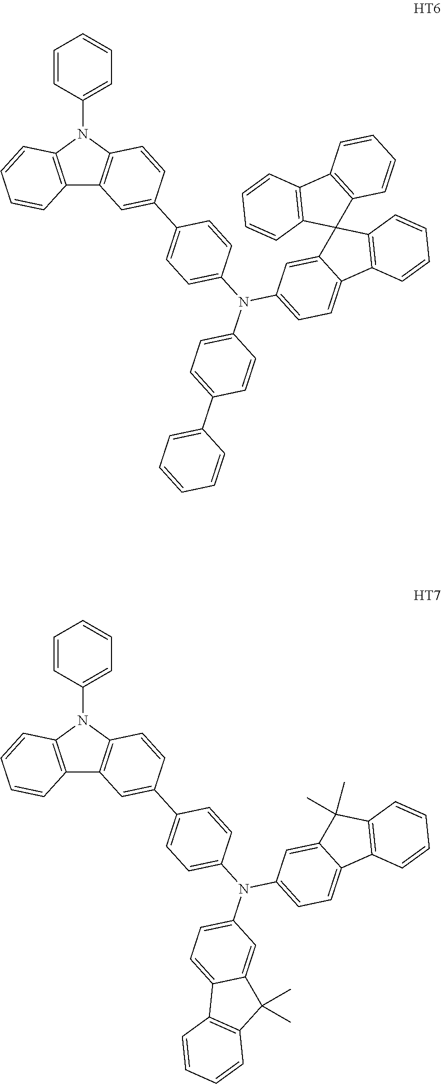 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

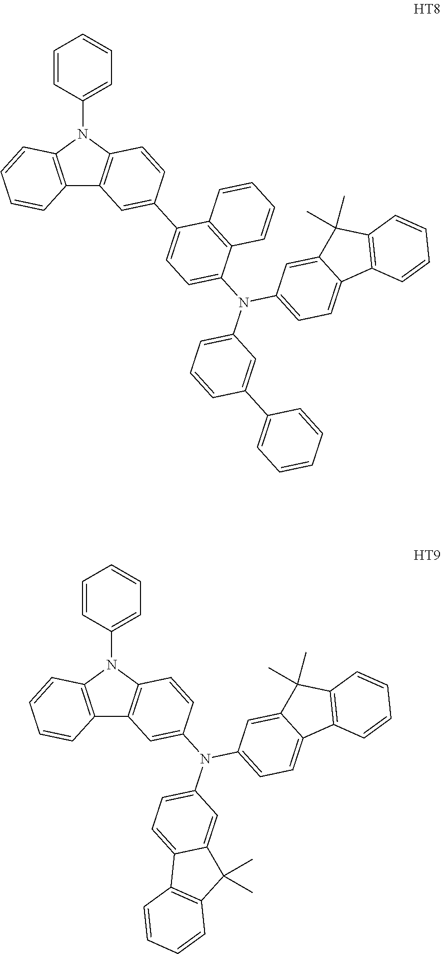 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

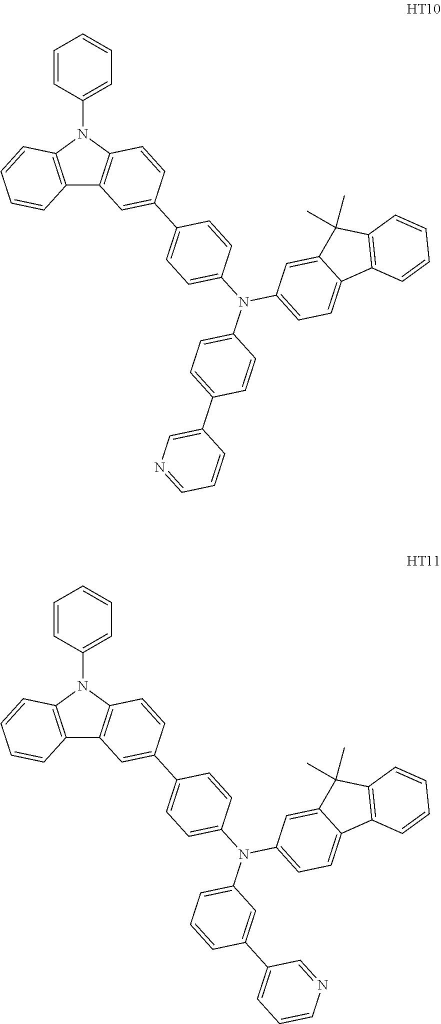 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

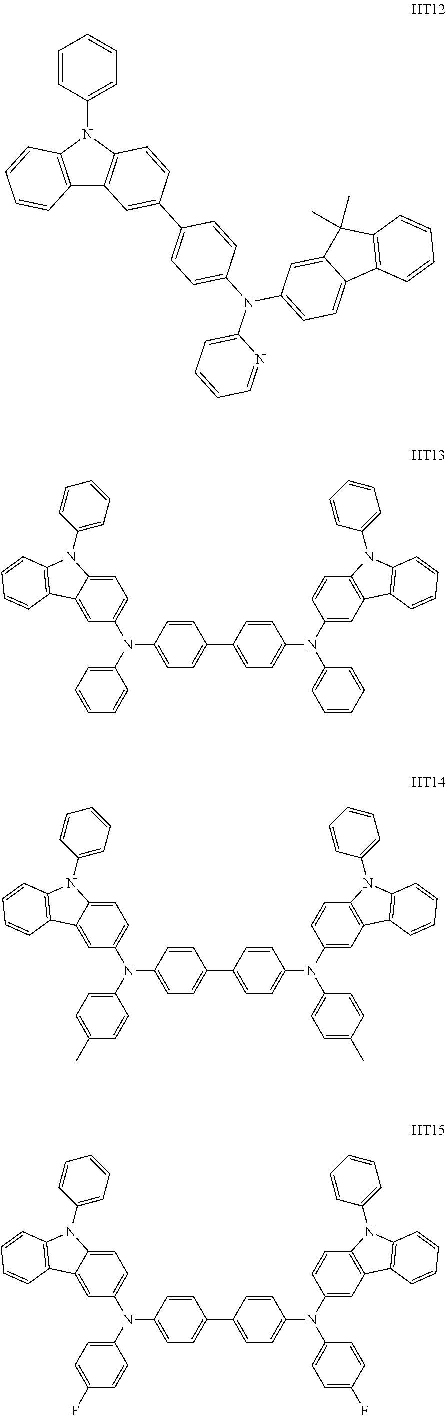 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

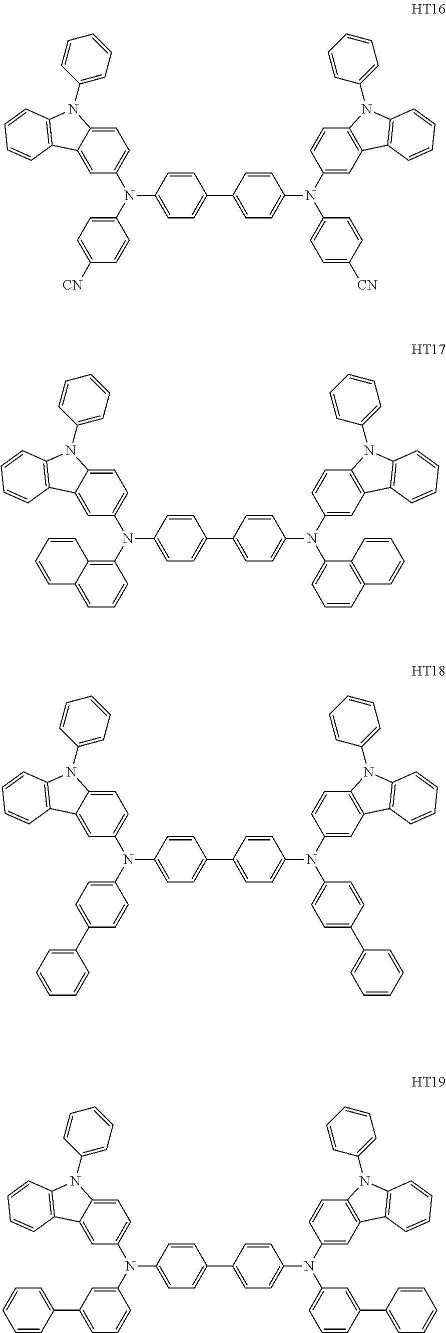

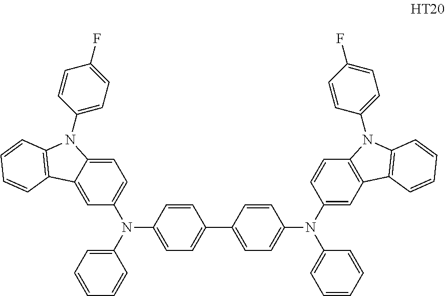 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes both a hole injection layer and a hole transport layer, a thickness of the hole injection layer may be in a range of about 100 Å to about 10000 Å, for example, in a range of about 100 Å to about 1000 Å, and a thickness of the hole transport layer may be in a range of about 50 Å to about 2000 Å, for example, about 100 Å to about 1500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material to help improve conductive properties. The charge-generation material may be homogeneously or non-homogeneously dispersed in the hole transport region.

The charge-generation material may be, e.g., a p-dopant. The p-dopant may be one of a quinone derivative, a metal oxide, and a cyano group-containing compound, but is not limited thereto. For example, non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide, and Compound HT-D1 illustrated below, but are not limited thereto.

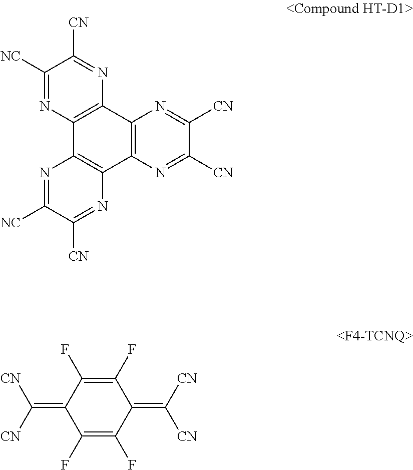

The hole transport region may further include, in addition to the hole injection layer and the hole transport layer, at least one of a buffer layer and an electron blocking layer. Since the buffer layer may compensate for an optical resonance distance according to a wavelength of light emitted from the emission layer, light-emission efficiency of a formed organic light-emitting device may be improved. For use as a material included in the buffer layer, materials that are included in the hole transport region may be used. The electron blocking layer prevents injection of electrons from the electron transport region.

An emission layer may be formed on the first electrode 110 or the hole transport region by using various methods, e.g., vacuum deposition, spin coating, casting, a LB method, ink-jet printing, laser-printing, or laser-induced thermal imaging. When the emission layer is formed by vacuum deposition or spin coating, deposition and coating conditions for the emission layer may be determined by referring to the deposition and coating conditions for the hole injection layer.

When the organic light-emitting device 10 is a full color organic light-emitting device, the emission layer may be patterned into a red emission layer, a green emission layer, or a blue emission layer, according to a sub pixel. In some embodiments, the emission layer may have a stacked structure of a red emission layer, a green emission layer, and a blue emission layer, or may include a red-light emission material, a green-light emission material, and a blue-light emission material, which are mixed with each other in a single layer, to emit white light. According to another embodiment, the emission layer may be a white emission layer, and may further include a color converting layer or a color filter to turn white light into light of a desired color.

The emission layer may include a host and a dopant.

The emission layer may include at least one first material, e.g., a first material represented by Formula 1-1 or Formula 1-2. For example, the host may include at least one first material represented by Formula 1-1 or Formula 1-2.

When the emission layer includes the at least one first material, an electron transport layer may include at least one second material, but is not limited thereto. When the emission layer includes at least one first material and an electron transport layer includes at least one second material, the emission layer may be adjacent to the electron transport layer. For example, the emission layer may be directly adjacent to or may directly contact the electron transport layer.

The emission layer may include at least one selected from TPBi, TBADN, ADN(also called as DNA), CBP, CDBP, TCP, SPPO, and MADN aside from or in addition to the first material represented by Formula 1-1 or 1-2:

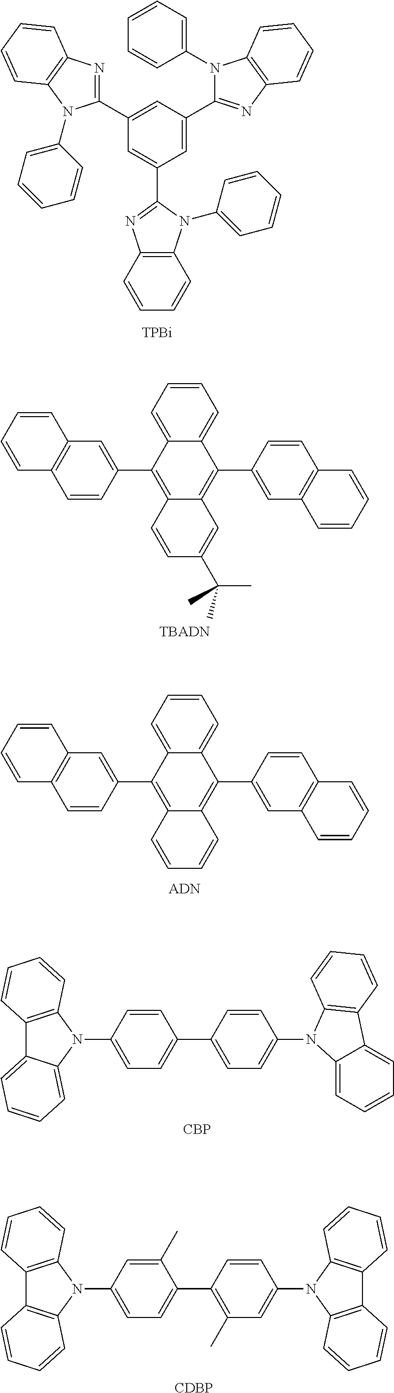

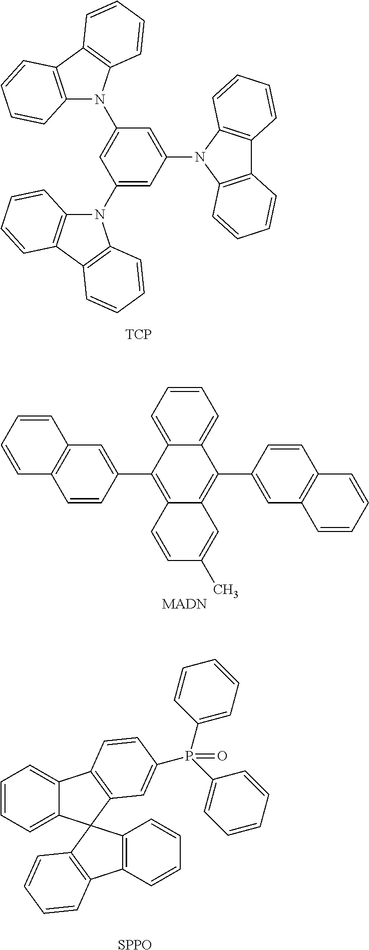

The dopant may be at least one selected from a fluorescent dopant and a phosphorescent dopant.

The phosphorescent dopant may include an organometallic complex represented by Formula 401 below:

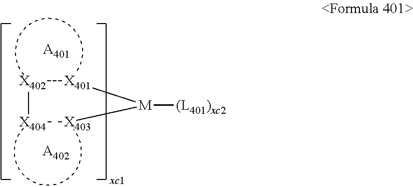

wherein in Formula 401,

M may be selected from iridium (Ir), platinum (Pt), osmium (Os), titanium (Ti), zirconium (Zr), hafnium (Hf), europium (Eu), terbium (Tb), and thulium (Tm);

X₄₀₁ to X₄₀₄ may be each independently nitrogen or carbon;

A₄₀₁ and A₄₀₂ rings may be each independently selected from a substituted or unsubstituted benzene group, a substituted or unsubstituted naphthalene group, a substituted or unsubstituted fluorenene group, a substituted or unsubstituted spiro-fluorenene group, a substituted or unsubstituted indene group, a substituted or unsubstituted pyrrol group, a substituted or unsubstituted thiophene group, a substituted or unsubstituted furan group, a substituted or unsubstituted imidazole group, a substituted or unsubstituted pyrazole group, a substituted or unsubstituted thiazole group, a substituted or unsubstituted isothiazole group, a substituted or unsubstituted oxazole group, a substituted or unsubstituted isoxazole group, a substituted or unsubstituted pyridine group, a substituted or unsubstituted pyrazine group, a substituted or unsubstituted pyrimidine group, a substituted or unsubstituted pyridazine group, a substituted or unsubstituted quinoline group, a substituted or unsubstituted isoquinoline group, a substituted or unsubstituted benzoquinoline group, a substituted or unsubstituted quinoxaline group, a substituted or unsubstituted quinazoline group, a substituted or unsubstituted carbazol group, a substituted or unsubstituted benzoimidazole group, a substituted or unsubstituted benzofuran group, a substituted or unsubstituted benzothiophene group, a substituted or unsubstituted isobenzothiophene group, a substituted or unsubstituted benzooxazole group, a substituted or unsubstituted isobenzooxazole group, a substituted or unsubstituted triazole group, a substituted or unsubstituted oxadiazole group, a substituted or unsubstituted triazine group, a substituted or unsubstituted dibenzofuran group, and a substituted or unsubstituted dibenzothiophene group; and

at least one substituent of the substituted benzene group, the substituted naphthalene group, the substituted fluorenene group, the substituted spiro-fluorenene group, the substituted indene group, the substituted pyrrol group, substituted thiophene group, the substituted furan group, the substituted imidazole group, the substituted pyrazole group, the substituted thiazole group, the substituted isothiazole group, the substituted oxazole group, the substituted isoxazole group, the substituted pyridine group, the substituted pyrazine group, the substituted pyrimidine group, the substituted pyridazine group, the substituted quinoline group, the substituted isoquinoline group, the substituted benzoquinoline group, the substituted quinoxaline group, the substituted quinazoline group, the substituted carbazol group, the substituted benzoimidazole group, the substituted benzofuran group, the substituted benzothiophene group, the substituted isobenzothiophene group, the substituted benzooxazole group, the substituted isobenzooxazole group, the substituted triazole group, the substituted oxadiazole group, the substituted triazine group, the substituted dibenzofuran group, and the substituted dibenzothiophene group may be selected from

a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₁-C₆₀ alkyl, a C₂-C₆₀ alkenyl, a C₂-C₆₀ alkynyl, and a C₁-C₆₀ alkoxy;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, a halogen atom, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed heteropolycyclic group, and —B(Q₄₀₆);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed heteropolycyclic group;

a C₃-C₁₀ cycloalkyl, a heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arythio, a C₂-C₆₀ heteroaryl, and a monovalent non-aromatic condensed polycyclic group, each substituted with at least one selected from a deuterium, a halogen atom, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₁-C₆₀ alkyl, a C₂-C₆₀ alkenyl, a C₁-C₆₀ alkynyl, a C₁-C₆₀ alkoxy, a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arythio, a C₁-C₆₀ heteroaryl, a monovalent non-aromatic condensed polycyclic group, a monovalent non-aromatic condensed heteropolycyclic group, —N(Q₄₁₁)(Q₄₁₂), —Si(Q₄₁₃)(Q₄₁₄)(Q₄₁₅), and —B(Q₄₁₆)(Q₄₁₇); and

—N(Q₄₂₀)(Q₄₂₂), —Si(Q₄₂₃)(Q₄₂₄)(Q₄₂₅), and —B(Q₄₂₆)(Q₄₂₇);

L₄₀₁ is an organic ligand;

xc1 is 1, 2, or 3; and

xc2 is 0, 1, 2, or 3.

L₄₀₁ may be a monovalent, divalent, or trivalent organic ligand. For example, L₄₀₁ may be selected from a halogen ligand (for example, Cl or F), a diketone ligand (for example, acetylacetonate, 1,3-diphenyl-1,3-propandionate, 2,2,6,6-tetramethyl-3,5-heptandionate, or hexafluoroacetonate), a carboxylic acid ligand (for example, picolinate, dimethyl-3-pyrazolecarboxylate, or benzoate), a carbon monooxide ligand, an isonitrile ligand, a cyano ligand, and a phosphorous ligand (for example, phosphine, and phosphaite), but is not limited thereto.

When A₄₀₁ in Formula 401 has two or more substituents, the substituents of A₄₀₁ may bind to each other to form a saturated or unsaturated ring.

When A₄₀₁ in Formula 402 has two or more substituents, the substituents of A₄₀₂ may bind to each other to form a saturated or unsaturated ring.

When xc1 in Formula 401 is two or more, a plurality of ligands

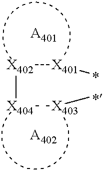

in Formula 401 may be identical or different. When xc1 in Formula 401 is two or more, A₄₀₁ and A₄₀₂ may be respectively directly connected to A₄₀₁ and A₄₀₂ of other neighboring ligands with or without a linker (for example, a C₁-C₅ alkylene, or —N(R′)— (wherein R′ may be a C₁-C₁₀ alkyl group or a C₆-C₂₀ aryl group) or —C(═O)—) therebetween.

The phosphorescent dopant may include at least one of Compounds PD1 to PD74 below, but is not limited thereto:

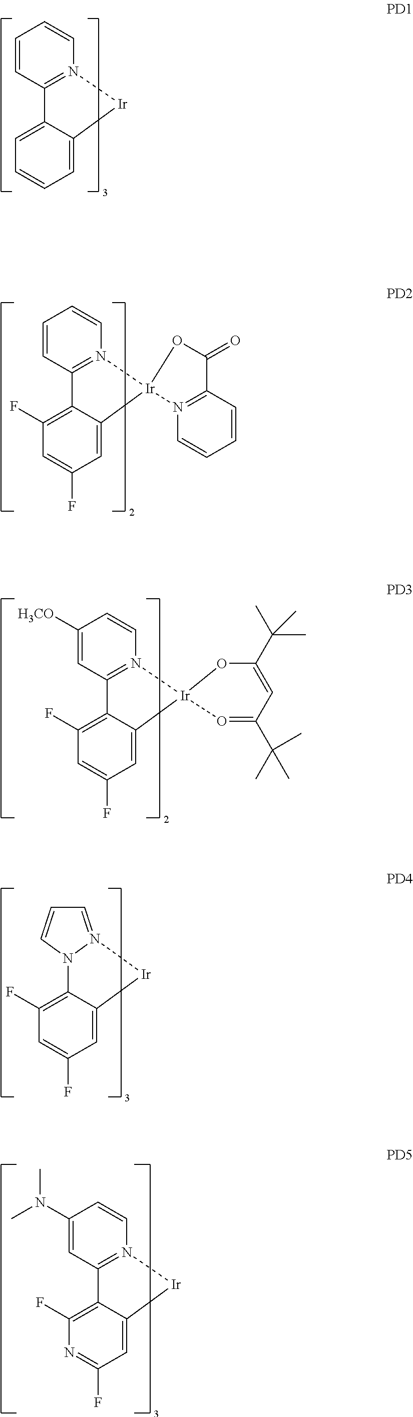

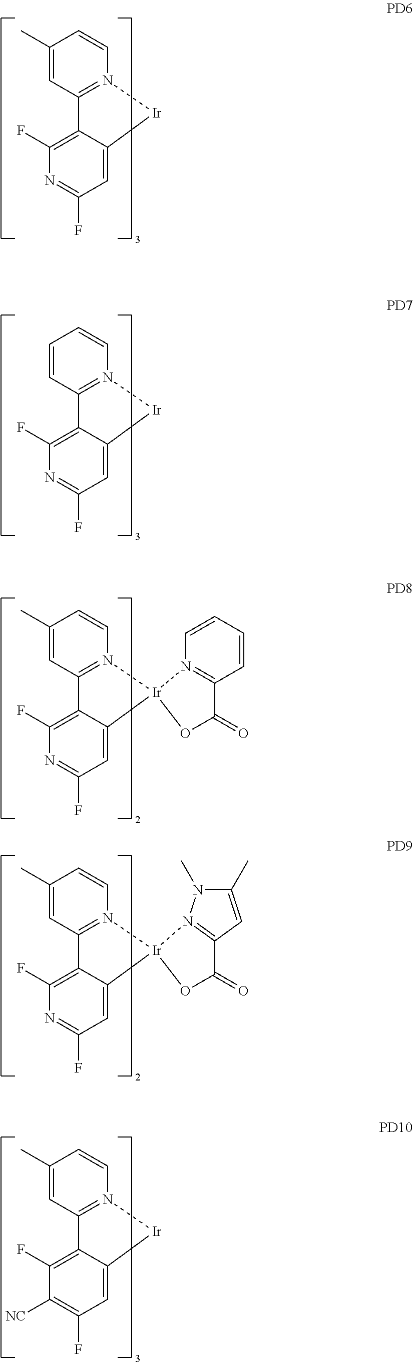

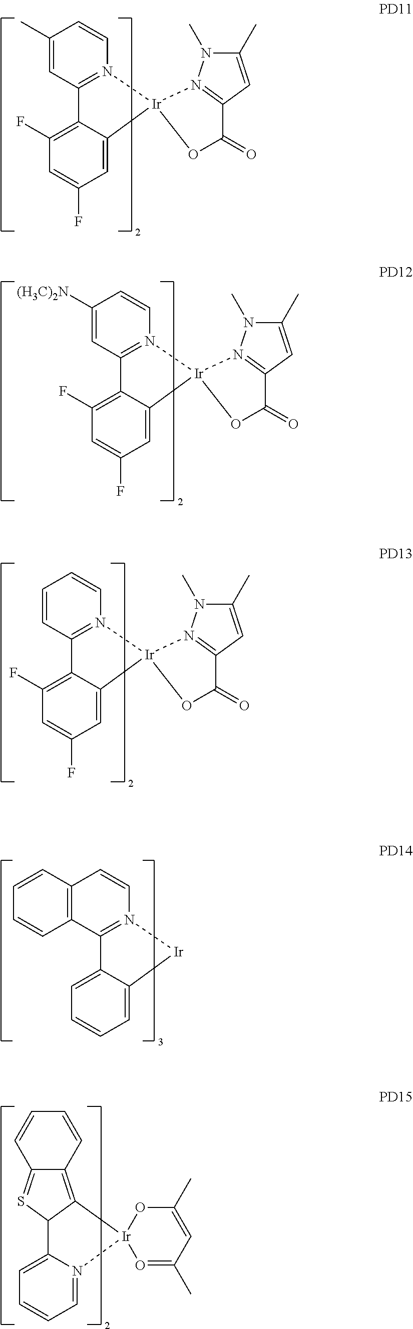

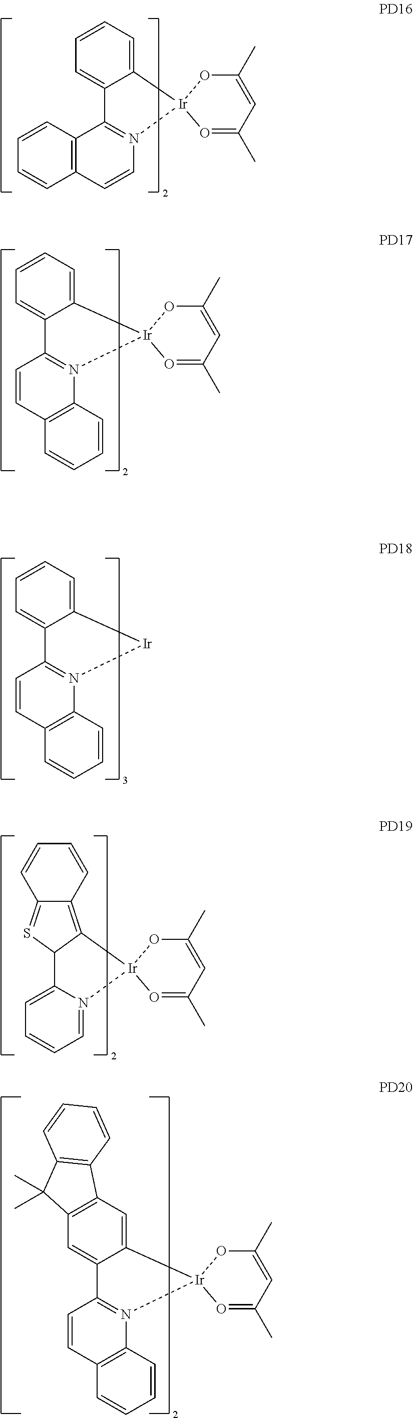

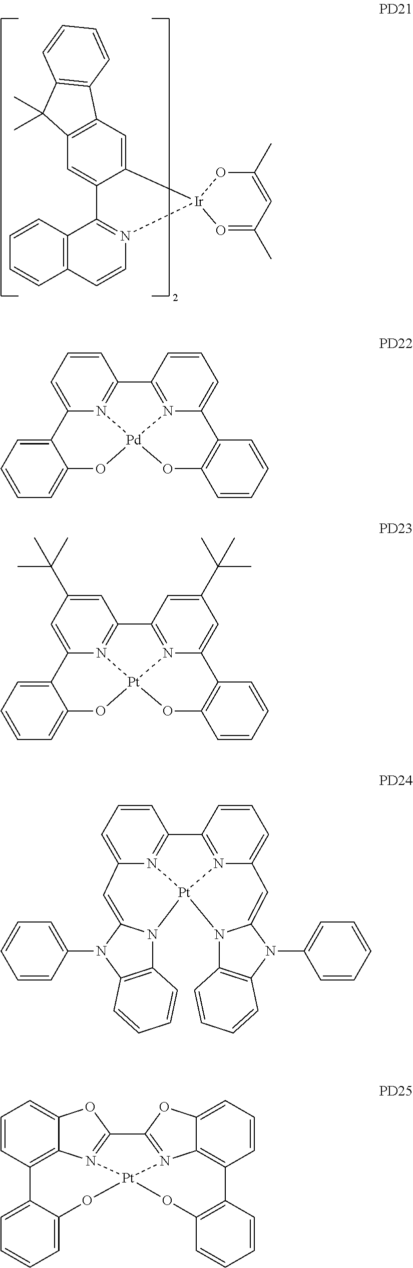

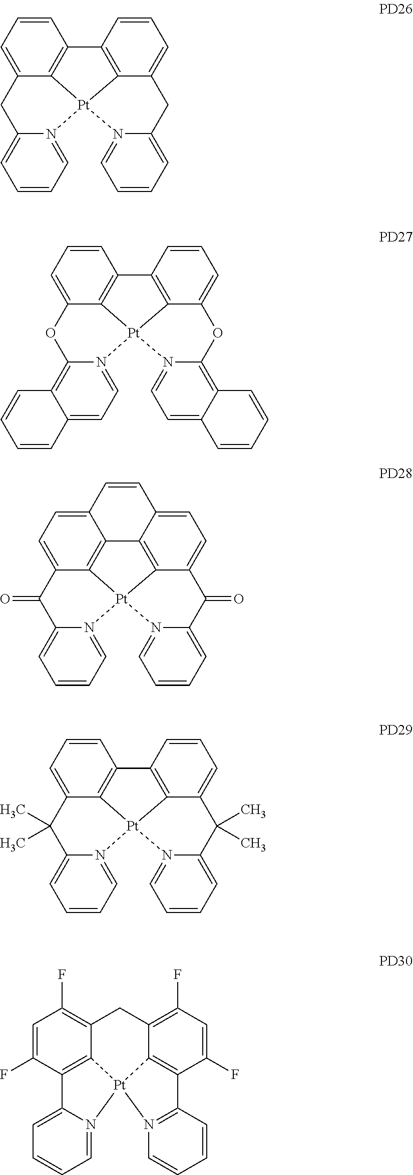

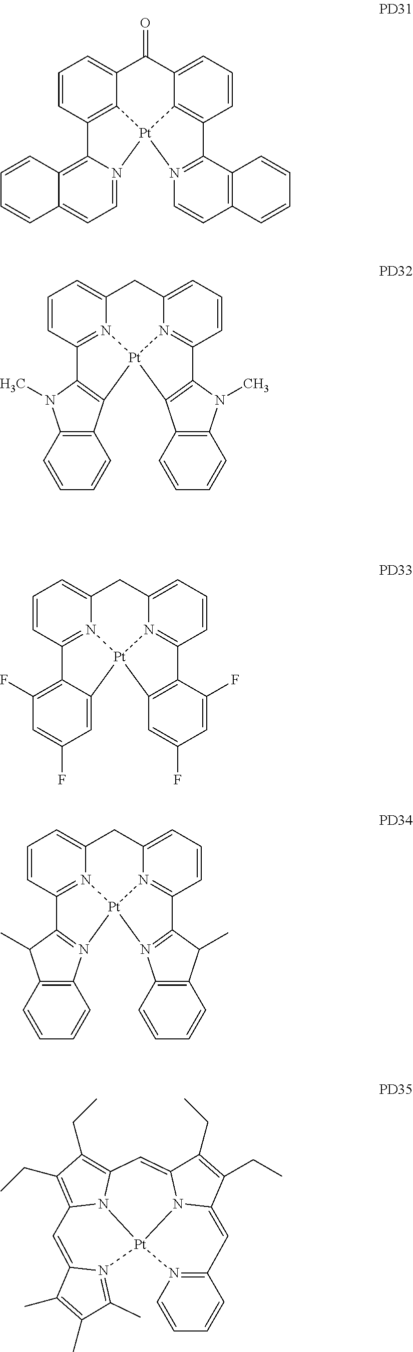

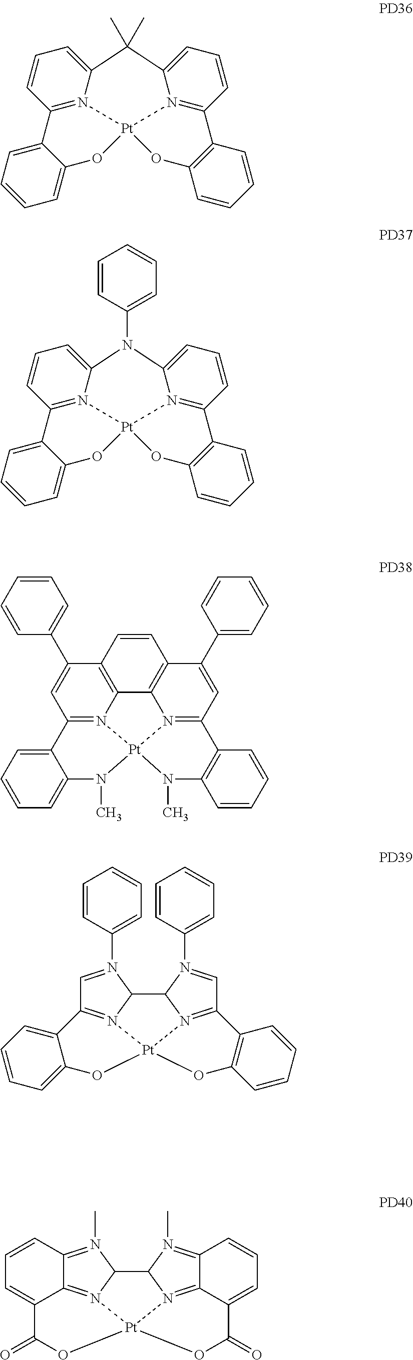

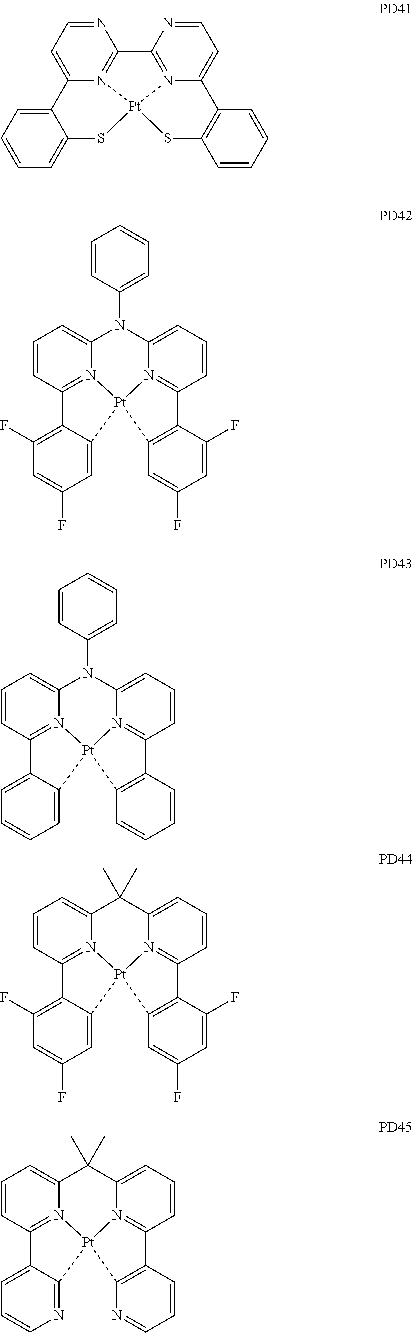

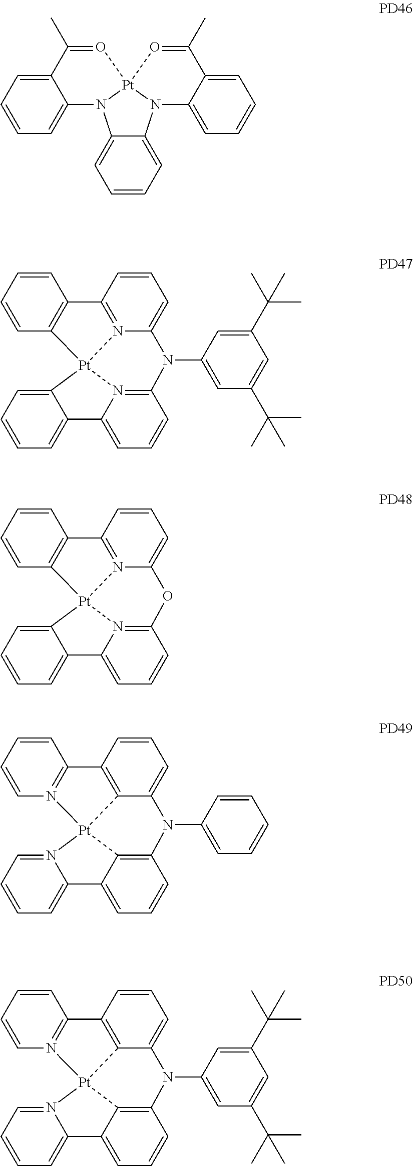

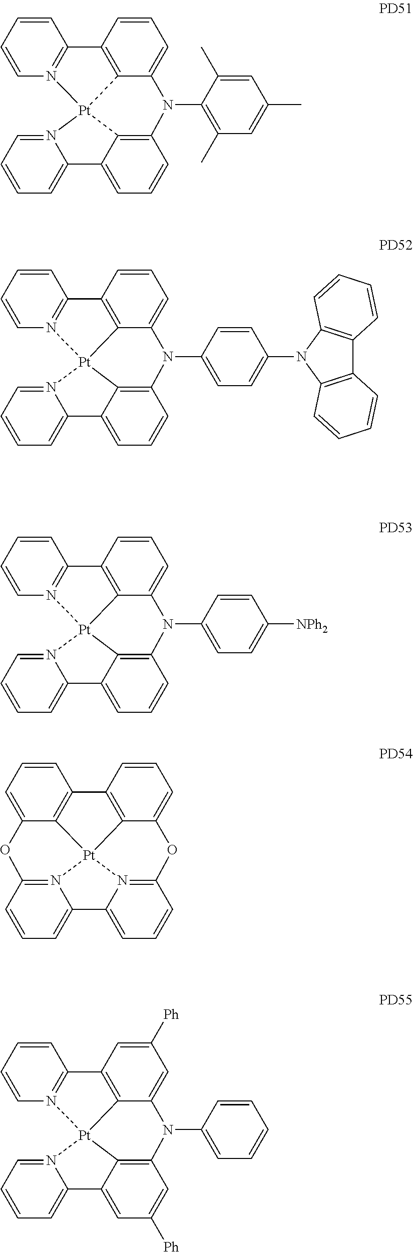

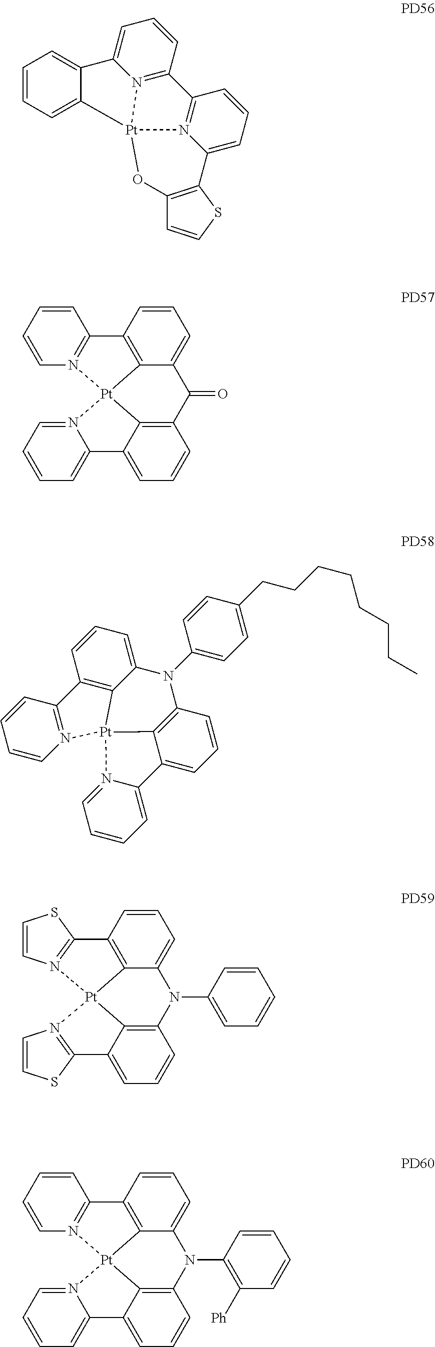

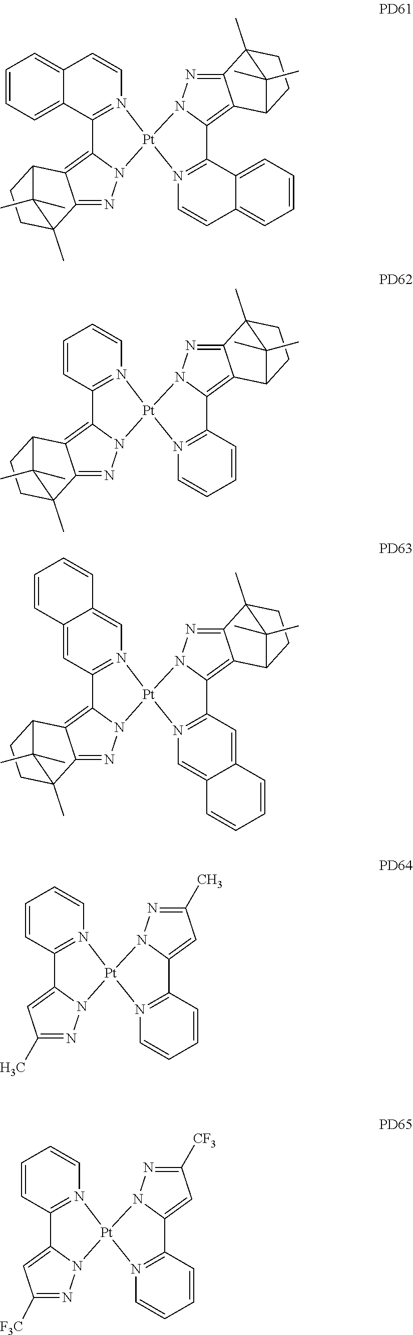

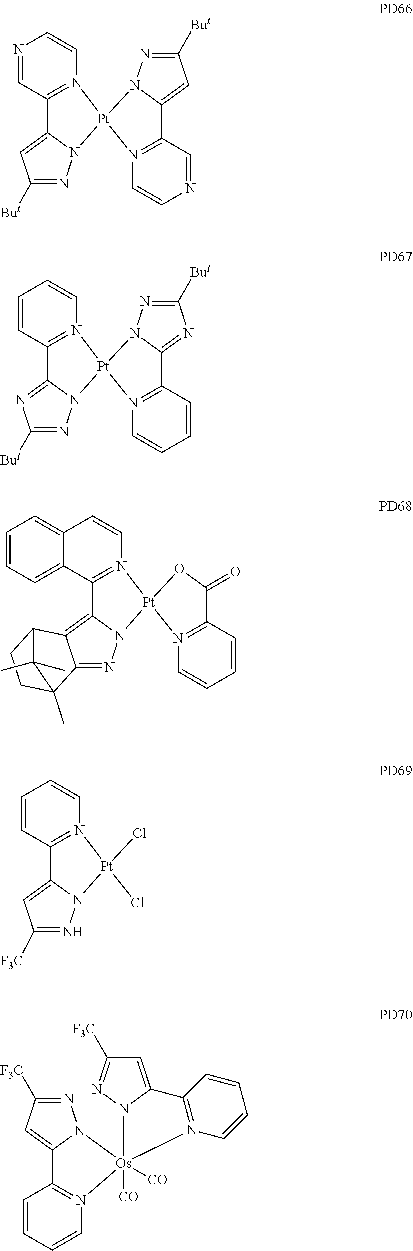

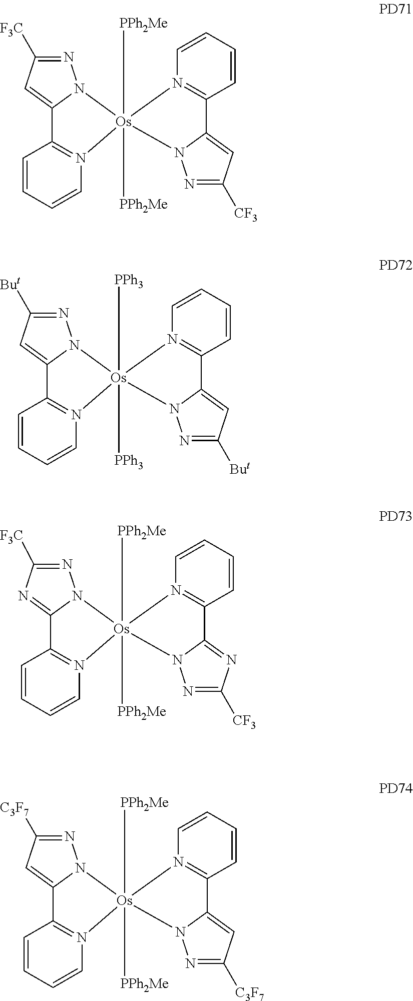

According to another embodiment, the phosphorescent dopant may include PtOEP:

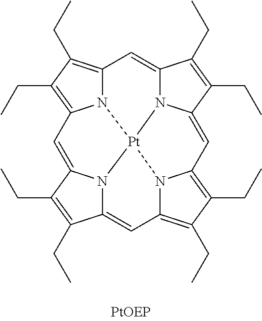

The fluorescent dopant may include at least one selected from DPAVBi, BDAVBi, TBPe, DCM, DCJTB, Coumarin 6, and C545T.

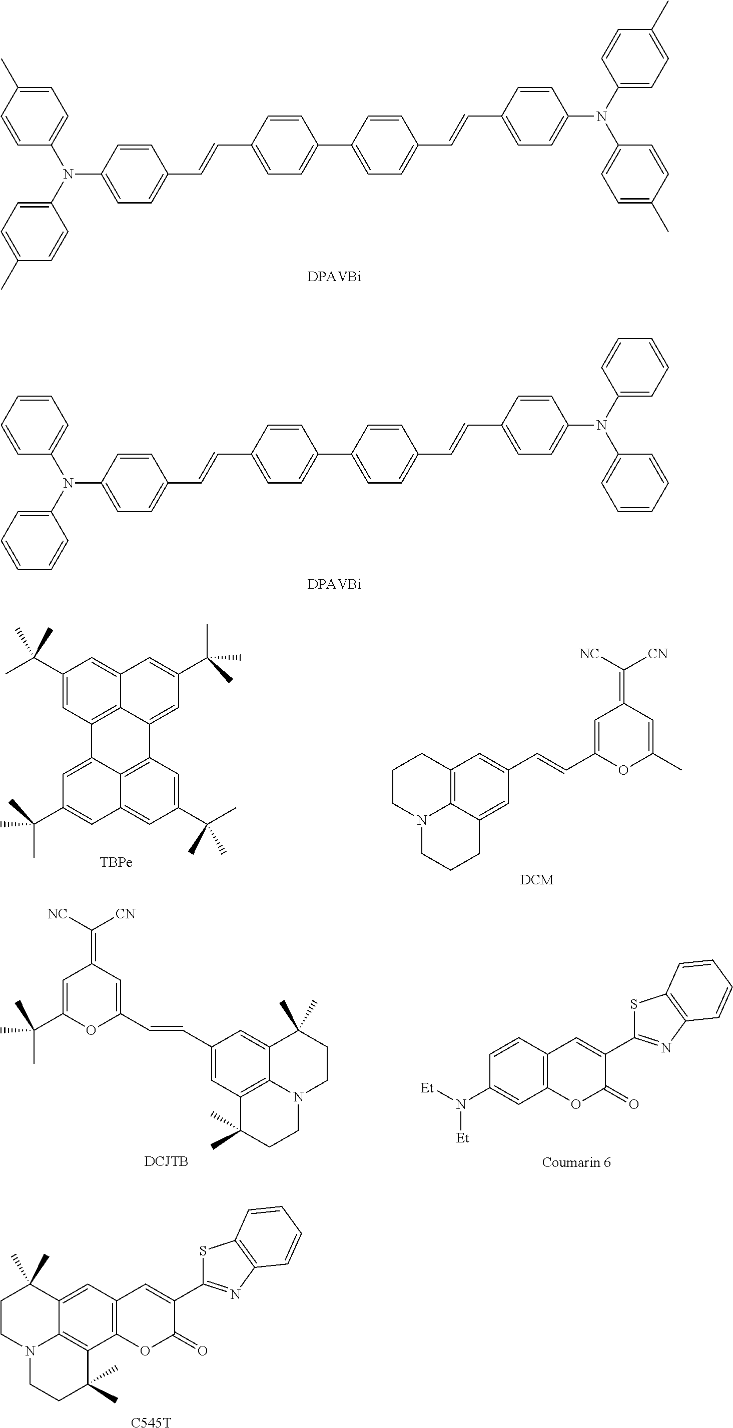

The fluorescent dopant may include a compound represented by Formula 501 below.

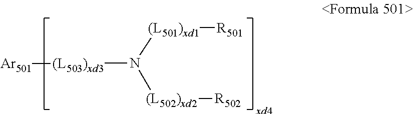

wherein in Formula 501,

Ar₅₀₁ may be selected from a naphthalene, a heptalene, a fluorenene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene;

a naphthalene, a heptalene, a fluorenene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene, each substituted with at least one selected from each substituted with at least one of a deuterium, —F, —Cl, —Br, —I, a hydroxyl, a cyano, a nitro, an amino, an amidino, a hydrazine, a hydrazone, a carboxylic acid and a salt thereof, a sulfonic acid and a salt thereof, a phosphoric acid and a salt thereof, a C₁-C₆₀ alkyl, a C₂-C₆₀ alkenyl, a C₂-C₆₀ alkynyl, a C₁-C₆₀ alkoxy, a C₃-C₁₀ cycloalkyl, a C₁-C₁₀ heterocycloalkyl, a C₃-C₁₀ cycloalkenyl, a C₁-C₁₀ heterocycloalkenyl, a C₆-C₆₀ aryl, a C₆-C₆₀ aryloxy, a C₆-C₆₀ arylthio, a C₁-C₆₀ heteroaryl, a monovalent non-aromatic condensed polycyclic group, a monovalent non-aromatic hetero-condensed polycyclic group, and —Si(Q₅₀₁)(Q₅₀₂)(Q₅₀₃)(Q₅₀₁ to Q₅₀₃ may be each independently selected from a hydrogen, a C₁-C₆₀ alkyl, a C₂-C₆₀ alkenyl, a C₆-C₆₀ aryl, and a C₁-C₆₀ heteroaryl);

L₅₀₁ to L₅₀₃ may be understood by referring to the description provided herein in connection with L₂₀₁;

R₅₀₁ and R₅₀₂ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a dibenzofuranyl group, and a dibenzothiophenyl group; and

a phenyl, a naphthyl, a fluorenyl, a spiro-fluorenyl, a benzofluorenyl, a dibenzofluorenyl, a pyridinyl, a pyrazinyl, a pyrimidinyl, a pyridazinyl, a quinolinyl, an isoquinolinyl, a quinoxalinyl, a quinazolinyl, a carbazolyl, and a triazinyl, each substituted with at least one selected from a deuterium, a halogen atom, a hydroxyl, a cyano, a nitro, an amino, an amidino, a hydrazine, a hydrazone, a carboxylic acid or a salt thereof, a sulfonic acid or a salt thereof, a phosphoric acid or a salt thereof, a C₁-C₂₀ alkyl, a C₁-C₂₀ alkoxy, a phenyl, a naphthyl, a fluorenyl, a spiro-fluorenyl, a benzofluorenyl, a dibenzofluorenyl, a phenanthrenyl, an anthracenyl, a pyrenyl, a chrysenyl, a pyridinyl, a pyrazinyl, a pyrimidinyl, a pyridazinyl, a quinolinyl, an isoquinolinyl, a quinoxalinyl, a quinazolinyl, a carbazolyl, a triazinyl, a dibenzofuranyl, and a dibenzothiophenyl; and

xd1 to xd3 may be each independently selected from 0, 1, 2, and 3; and

xb4 may be selected from 1, 2, 3, and 4.

The fluorescent dopant may include at least one of Compounds FD1 to FD8:

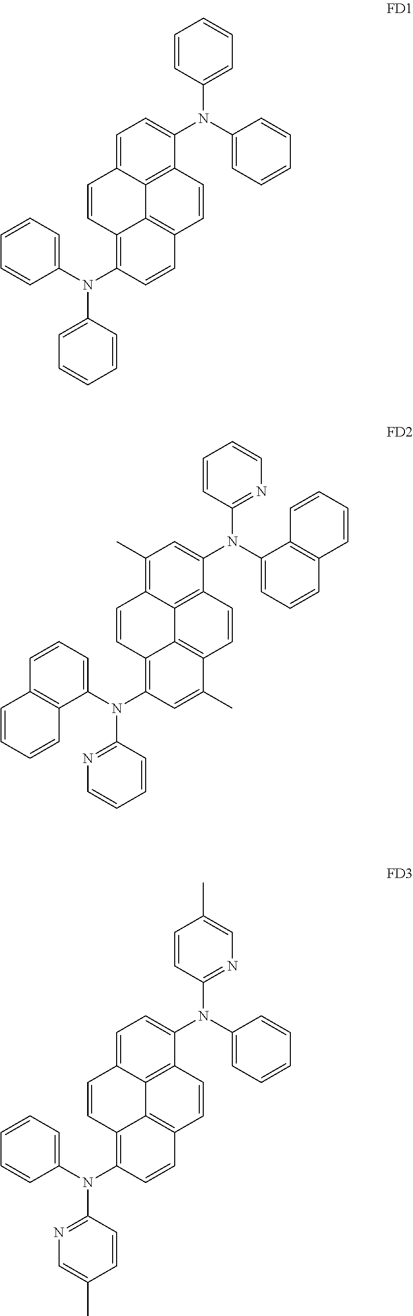 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

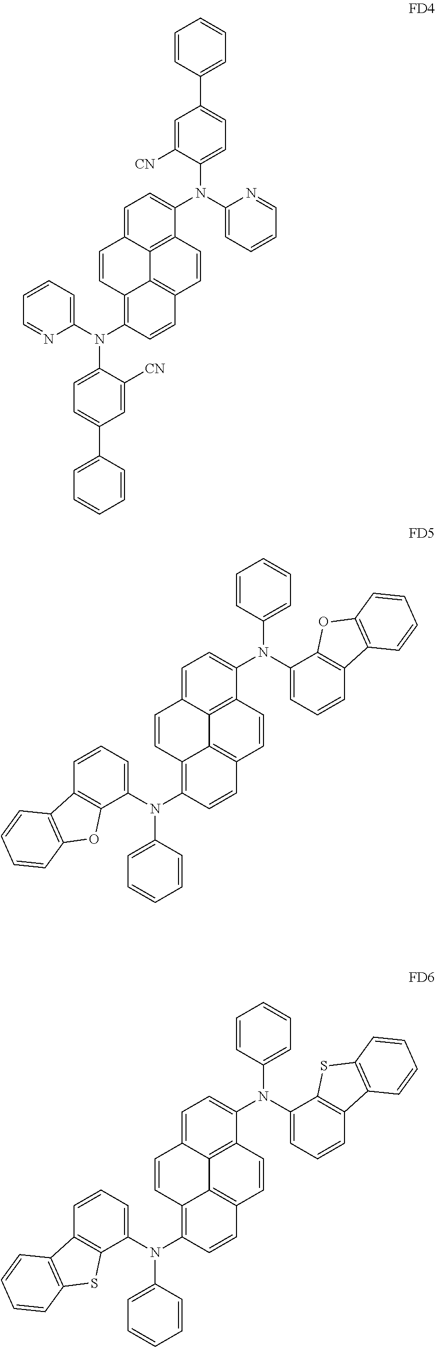

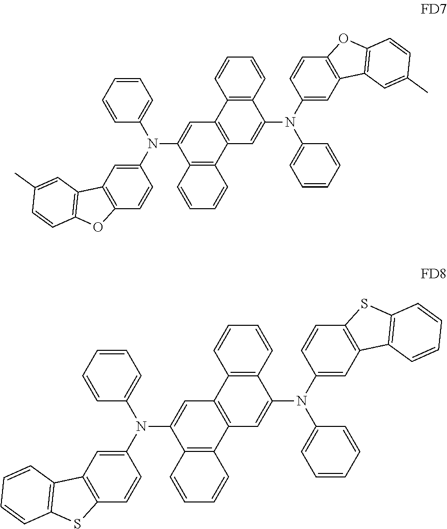

An amount of the dopant in the emission layer may be, e.g., in a range of about 0.01 to about 15 parts by weight based on 100 parts by weight of the host, but is not limited thereto.

A thickness of the emission layer may be in a range of about 100 Å to about 1,000 Å, e.g., about 200 Å to about 600 Å. When the thickness of the emission layer is within this range, excellent light-emission characteristics may be obtained without a substantial increase in driving voltage.

Then, the electron transport region may be disposed on the emission layer.

The electron transport region may include at least one selected from a buffer layer, an electron transport layer (ETL), and an electron injection layer, but is not limited thereto.

For example, the electron transport region may have an electron transport layer alone, a structure of electron transport layer/electron injection layer, or a structure of buffer layer/electron transport layer/electron injection layer, wherein layers of each structure are sequentially stacked from the emission layer in this stated order, but is not limited thereto.

The electron transport region may include a buffer layer. Luminescent efficiency and lifespan of an organic light-emitting device may be improved by optimizing balance of holes and electrons in an emission layer. The buffer layer may help prevent electrons from being injected too fast into the emission layer, and may help control moving speed of electrons, thereby improving the luminescent efficiency and lifespan of the organic light-emitting device.

The buffer layer may include at least one first material. When the buffer layer includes the first material, the electron transport layer may include at least one second material, but is not limited thereto. When the buffer layer includes the first material and the electron transport layer includes the second material, the buffer layer may be disposed adjacent to the electron transport layer. For example, the buffer layer may be directly adjacent to or may directly contact the electron transport layer.

When the electron transport region includes the buffer layer, the buffer layer may be formed on the emission layer by using various methods, such as vacuum deposition, spin coating casting, a Langmuir-Blodgett (LB) method, ink-jet printing, laser-printing, or laser-induced thermal imaging. When the buffer layer is formed by vacuum deposition or spin coating, deposition and coating conditions for the buffer layer may be determined by referring to the deposition and coating conditions for the hole injection layer.

A thickness of the buffer layer may be in a range of about 20 Å to about 1,000 Å, e.g., about 30 Å to about 300 Å. When the thickness of the hole blocking layer is within these ranges, the hole blocking layer may have excellent electron buffer characteristics without a substantial increase in driving voltage.

The electron transport region may include an electron transport layer. The electron transport layer may be formed on the emission layer or the buffer layer by using various methods, for example vacuum deposition, spin coating casting, a LB method, ink-jet printing, laser-printing, or laser-induced thermal imaging. When an electron transport layer is formed by vacuum deposition or spin coating, deposition and coating conditions for the electron transport layer may be determined by referring to the deposition and coating conditions for the hole injection layer.

The electron transport layer may include, for example, at least one selected from second materials represented by Formula 2.

A thickness of the electron transport layer may be in a range of about 100 Å to about 1,000 Å, e.g., about 150 Å to about 500 Å. When the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium quinolate, LiQ) or ET-D2.

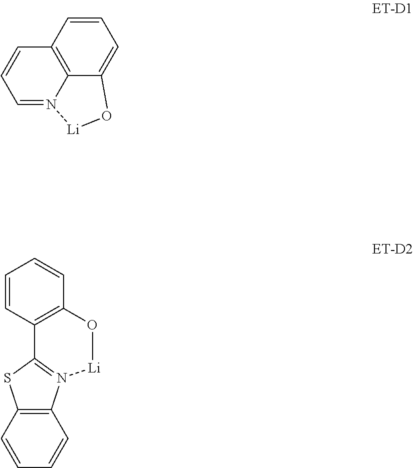

The electron transport region may include an electron injection layer that allows electrons to be easily provided from the second electrode 190.

The electron injection layer may be formed on the electron transport layer by using various methods, such as vacuum deposition, spin coating casting, a LB method, ink-jet printing, laser-printing, or laser-induced thermal imaging. When an electron injection layer is formed by vacuum deposition or spin coating, deposition and coating conditions for the electron injection layer may be determined by referring to the deposition and coating conditions for the hole injection layer.

The electron injection layer may include at least one selected from, LiF, NaCl, CsF, Li₂O, BaO, and LiQ.

A thickness of the electron injection layer may be in a range of about 1 Å to about 100 Å, e.g., about 3 Å to about 90 Å. When the thickness of the electron injection layer is within the range described above, the electron injection layer may have satisfactory electron injection characteristics without a substantial increase in driving voltage.

The second electrode 190 may be disposed on the organic layer 150 having the above-described structure. The second electrode 190 may be a cathode, which is an electron injection electrode, and in this regard, a material for the second electrode 190 may include metal, an alloy, an electrically conductive compound, and a mixture thereof, which have a relatively low work function. Examples of the second electrode 190 may include lithium (Li), magnesium (Mg), aluminum (Al), aluminum-lithium (Al—Li), calcium (Ca), magnesium-indium (Mg—In), or magnesium-silver (Mg—Ag). According to another embodiment, the material for forming the second electrode 190 may be ITO or IZO. The second electrode 190 may be a reflective electrode, a semi-transmissive electrode, or a transmissive electrode.

Hereinbefore, the organic light-emitting device has been described with reference to FIG. 1, but is not limited thereto.

A C₁-C₆₀ alkyl group used herein refers to a linear or branched aliphatic hydrocarbon monovalent group having 1 to 60 carbon atoms, and detailed examples thereof are a methyl group, an ethyl group, a propyl group, an isobutyl group, a sec-butyl group, a ter-butyl group, a pentyl group, an iso-amyl group, and a hexyl group. A C₁-C₆₀ alkylene group used herein refers to a divalent group having the same structure as the C₁-C₆₀ alkyl group.

A C₁-C₆₀ alkoxy group used herein refers to a monovalent group represented by —OA₁₀₁ (wherein A₁₀₁ is the C₁-C₆₀ alkyl group), and detailed examples thereof are a methoxy group, an ethoxy group, and an isopropyloxy group.

A C₂-C₆₀ alkenyl group used herein refers to a hydrocarbon group formed by substituting at least one carbon double bond in the middle or terminal of the C₂-C₆₀ alkyl group, and detailed examples thereof are an ethenyl group, a prophenyl group, and a butenyl group. A C₂-C₆₀ alkenylene group used herein refers to a divalent group having the same structure as the C₂-C₆₀ alkenyl group.

A C₂-C₆₀ alkynyl group used herein refers to a hydrocarbon group formed by substituting at least one carbon triple bond in the middle or terminal of the C₂-C₆₀ alkyl group, and detailed examples thereof are an ethynyl group, and a propynyl group. A C₂-C₆₀ alkynylene group used herein refers to a divalent group having the same structure as the C₂-C₆₀ alkynyl group.

A C₃-C₁₀ cycloalkyl group used herein refers to a monovalent hydrocarbon monocyclic group having 3 to 10 carbon atoms, and detailed examples thereof are a cyclopropyl group, a cyclobutyl group, a cyclopentyl group, a cyclohexyl group, and a cycloheptyl group. A C₃-C₁₀ cycloalkylene group used herein refers to a divalent group having the same structure as the C₃-C₁₀ cycloalkyl group.

A C₁-C₁₀ heterocycloalkyl group used herein refers to a monovalent monocyclic group having at least one hetero atom selected from N, O, P, and S as a ring-forming atom and 1 to 10 carbon atoms, and detailed examples thereof are a tetrahydrofuranyl group, and a tetrahydrothiophenyl group. A C₁-C₁₀ heterocycloalkylene group used herein refers to a divalent group having the same structure as the C₁-C₁₀ heterocycloalkyl group.

A C₃-C₁₀ cycloalkenyl group used herein refers to a monovalent monocyclic group that has 3 to 10 carbon atoms and at least one double bond in the ring thereof and does not have aromacity, and detailed examples thereof are a cyclopentenyl group, a cyclohexenyl group, and a cycloheptenyl group. A C₃-C₁₀ cycloalkenylene group used herein refers to a divalent group having the same structure as the C₃-C₁₀ cycloalkenyl group.

A C₁-C₁₀ heterocycloalkenyl group used herein refers to a monovalent monocyclic group that has at least one hetero atom selected from N, O, P, and S as a ring-forming atom, 1 to 10 carbon atoms, and at least one double bond in its ring. Detailed examples of the C₁-C₁₀ heterocycloalkenyl group are a 2,3-hydrofuranyl group and a 2,3-hydrothiophenyl group. A C₁-C₁₀ heterocycloalkenylene group used herein refers to a divalent group having the same structure as the C₁-C₁₀ heterocycloalkenyl group.

A C₆-C₆₀ aryl group used herein refers to a monovalent group having a carbocyclic aromatic system having 6 to 60 carbon atoms, and a C₆-C₆₀ arylene group used herein refers to a divalent group having a carbocyclic aromatic system having 6 to 60 carbon atoms. Detailed examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

A C₁-C₆₀ heteroaryl group used herein refers to a monovalent group having a carboncyclic aromatic system that has at least one hetero atom selected from N, O, P, and S as a ring-forming atom, and 1 to 60 carbon atoms. A C₁-C₆₀ heteroarylene group used herein refers to a divalent group having a carbocyclic aromatic system that has at least one hetero atom selected from N, O, P, and S as a ring-forming atom, and 1 to 60 carbon atoms. Examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

A C₆-C₆₀ aryloxy group used herein indicates —OA₁₀₂ (wherein A₁₀₂ is the C₆-C₆₀ aryl group), and a C₆-C₆₀ arylthio group indicates —SA₁₀₃ (wherein A₁₀₃ is the C₆-C₆₀ aryl group).

A monovalent non-aromatic condensed polycyclic group used herein refers to a monovalent group that has two or more rings condensed to each other, only carbon atoms (for example, the number of carbon atoms may be in a range of 8 to 60) as a ring forming atom, and non-aromacity in the entire molecular structure. An example of the monovalent non-aromatic condensed polycyclic group is a fluorenyl group. A divalent non-aromatic condensed polycyclic group used herein refers to a divalent group having the same structure as the monovalent non-aromatic condensed polycyclic group.

A monovalent non-aromatic condensed hetero-polycyclic group used herein refers to a monovalent group that has two or more rings condensed to each other, has a heteroatom selected from N, O P, and S, other than carbon atoms (for example, the number of carbon atoms may be in a range of 2 to 60), as a ring forming atom, and has non-aromacity in the entire molecular structure. An example of the monovalent non-aromatic condensed hetero-polycyclic group is a carbazolyl group. A divalent non-aromatic condensed hetero-polycyclic group used herein refers to a divalent group having the same structure as the monovalent non-aromatic condensed hetero-polycyclic group.

The term “Ph” used herein refers to phenyl group, the term “Me” used herein refers to methyl group, the term “Et” used herein refers to ethyl group, and the term “ter-Bu” or “But” used herein refers to tert-butyl.

Hereinafter, an organic light-emitting device according to an embodiment will be described in detail with reference to Synthesis Examples and Examples.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1-1

An anode was manufactured by cutting a Corning 15 Ωcm² (1,200 Å) ITO glass substrate to a size of 50 mm×50 mm×0.7 mm, ultrasonically cleaning the glass substrate by using isopropyl alcohol and pure water for 5 minutes each, and then irradiating UV light for 30 minutes thereto and exposing to ozone to clean. Then, the anode was loaded into a vacuum deposition apparatus.

HT3 was vacuum deposited on the substrate to form a hole transport layer having a thickness of 600 Å. And then, Compound 1 and Ir(ppy)₃ were co-deposited at a weight ratio of 95:5 to form an emission layer having a thickness of 300 Å.

Thereafter, Compound 201 was deposited on the emission layer to form an electron transport layer having a thickness of 400 Å, LiF was deposited on the electron transport layer to form an electron injection layer having a thickness of 10 Å, and Al was vacuum deposited to form a cathode having a thickness of 2000 Å, thereby completing the manufacture of an organic light-emitting device.

### Example 1-2

An organic light-emitting device was manufactured in the same manner as in Example 1-1, except that in forming an electron transport layer, Compound 213 was used instead of Compound 201.

### Example 1-3

An organic light-emitting device was manufactured in the same manner as in Example 1-1, except that in forming an electron transport layer, Compound 223 was used instead of Compound 201.

### Example 1-4

An organic light-emitting device was manufactured in the same manner as in Example 1-1, except that in forming an electron transport layer, Compound 233 was used instead of Compound 201.

### Example 1-5

An organic light-emitting device was manufactured in the same manner as in Example 1-1, except that in forming an electron transport layer, Compound 229 was used instead of Compound 201.

### Comparative Example 1-1

An organic light-emitting device was manufactured in the same manner as in Example 1-1, except that in forming an emission layer, Compound SPPO was used instead of Compound 1, and in forming an electron transport layer, Alq₃ was used instead of Compound 201.

### Comparative Example 1-2

An organic light-emitting device was manufactured in the same manner as in Example 1-1, except that in forming an emission layer, SPPO was used instead of Compound 1.

### Comparative Example 1-3

An organic light-emitting device was manufactured in the same manner as in Example 1-1, except that in forming an electron transport layer, Alq₃ was used instead of Compound 201.

### Example 1-6

An anode was manufactured by cutting a Corning 15 Ωcm² (1200 Å) ITO glass substrate to a size of 50 mm×50 mm×0.7 mm, ultrasonically cleaning the glass substrate by using isopropyl alcohol and pure water for 5 minutes each, and then irradiating UV light for 30 minutes thereto and being exposed to ozone to clean. Then, the anode was loaded into a vacuum deposition apparatus.

HT3 was vacuum deposited on the substrate to form a hole transport layer having a thickness of 600 Å. Then, SPPO and Ir(ppy)₃ were co-deposited at a weight ratio of 95:5 to form an emission layer having a thickness of 300 Å.

Thereafter, Compound 2 was deposited on the emission layer to form a buffer layer having a thickness of 100 Å. Compound 201 was deposited on the buffer layer to form an electron transport layer having a thickness of 300 Å, LiF was deposited on the electron transport layer to form an electron injection layer having a thickness of 10 Å, and Al was vacuum deposited to form a cathode having a thickness of 2000 Å, thereby completing the manufacture of an organic light-emitting device.

### Example 1-7

An organic light-emitting device was manufactured in the same manner as in Example 1-6, except that in forming a buffer layer, Compound 3 was used instead of Compound 2.

### Comparative Example 1-4

An organic light-emitting device was manufactured in the same manner as in Example 1-6, except that in forming an electron transport layer, Alq₃ was used instead of Compound 201.

### Comparative Example 1-5

An organic light-emitting device was manufactured in the same manner as in Example 1-6, except that in forming a buffer layer, BCP was used instead of Compound 2.

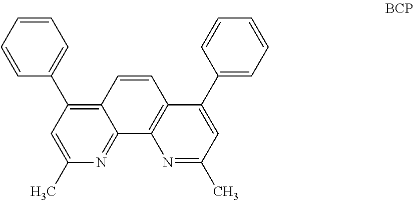 [SMILES: Cc1cc(-c2ccccc2)c2ccc3c(-c4ccccc4)cc(C)nc3c2n1]

### Example 2-1

An anode was manufactured by cutting a Corning 15 Ωcm² (1,200 Å) ITO glass substrate to a size of 50 mm×50 mm×0.7 mm, ultrasonically cleaning the glass substrate by using isopropyl alcohol and pure water for 5 minutes each, and then irradiating UV light for 30 minutes thereto and being exposed to ozone to clean. Then, the anode was loaded into a vacuum deposition apparatus.

HT3 was vacuum deposited on the substrate to form a hole transport layer having a thickness of 600 Å. Then, MADN and FD1 were co-deposited at a weight ratio of 95:5 to form an emission layer having a thickness of 300 Å.

Thereafter, Compound 2 was deposited on the emission layer to form a buffer layer having a thickness of 100 Å. Compound 201 was deposited on the buffer layer to form an electron transport layer having a thickness of 300 Å, LiF was deposited on the electron transport layer to from an electron injection layer having a thickness of 10 Å, and Al was vacuum deposited to form a cathode having a thickness of 2000 Å, thereby completing the manufacture of an organic light-emitting device.

### Example 2-2

An organic light-emitting device was manufactured in the same manner as in Example 2-1, except that in forming an electron transport layer, Compound 213 was used instead of Compound 201.

### Example 2-3

An organic light-emitting device was manufactured in the same manner as in Example 2-1, except that in forming an electron transport layer, Compound 223 was used instead of Compound 201.

### Example 2-4

An organic light-emitting device was manufactured in the same manner as in Example 2-1, except that in forming an electron transport layer, Compound 233 was used instead of Compound 201.

### Example 2-5

An organic light-emitting device was manufactured in the same manner as in Example 2-1, except that in forming an electron transport layer, Compound 229 was used instead of Compound 201.

### Comparative Example 2-1

An organic light-emitting device was manufactured in the same manner as in Example 2-1, except that in forming a buffer layer, BCP was used instead of Compound 2, and in forming an electron transport layer, Alq₃ was used instead of Compound 201.

### Comparative Example 2-2

An organic light-emitting device was manufactured in the same manner as in Example 2-1, except that in forming a buffer layer, BCP was used instead of Compound 2.

### Comparative Example 2-3

An organic light-emitting device was manufactured in the same manner as in Example 2-1, except that in forming an electron transport layer, Alq₃ was used instead of Compound 201.

### Evaluation Example

The maximum efficiency and lifespan T90 (at a required condition of brightness 1500 nit) of organic light-emitting devices manufactured according to Examples 1-1 to 1-7 and 2-1 to 2-5, and Comparative Examples 1-1 to 1-5 and 2-1 to 2-3 were evaluated by using a PR650 Spectroscan Source Measurement Unit. (a product of PhotoResearch). T90 means a period of time spent until brightness reduces to 90% of the initial brightness. Results thereof are shown in Table 1, below.

TABLE 1

| | | | Electron | Effi- | |
|---|---|---|---|---|---|
| | | Buffer | transport | ciency | T90 |
| | Host | layer | layer | (cd/A) | (hr) |
| Example 1-1 | Compound 1 | — | Compound 201 | 47 | 169 |
| Example 1-2 | Compound 1 | — | Compound 213 | 45 | 155 |
| Example 1-3 | Compound 1 | — | Compound 223 | 49 | 238 |
| Example 1-4 | Compound 1 | — | Compound 233 | 51 | 207 |
| Example 1-5 | Compound 1 | — | Compound 229 | 50 | 213 |
| Comparative | SPPO | — | Alq₃ | 23 | 49 |
| Example 1-1 | | | | | |
| Comparative | SPPO | — | Compound 201 | 36 | 81 |
| Example 1-2 | | | | | |
| Comparative | Compound 1 | — | Alq₃ | 27 | 66 |
| Example 1-3 | | | | | |
| Example 1-6 | SPPO | Compound 2 | Compound 201 | 44 | 269 |
| Example 1-7 | SPPO | Compound 3 | Compound 201 | 45 | 231 |
| Comparative | SPPO | Compound 2 | Alq₃ | 31 | 73 |
| Example 1-4 | | | | | |
| Comparative | SPPO | BCP | Compound 201 | 30 | 80 |
| Example 1-5 | | | | | |
| Example 2-1 | MADN | Compound 2 | Compound 201 | 4.3 | 83 |
| Example 2-2 | MADN | Compound 2 | Compound 213 | 4.5 | 90 |
| Example 2-3 | MADN | Compound 2 | Compound 223 | 4.7 | 105 |
| Example 2-4 | MADN | Compound 2 | Compound 233 | 4.7 | 96 |
| Example 2-5 | MADN | Compound 2 | Compound 229 | 4.5 | 123 |
| Comparative | MADN | BCP | Alq₃ | 3.4 | 21 |
| Example 2-1 | | | | | |
| Comparative | MADN | BCP | Compound 201 | 3.8 | 40 |
| Example 2-2 | | | | | |
| Comparative | MADN | Compound 2 | Alq₃ | 3.7 | 35 |
| Example 2-3 | | | | | |

According to Table 1, it may be that the organic light-emitting devices of Examples 1-1 to 1-7 and 2-1 to 2-5 had higher efficiency and longer lifespan than the organic light-emitting devices of Comparative Examples 1-1 to 1-5 and 2-1 to 2-3.

As described above, according to the embodiments, organic light-emitting devices may have high efficiency and long lifespan characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode; and
an organic layer between the first electrode and the second electrode,
wherein the organic layer includes at least one first material and at least one second material, the first material being represented by one of Formulae 1-1 and 1-2, below, and the second material being represented by Formula 2, below: 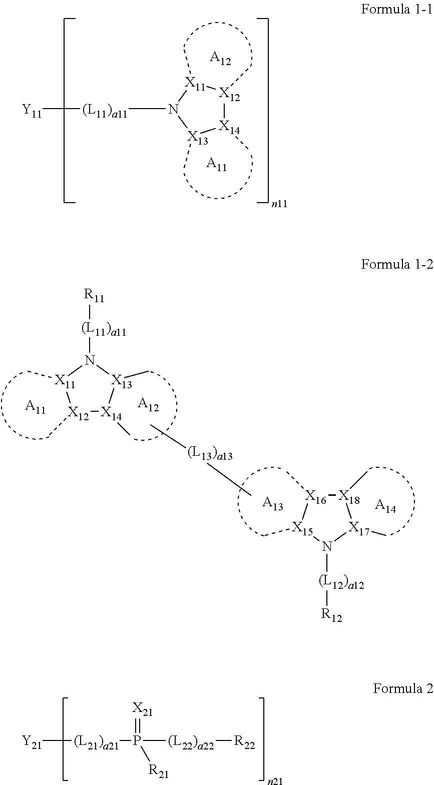
in Formulae 1-1, 1-2, and 2,
A₁₁ to A₁₄ are each independently a moiety represented by one of Formulae 9-1 to 9-12; 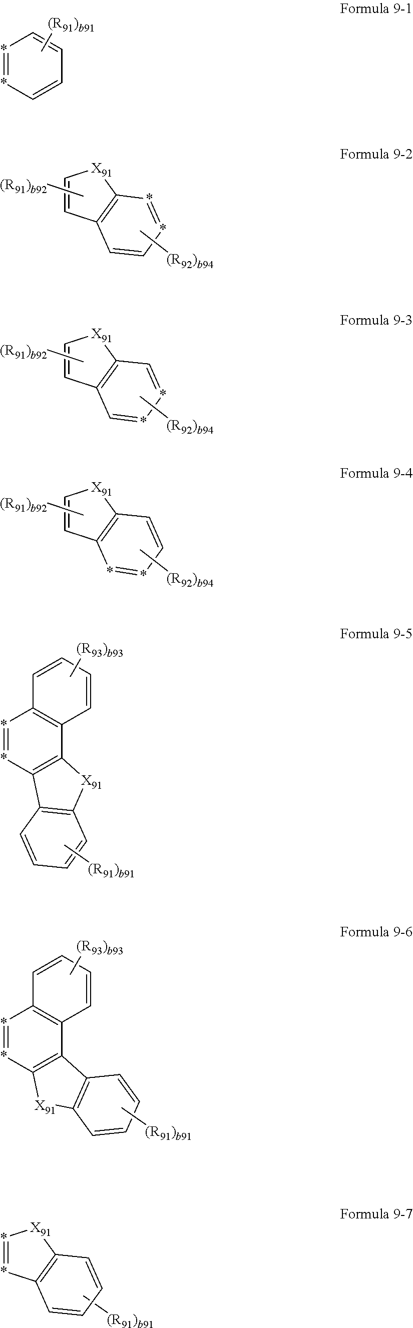 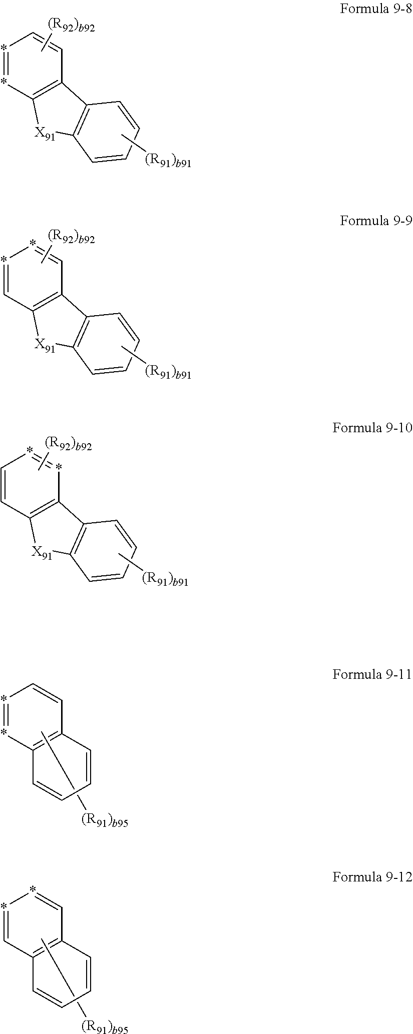
in Formulae 1-1, 1-2, 2, and 9-1 to 9-12,
two adjacent ones of X₁₁ to X₁₈ are each independently a carbon atom corresponding to * in Formulae 9-1 to 9-12;
L₁₁ to L₁₃ are each independently selected from a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed hetero-polycyclic group;
L₂₁ and L₂₂ are each independently selected from a substituted or unsubstituted C₁-C₁₀ alkylene group, a substituted or unsubstituted silylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed hetero-polycyclic group;
a11 to a13, a21, and a22 are each independently 0 or 1;
R₁₁, R₁₂, R₂₁, and R₂₂ are each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;
X₂₁ is selected from an oxygen atom, a sulfur atom, and a selenium atom;
Y₁₁ and Y₂₁ are each independently selected from a substituted or unsubstituted C₆-C₆₀ aryl ring and a substituted or unsubstituted C₁-C₆₀ heteroaryl ring;
n11 and n21 are each independently selected from 1, 2, and 3;
X₉₁ is selected from an oxygen atom, a sulfur atom, C(Q₁)(Q₂), and N(Q₁);
R₉₁ to R₉₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arythio group, a substituted or unsubstituted C₁-C₆₀ heteroaryl group, a substituted or unsubstituted monovalent non-aromatic condensed polycyclic group, and a substituted or unsubstituted monovalent non-aromatic hetero-condensed polycyclic group;
b91 and b93 are each independently selected from 1, 2, 3, and 4;
b92 and b94 are each independently 1 or 2;
b95 is selected from 1, 2, 3, 4, 5, and 6; and
at least one substituent of the substituted C₁-C₁₀ alkylene group, the substituted silylene group, the substituted C₆-C₆₀ arylene group, the substituted C₁-C₆₀ heteroarylene group, the substituted divalent non-aromatic condensed polycyclic group, the substituted divalent non-aromatic condensed hetero-polycyclic group, the substituted C₆-C₆₀ aryl group, the substituted C₁-C₆₀ heteroaryl group, the substituted monovalent non-aromatic condensed polycyclic group, the substituted monovalent non-aromatic condensed hetero-polycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryloxy group, the substituted C₆-C₆₀ arylthio group, the substituted C₆-C₆₀ aryl ring, and the substituted C₁-C₆₀ heteroaryl ring is selected from:
a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₁-C₆₀ alkenyl group, a C₁-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₁₁)(Q₁₂)(Q₁₃);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed hetero-polycyclic group;
a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed hetero-polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, a monovalent non-aromatic condensed hetero-polycyclic group, and —Si(Q₂₁)(Q₂₂)(Q₂₃); and
—Si(Q₃₁)(Q₃₂)(Q₃₃),
wherein Q₁, Q₂, Q₁₁ to Q₁₃, Q₂₁ to Q₂₃ and Q₃₁ to Q₃₃ are each independently selected from a C₁-C₆₀ alkyl group, a C₆-C₆₀ aryl group, a C₁-C₆₀ heteroaryl group, a monovalent non-aromatic condensed polycyclic group, and a monovalent non-aromatic hetero-condensed polycyclic group.

2. The organic light-emitting device as claimed in claim 1, wherein L₁₁ to L₁₃ are each independently selected from:
a phenylene group, a naphthylene group, a pyridinylene group, a pyrazinylene group, a pyrimidinylene group, a quinolinylene group, an isoquinolinylene group, a triazinylene group, a carbazolylene group, a dibenzofuranylene group, and a dibenzothiophenylene group; and
a phenylene group, a naphthylene group, a pyridinylene group, a pyrazinylene group, a pyrimidinylene group, a quinolinylene group, an isoquinolinylene group, a triazinylene group a carbazolylene group, a dibenzofuranylene group, and a dibenzothiophenylene group, each substituted with at least one selected from a deuterium, —F, —Cl, —Br, —I, a cyano group, a nitro group, a C1-C₂₀ alkyl group, a phenyl group, and a naphthyl group.

3. The organic light-emitting device as claimed in claim 1, wherein L₁₁ to L₁₃ are each independently selected from a phenylene group, a naphthylene group, a pyridinylene group, a pyrazinylene group, a pyrimidinylene group, a quinolinylene group, an isoquinolinylene group, a triazinylene group, a carbazolylene group, a dibenzofuranylene group, and a dibenzothiophenylene group.

4. The organic light-emitting device as claimed in claim 1, wherein L₂₁ and L₂₂ are each independently selected from a phenylene group and naphthylene group.

5. The organic light-emitting device as claimed in claim 1, wherein L₂₁ and L₂₂ are each independently a group represented by one of Formulae 3-1 to 3-9 below: 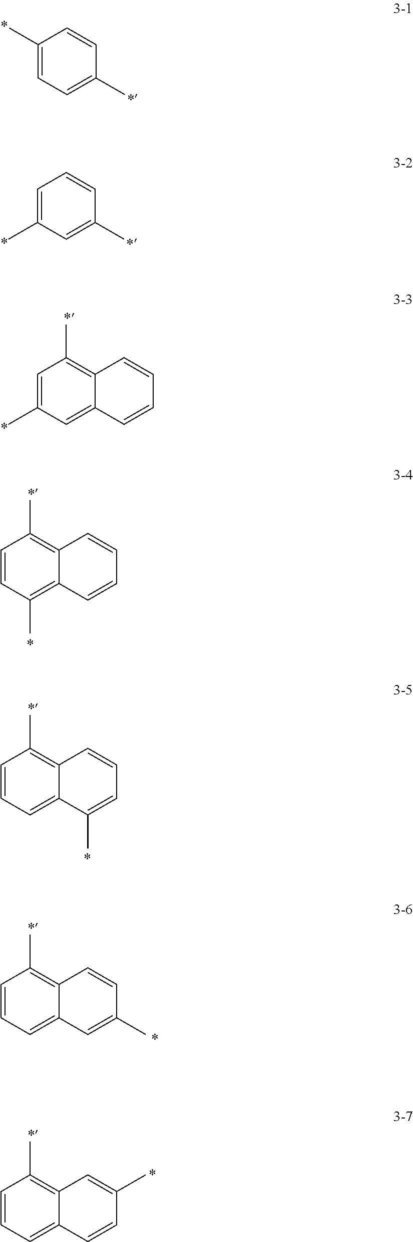 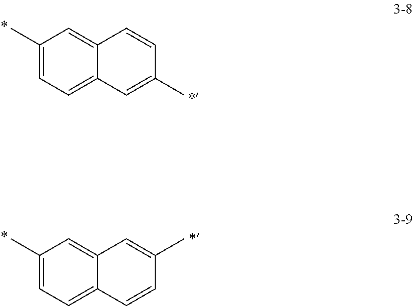
wherein in Formulae 3-1 to 3-9, * and *′ indicate binding sites to a neighboring atom.

6. The organic light-emitting device as claimed in claim 1, wherein R₁₁, R₁₂, R₂₁, and R₂₂ are each independently selected from:
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, a ovalenyl group, a pyrrolyl group, a thiophenyl group, a furanyl group, an imidazolyl group, a pyrazolyl group, a thiazolyl group, an isoothiazolyl group, a oxazolyl group, an isoooxazolyl group, a pyridinyl group, a pyrazinyl group, a pyrimidinyl group, a pyridazinyl group, an isooindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, an isoobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, and a dibenzocarbazolyl group; and
a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a carbazolyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group.

7. The organic light-emitting device as claimed in claim 1, wherein R₁₁ and R₁₂ are each independently a group represented by one of Formulae 4-31 to 4-38 below: 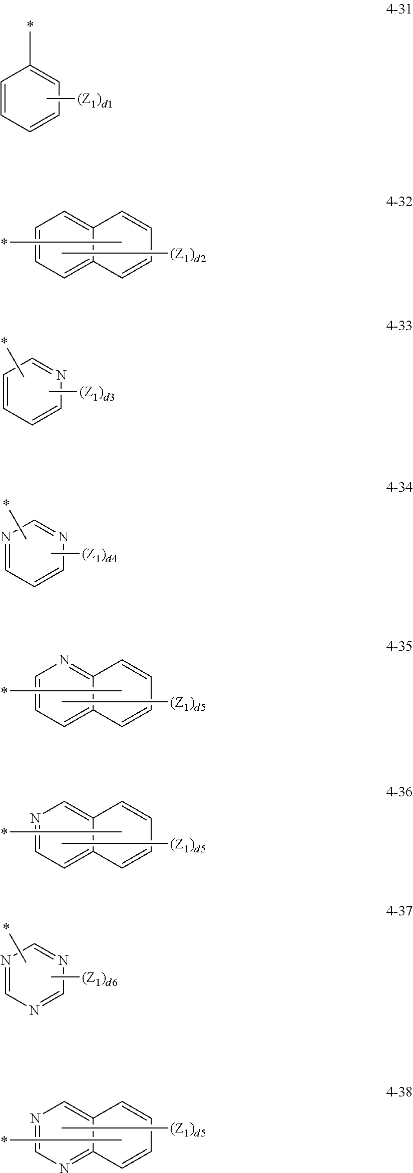
wherein in Formulae 4-31 to 4-38,
Z₁ is selected from a hydrogen, a deuterium, —F, —Cl, —Br, —I, a methyl group, a phenyl group, and a naphthyl group;
d1 is selected from 1, 2, 3, 4, and 5;
d2 is selected from 1, 2, 3, 4, 5, 6, and 7;
d3 is selected from 1, 2, 3, and 4;
d4 is selected from 1, 2, and 3;
d5 is selected from 1, 2, 3, 4, 5, and 6;
d6 is 1 or 2; and
* indicates a binding site to a neighboring atom.

8. The organic light-emitting device as claimed in claim 1, wherein R₂₁ and R₂₂ are each independently a group represented by one of Formulae 4-1 to 4-14 below: 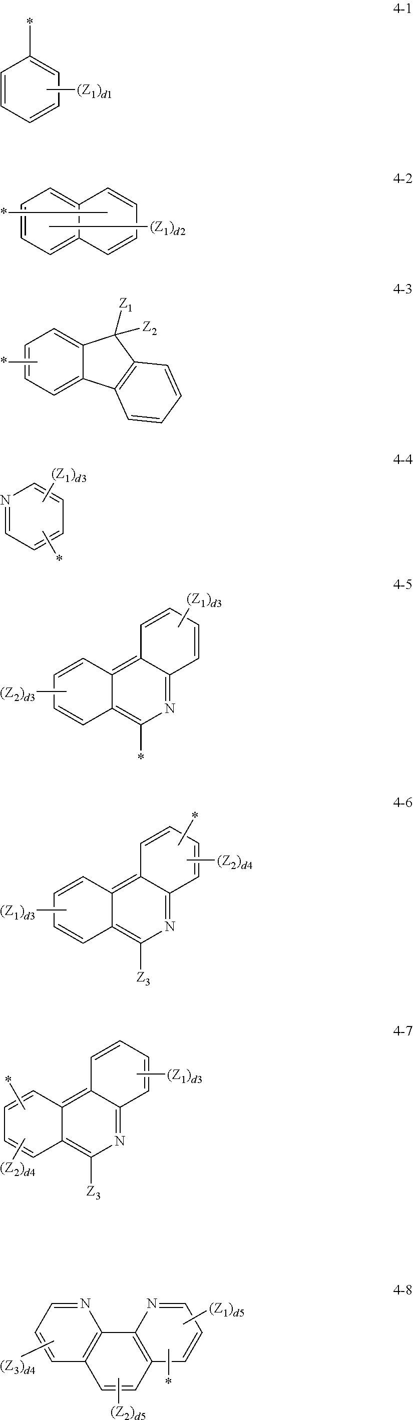 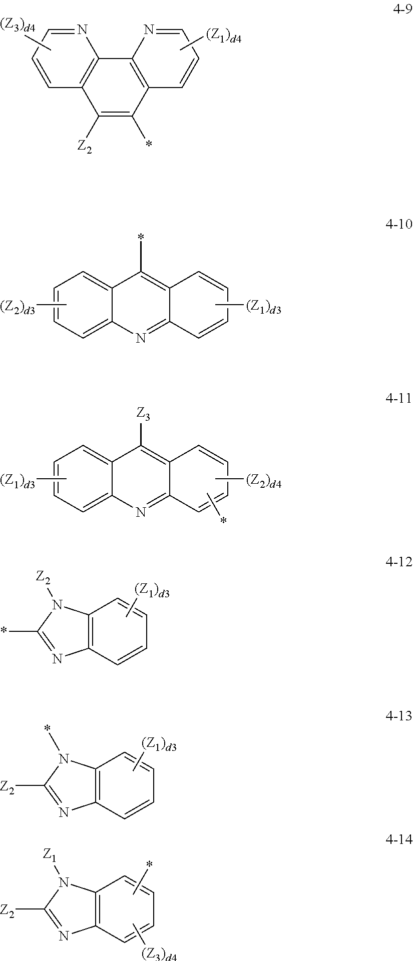
wherein in Formulae 4-1 to 4-14,
Z₁, Z₂, and Z₃ are each independently selected from a hydrogen, a deuterium, —F, —Cl, —Br, —I, a methyl group, a phenyl group, and a naphthyl group;
d1 is selected from 1, 2, 3, 4, and 5;
d2 is selected from 1, 2, 3, 4, 5, 6, and 7;
d3 is selected from 1, 2, 3, and 4;
d4 is selected from 1, 2, and 3;
d5 is 1 or 2; and
* indicates a binding site to a neighboring atom.

9. The organic light-emitting device as claimed in claim 1, wherein X₂₁ is an oxygen atom.

10. The organic light-emitting device as claimed in claim 1, wherein Y₁₁ includes a moiety selected from:
a benzene, a naphthalene, a pyridine, a pyrimidine, a quinoline, an isoquinoline, a quinazoline, and a triazine; and
a benzene, a naphthalene, a pyridine, a pyrimidine, a quinoline, an isoquinoline, a quinazoline, and a triazine, each substituted with at least one selected from a phenyl group and a naphthyl group.

11. The organic light-emitting device as claimed in claim 1, wherein Y₂₁ includes a moiety represented by one of Formulae 7-1 to 7-7 below: 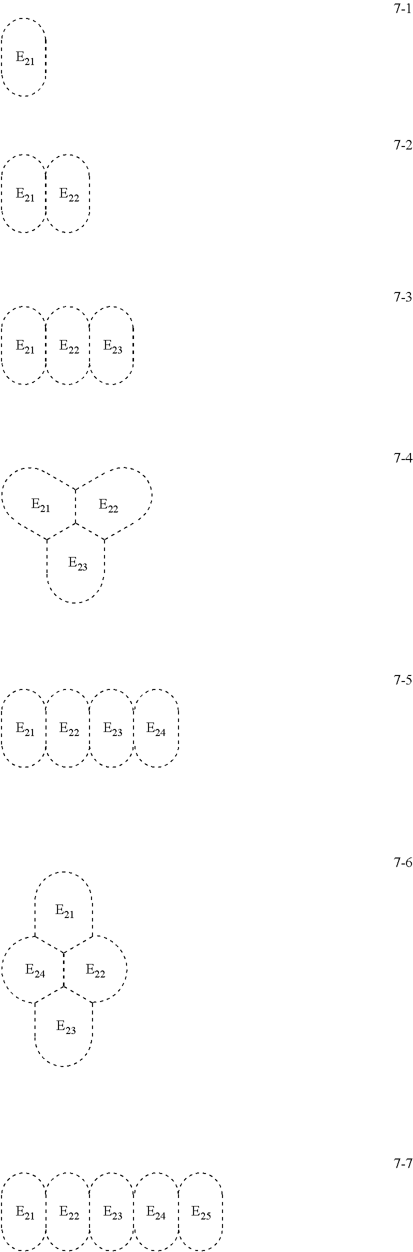
wherein in Formulae 7-1 to 7-7,
E₂₁ to E₂₅ are each independently selected from:
a benzene, a naphthalene, a phenanthrene, an anthracene, a triphenylene, a pyrrole, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine; and
a benzene, a naphthalene, a phenanthrene, an anthracene, a triphenylene, a pyrrole, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine, each substituted with at least one selected from a methyl group, a phenyl group, and a naphthyl group;
wherein E₂₁ in Formula 7-1, one selected from E₂₁ and E₂₂ in Formula 7-2, one selected from E₂₁, F₂₂, and E₂₃ in Formula 7-3, one selected from E₂₁, E₂₂, and E₂₃ in Formula 7-4, one selected from E₂₁, E₂₂, E₂₃, and E₂₄ in Formula 7-5, one selected from E₂₁, E₂₂, E₂₃, and E₂₄ in Formula 7-6, and one selected from E₂₁, E₂₂, E₂₃, and E₂₄ in Formula 7-7 are each independently selected from a pyrrole, an imidazole, a benzoxazole, a benzothiazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine.

12. The organic light-emitting device as claimed in claim 1, wherein Y₂₁ includes a moiety represented by one of Formulae 8-1 to 8-38 below: 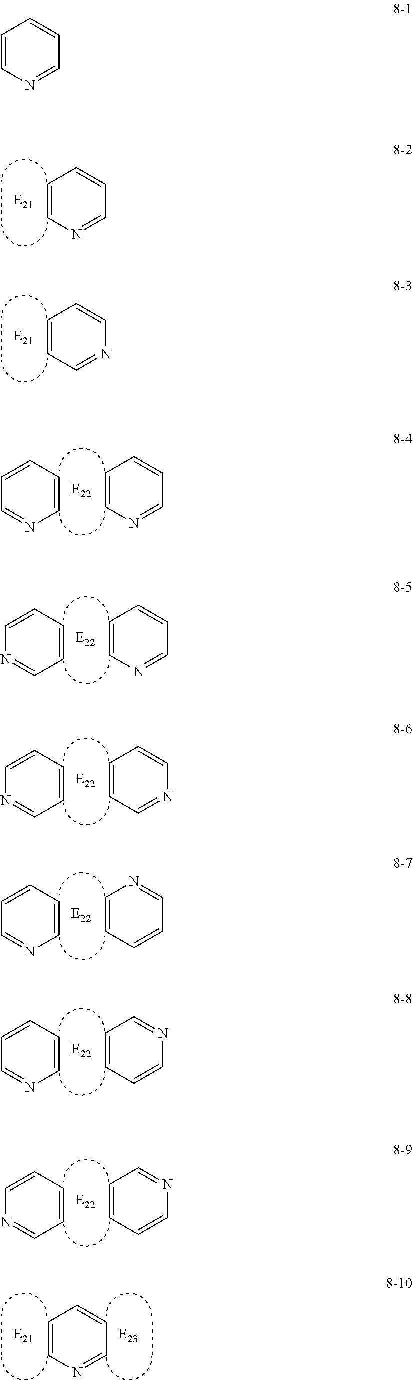 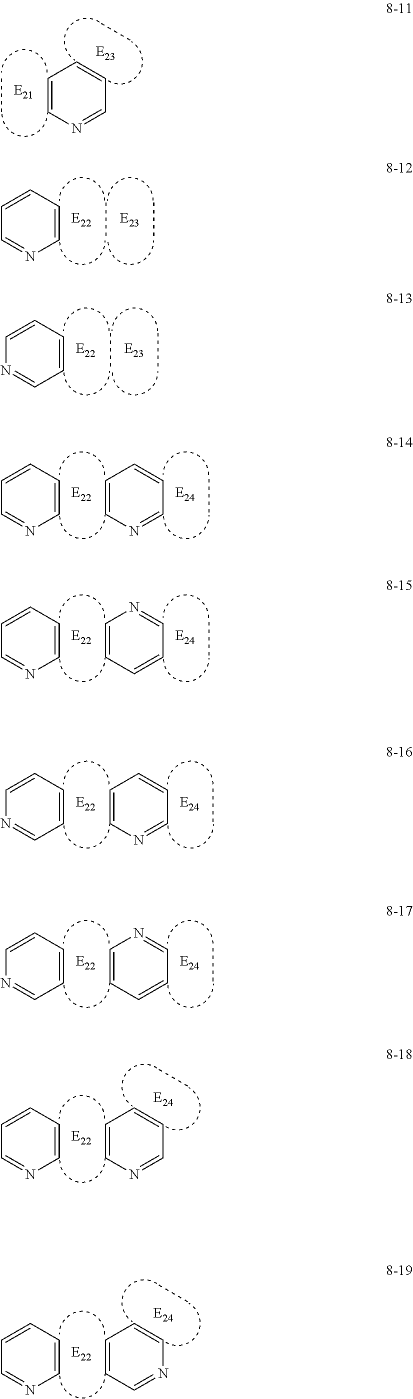 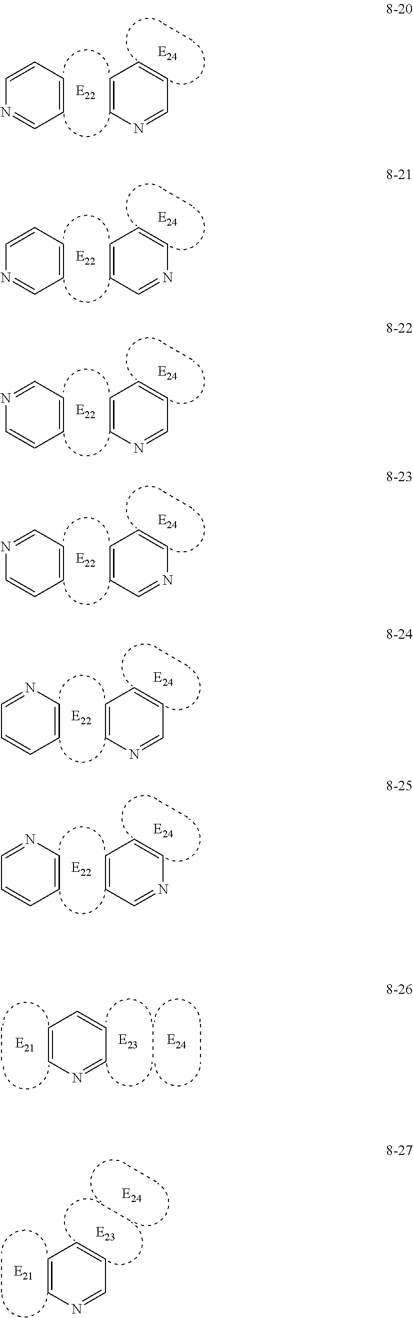 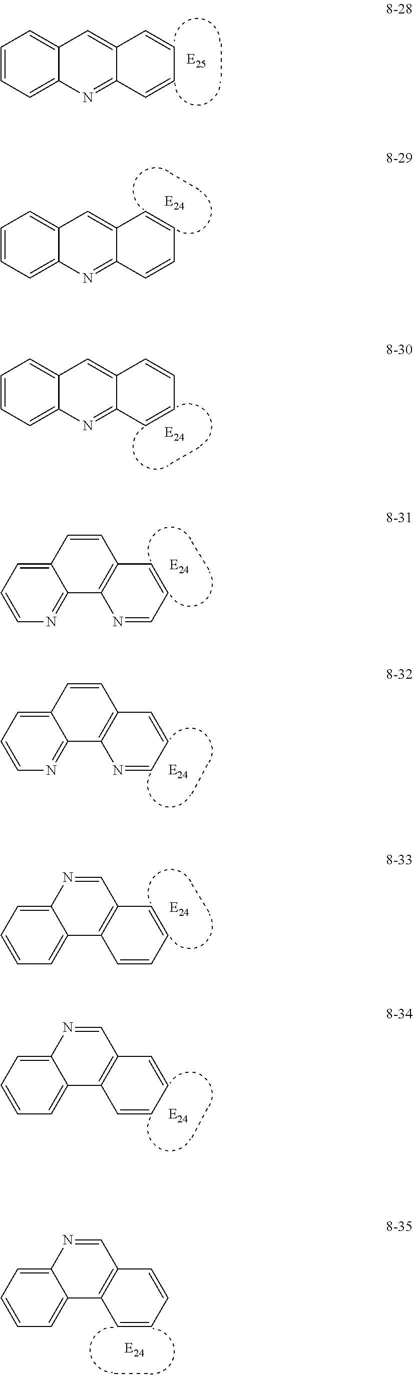 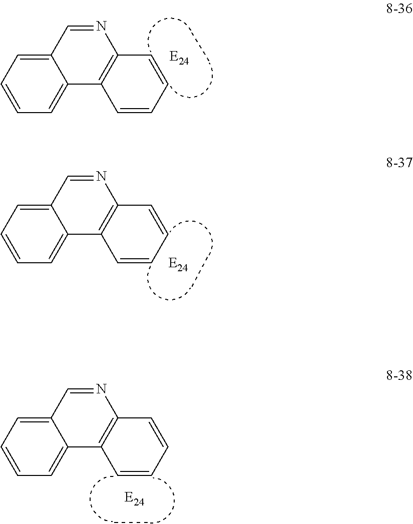
wherein, in Formulae 8-1 to 8-38, E₂₁ to E₂₄ are each independently selected from a benzene, a naphthalene, a phenanthrene, an anthracene, a triphenylene, a pyrrole, an imidazole, a benzoimidazole, a pyridine, a pyrazine, a pyrimidine, an indole, a quinoline, an isoquinoline, a benzoquinoline, a phenanthridine, an acridine, a phenanthroline, a triazole, a tetrazole, and a triazine.

13. The organic light-emitting device as claimed in claim 1, wherein n11 is 1 or 3.

14. The organic light-emitting device as claimed in claim 1, wherein n21 is 1 or 2.

15. The organic light-emitting device as claimed in claim 1, wherein:
the first material is represented by Formula 1-2A, below, and
the second material is represented by one of Formulae 2A-1 and 2B-1, below: 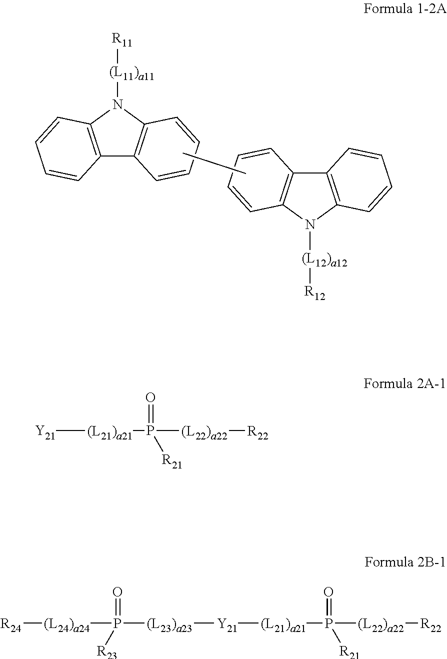
wherein in Formulae 1-2A, 2A-1, and 2B-1,
L₁₁, L₁₂, a11, a12, R₁₁, and R₁₂ are defined the same as in Formula 1-2;
L₂₁, L₂₂, a21, a22, R₂₁, R₂₂, and Y₂₁ are defined the same as in Formula 2;
L₂₃ and L₂₄ are each independently defined the same as L₂₁ in Formula 2:
a23 and a24 are each independently defined the same as a21 in Formula 2; and
R₂₃ and R₂₄ are each independently defined the same as R₂₁ in Formula 2.

16. The organic light-emitting device as claimed in claim 1, wherein:
the first material is selected from Compounds 1 to 173 below; and
the second material is selected from Compounds 201 to 276 below:

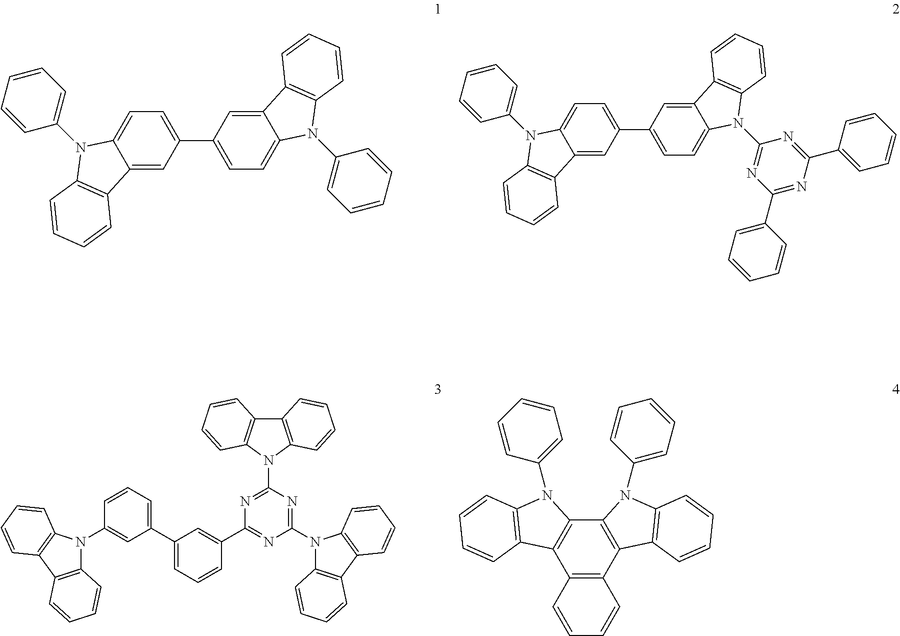 [SMILES: c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1cc(-c2cccc(-n3c4ccccc4c4ccccc43)c2)cc(-c2nc(-n3c4ccccc4c4ccccc43)nc(-n3c4ccccc4c4ccccc43)n2)c1 ; c1ccc(-n2c3ccccc3c3c4ccccc4c4c5ccccc5n(-c5ccccc5)c4c32)cc1]

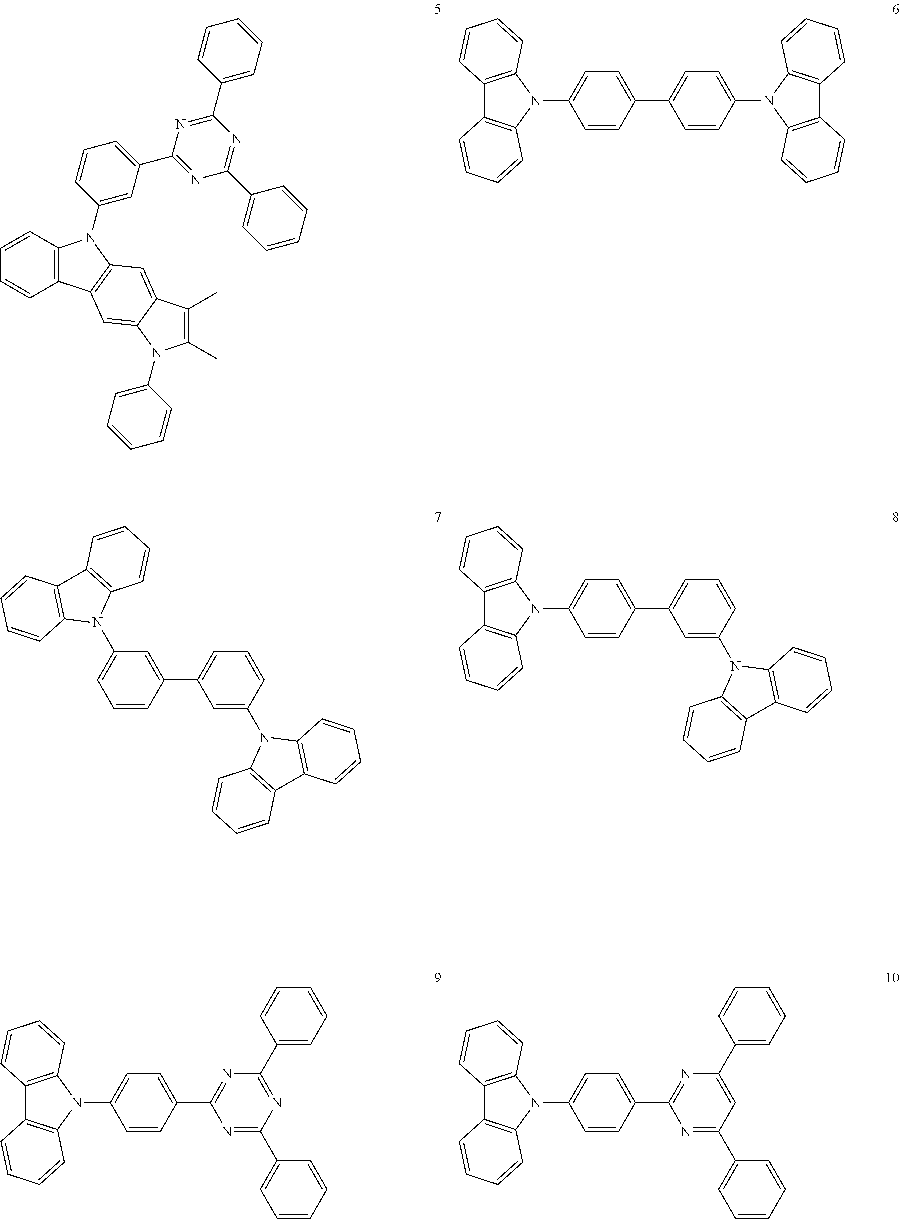 [SMILES: Cc1c(C)n(-c2ccccc2)c2cc3c4ccccc4n(-c4cccc(-c5nc(-c6ccccc6)nc(-c6ccccc6)n5)c4)c3cc12 ; c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; c1cc(-c2ccc(-n3c4ccccc4c4ccccc43)cc2)cc(-n2c3ccccc3c3ccccc32)c1 ; c1ccc(-c2nc(-c3ccccc3)nc(-c3ccc(-n4c5ccccc5c5ccccc54)cc3)n2)cc1 ; c1ccc(-c2cc(-c3ccccc3)nc(-c3ccc(-n4c5ccccc5c5ccccc54)cc3)n2)cc1]

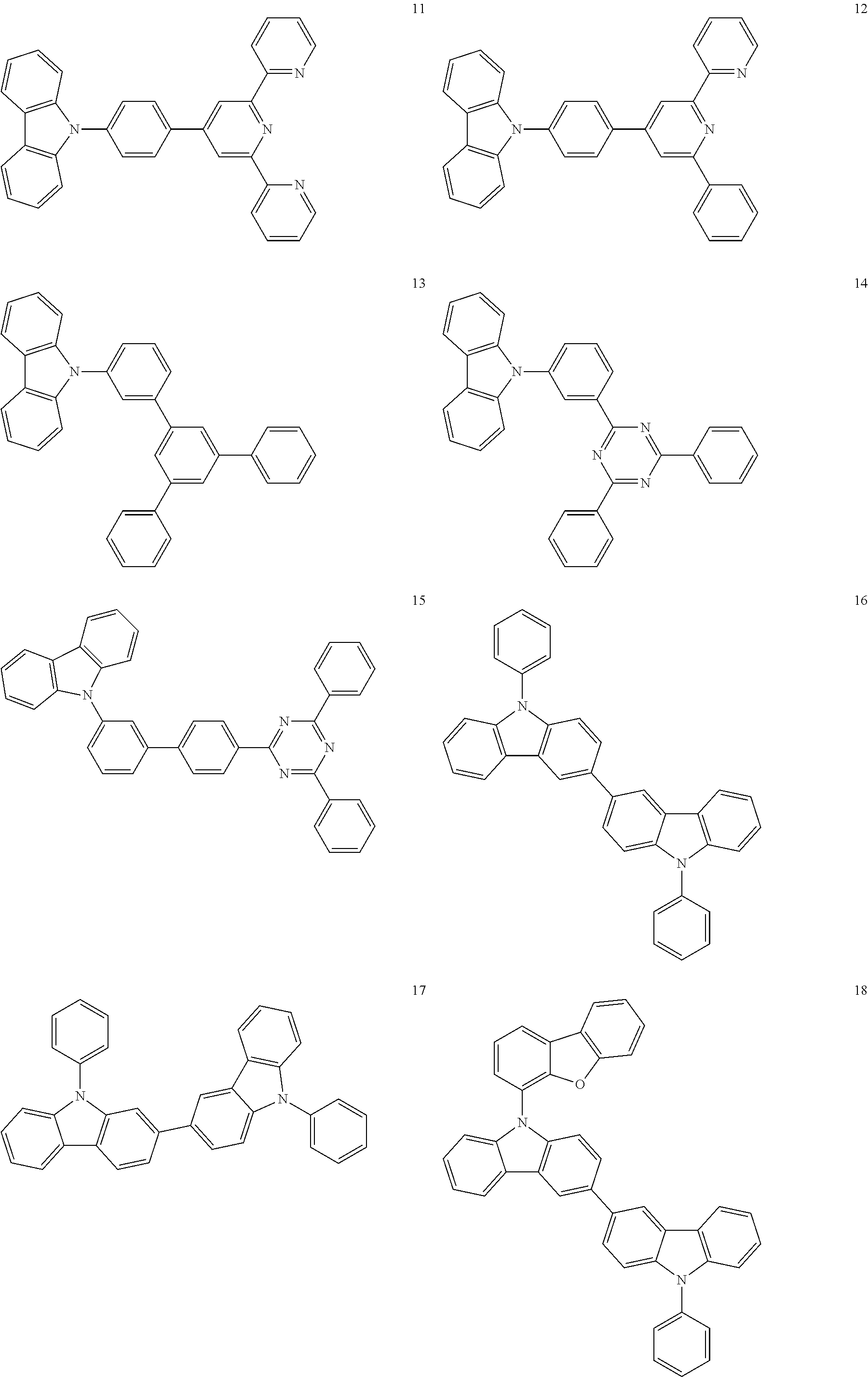

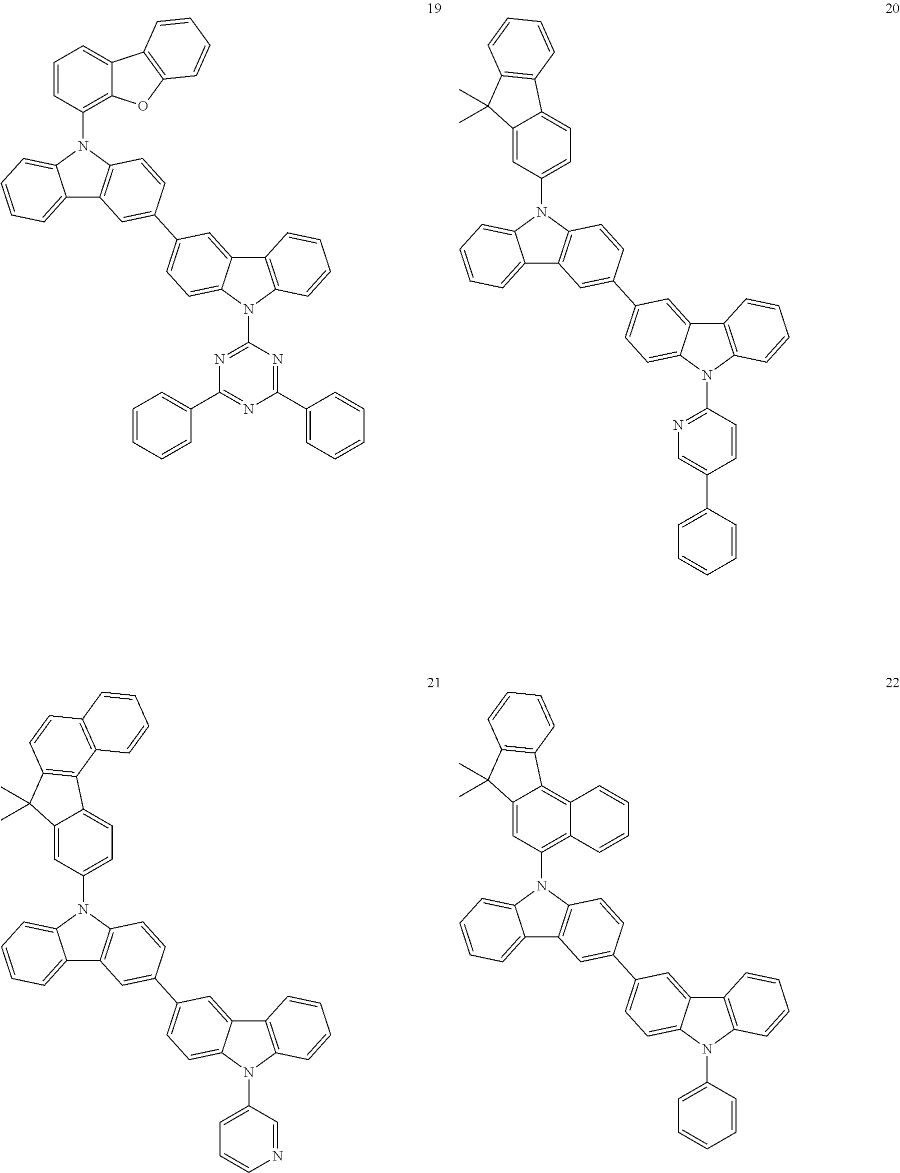 [SMILES: c1ccc(-c2nc(-c3ccccc3)nc(-n3c4ccccc4c4cc(-c5ccc6c(c5)c5ccccc5n6-c5cccc6c5oc5ccccc56)ccc43)n2)cc1 ; CC1(C)c2ccccc2-c2ccc(-n3c4ccccc4c4cc(-c5ccc6c(c5)c5ccccc5n6-c5ccc(-c6ccccc6)cn5)ccc43)cc21 ; CC1(C)c2cc(-n3c4ccccc4c4cc(-c5ccc6c(c5)c5ccccc5n6-c5cccnc5)ccc43)ccc2-c2c1ccc1ccccc21 ; CC1(C)c2ccccc2-c2c1cc(-n1c3ccccc3c3cc(-c4ccc5c(c4)c4ccccc4n5-c4ccccc4)ccc31)c1ccccc21]

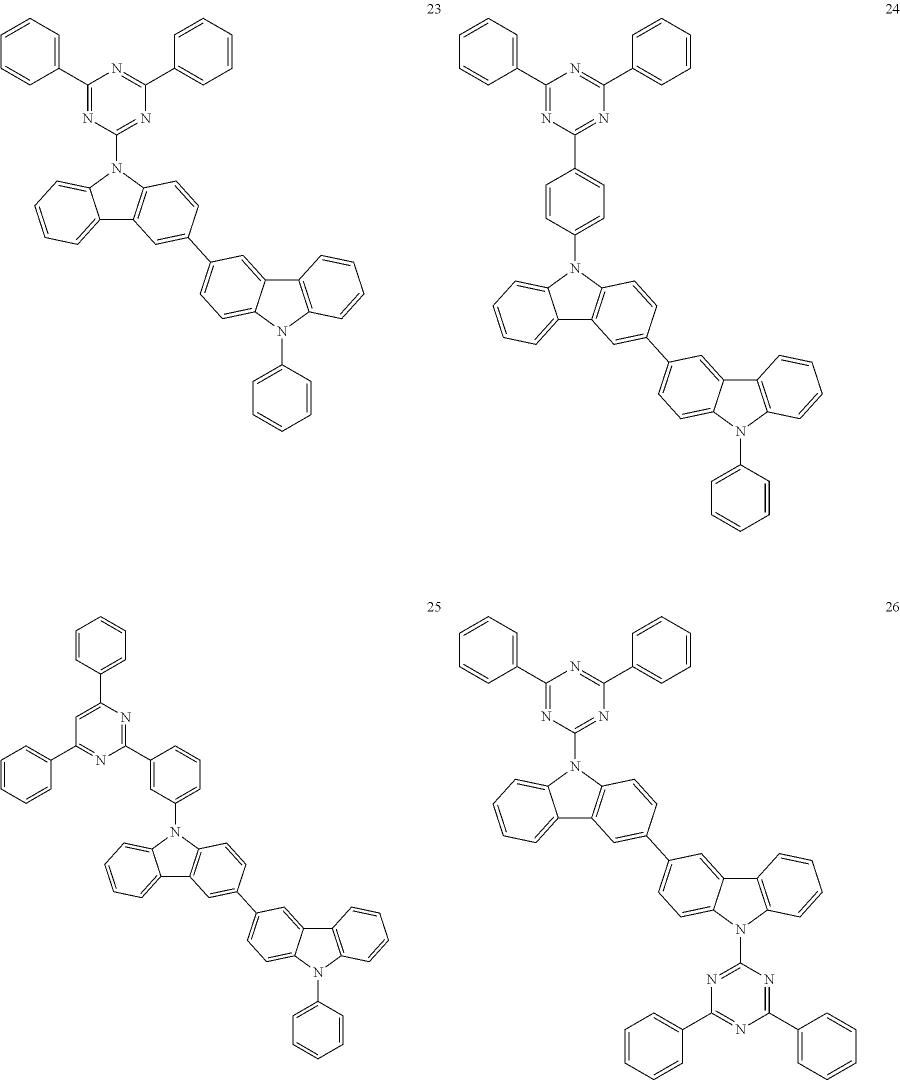 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4cc(-c5ccc6c(c5)c5ccccc5n6-c5nc(-c6ccccc6)nc(-c6ccccc6)n5)ccc43)n2)cc1]

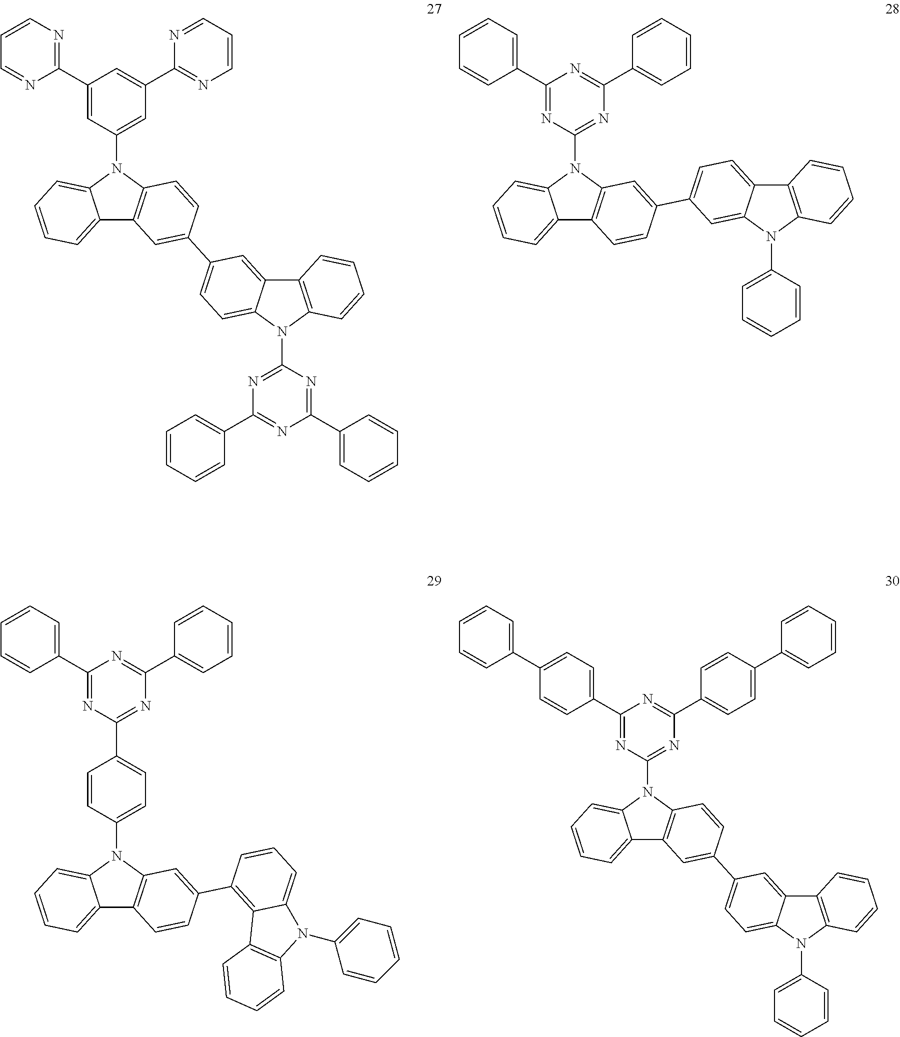 [SMILES: c1ccc(-c2nc(-c3ccccc3)nc(-n3c4ccccc4c4cc(-c5ccc6c(c5)c5ccccc5n6-c5cc(-c6ncccn6)cc(-c6ncccn6)c5)ccc43)n2)cc1 ; c1ccc(-c2nc(-c3ccccc3)nc(-n3c4ccccc4c4ccc(-c5ccc6c7ccccc7n(-c7ccccc7)c6c5)cc43)n2)cc1 ; c1ccc(-c2nc(-c3ccccc3)nc(-c3ccc(-n4c5ccccc5c5ccc(-c6cccc7c6c6ccccc6n7-c6ccccc6)cc54)cc3)n2)cc1 ; c1ccc(-c2ccc(-c3nc(-c4ccc(-c5ccccc5)cc4)nc(-n4c5ccccc5c5cc(-c6ccc7c(c6)c6ccccc6n7-c6ccccc6)ccc54)n3)cc2)cc1]

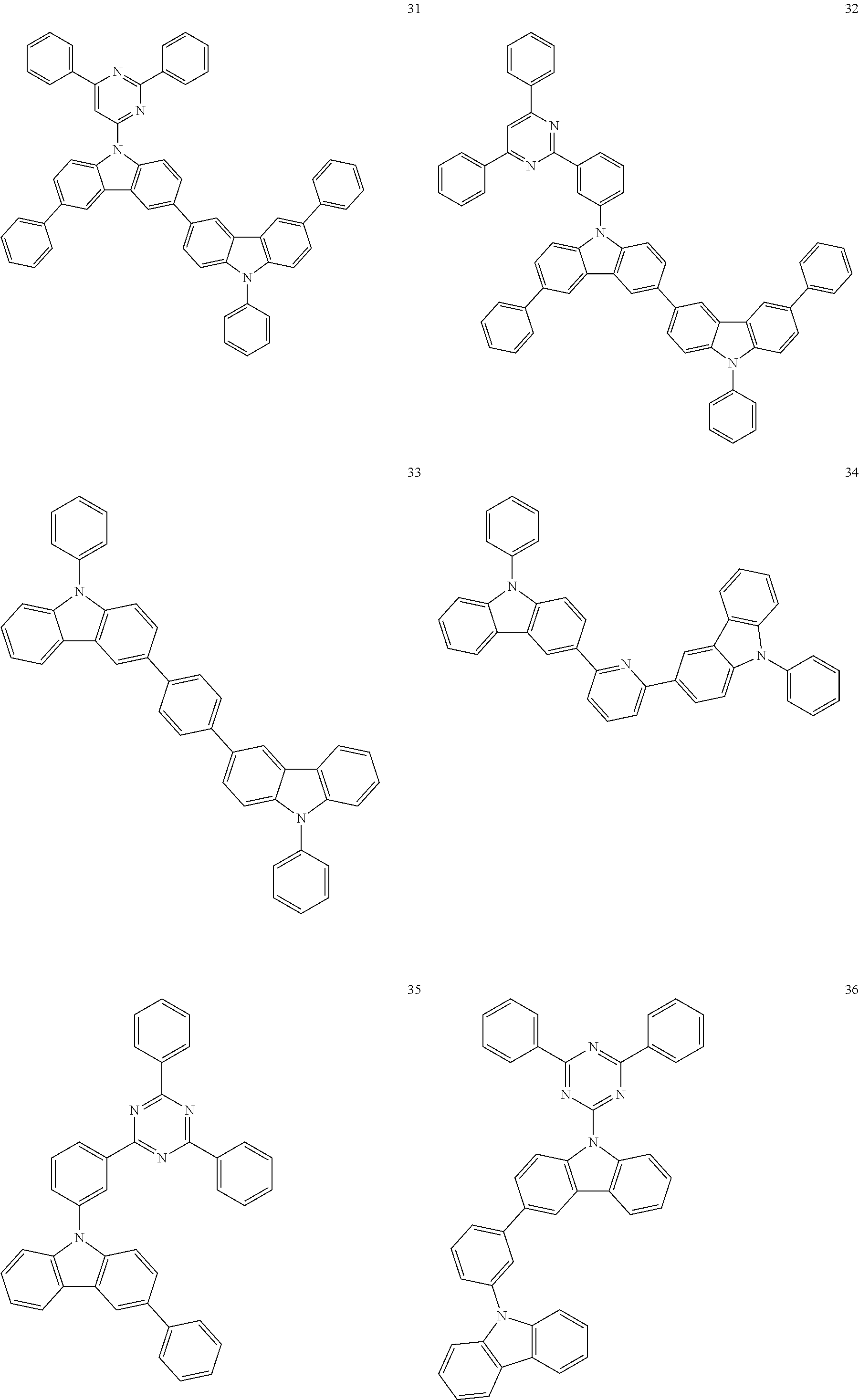

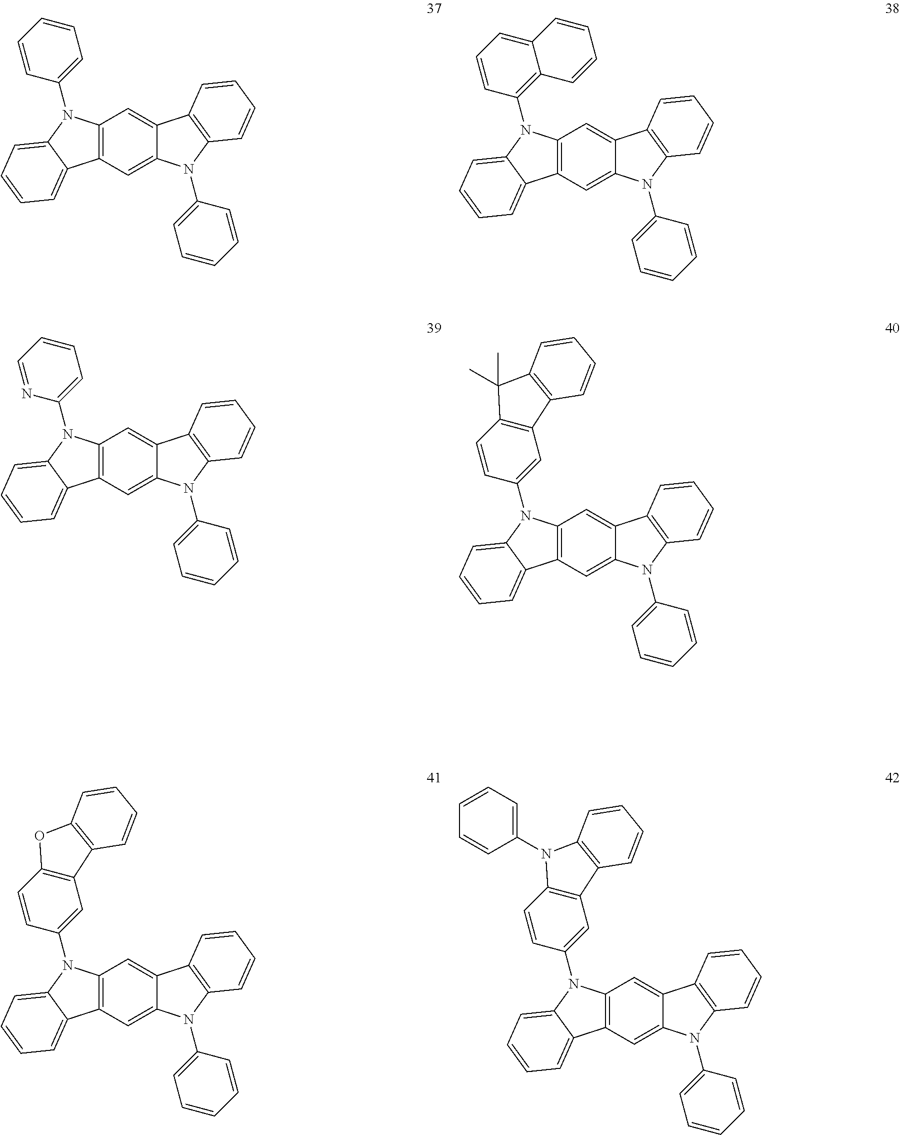 [SMILES: c1ccc(-n2c3ccccc3c3cc4c(cc32)c2ccccc2n4-c2ccccc2)cc1 ; c1ccc(-n2c3ccccc3c3cc4c(cc32)c2ccccc2n4-c2cccc3ccccc23)cc1 ; c1ccc(-n2c3ccccc3c3cc4c(cc32)c2ccccc2n4-c2ccccn2)cc1 ; CC1(C)c2ccccc2-c2cc(-n3c4ccccc4c4cc5c(cc43)c3ccccc3n5-c3ccccc3)ccc21 ; c1ccc(-n2c3ccccc3c3cc4c(cc32)c2ccccc2n4-c2ccc3oc4ccccc4c3c2)cc1 ; c1ccc(-n2c3ccccc3c3cc(-n4c5ccccc5c5cc6c(cc54)c4ccccc4n6-c4ccccc4)ccc32)cc1]

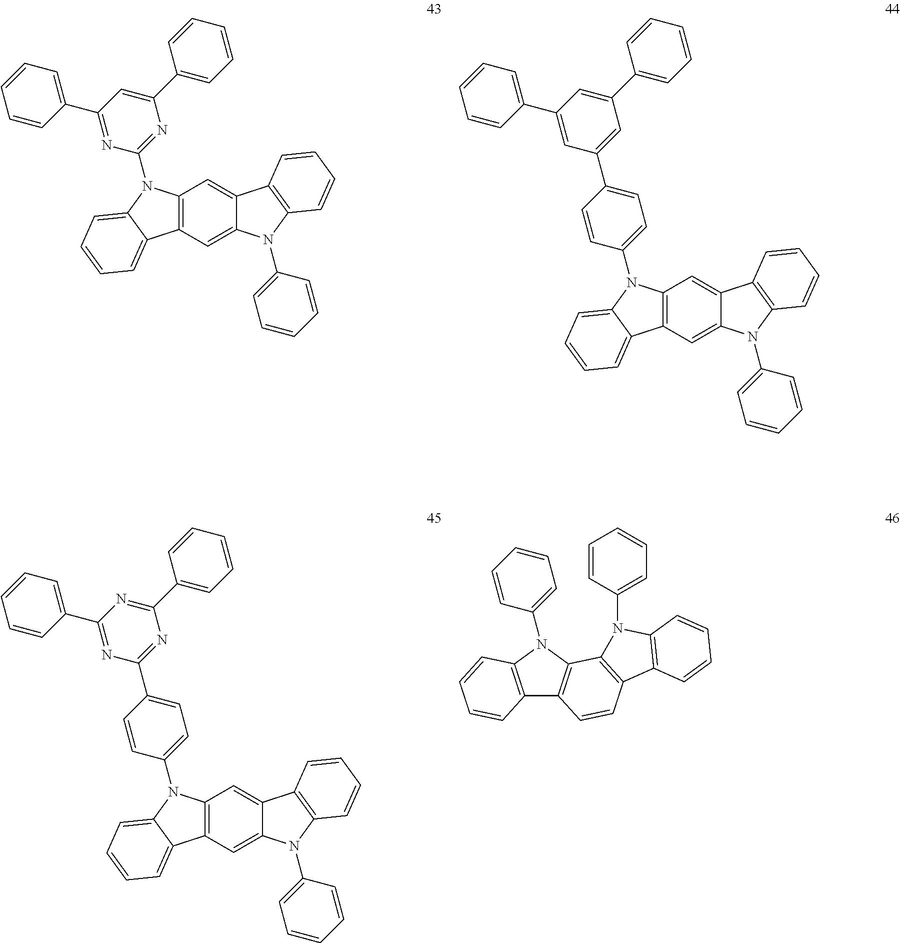 [SMILES: c1ccc(-c2cc(-c3ccccc3)nc(-n3c4ccccc4c4cc5c(cc43)c3ccccc3n5-c3ccccc3)n2)cc1 ; c1ccc(-c2cc(-c3ccccc3)cc(-c3ccc(-n4c5ccccc5c5cc6c(cc54)c4ccccc4n6-c4ccccc4)cc3)c2)cc1 ; c1ccc(-c2nc(-c3ccccc3)nc(-c3ccc(-n4c5ccccc5c5cc6c(cc54)c4ccccc4n6-c4ccccc4)cc3)n2)cc1 ; c1ccc(-n2c3ccccc3c3ccc4c5ccccc5n(-c5ccccc5)c4c32)cc1]

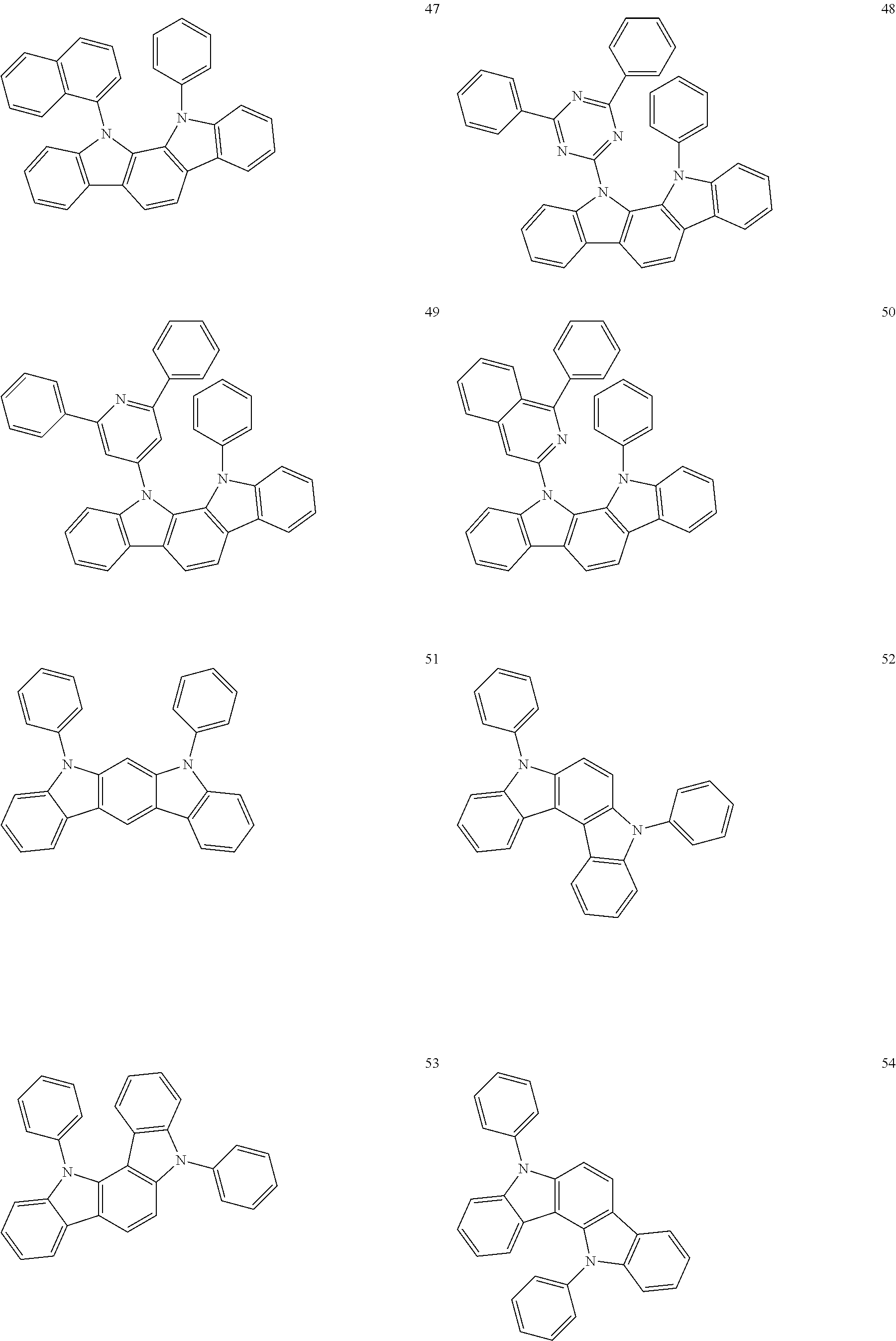

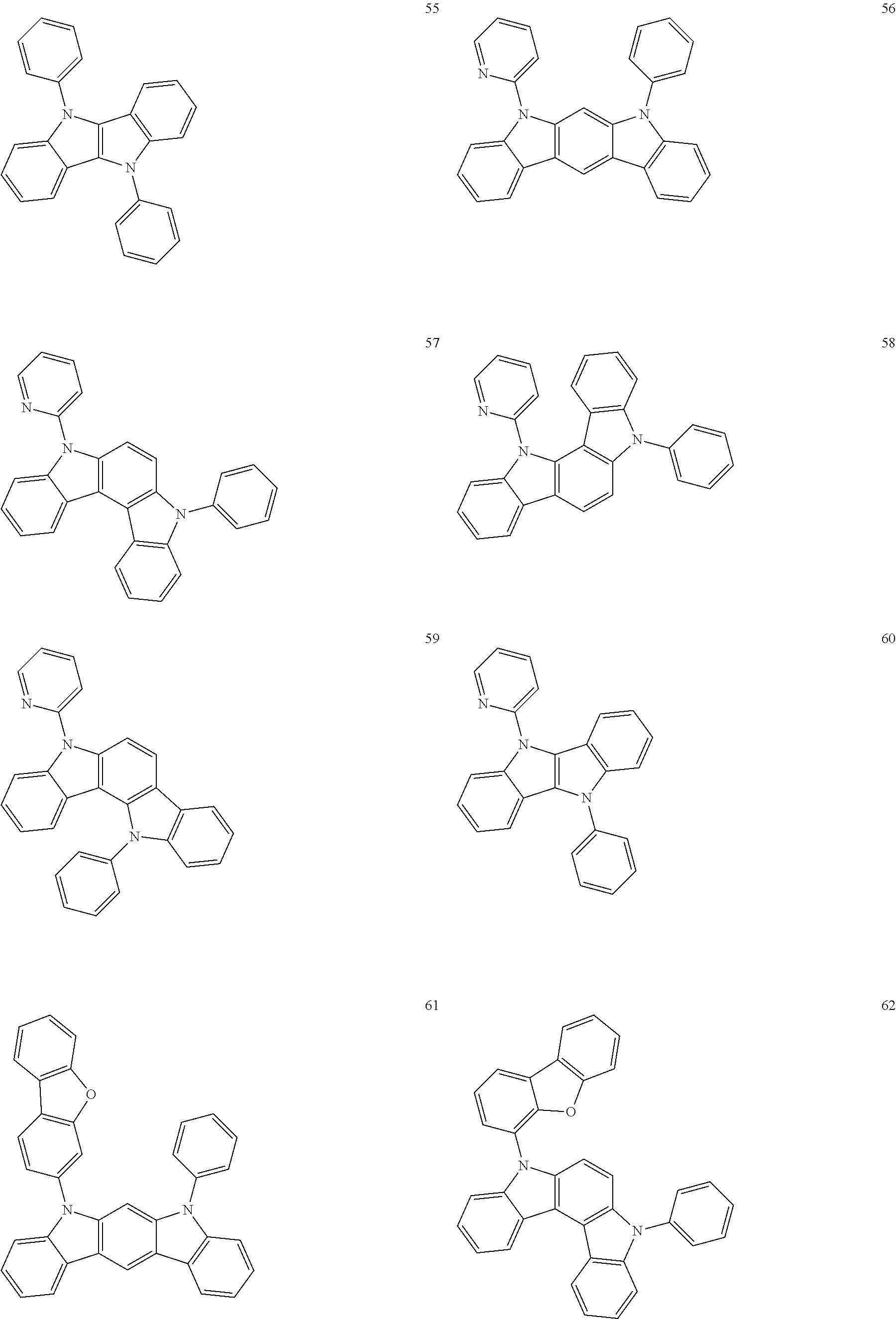

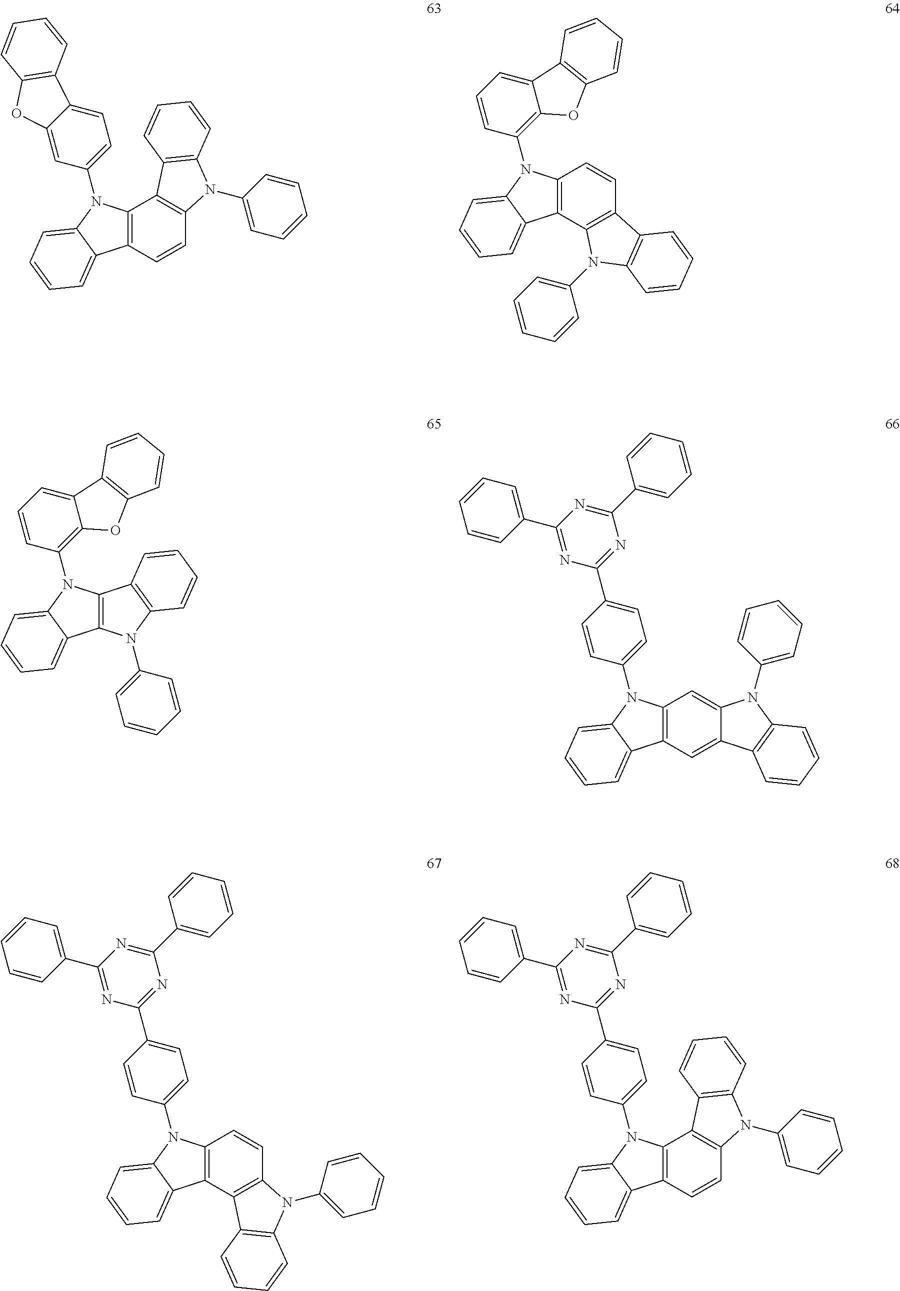 [SMILES: c1ccc(-n2c3ccccc3c3c2ccc2c4ccccc4n(-c4ccc5c(c4)oc4ccccc45)c23)cc1 ; c1ccc(-n2c3ccccc3c3ccc4c(c5ccccc5n4-c4cccc5c4oc4ccccc45)c32)cc1 ; c1ccc(-n2c3ccccc3c3c2c2ccccc2n3-c2cccc3c2oc2ccccc23)cc1 ; c1ccc(-c2nc(-c3ccccc3)nc(-c3ccc(-n4c5ccccc5c5cc6c7ccccc7n(-c7ccccc7)c6cc54)cc3)n2)cc1 ; c1ccc(-c2nc(-c3ccccc3)nc(-c3ccc(-n4c5ccccc5c5c6c7ccccc7n(-c7ccccc7)c6ccc54)cc3)n2)cc1 ; c1ccc(-c2nc(-c3ccccc3)nc(-c3ccc(-n4c5ccccc5c5ccc6c(c7ccccc7n6-c6ccccc6)c54)cc3)n2)cc1]

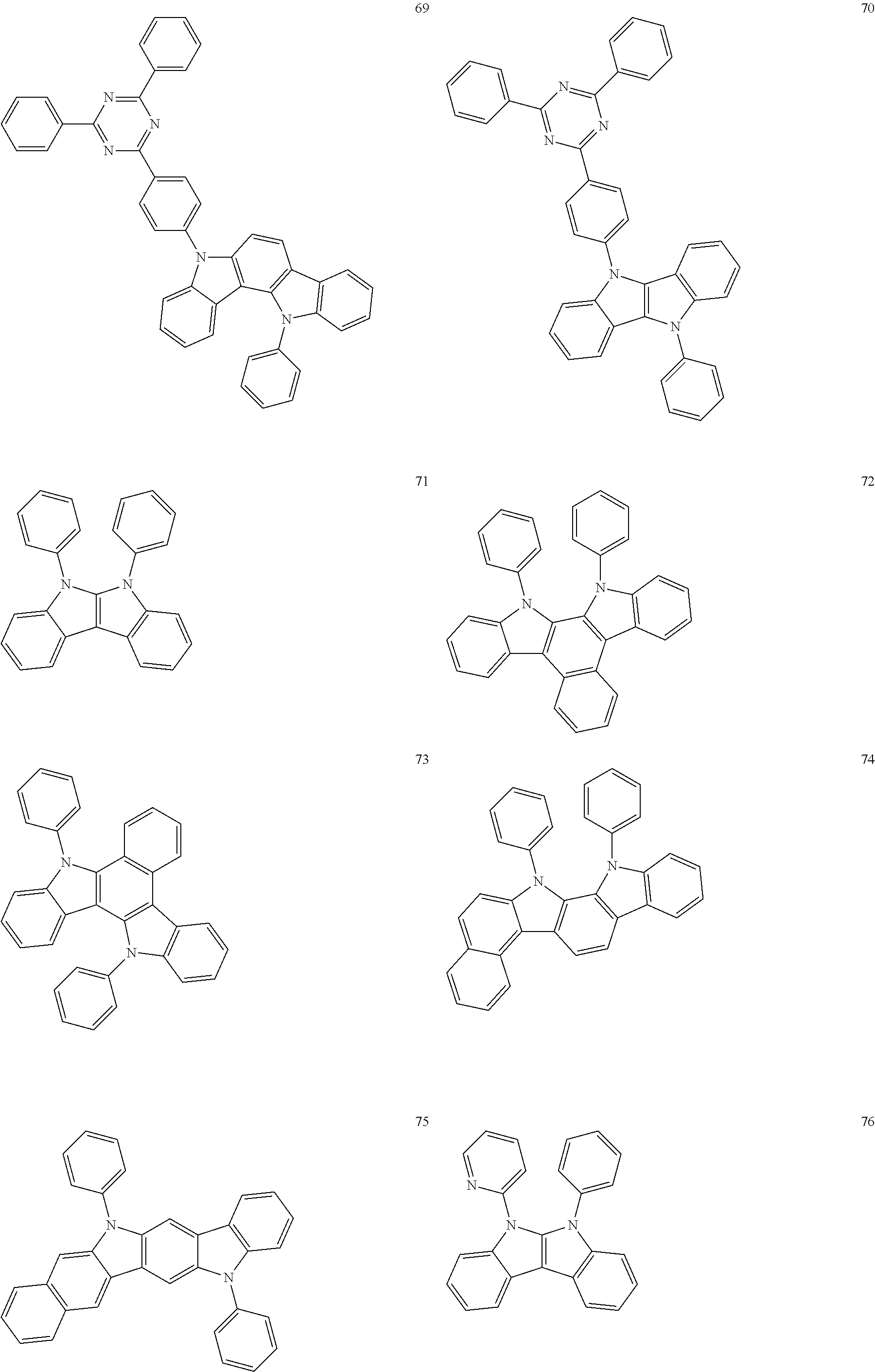

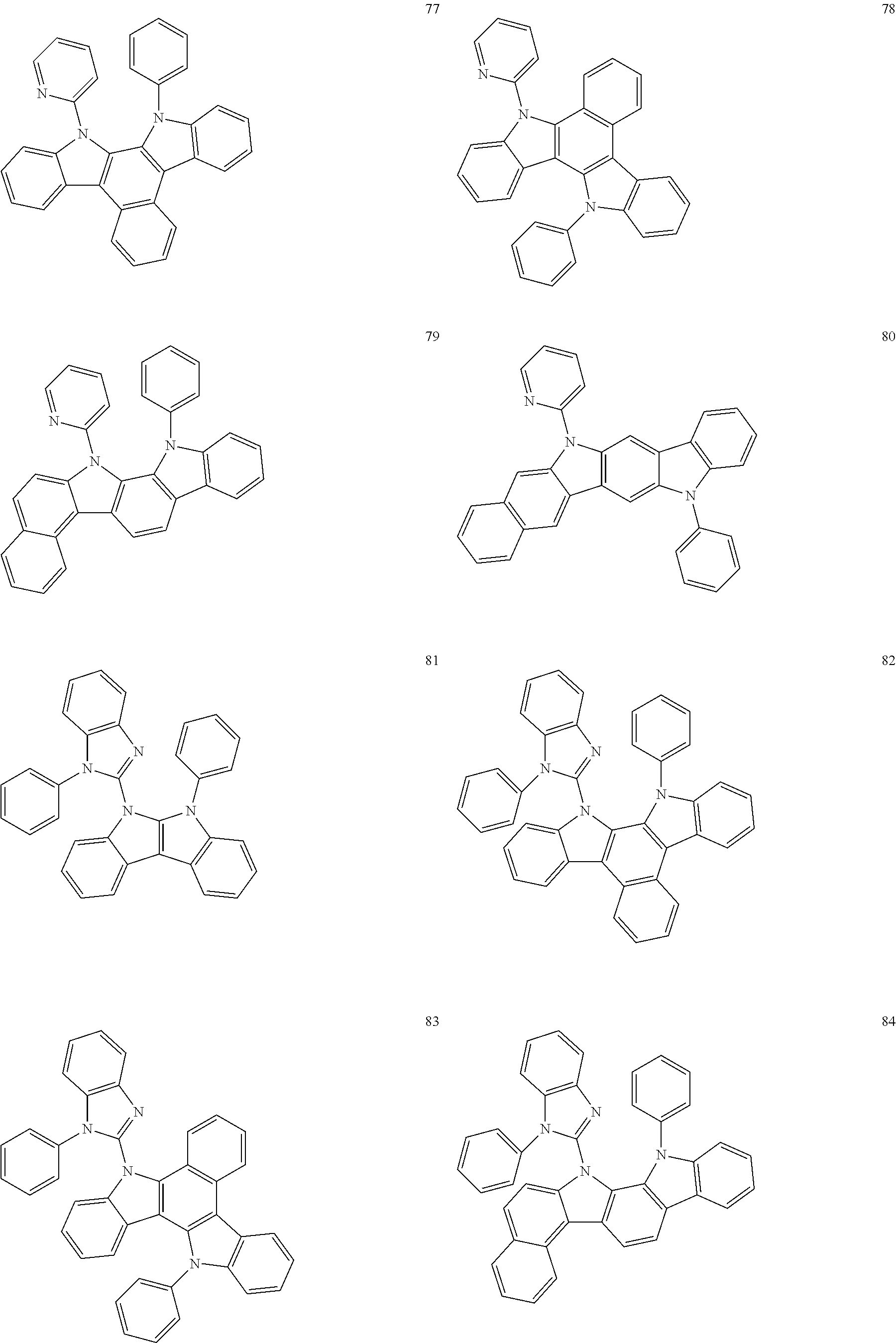

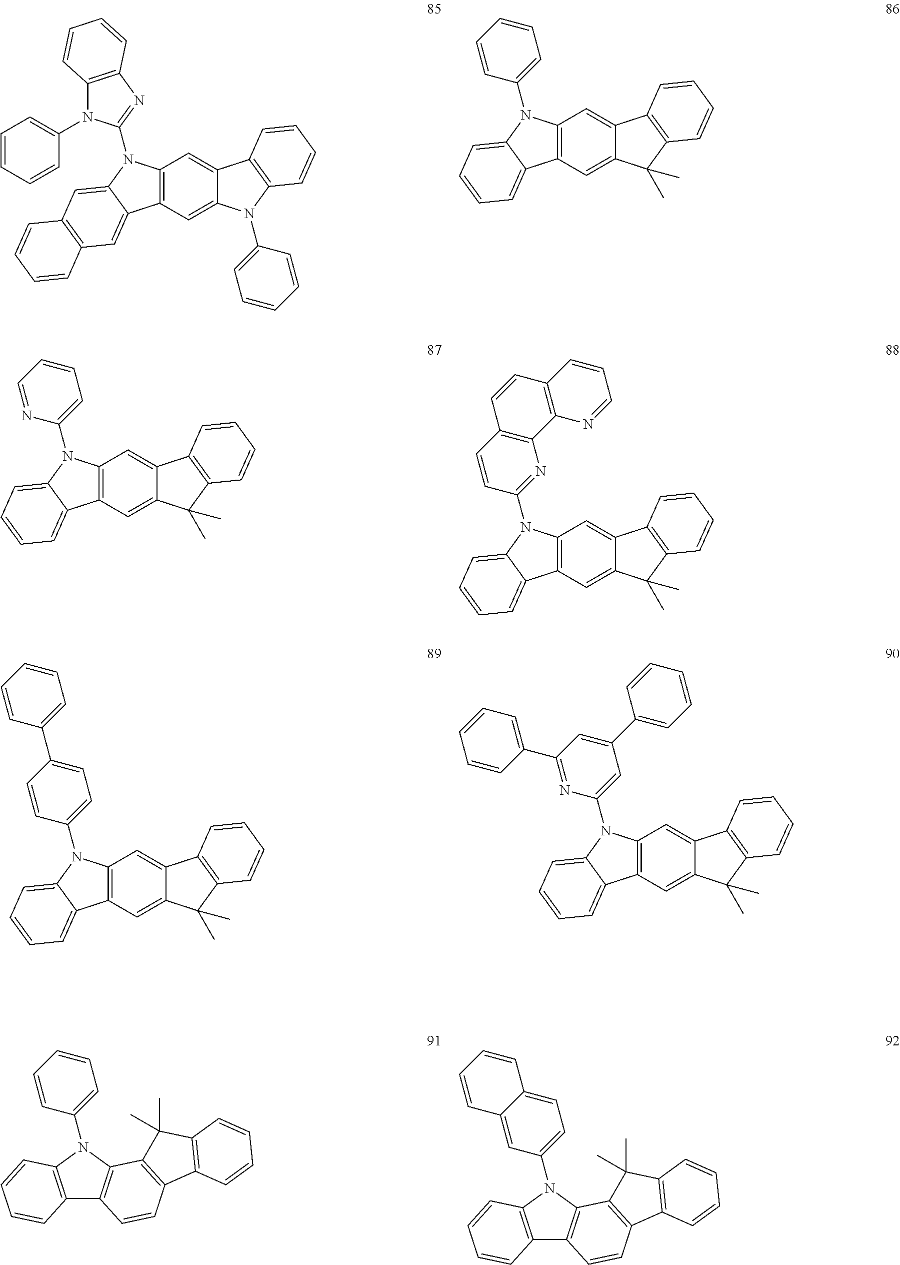

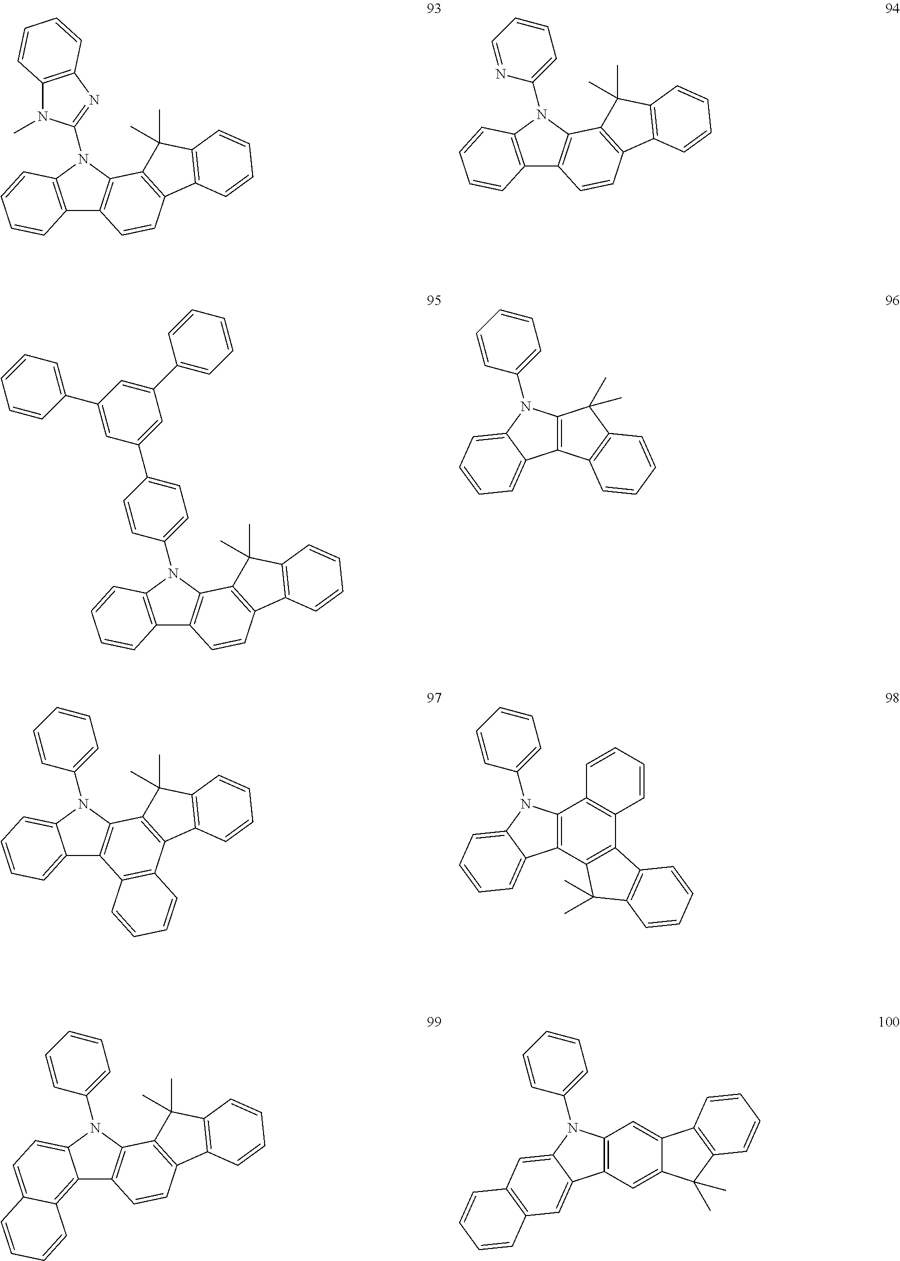

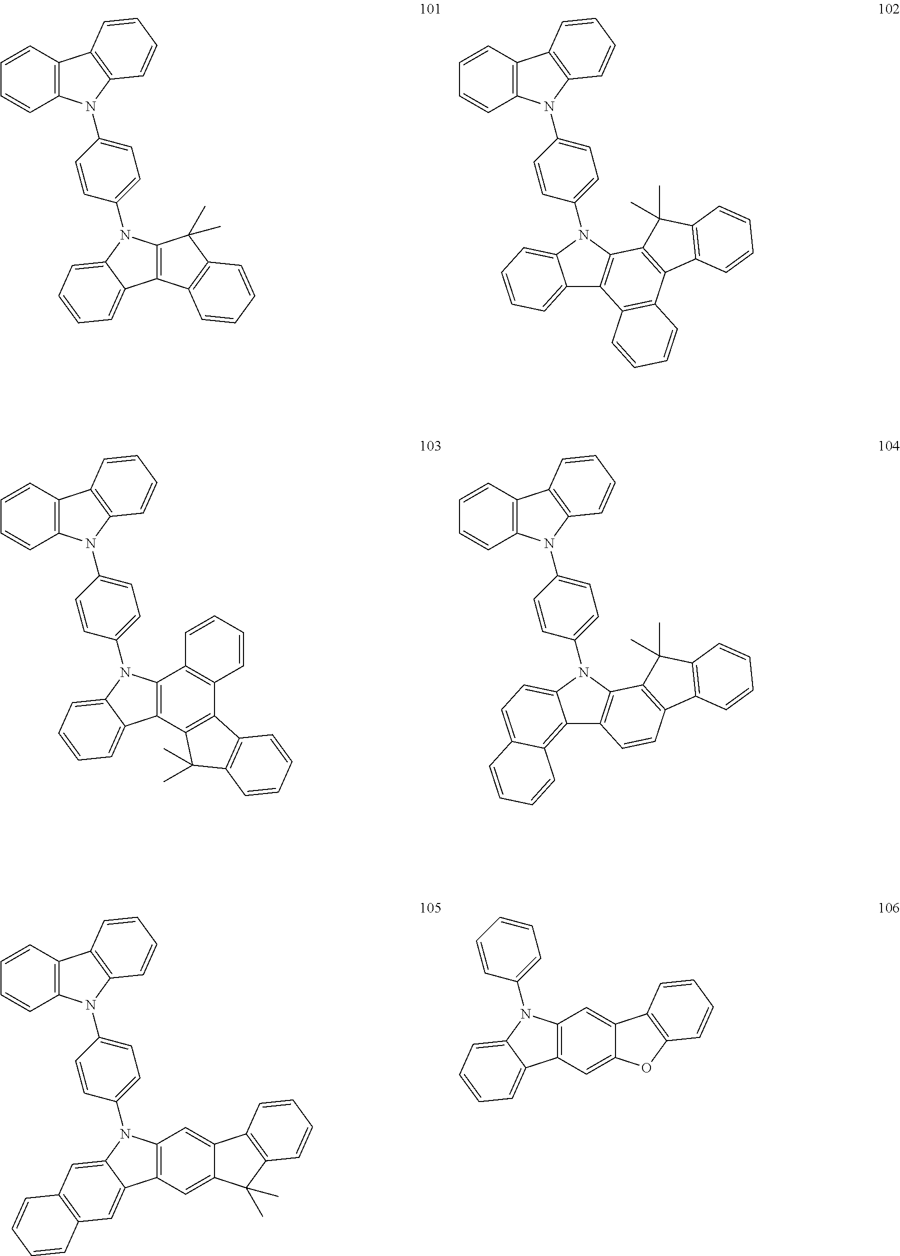 [SMILES: CC1(C)c2ccccc2-c2c1n(-c1ccc(-n3c4ccccc4c4ccccc43)cc1)c1ccccc21 ; CC1(C)c2ccccc2-c2c1c1c(c3ccccc23)c2ccccc2n1-c1ccc(-n2c3ccccc3c3ccccc32)cc1 ; CC1(C)c2ccccc2-c2c1c1c3ccccc3n(-c3ccc(-n4c5ccccc5c5ccccc54)cc3)c1c1ccccc21 ; CC1(C)c2ccccc2-c2ccc3c4c5ccccc5ccc4n(-c4ccc(-n5c6ccccc6c6ccccc65)cc4)c3c21 ; CC1(C)c2ccccc2-c2cc3c(cc21)c1cc2ccccc2cc1n3-c1ccc(-n2c3ccccc3c3ccccc32)cc1 ; c1ccc(-n2c3ccccc3c3cc4oc5ccccc5c4cc32)cc1]

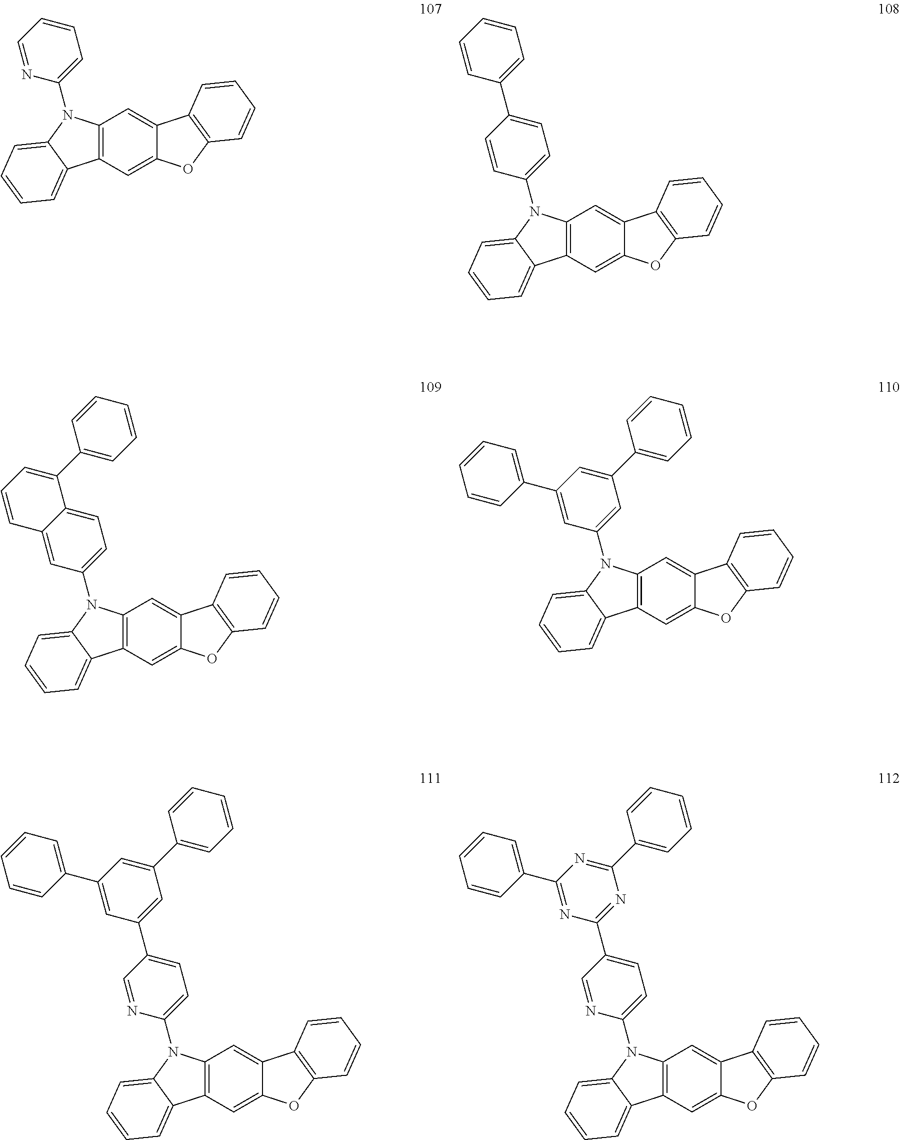 [SMILES: c1ccc(-n2c3ccccc3c3cc4oc5ccccc5c4cc32)nc1 ; c1ccc(-c2ccc(-n3c4ccccc4c4cc5oc6ccccc6c5cc43)cc2)cc1 ; c1ccc(-c2cccc3cc(-n4c5ccccc5c5cc6oc7ccccc7c6cc54)ccc23)cc1 ; c1ccc(-c2cc(-c3ccccc3)cc(-n3c4ccccc4c4cc5oc6ccccc6c5cc43)c2)cc1 ; c1ccc(-c2cc(-c3ccccc3)cc(-c3ccc(-n4c5ccccc5c5cc6oc7ccccc7c6cc54)nc3)c2)cc1 ; c1ccc(-c2nc(-c3ccccc3)nc(-c3ccc(-n4c5ccccc5c5cc6oc7ccccc7c6cc54)nc3)n2)cc1]

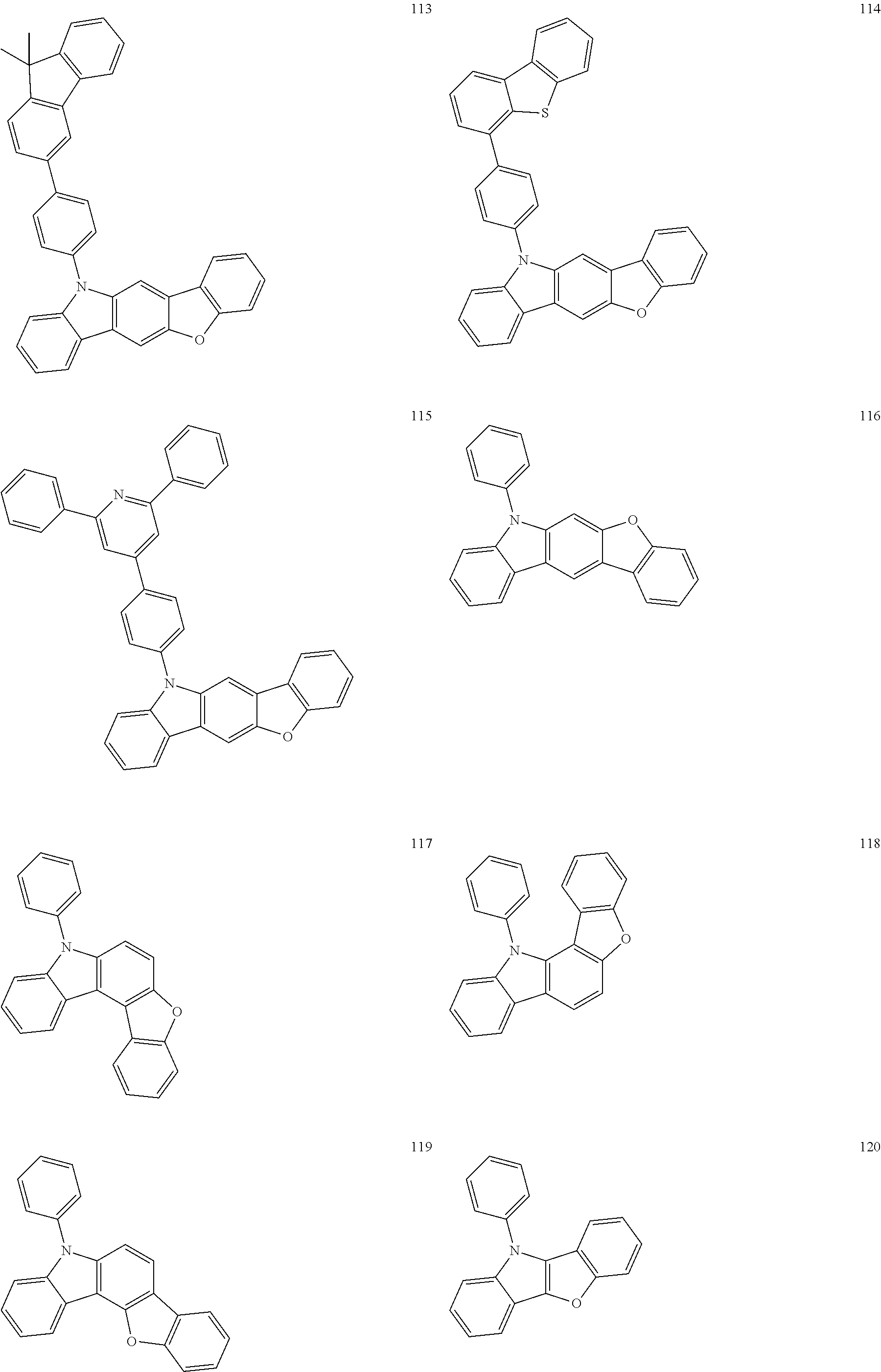

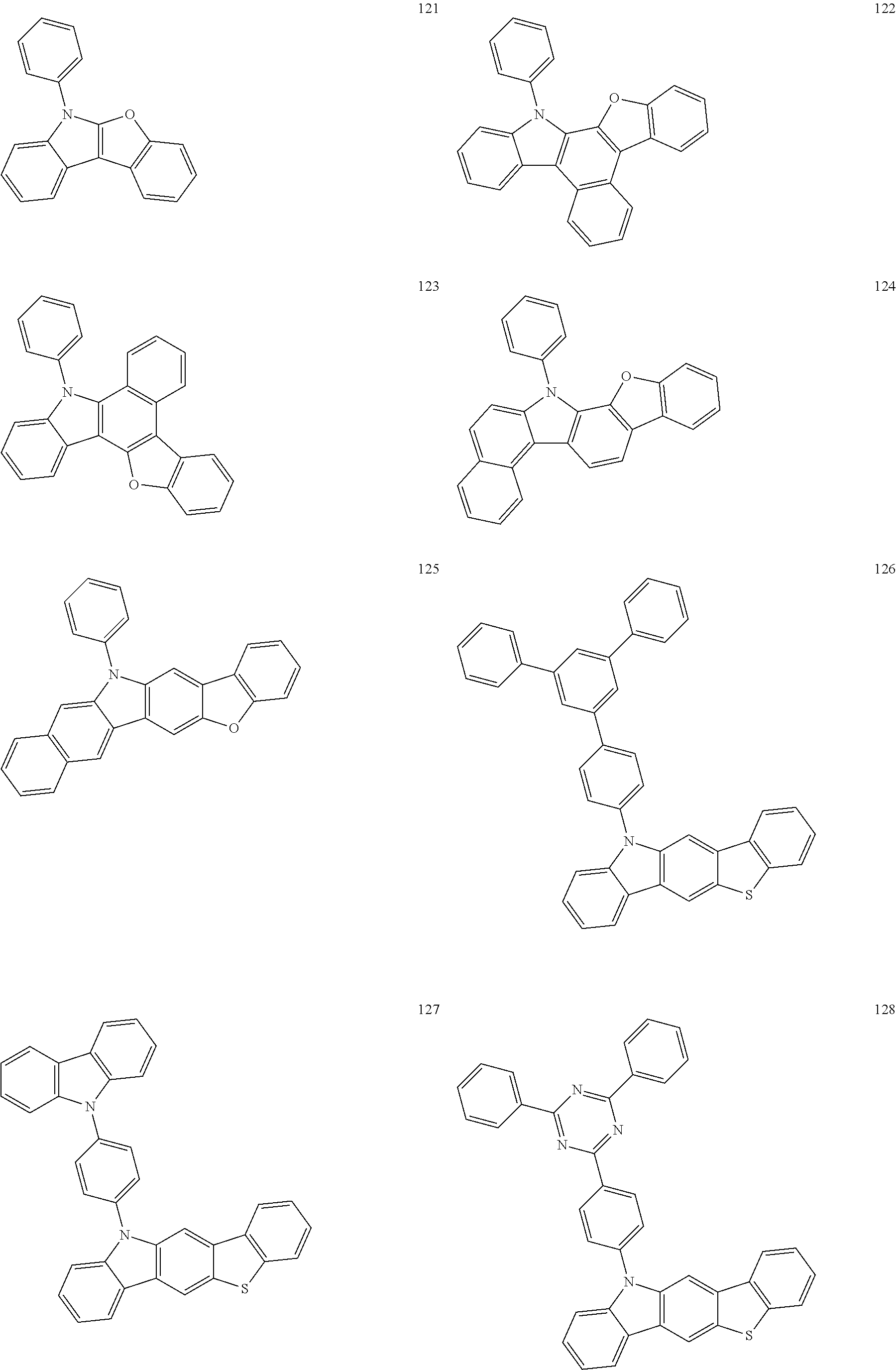

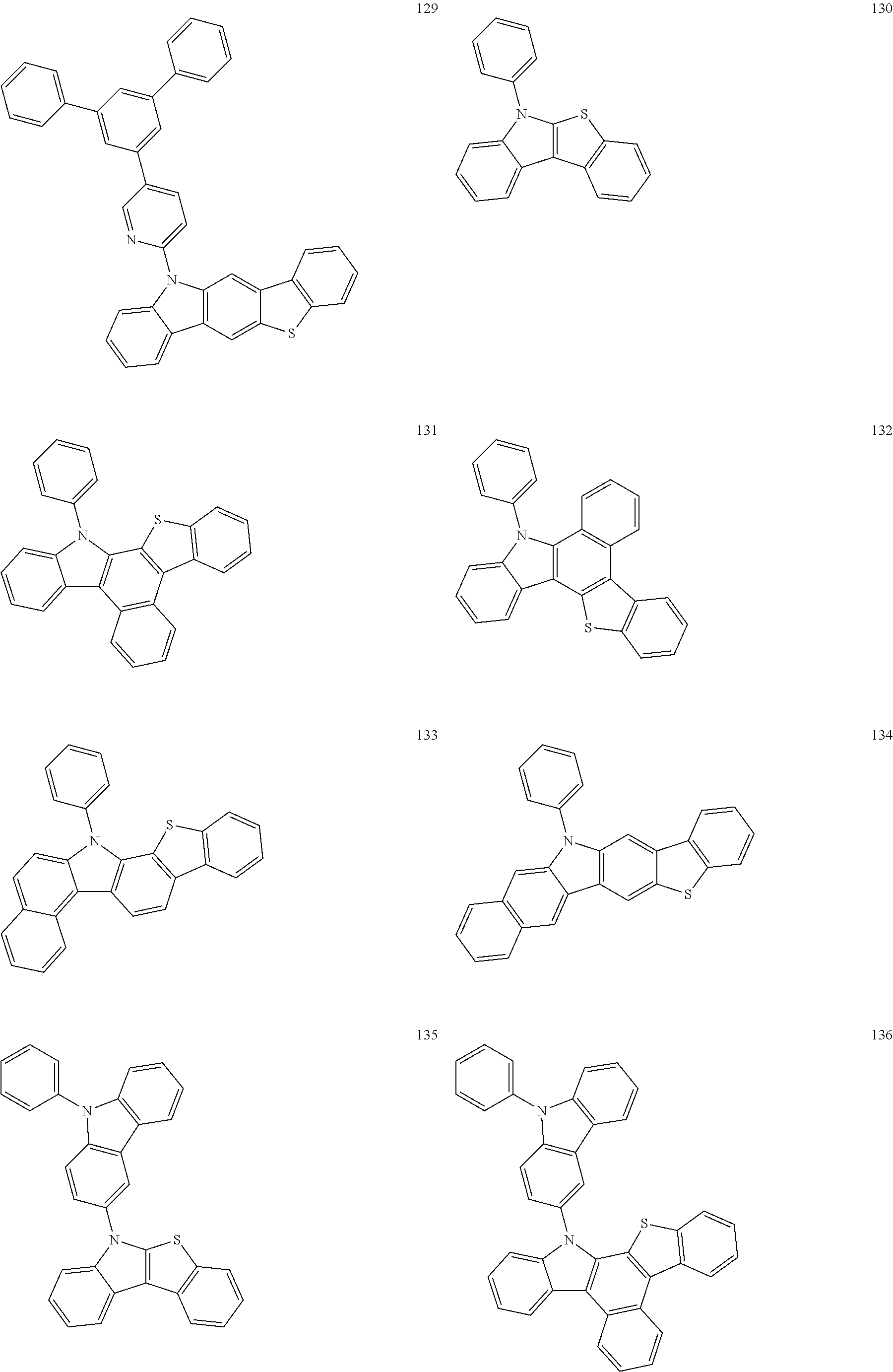

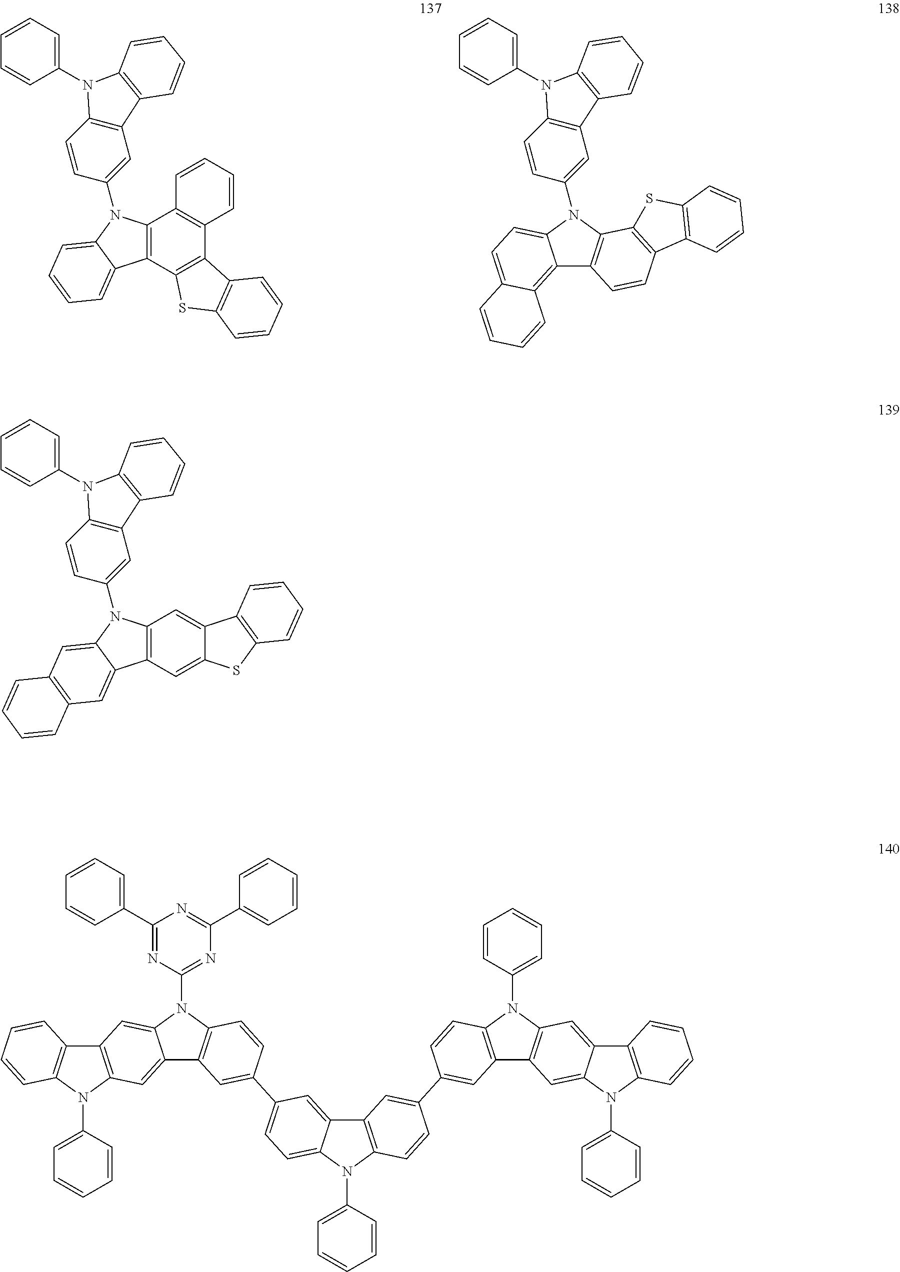 [SMILES: c1ccc(-n2c3ccccc3c3cc(-n4c5ccccc5c5c6sc7ccccc7c6c6ccccc6c54)ccc32)cc1 ; c1ccc(-n2c3ccccc3c3cc(-n4c5ccc6ccccc6c5c5ccc6c7ccccc7sc6c54)ccc32)cc1 ; c1ccc(-n2c3ccccc3c3cc(-n4c5cc6ccccc6cc5c5cc6sc7ccccc7c6cc54)ccc32)cc1 ; c1ccc(-c2nc(-c3ccccc3)nc(-n3c4ccc(-c5ccc6c(c5)c5cc(-c7ccc8c(c7)c7cc9c(cc7n8-c7ccccc7)c7ccccc7n9-c7ccccc7)ccc5n6-c5ccccc5)cc4c4cc5c(cc43)c3ccccc3n5-c3ccccc3)n2)cc1]

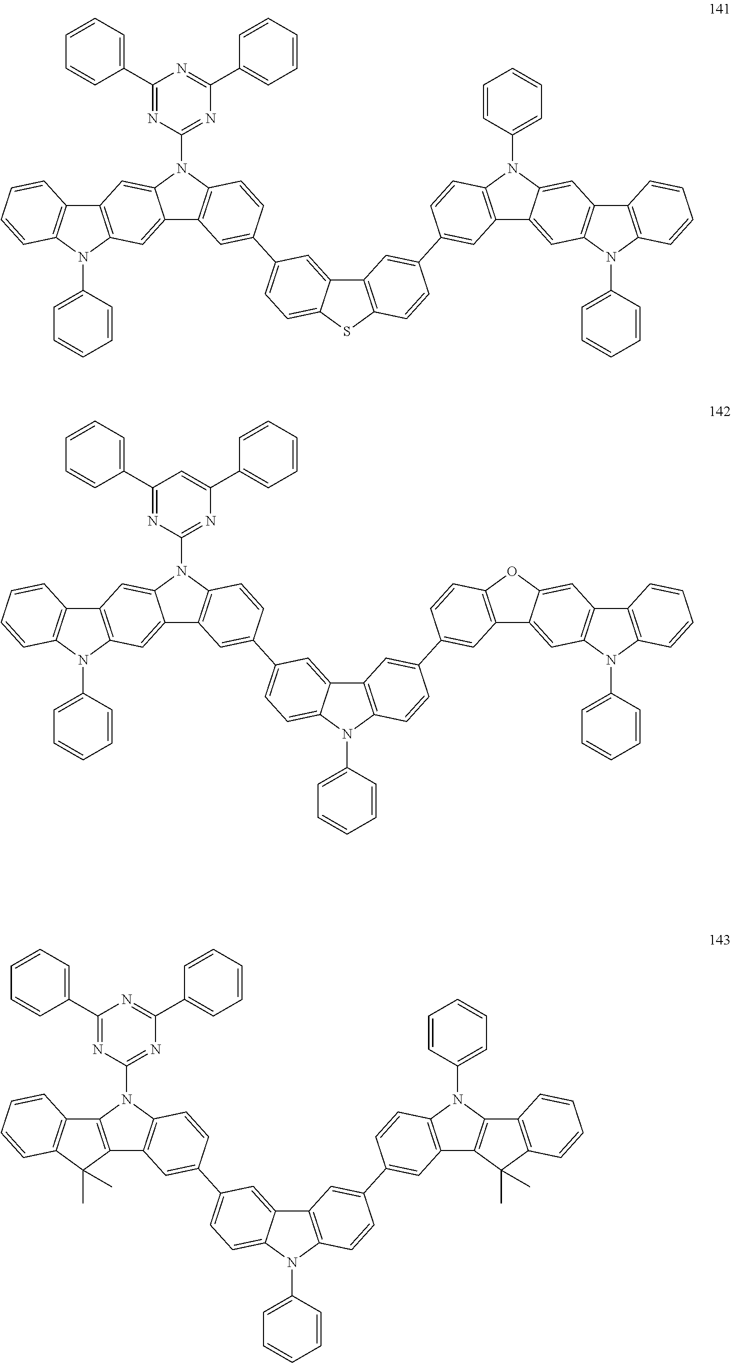 [SMILES: c1ccc(-c2nc(-c3ccccc3)nc(-n3c4ccc(-c5ccc6sc7ccc(-c8ccc9c(c8)c8cc%10c(cc8n9-c8ccccc8)c8ccccc8n%10-c8ccccc8)cc7c6c5)cc4c4cc5c(cc43)c3ccccc3n5-c3ccccc3)n2)cc1 ; c1ccc(-c2cc(-c3ccccc3)nc(-n3c4ccc(-c5ccc6c(c5)c5cc(-c7ccc8oc9cc%10c%11ccccc%11n(-c%11ccccc%11)c%10cc9c8c7)ccc5n6-c5ccccc5)cc4c4cc5c(cc43)c3ccccc3n5-c3ccccc3)n2)cc1 ; CC1(C)c2ccccc2-c2c1c1cc(-c3ccc4c(c3)c3cc(-c5ccc6c(c5)c5c(n6-c6nc(-c7ccccc7)nc(-c7ccccc7)n6)-c6ccccc6C5(C)C)ccc3n4-c3ccccc3)ccc1n2-c1ccccc1]

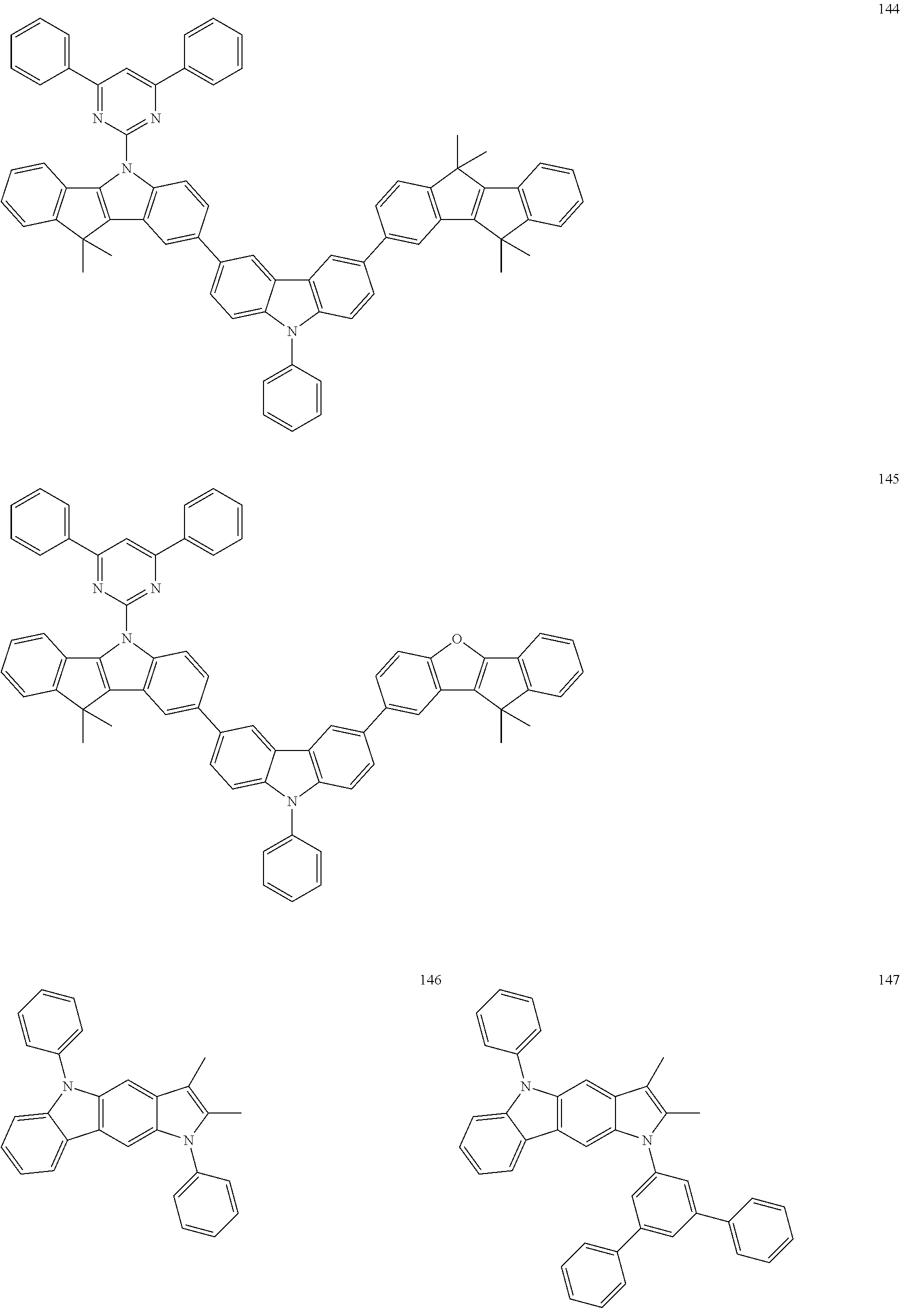 [SMILES: CC1(C)C2=C(c3ccccc31)C(C)(C)c1ccc(-c3ccc4c(c3)c3cc(-c5ccc6c(c5)c5c(n6-c6nc(-c7ccccc7)cc(-c7ccccc7)n6)-c6ccccc6C5(C)C)ccc3n4-c3ccccc3)cc12 ; CC1(C)c2ccccc2-c2oc3ccc(-c4ccc5c(c4)c4cc(-c6ccc7c(c6)c6c(n7-c7nc(-c8ccccc8)cc(-c8ccccc8)n7)-c7ccccc7C6(C)C)ccc4n5-c4ccccc4)cc3c21 ; Cc1c(C)n(-c2ccccc2)c2cc3c4ccccc4n(-c4ccccc4)c3cc12 ; Cc1c(C)n(-c2cc(-c3ccccc3)cc(-c3ccccc3)c2)c2cc3c4ccccc4n(-c4ccccc4)c3cc12]

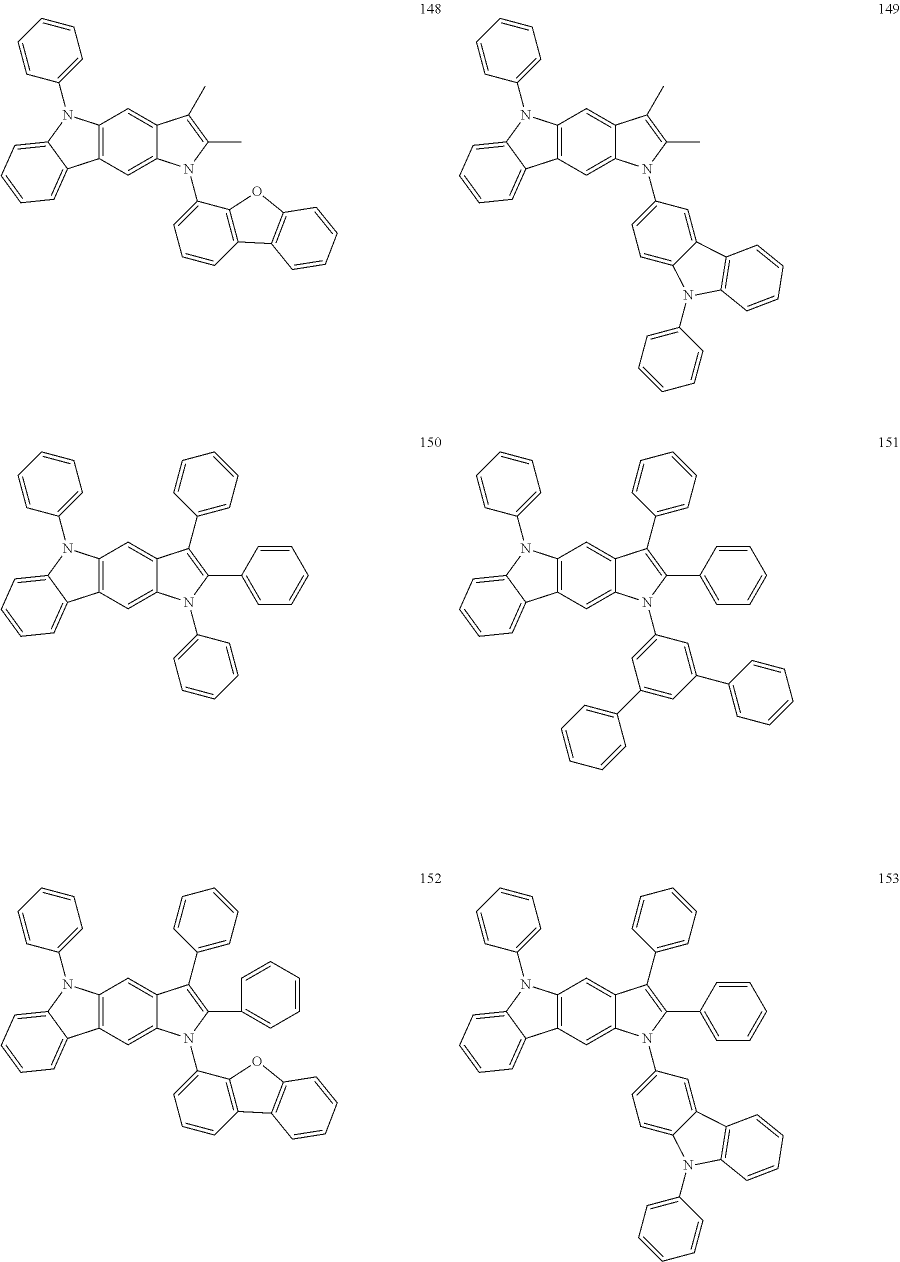 [SMILES: Cc1c(C)n(-c2cccc3c2oc2ccccc23)c2cc3c4ccccc4n(-c4ccccc4)c3cc12 ; Cc1c(C)n(-c2ccc3c(c2)c2ccccc2n3-c2ccccc2)c2cc3c4ccccc4n(-c4ccccc4)c3cc12 ; c1ccc(-c2c(-c3ccccc3)n(-c3ccccc3)c3cc4c5ccccc5n(-c5ccccc5)c4cc23)cc1 ; c1ccc(-c2cc(-c3ccccc3)cc(-n3c(-c4ccccc4)c(-c4ccccc4)c4cc5c(cc43)c3ccccc3n5-c3ccccc3)c2)cc1 ; c1ccc(-c2c(-c3ccccc3)n(-c3cccc4c3oc3ccccc34)c3cc4c5ccccc5n(-c5ccccc5)c4cc23)cc1 ; c1ccc(-c2c(-c3ccccc3)n(-c3ccc4c(c3)c3ccccc3n4-c3ccccc3)c3cc4c5ccccc5n(-c5ccccc5)c4cc23)cc1]

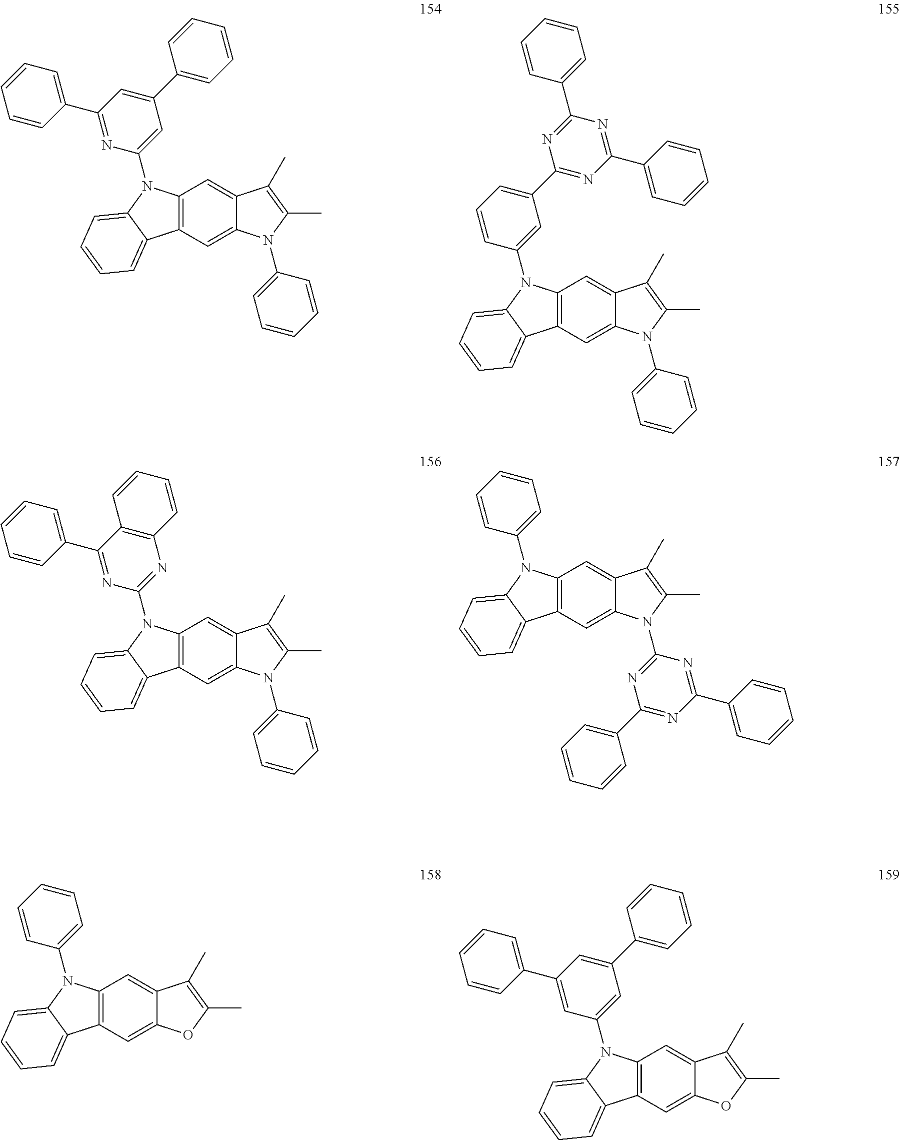 [SMILES: Cc1c(C)n(-c2ccccc2)c2cc3c4ccccc4n(-c4cc(-c5ccccc5)cc(-c5ccccc5)n4)c3cc12 ; Cc1c(C)n(-c2ccccc2)c2cc3c4ccccc4n(-c4cccc(-c5nc(-c6ccccc6)nc(-c6ccccc6)n5)c4)c3cc12 ; Cc1c(C)n(-c2ccccc2)c2cc3c4ccccc4n(-c4nc(-c5ccccc5)c5ccccc5n4)c3cc12 ; Cc1c(C)n(-c2nc(-c3ccccc3)nc(-c3ccccc3)n2)c2cc3c4ccccc4n(-c4ccccc4)c3cc12 ; Cc1oc2cc3c4ccccc4n(-c4ccccc4)c3cc2c1C ; Cc1oc2cc3c4ccccc4n(-c4cc(-c5ccccc5)cc(-c5ccccc5)c4)c3cc2c1C]

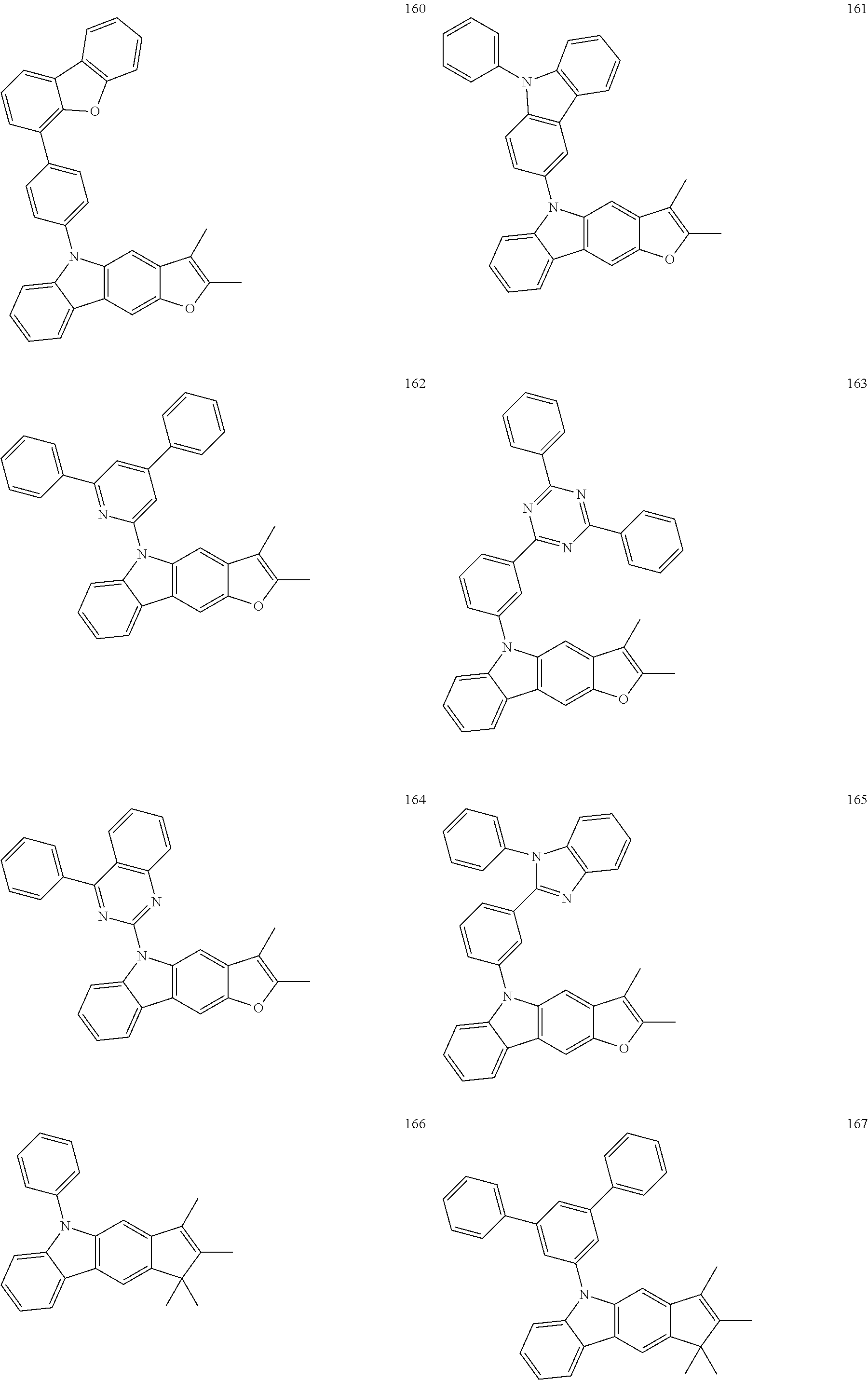

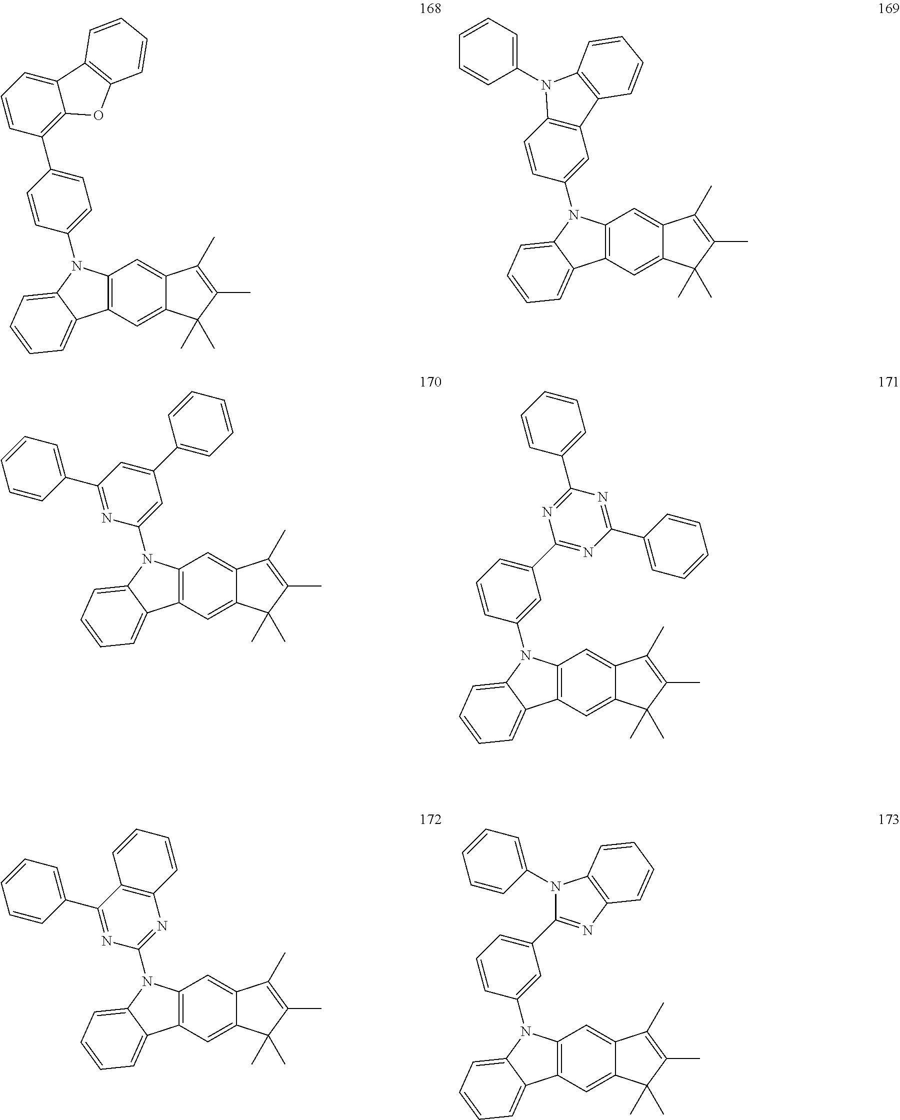

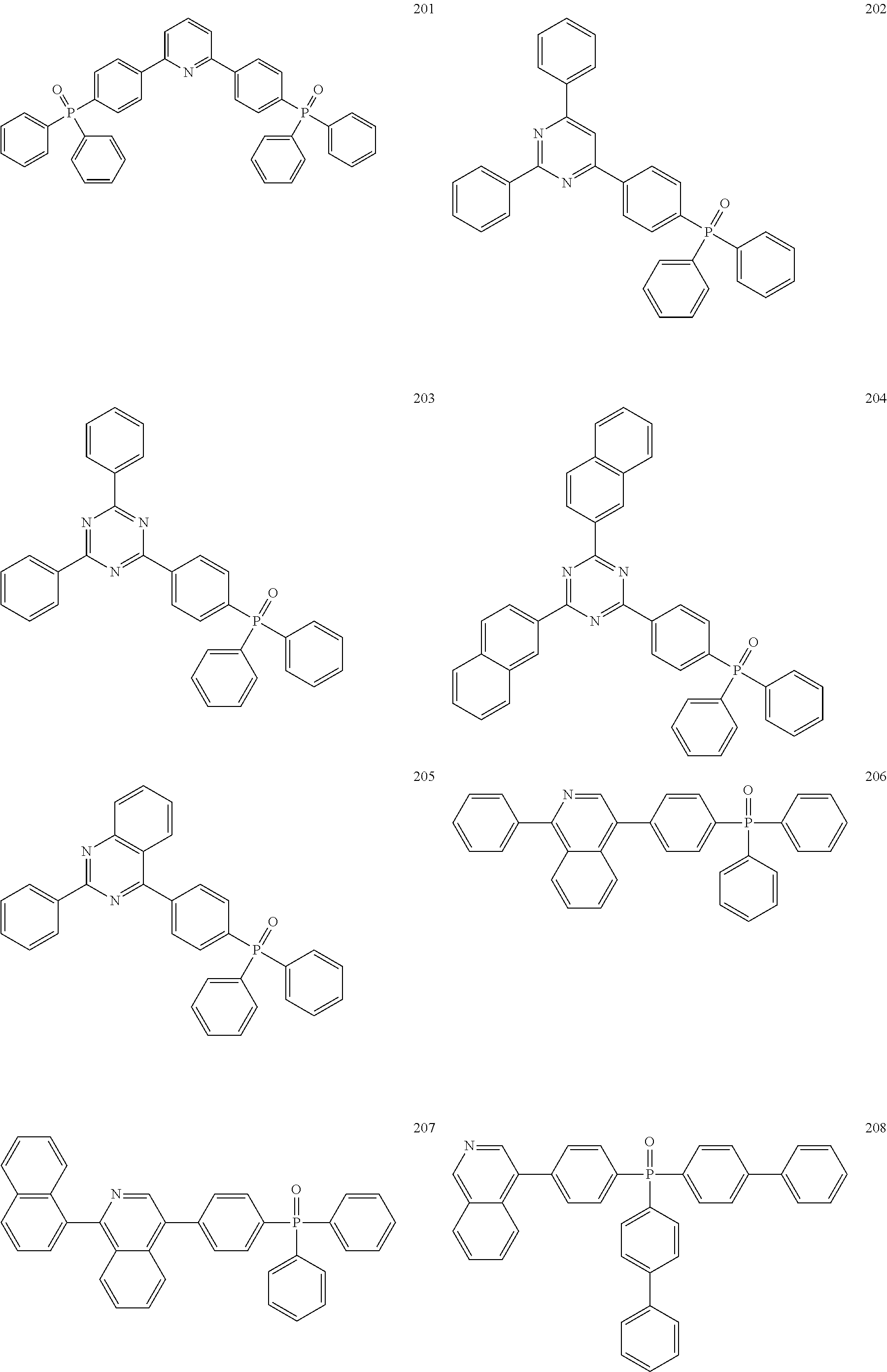

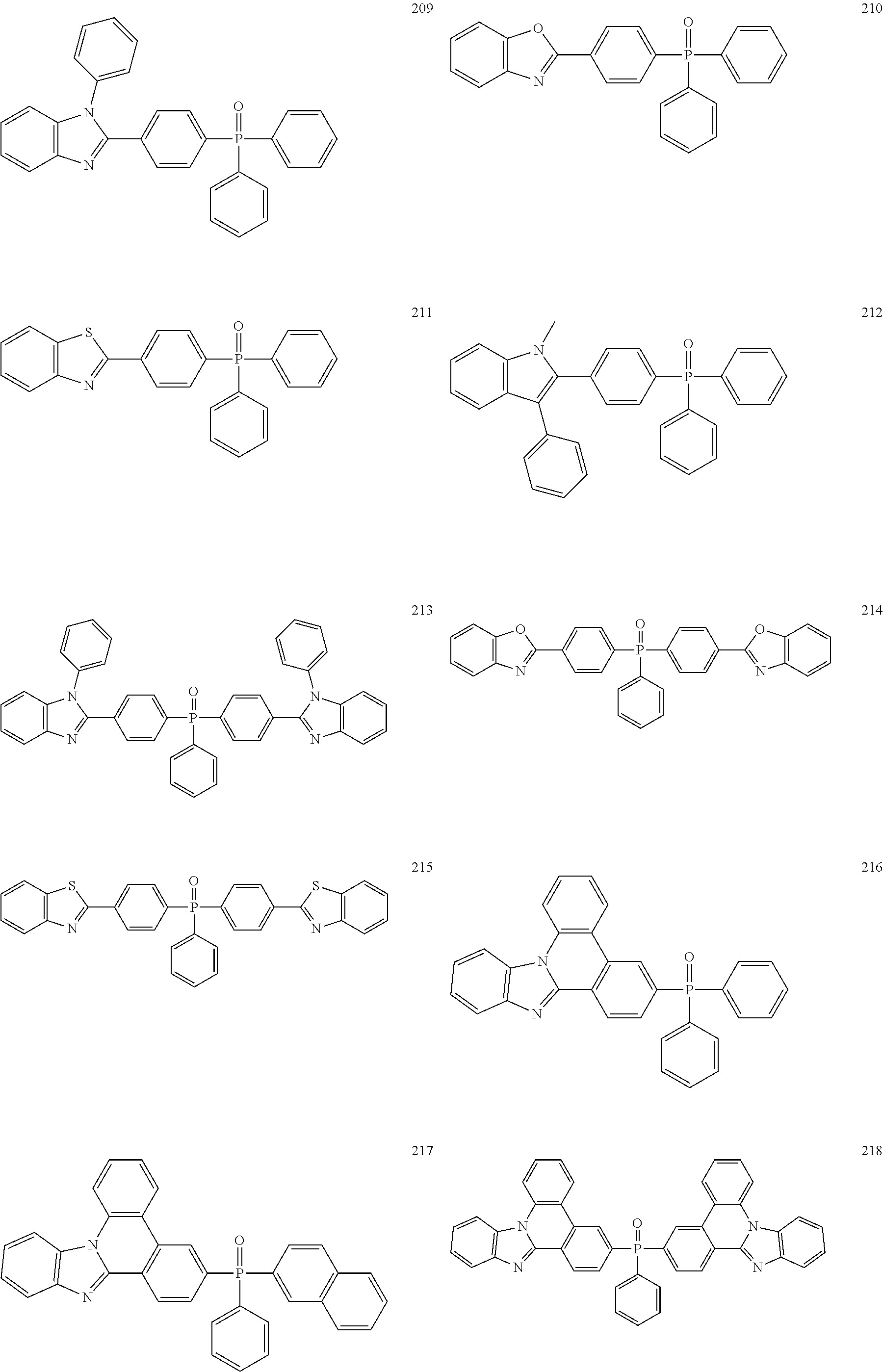

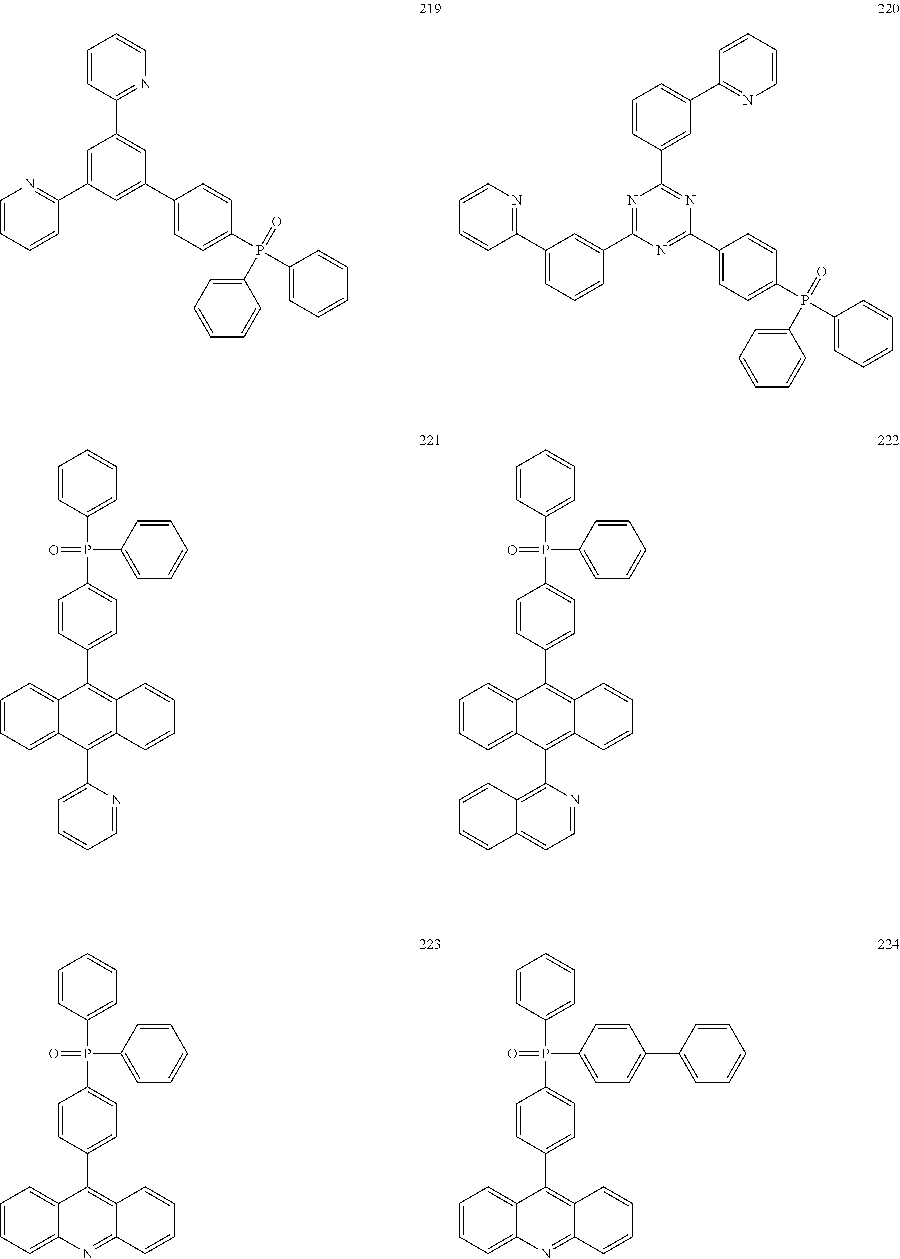 [SMILES: O=P(c1ccccc1)(c1ccccc1)c1ccc(-c2cc(-c3ccccn3)cc(-c3ccccn3)c2)cc1 ; O=P(c1ccccc1)(c1ccccc1)c1ccc(-c2nc(-c3cccc(-c4ccccn4)c3)nc(-c3cccc(-c4ccccn4)c3)n2)cc1 ; O=P(c1ccccc1)(c1ccccc1)c1ccc(-c2c3ccccc3c(-c3ccccn3)c3ccccc23)cc1 ; O=P(c1ccccc1)(c1ccccc1)c1ccc(-c2c3ccccc3c(-c3nccc4ccccc34)c3ccccc23)cc1 ; O=P(c1ccccc1)(c1ccccc1)c1ccc(-c2c3ccccc3nc3ccccc23)cc1 ; O=P(c1ccccc1)(c1ccc(-c2ccccc2)cc1)c1ccc(-c2c3ccccc3nc3ccccc23)cc1]

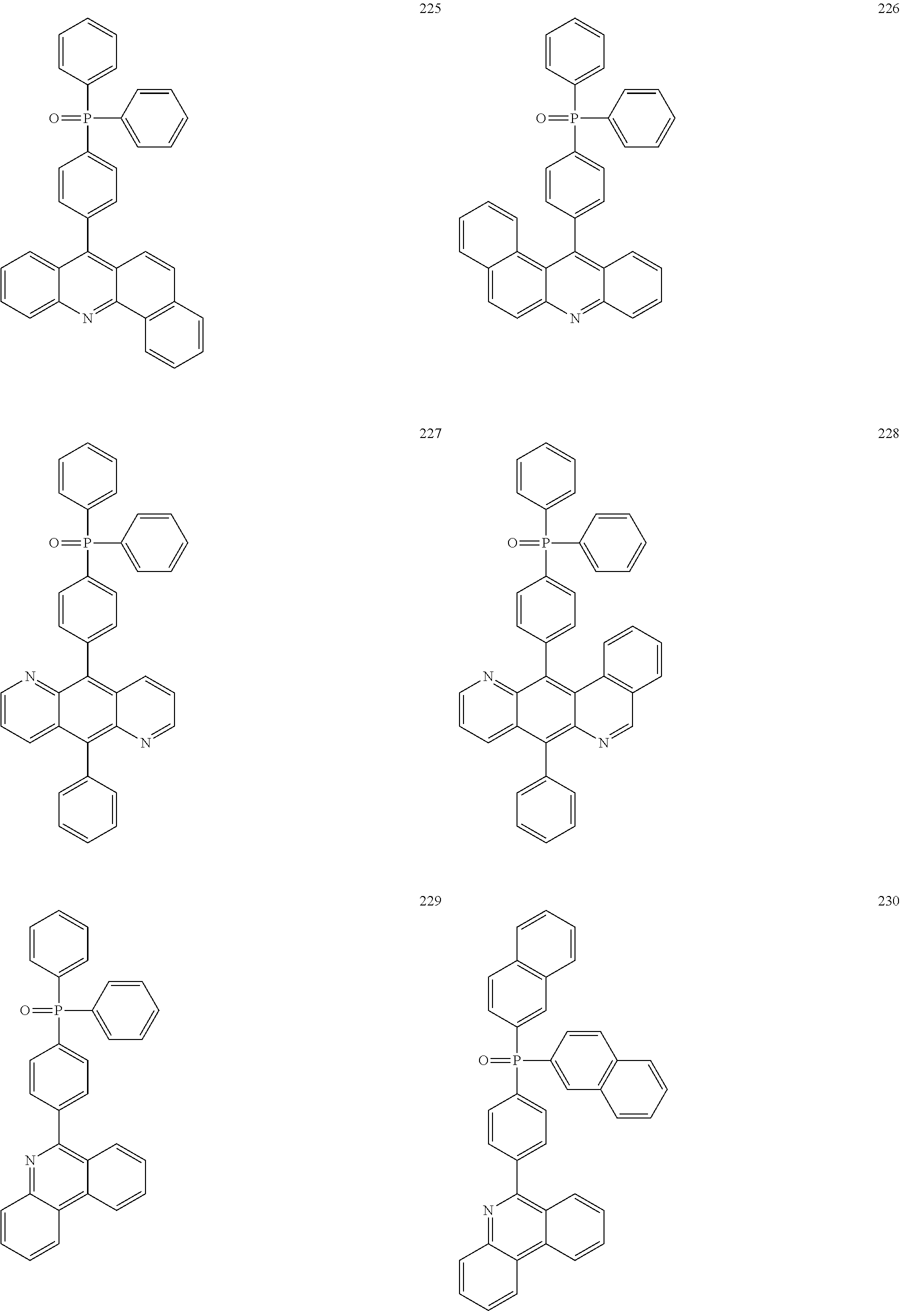 [SMILES: O=P(c1ccccc1)(c1ccccc1)c1ccc(-c2c3ccccc3nc3c2ccc2ccccc23)cc1 ; O=P(c1ccccc1)(c1ccccc1)c1ccc(-c2c3ccccc3nc3ccc4ccccc4c23)cc1 ; O=P(c1ccccc1)(c1ccccc1)c1ccc(-c2c3cccnc3c(-c3ccccc3)c3cccnc23)cc1 ; O=P(c1ccccc1)(c1ccccc1)c1ccc(-c2c3ncccc3c(-c3ccccc3)c3ncc4ccccc4c23)cc1 ; O=P(c1ccccc1)(c1ccccc1)c1ccc(-c2nc3ccccc3c3ccccc23)cc1 ; O=P(c1ccc(-c2nc3ccccc3c3ccccc23)cc1)(c1ccc2ccccc2c1)c1ccc2ccccc2c1]

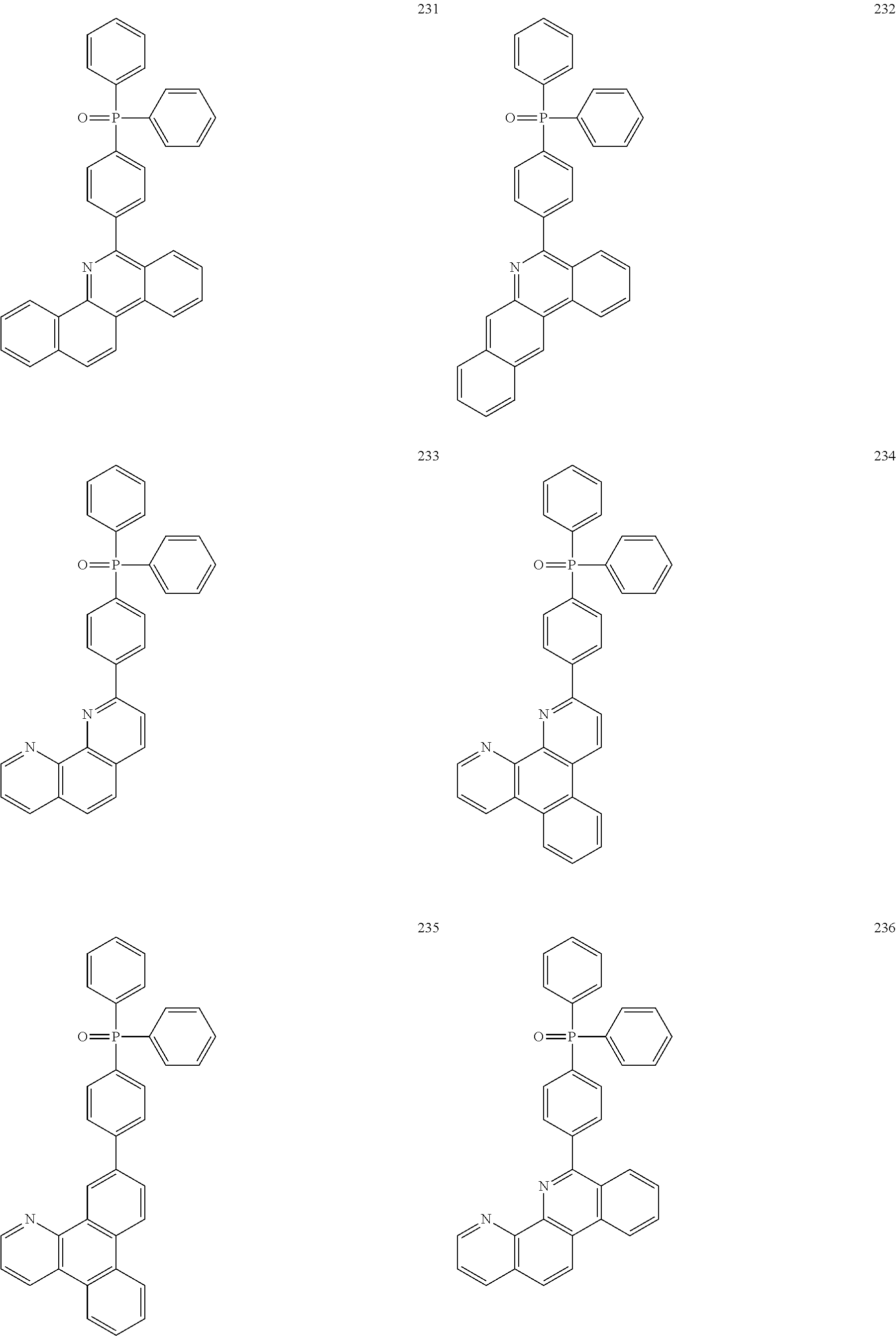 [SMILES: O=P(c1ccccc1)(c1ccccc1)c1ccc(-c2nc3c4ccccc4ccc3c3ccccc23)cc1 ; O=P(c1ccccc1)(c1ccccc1)c1ccc(-c2nc3cc4ccccc4cc3c3ccccc23)cc1 ; O=P(c1ccccc1)(c1ccccc1)c1ccc(-c2ccc3ccc4cccnc4c3n2)cc1 ; O=P(c1ccccc1)(c1ccccc1)c1ccc(-c2ccc3c4ccccc4c4cccnc4c3n2)cc1 ; O=P(c1ccccc1)(c1ccccc1)c1ccc(-c2ccc3c4ccccc4c4cccnc4c3c2)cc1 ; O=P(c1ccccc1)(c1ccccc1)c1ccc(-c2nc3c(ccc4cccnc43)c3ccccc23)cc1]

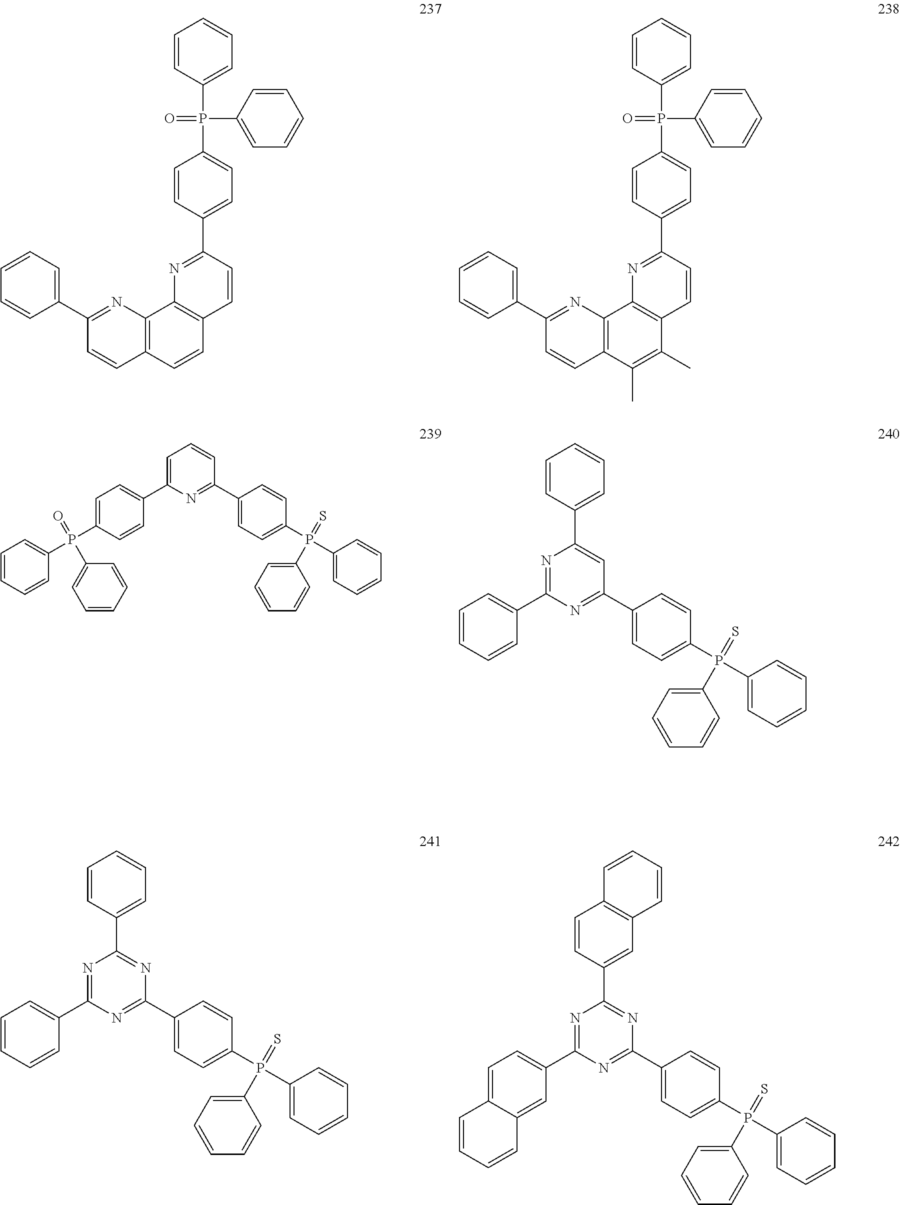 [SMILES: O=P(c1ccccc1)(c1ccccc1)c1ccc(-c2ccc3ccc4ccc(-c5ccccc5)nc4c3n2)cc1 ; Cc1c(C)c2ccc(-c3ccc(P(=O)(c4ccccc4)c4ccccc4)cc3)nc2c2nc(-c3ccccc3)ccc12 ; O=P(c1ccccc1)(c1ccccc1)c1ccc(-c2cccc(-c3ccc(P(=S)(c4ccccc4)c4ccccc4)cc3)n2)cc1 ; S=P(c1ccccc1)(c1ccccc1)c1ccc(-c2cc(-c3ccccc3)nc(-c3ccccc3)n2)cc1 ; S=P(c1ccccc1)(c1ccccc1)c1ccc(-c2nc(-c3ccccc3)nc(-c3ccccc3)n2)cc1 ; S=P(c1ccccc1)(c1ccccc1)c1ccc(-c2nc(-c3ccc4ccccc4c3)nc(-c3ccc4ccccc4c3)n2)cc1]

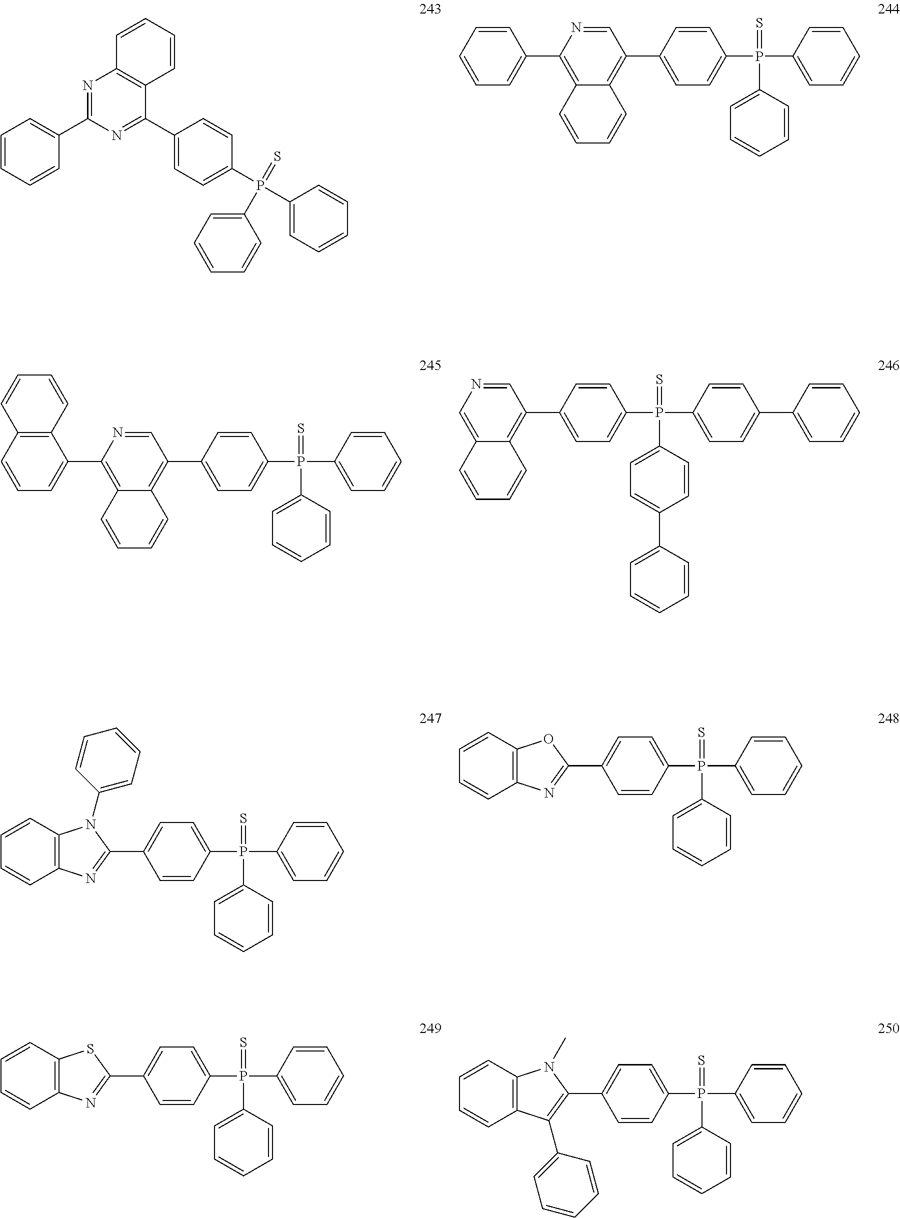

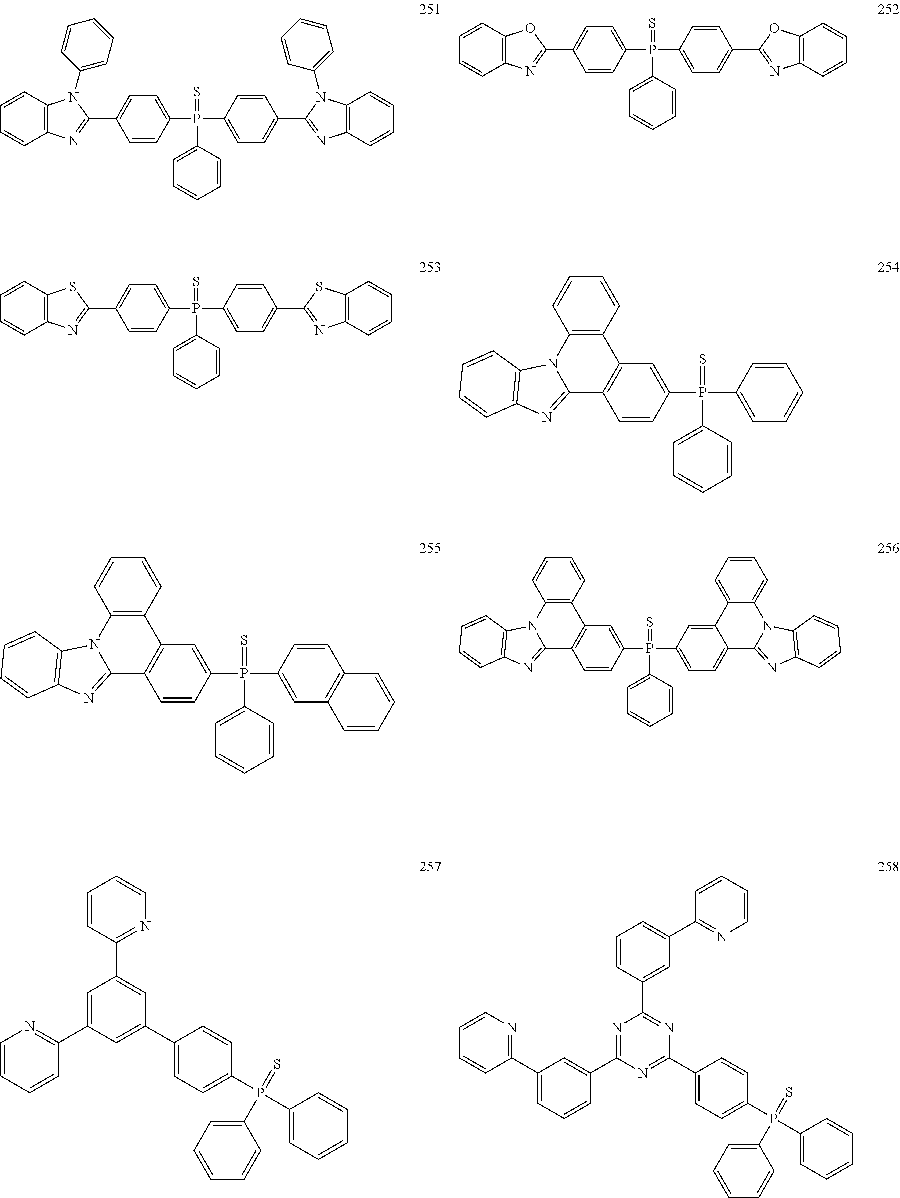

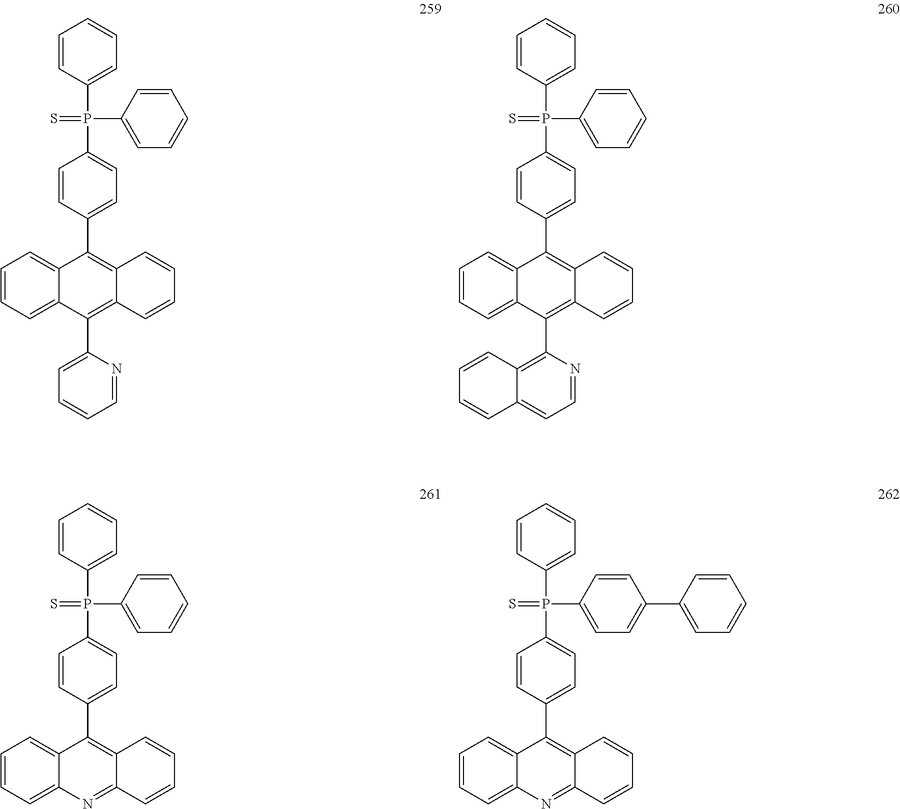 [SMILES: S=P(c1ccccc1)(c1ccccc1)c1ccc(-c2c3ccccc3c(-c3ccccn3)c3ccccc23)cc1 ; S=P(c1ccccc1)(c1ccccc1)c1ccc(-c2c3ccccc3c(-c3nccc4ccccc34)c3ccccc23)cc1 ; S=P(c1ccccc1)(c1ccccc1)c1ccc(-c2c3ccccc3nc3ccccc23)cc1 ; S=P(c1ccccc1)(c1ccc(-c2ccccc2)cc1)c1ccc(-c2c3ccccc3nc3ccccc23)cc1]

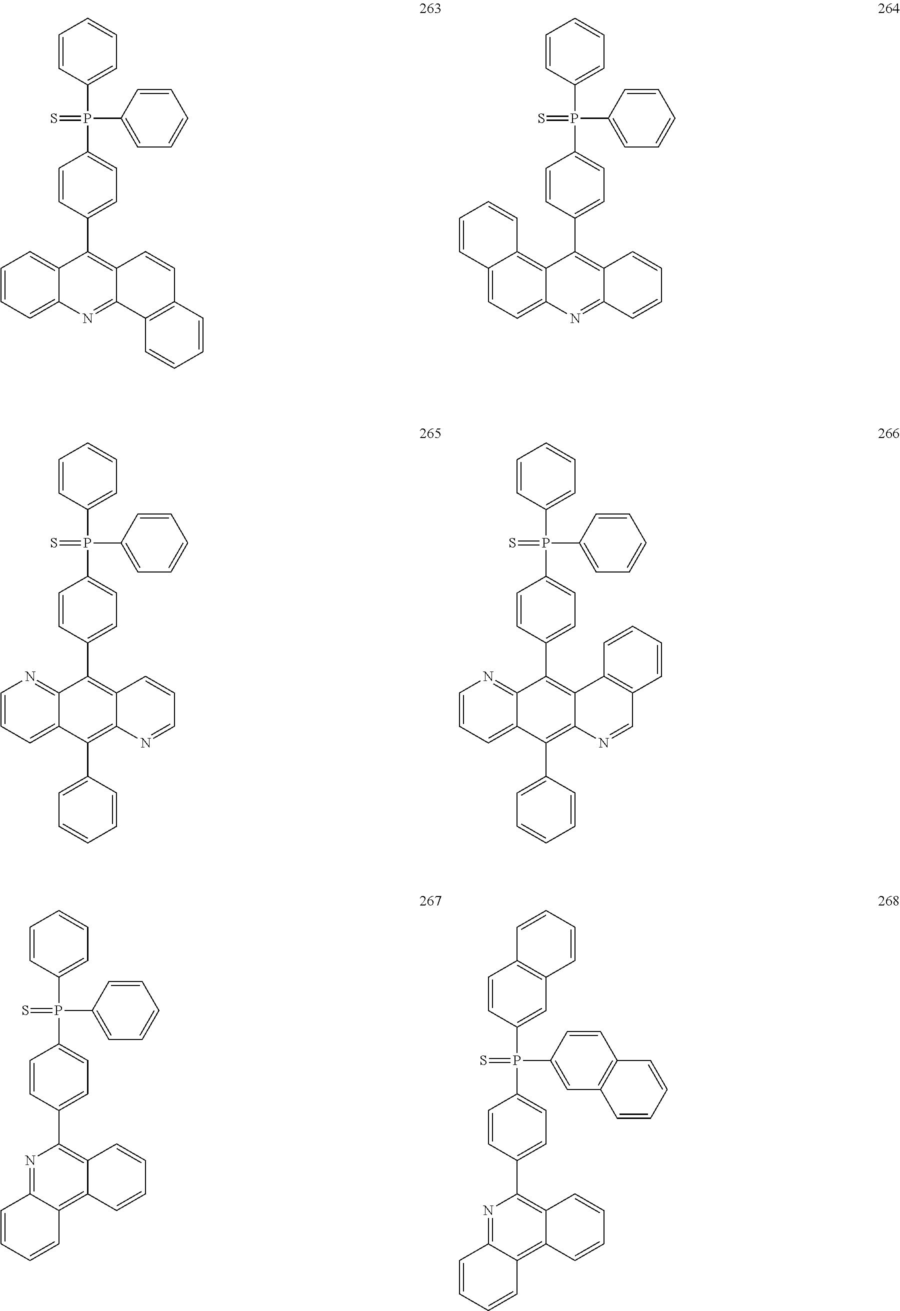 [SMILES: S=P(c1ccccc1)(c1ccccc1)c1ccc(-c2c3ccccc3nc3c2ccc2ccccc23)cc1 ; S=P(c1ccccc1)(c1ccccc1)c1ccc(-c2c3ccccc3nc3ccc4ccccc4c23)cc1 ; S=P(c1ccccc1)(c1ccccc1)c1ccc(-c2c3cccnc3c(-c3ccccc3)c3cccnc23)cc1 ; S=P(c1ccccc1)(c1ccccc1)c1ccc(-c2c3ncccc3c(-c3ccccc3)c3ncc4ccccc4c23)cc1 ; S=P(c1ccccc1)(c1ccccc1)c1ccc(-c2nc3ccccc3c3ccccc23)cc1 ; S=P(c1ccc(-c2nc3ccccc3c3ccccc23)cc1)(c1ccc2ccccc2c1)c1ccc2ccccc2c1]

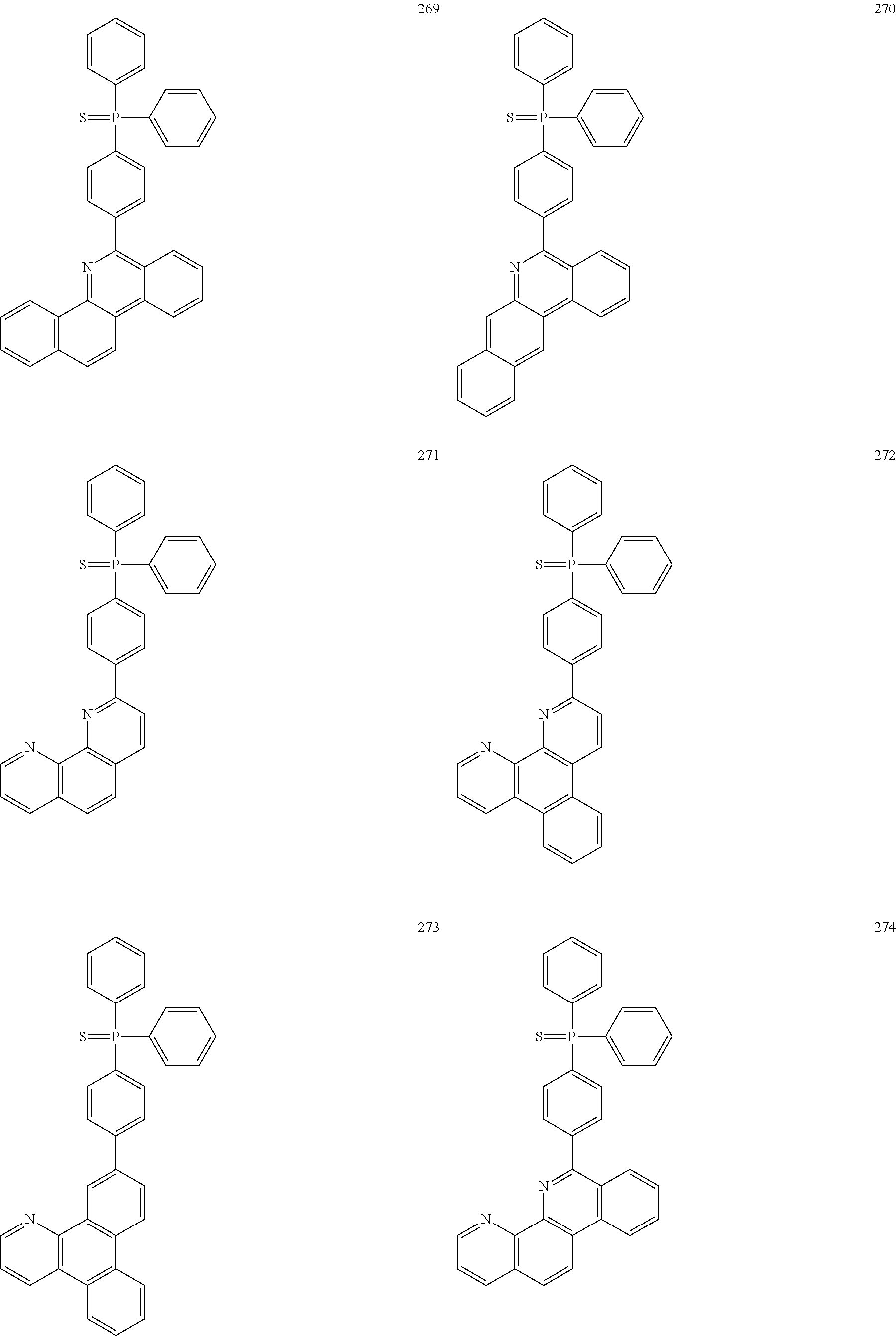 [SMILES: S=P(c1ccccc1)(c1ccccc1)c1ccc(-c2nc3c4ccccc4ccc3c3ccccc23)cc1 ; S=P(c1ccccc1)(c1ccccc1)c1ccc(-c2nc3cc4ccccc4cc3c3ccccc23)cc1 ; S=P(c1ccccc1)(c1ccccc1)c1ccc(-c2ccc3ccc4cccnc4c3n2)cc1 ; S=P(c1ccccc1)(c1ccccc1)c1ccc(-c2ccc3c4ccccc4c4cccnc4c3n2)cc1 ; S=P(c1ccccc1)(c1ccccc1)c1ccc(-c2ccc3c4ccccc4c4cccnc4c3c2)cc1 ; S=P(c1ccccc1)(c1ccccc1)c1ccc(-c2nc3c(ccc4cccnc43)c3ccccc23)cc1]

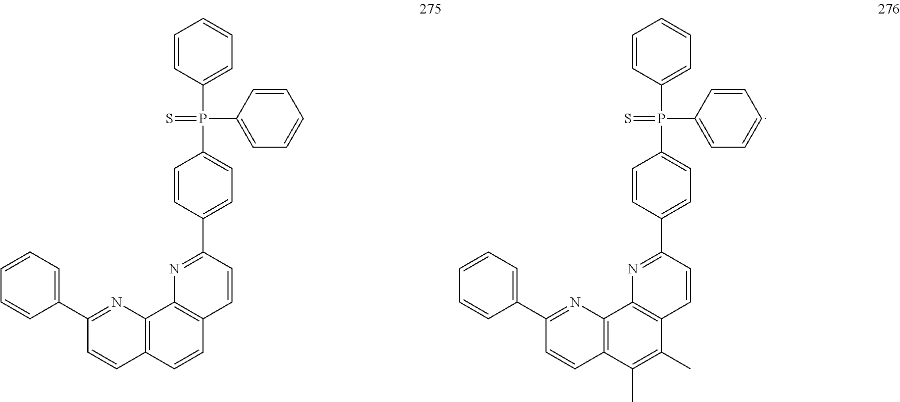 [SMILES: S=P(c1ccccc1)(c1ccccc1)c1ccc(-c2ccc3ccc4ccc(-c5ccccc5)nc4c3n2)cc1 ; Cc1c(C)c2ccc(-c3ccc(P(=S)(c4ccccc4)c4ccccc4)cc3)nc2c2nc(-c3ccccc3)ccc12]

17. The organic light-emitting device as claimed in claim 1, wherein:
the organic layer includes an emission layer and an electron transport region between the second electrode and the emission layer, the electron transport region including an electron transport layer,
the emission layer includes the at least one first material, and
the electron transport layer includes the at least one second material.

18. The organic light-emitting device as claimed in claim 17, wherein the emission layer is adjacent to the electron transport layer.

19. The organic light-emitting device as claimed in claim 1, wherein
the organic layer includes an emission layer and an electron transport region between the second electrode and the emission layer, the electron transport region including a buffer layer and an electron transport layer;
the electron transport layer is between the buffer layer and the second electrode;
the buffer layer includes the at least one first material, and
the electron transport layer includes the at least one second material.

20. The organic light-emitting device as claimed in claim 19, wherein the buffer layer is adjacent to the electron transport layer.
